(19) United States
(12) Patent Application Publication
(10) Pub. No.: US 2024/0292732 A1
(43) Pub. Date: Aug. 29, 2024

(54) ORGANOMETALLIC IRIDIUM COMPOUND AND APPLICATION THEREOF

(71) Applicant: GUANGDONG AGLAIA OPTOELECTRONIC MATERIALS CO., LTD., Foshan, Guangdong (CN)

(72) Inventors: Shaofu CHEN, Foshan (CN); Zhiqiao CHENG, Foshan (CN); Liangliang YAN, Foshan (CN); Lei DAI, Foshan (CN); Lifei CAI, Foshan (CN)

(73) Assignee: GUANGDONG AGLAIA OPTOELECTRONIC MATERIALS CO., LTD., Foshan, Guangdong (CN)

(21) Appl. No.: 18/289,445

(22) PCT Filed: Feb. 26, 2022
(86) PCT No.: PCT/CN2022/078117

§ 371 Date: Nov. 3, 2023

(30) Foreign Application Priority Data
May 18, 2021 (CN) 202110538115.6

(51) Int. Cl. H10K 85/30; C07F 15/00; C09K 11/06; H10K 50/12

(52) U.S. Cl. CPC H10K 85/342; C07F 15/0033; C09K 11/06; C07B 2200/05; C09K 2211/1044; C09K 2211/185; H10K 50/12

(57) ABSTRACT

The present invention relates to an organometallic iridium compound and application thereof. The organometallic iridium compound has a structure represented by Formula (1). The compound provided by the present invention has the advantages of high optical and electrochemical stability, narrow emission half-peak width, high color saturation, high luminous efficiency, long device service life and the like, and can be used in organic electroluminescent devices. In particular, the compound has the potential for application in the AMOLED industry as a green light-emitting dopant.

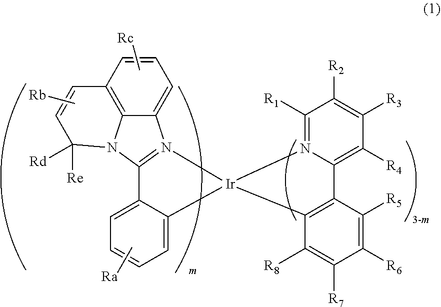

### TECHNICAL FIELD

The present invention relates to the technical field of organic electroluminescence, in particular to an organic light-emitting material applicable to organic electroluminescent devices, and specially relates to an organometallic iridium compound and application thereof in an organic electroluminescent device.

### BACKGROUND

At present, as a new-generation display technology, an organic electroluminescent device (OLED) has attracted more and more attention in display and lighting technologies, thus having a wide application prospect. However, compared with market application requirements, properties, such as luminous efficiency, driving voltage and service life, of the OLED still need to be strengthened and improved.

In generally, the OLED includes various organic functional material films with different functions sandwiched between metal electrodes as a basic structure, which is similar to a sandwich structure. Under the driving of a current, holes and electrons are injected from a cathode and an anode, respectively. After moving to a certain distance, the holes and the electrons are compounded in a light-emitting layer, and then released in the form of light or heat to achieve luminescence of the OLED.

However, organic functional materials are core components of the OLED, and the thermal stability, photochemical stability, electrochemical stability, quantum yield, film forming stability, crystallinity, color saturation and the like of the materials are main factors affecting properties of the device.

Generally, the organic functional materials include fluorescent materials and phosphorescent materials. The fluorescent materials are usually organic small-molecule materials, which can only utilize 25% of a singlet state for luminescence, so that the luminous efficiency is relatively low. Meanwhile, due to an earth-spin orbit coupling effect caused by a heavy atom effect, the phosphorescent materials can utilize 25% of a singlet state and can also utilize 75% of the energy of triplet excitons, so that the luminous efficiency can be improved. However, compared with the fluorescent materials, the phosphorescent materials are developed later, and the thermal stability, service life, color saturation and the like of the materials need to be improved. Thus, the phosphorescent materials have become a challenging topic. Various organometallic iridium compounds have been developed to serve as the phosphorescent materials. For example, an invention patent (CN1726606) discloses an arylbenzimidazole iridium compound. However, the luminous efficiency of the compound is far from enough to meet market demands. A non-patent document published by Wen et al. in 2004 (Chem. Mater. 2004, 16, 2480-2488) discloses a benzimidazole-aromatic ring metallic iridium complex, which has certain luminous efficiency. However, due to too large half-peak width and short device service life, especially short T95, of the material, market application demands are difficult to meet, and the material needs to be further improved. An invention patent document (CN102272261) discloses an iridium compound connected with aryl-substituted benzimidazole having steric hindrance on N. However, the color saturation, the emission spectrum half-peak width and device properties, especially the luminous efficiency and the device service life, of the compound need to be improved. An invention patent document (CN103396455) discloses a substituted benzimidazole iridium compound connected with alkyl on N. Similarly, the compound also has the problems of poor color saturation, too large emission spectrum half-peak width, low device efficiency, short device service life and the like, which need to be solved. An invention patent document (CN103254238) discloses an iridium compound connected with aryl-substituted benzimidazole-dibenzoheterocyclic ring having steric hindrance on N. However, the compound also has the problems of too large emission spectrum half-peak width, low device efficiency, short device service life and the like, which need to be solved. An invention patent document (CN102898477) discloses an iridium compound shown as

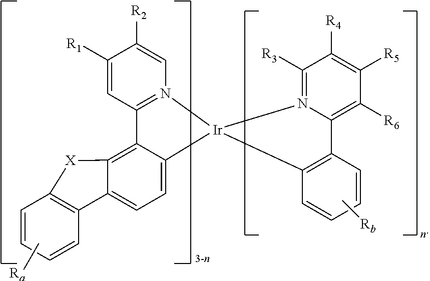

However, the compound also has the problems of too large emission spectrum half-peak width, low device efficiency, short device service life and the like, which need to be solved.

### SUMMARY

In order to overcome the above disadvantages, the present invention provides an organic electroluminescent device with high properties and an organometallic iridium compound material capable of realizing the organic electroluminescent device.

An organometallic iridium compound of the present invention has a structure represented by Formula (1). The iridium complex provided by the present invention has the advantages of high optical and electrical stability, narrow emission half-peak width, high luminous efficiency, long service life, high color saturation and the like, and can be used in organic light-emitting devices. In particular, the compound has the potential for application in the AMOLED industry as a green light-emitting phosphorescent material.

An organometallic iridium compound has a structure formula represented by Formula (1):

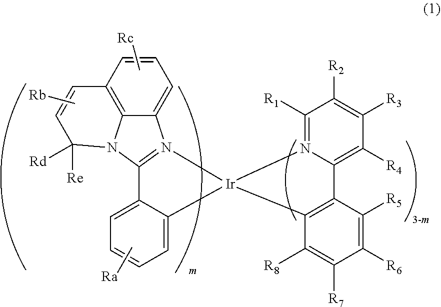

where

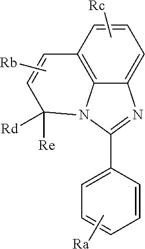

### is L1, and

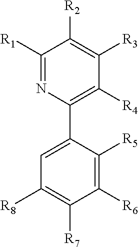

### is L2;

m is 1, 2 or 3, two L2 groups are the same or different when the m is 1, and multiple L1 groups are the same or different when the m is greater than 1;
the number of Ra, Rb and Rc is from 1 to a maximum substitution number;
Ra, Rb, Rc, Rd and Re are independently selected from hydrogen, deuterium, halogen, substituted or unsubstituted C₁-C₁₀ alkyl, substituted or unsubstituted C₃-C₂₀ cycloalkyl, substituted or unsubstituted C₆-C₁₈ aryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
at least one of the Rd and the Re is not hydrogen;
R₁-R₈ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl, or any two adjacent groups of the R₁-R₈ may be connected to each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

The m is 1 or 2, and the two L1 groups or the two L2 groups are the same.

As a optional organometallic iridium compound, at least one of the Rd and the Re is not hydrogen, and at least one of the Rd and the Re is substituted or unsubstituted C₁-C₆ alkyl, or substituted or unsubstituted C₃-C₆ cycloalkyl.

As a optional organometallic iridium compound, the Ra is hydrogen.

As a optional organometallic iridium compound, at least one of the R₁-R₄ is not hydrogen.

As a optional organometallic iridium compound, at least one of the R₅-R₈ is not hydrogen.

As a optional organometallic iridium compound, at least one of the R₁-R₄ is not hydrogen, and at least one of the R₅-R₈ is not hydrogen.

As a optional organometallic iridium compound, one of the R₁-R₄ is deuterium, C₁-C₅ alkyl substituted or unsubstituted with deuterium, or C₃-C₅ cycloalkyl substituted or unsubstituted with deuterium, one of the R₅-R₈ is deuterium, C₁-C₅ alkyl substituted or unsubstituted with deuterium, or C₃-C₅ cycloalkyl substituted or unsubstituted with deuterium, and the other groups are hydrogen.

As a optional organometallic iridium compound, the R₅ and the R₆, the R₆ and the R₇, or the R₇ and the R₈ are connected to each other to form a ring-fused structure represented by Formula (2):

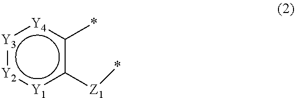

where * indicates a connecting position;
Y₁-Y₄ are independently CR₀ or N;
Z1 is selected from O and S;
R₀ is independently hydrogen, deuterium, F, cyano, substituted or unsubstituted C₁-C₁₀ alkyl, substituted or unsubstituted C₃-C₂₀ cycloalkyl, substituted or unsubstituted C₂-C₃₀ alkenyl, substituted or unsubstituted C₂-C₃₀ alkynyl, substituted or unsubstituted C₆-C₃₀ aryl, substituted or unsubstituted C₁-C₃₀ heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

As a optional organometallic iridium compound, the R₄ and the R₅ are connected to each other to form an aliphatic ring structure represented by Formula (3):

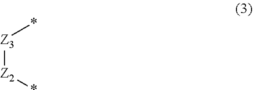

where * indicates a connecting position;
Z2 and Z3 are independently selected from O, S, N(R₀) and C(R₀)₂, and at least one of the Z2 and the Z3 is C(R₀)₂;
R₀ is independently hydrogen, deuterium, F, cyano, substituted or unsubstituted C₁-C₁₀ alkyl, substituted or unsubstituted C₃-C₂₀ cycloalkyl, substituted or unsubstituted C₂-C₃₀ alkenyl, substituted or unsubstituted C₂-C₃₀ alkynyl, substituted or unsubstituted C₆-C₃₀ aryl, substituted or unsubstituted C₁-C₃₀ heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

As a optional organometallic iridium compound, at least one of the Rb and the Rc is not hydrogen.

As a optional organometallic iridium compound, at least one of the Rb and the Rc is substituted or unsubstituted C₁-C₆ alkyl, or substituted or unsubstituted C₃-C₆ cycloalkyl.

As a optional organometallic iridium compounds, one of the Rb and the Rc is substituted or unsubstituted C₁-C₆ alkyl, or substituted or unsubstituted C₃-C₆ cycloalkyl, and the other groups are hydrogen.

As a optional organometallic iridium compound, the L1 optionally has one of the following structural formulas, or is partially or completely deuterated or fluorinated correspondingly,

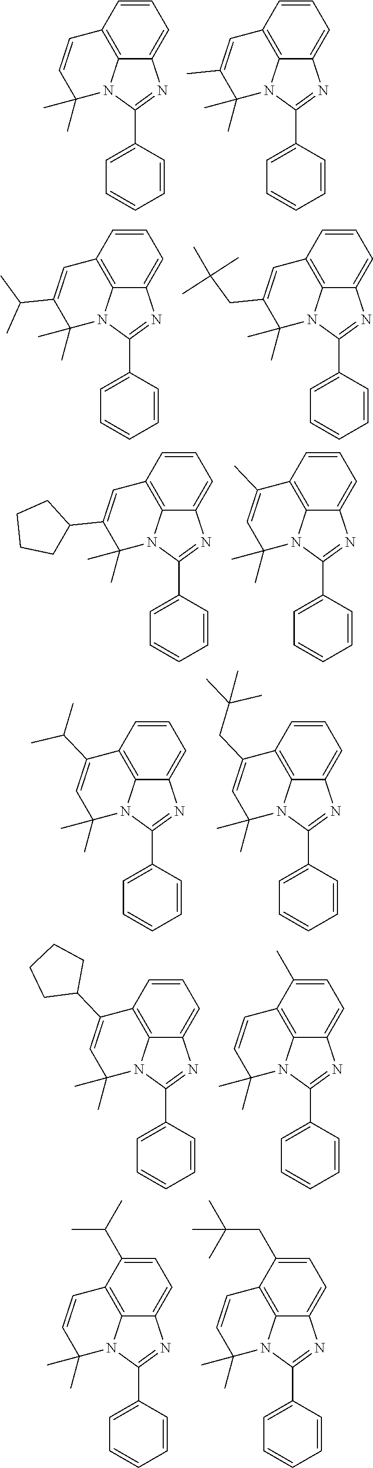

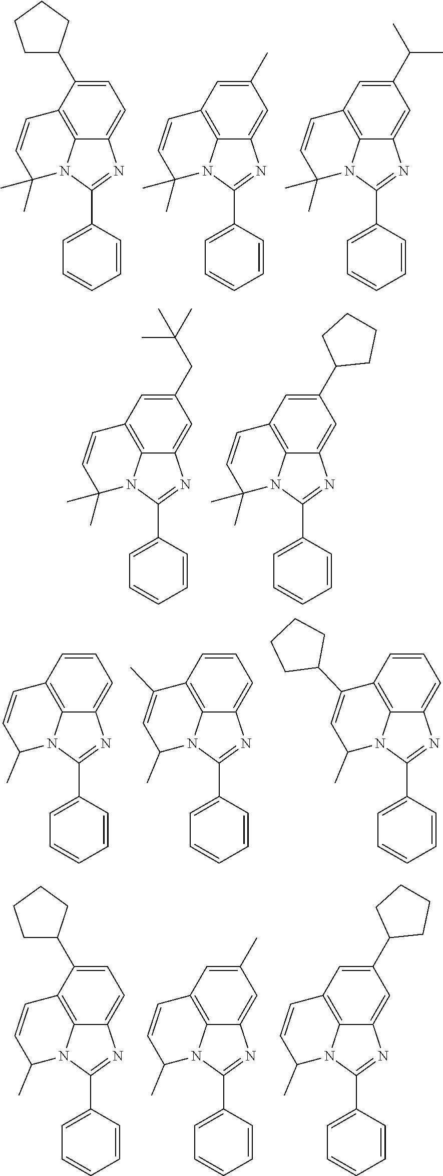

As a optional organometallic iridium compound, the L2 optionally has one of the following structural formulas, or is partially or completely deuterated or fluorinated correspondingly,

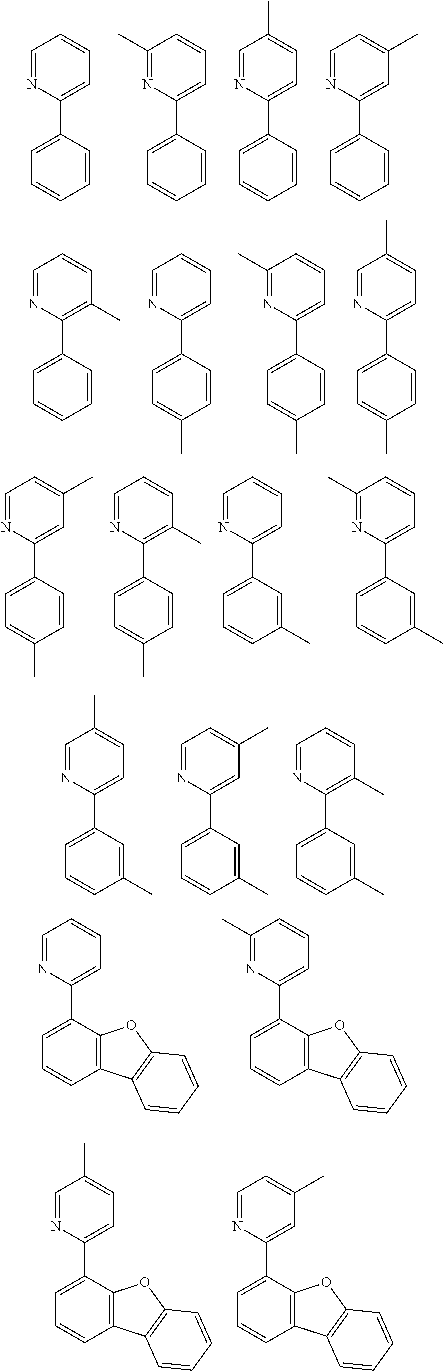

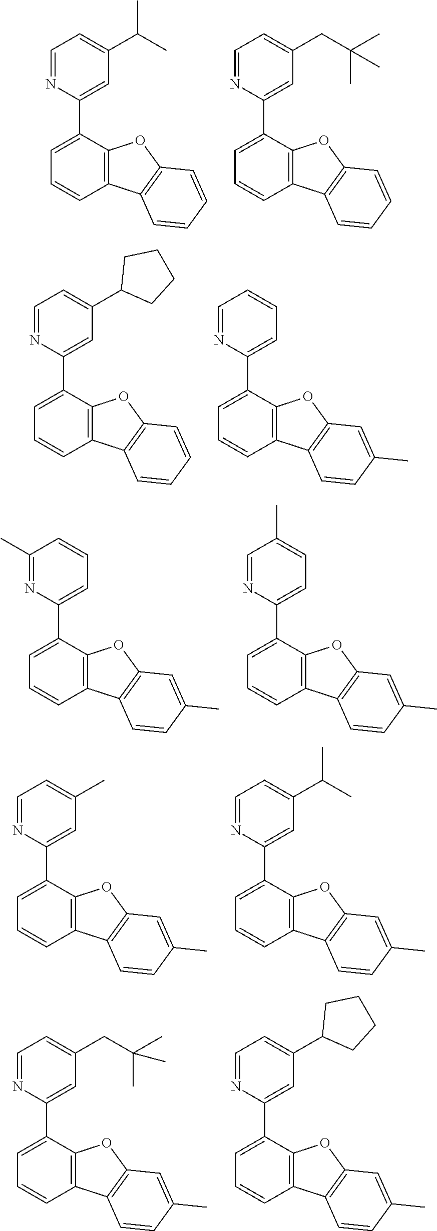

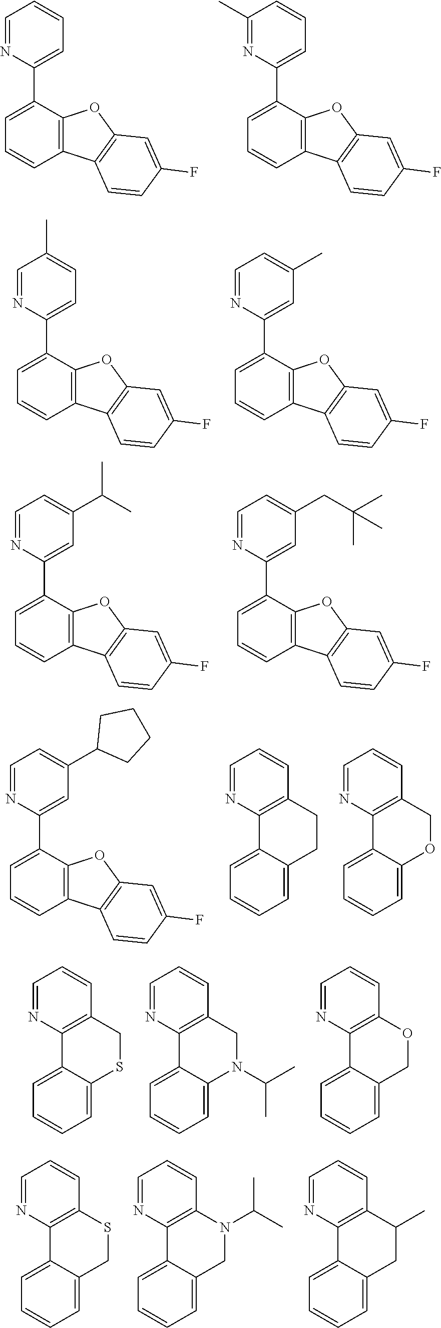

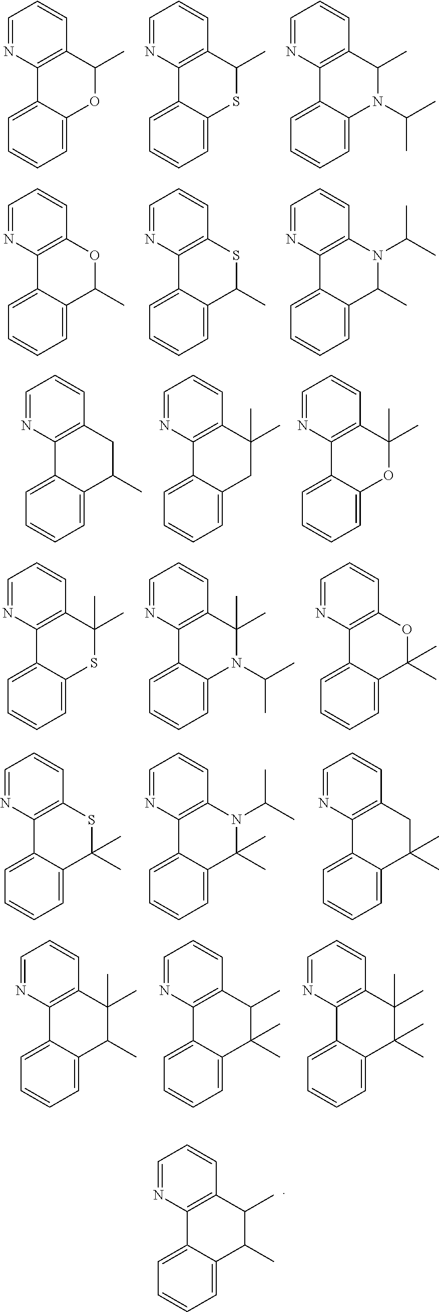

As a optional organometallic iridium compound, the compound represented by Formula (1) optionally has one of the following structural formulas, or is selected from corresponding partial or complete deuterides or fluorides thereof,

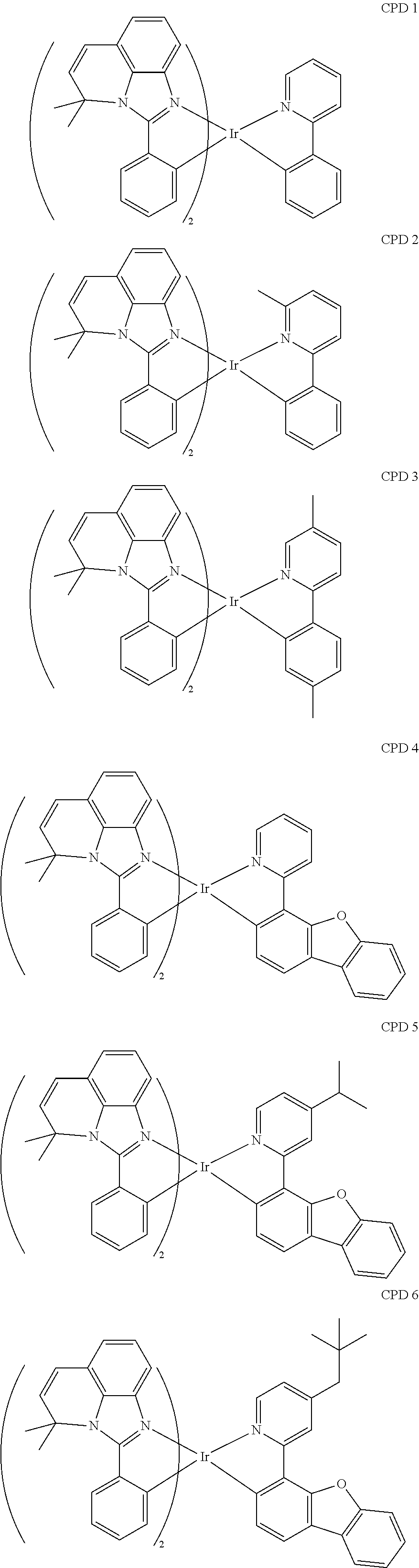

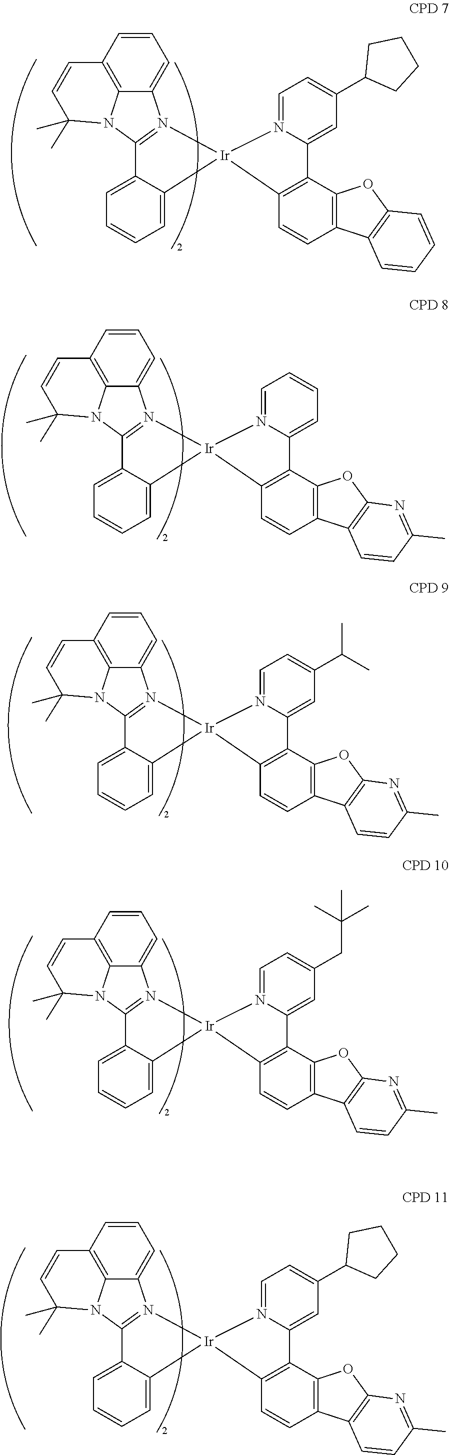

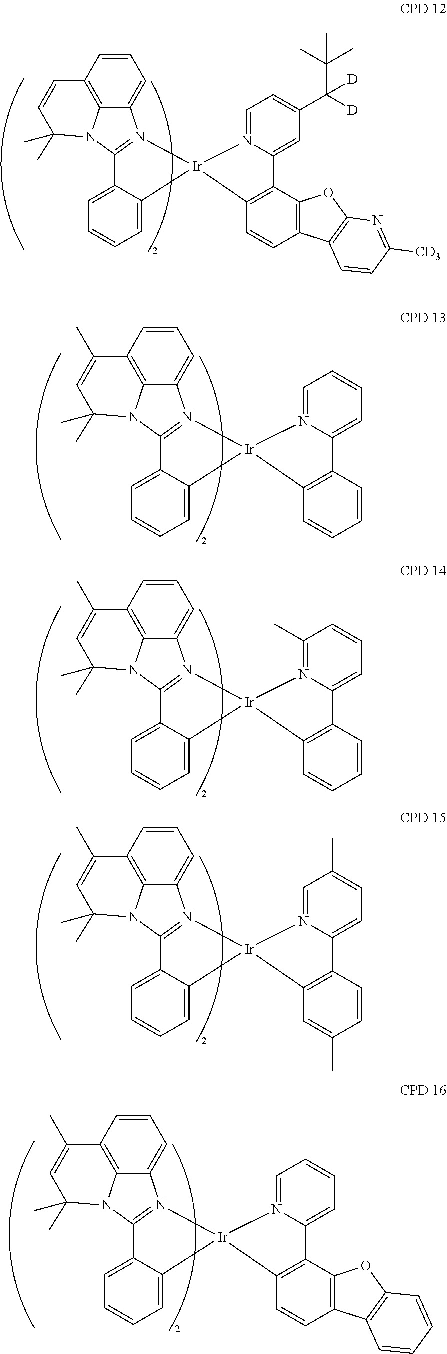

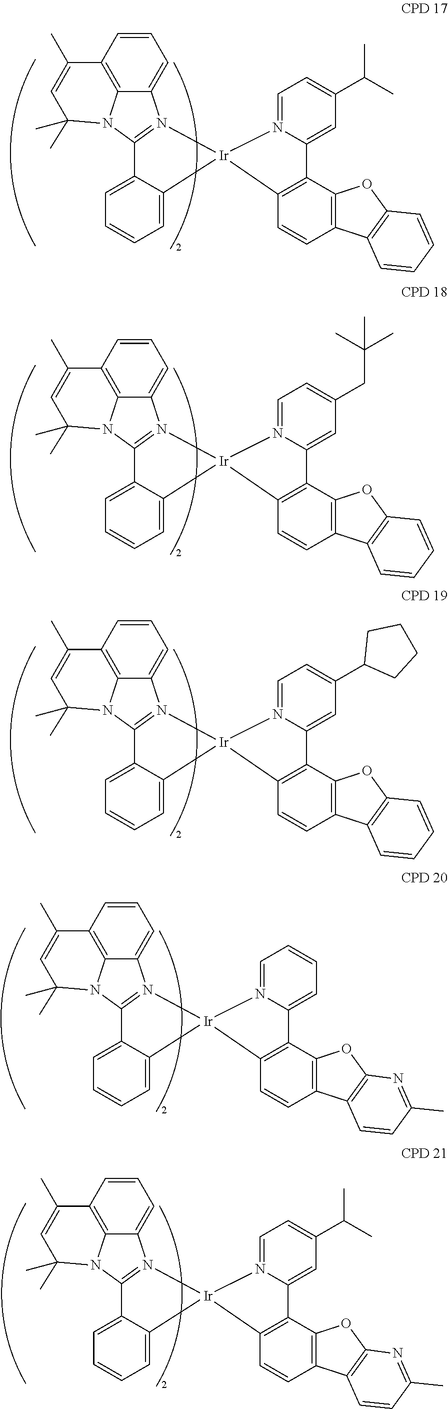

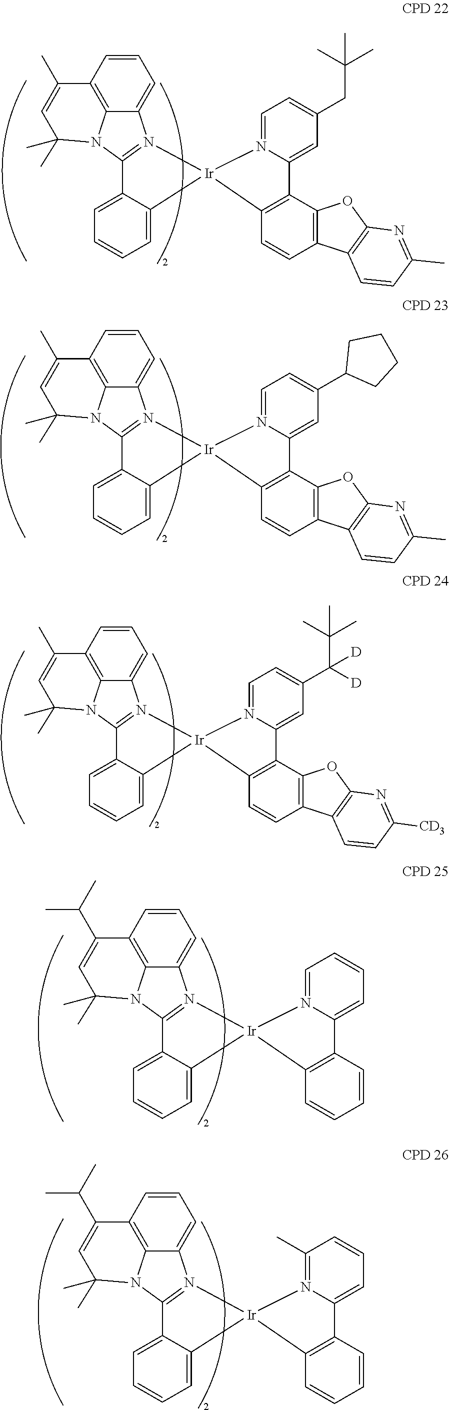

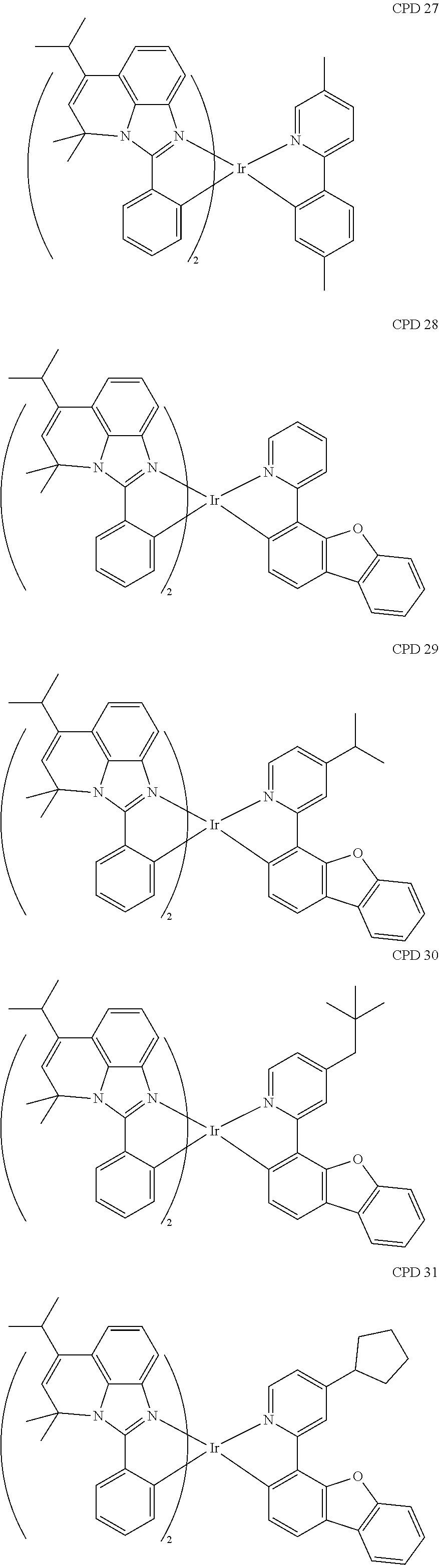

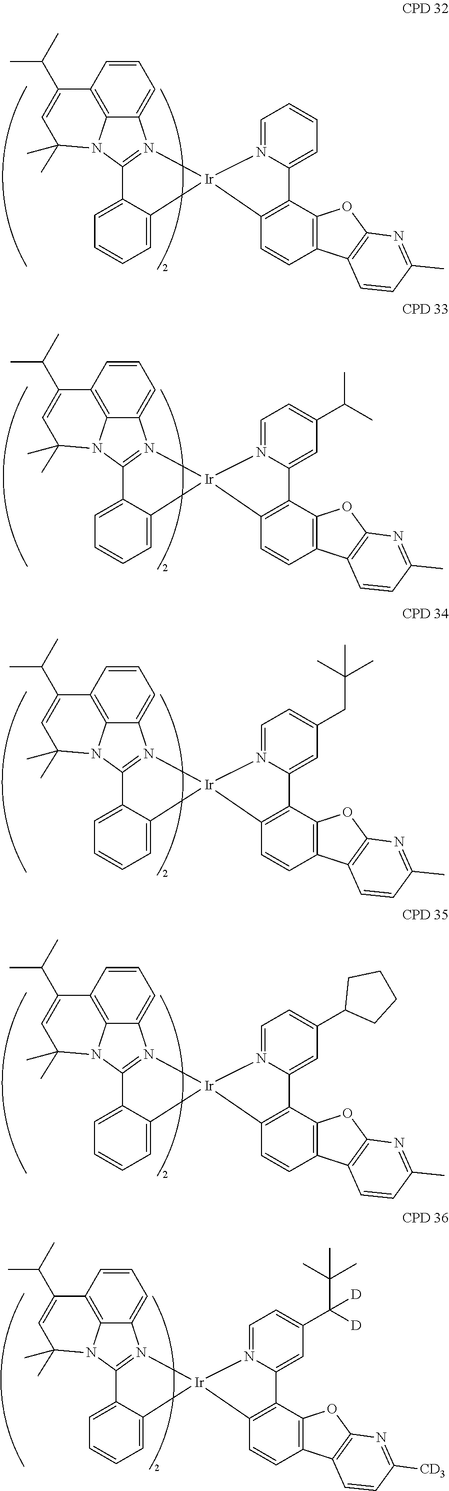

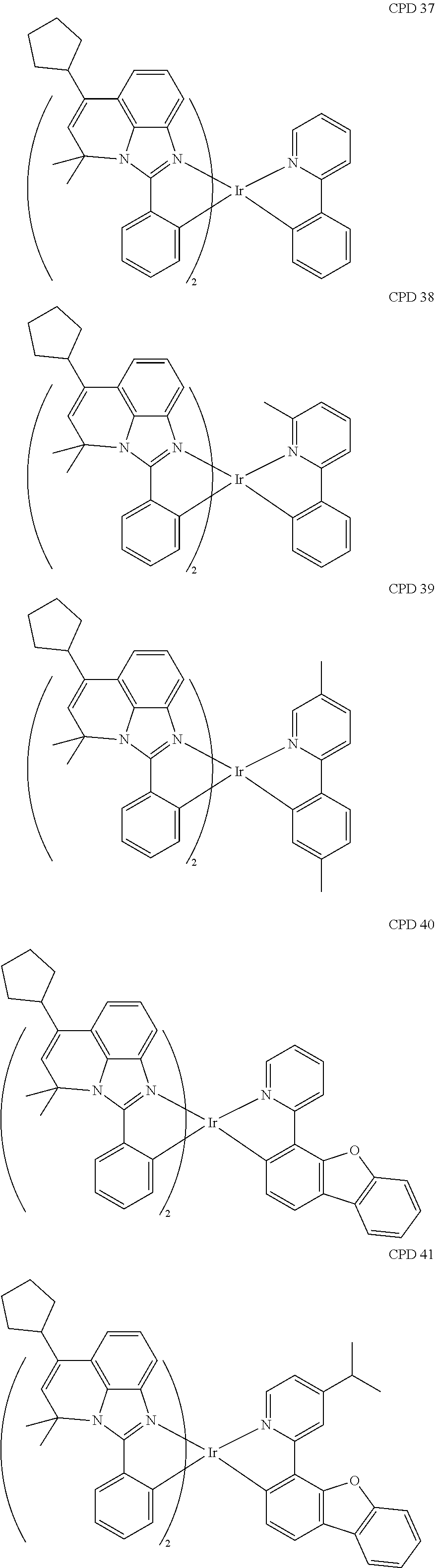

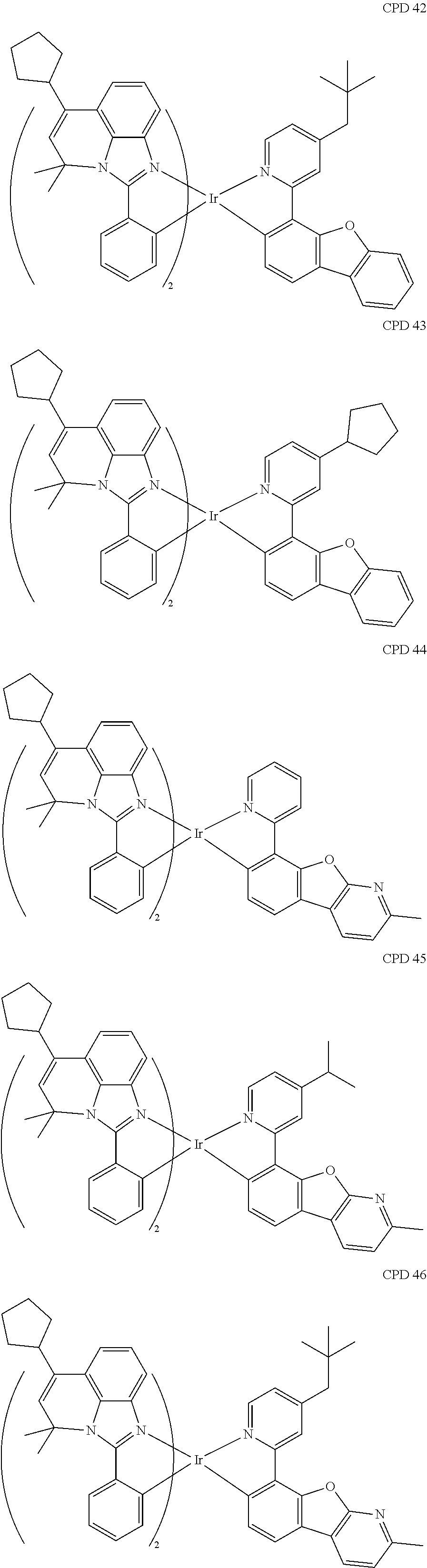

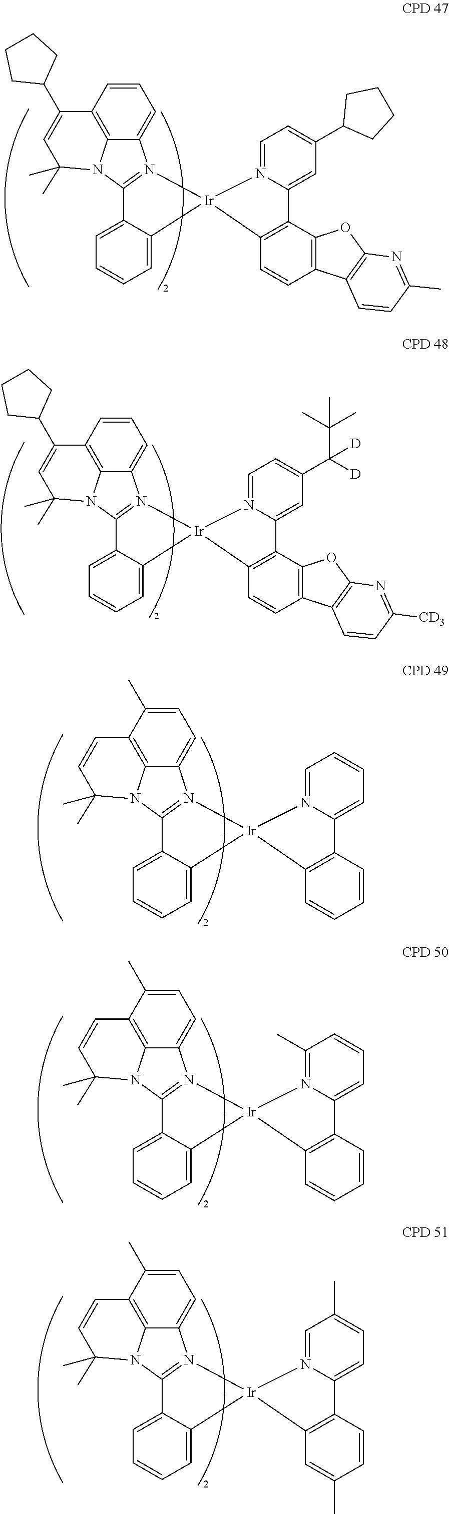

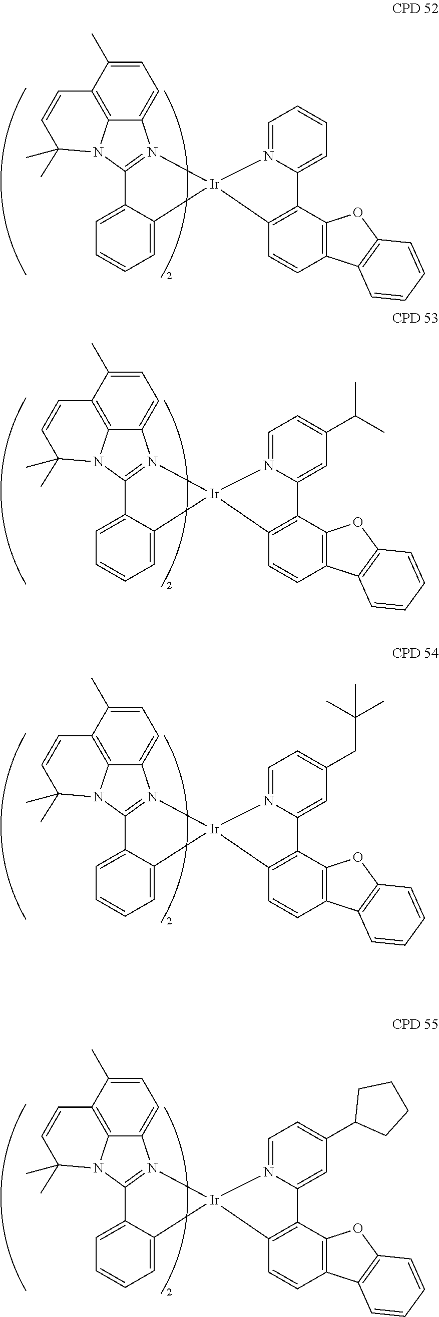

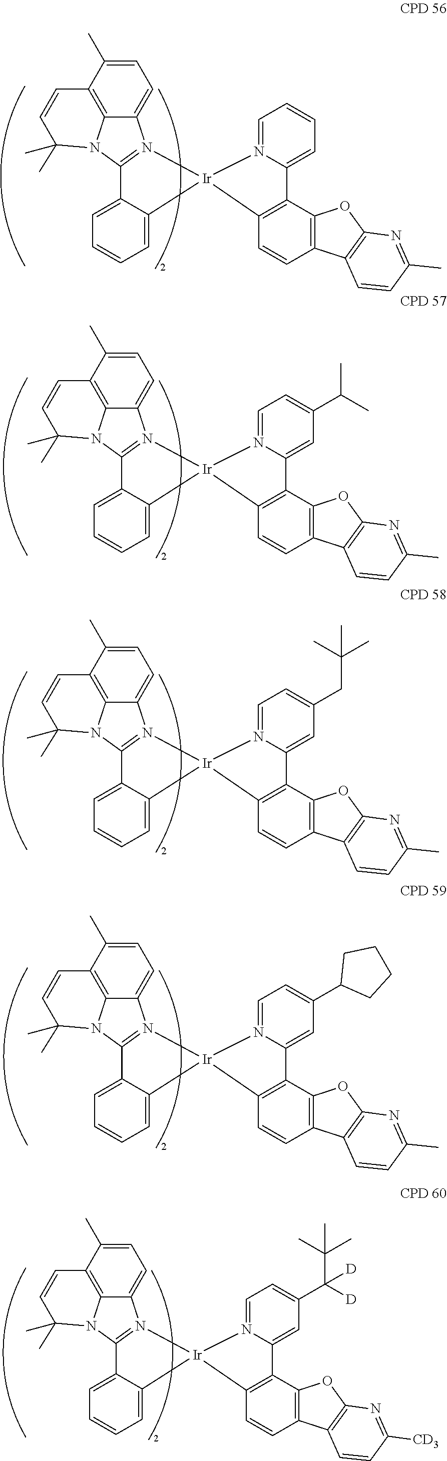

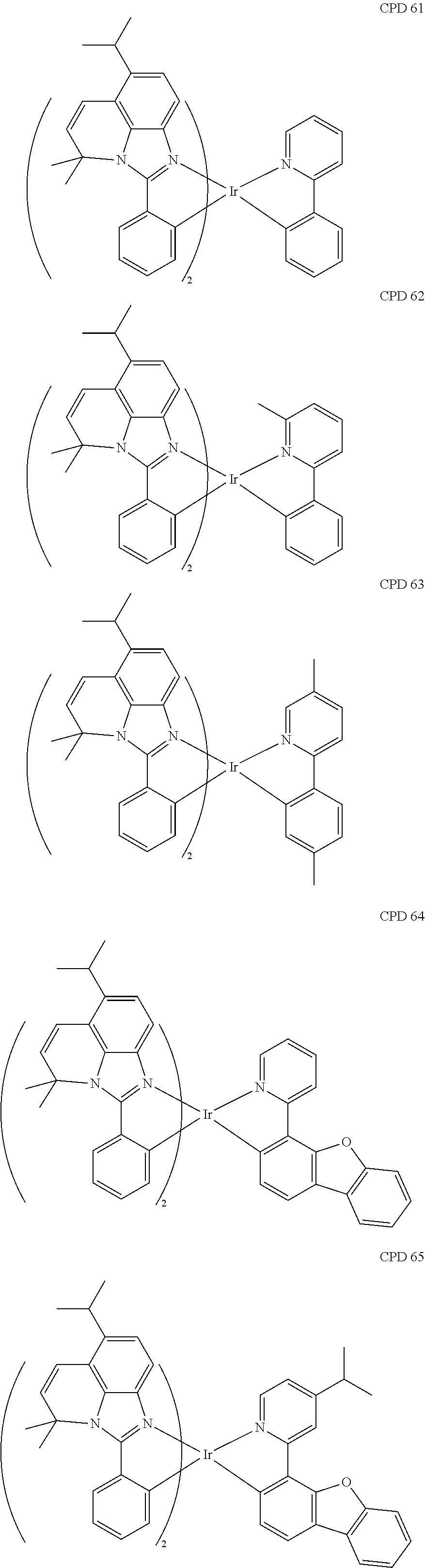

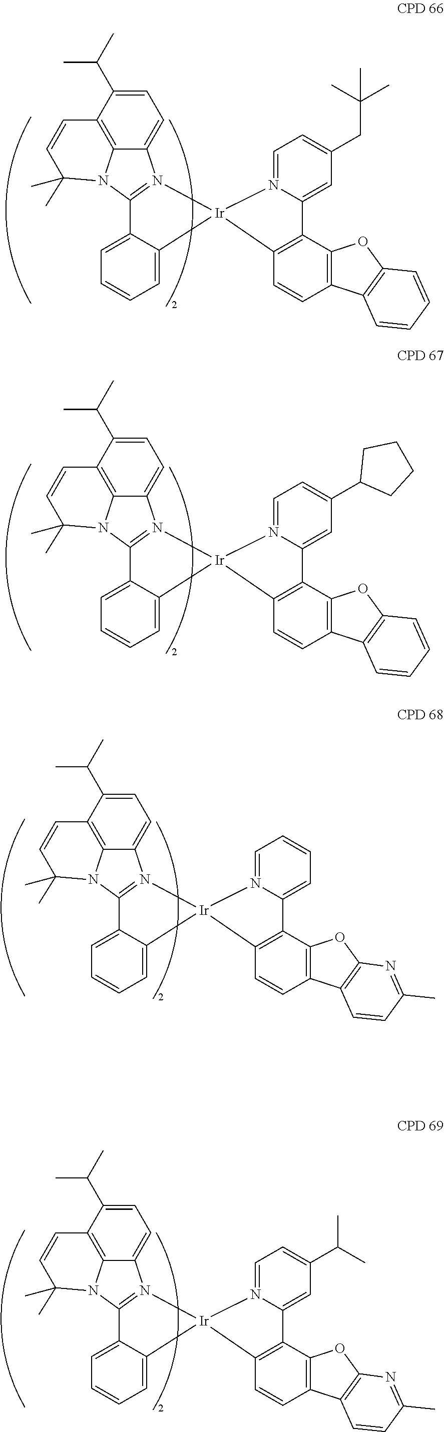

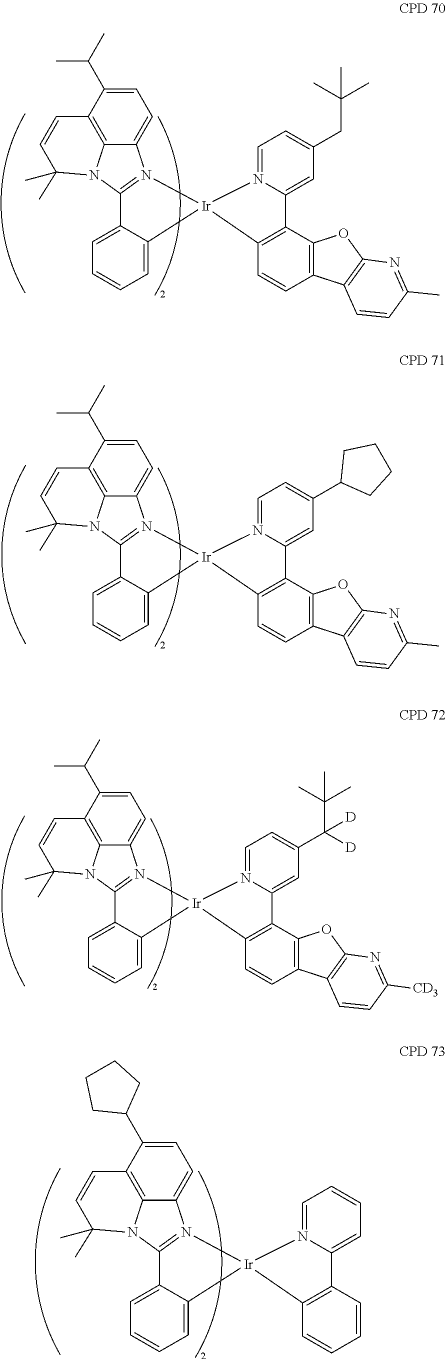

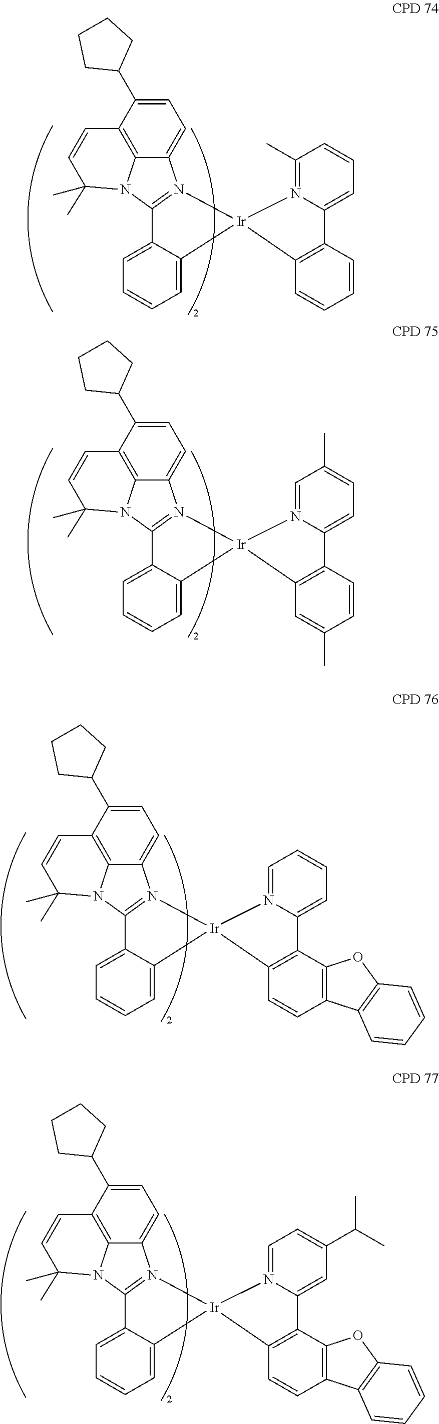

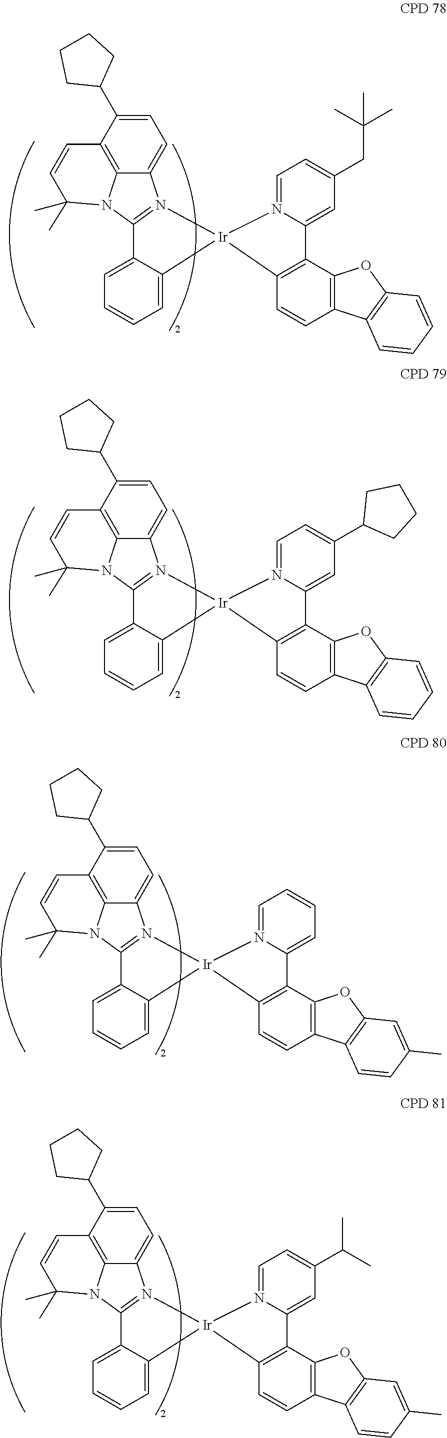

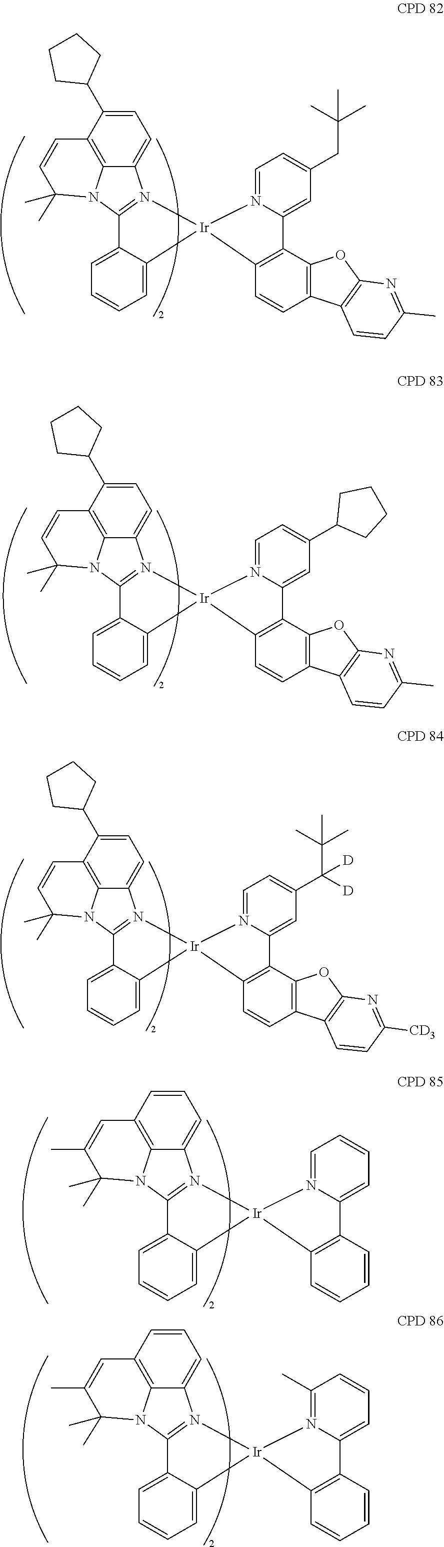

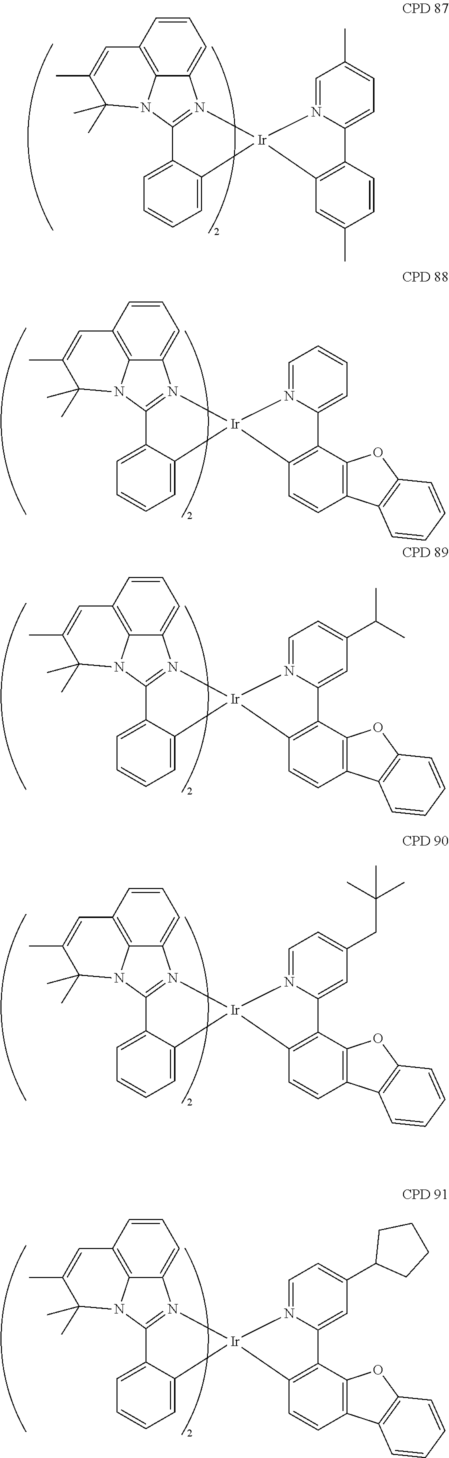

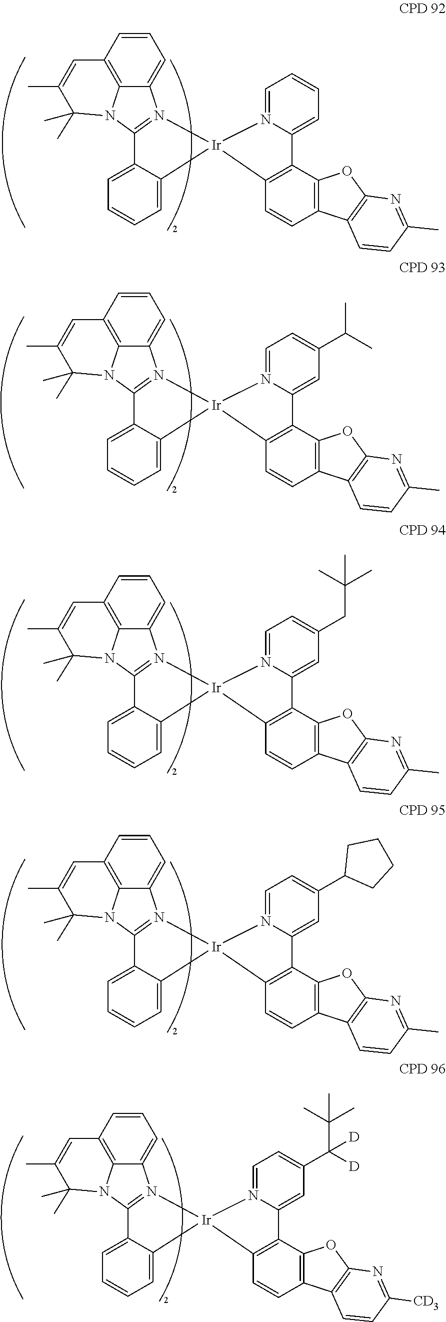

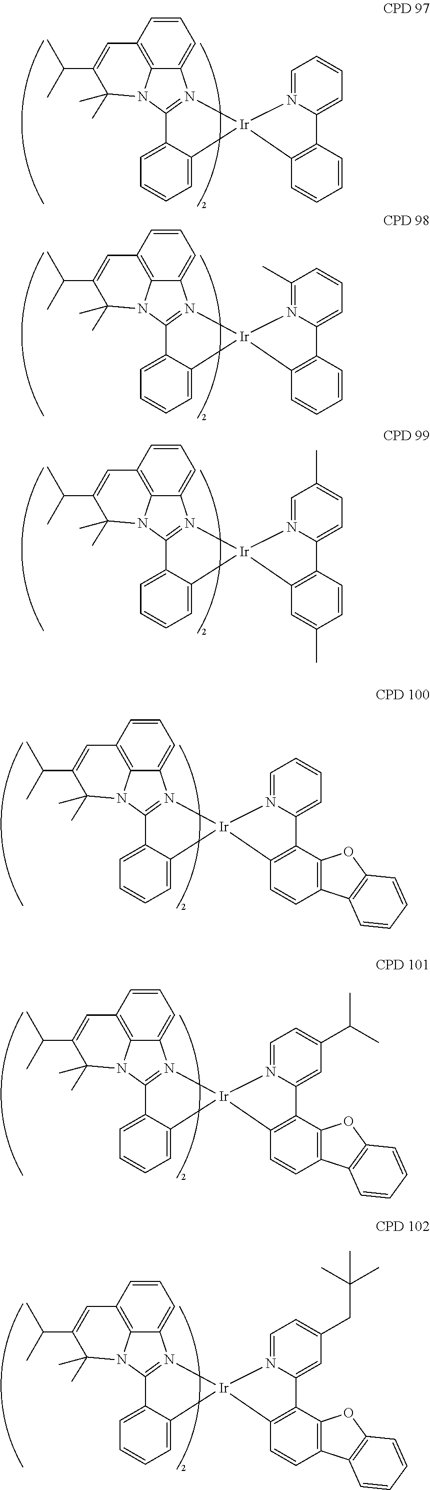

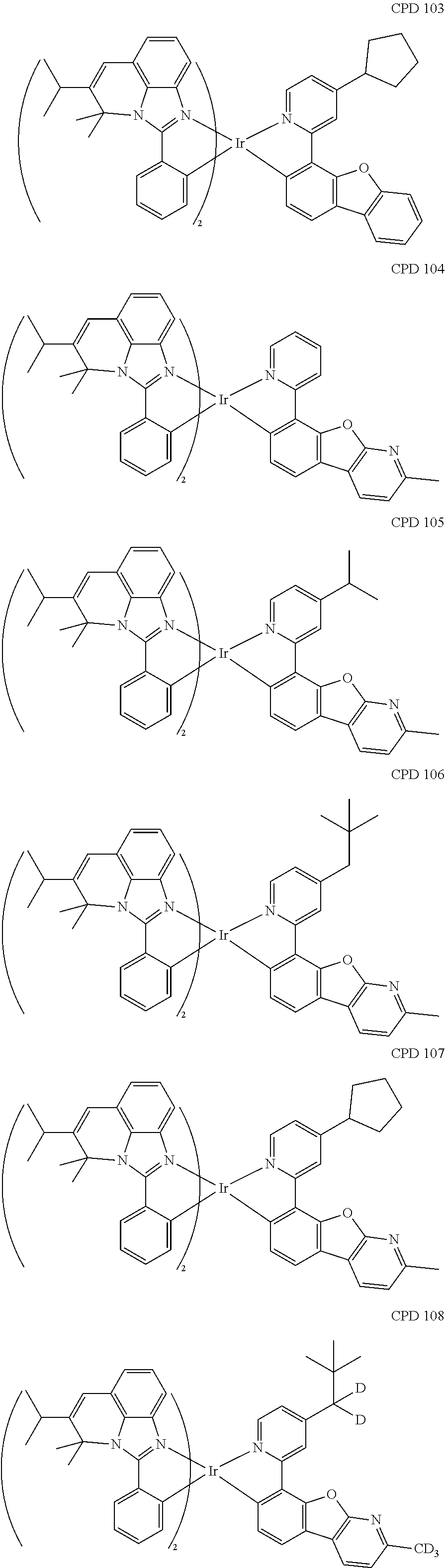

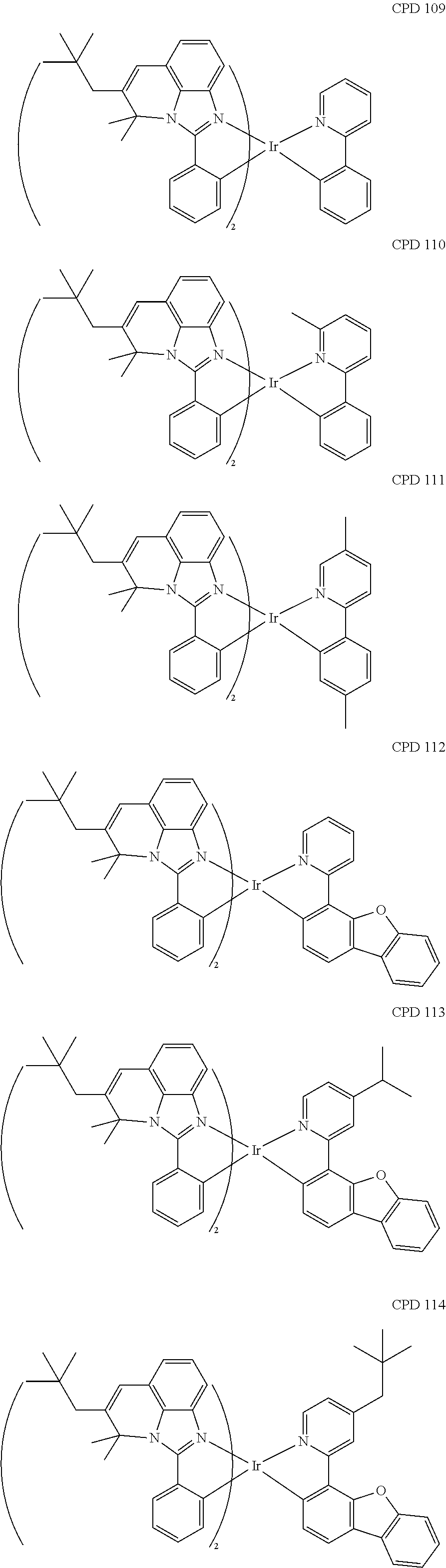

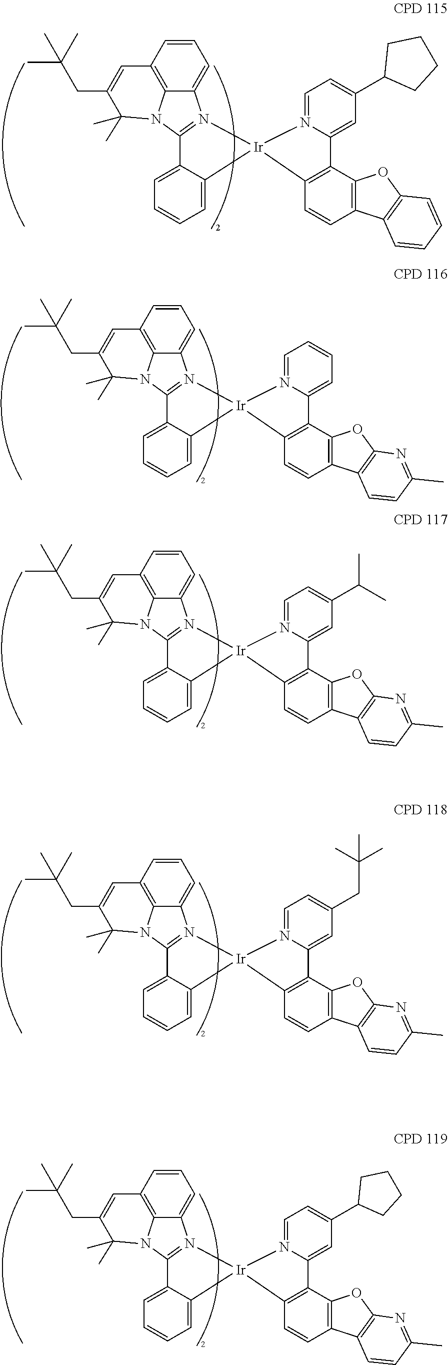

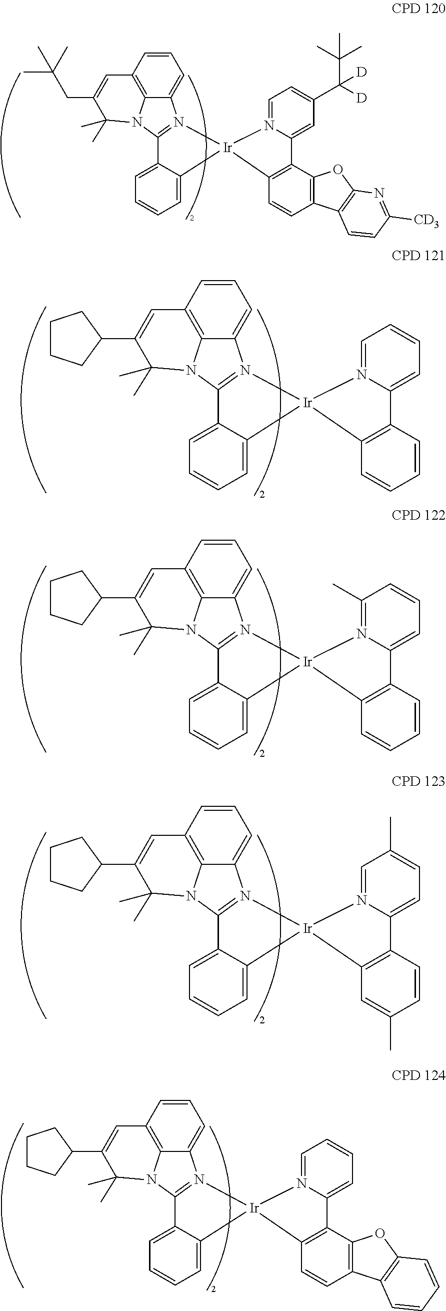

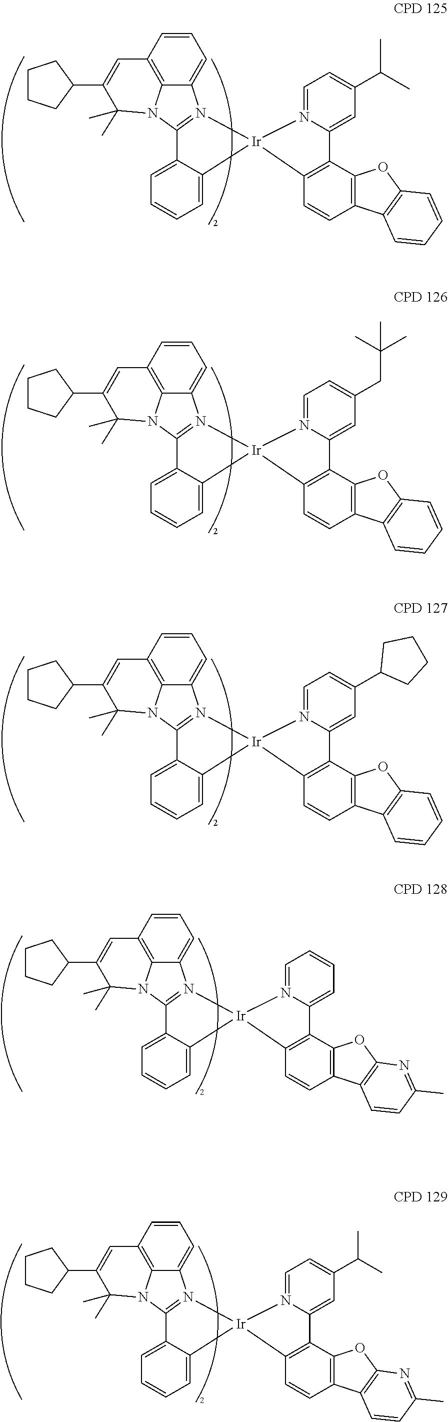

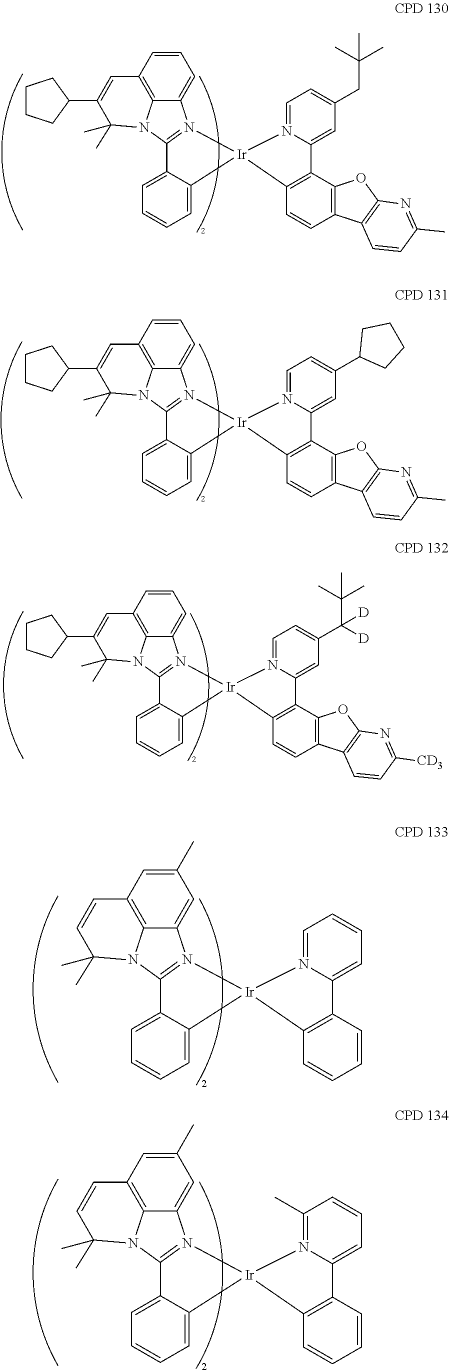

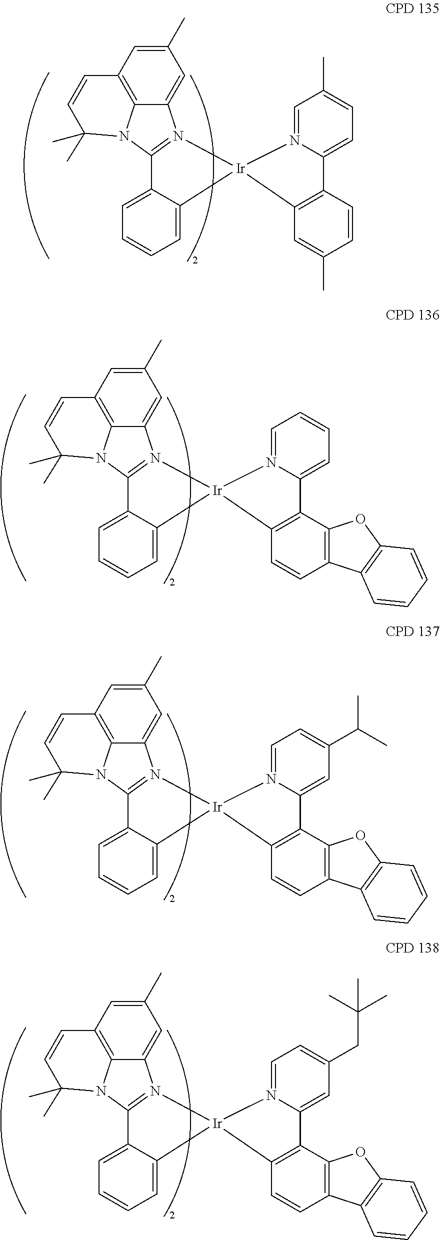

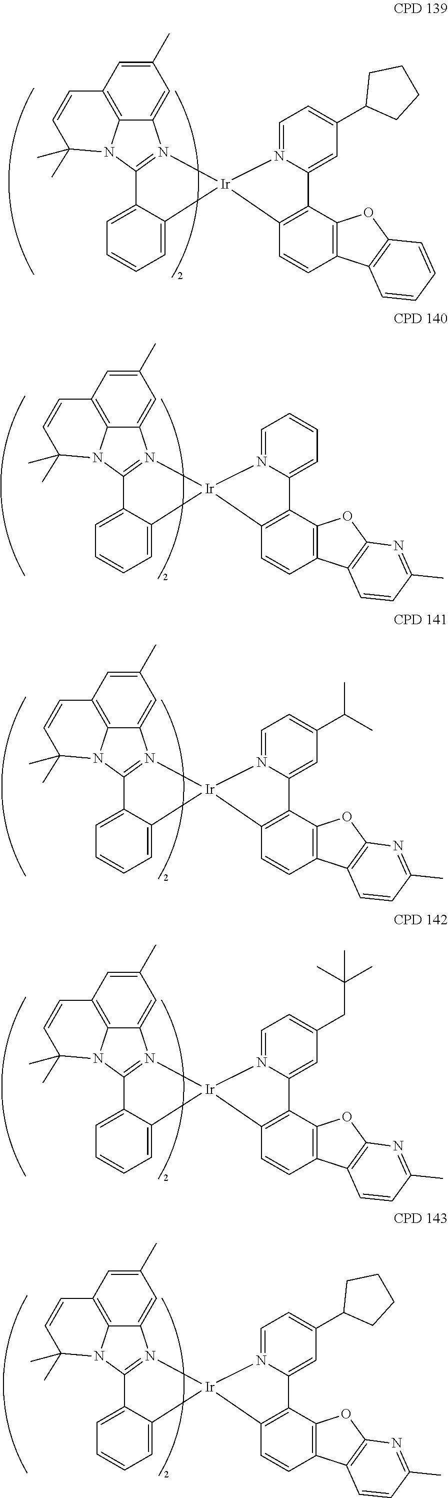

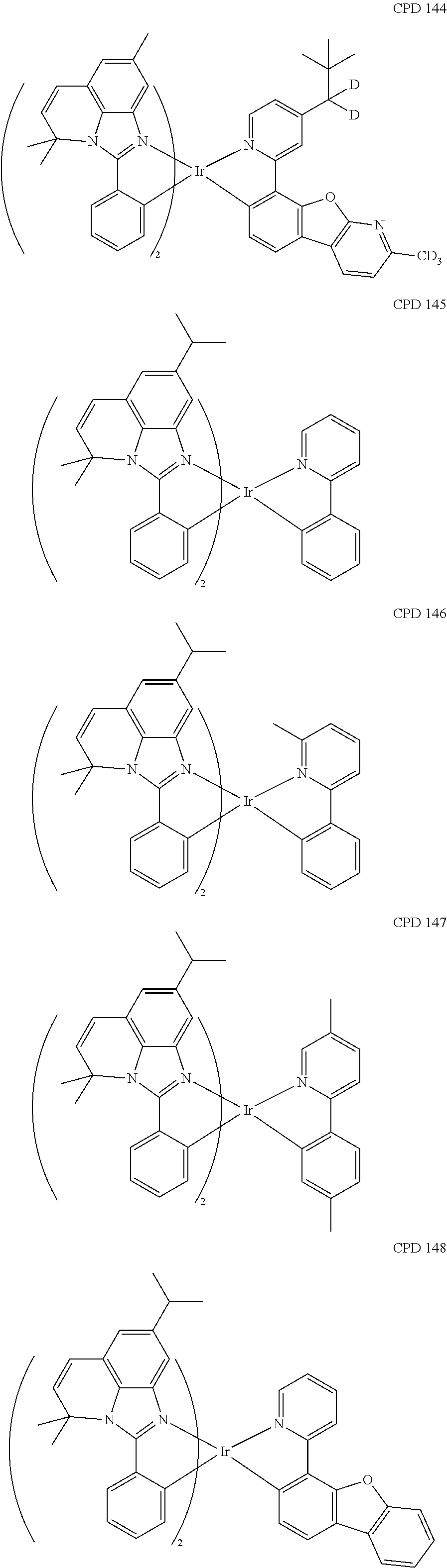

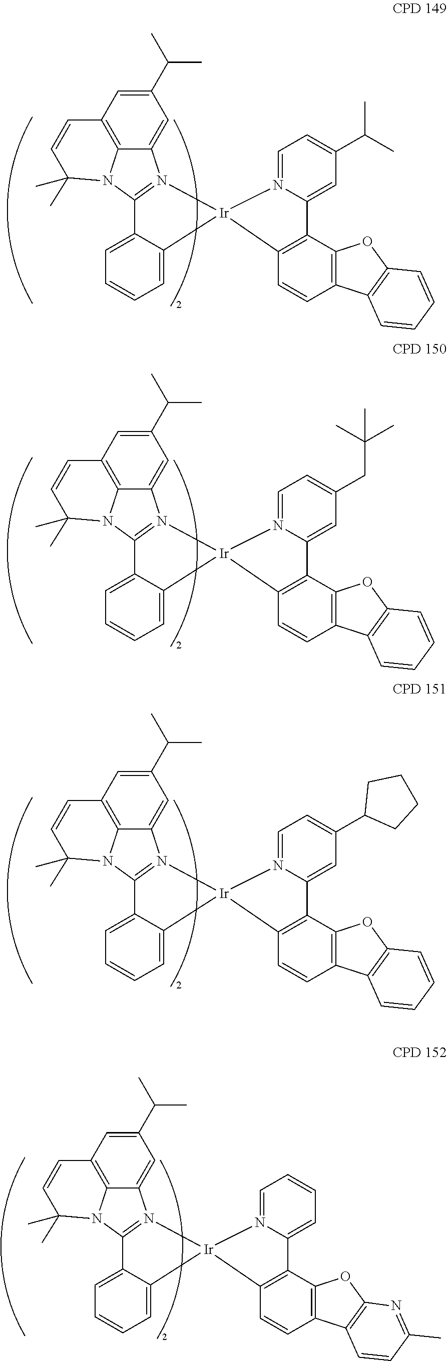

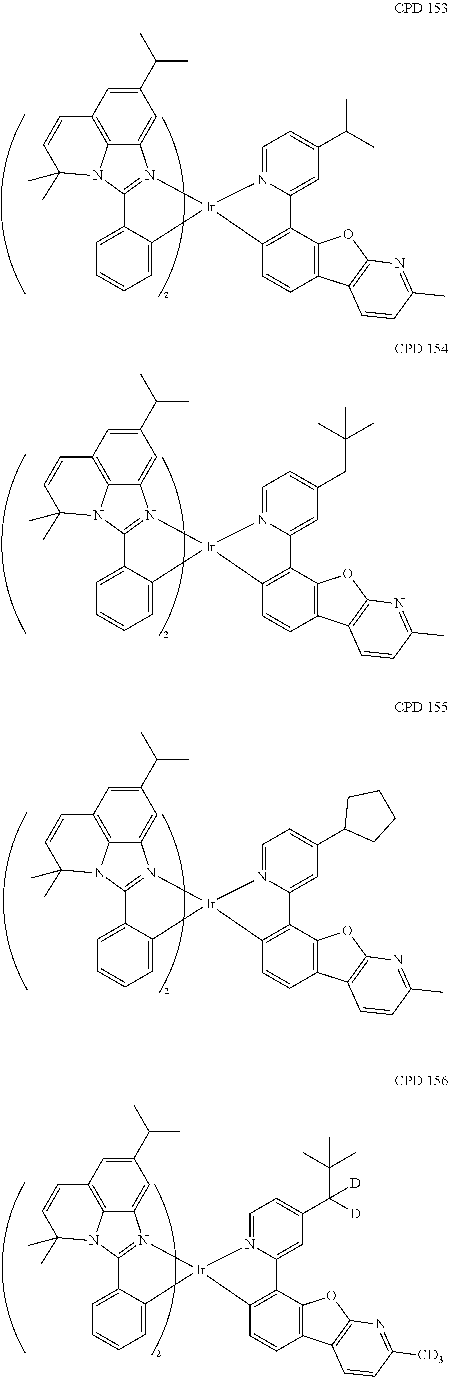

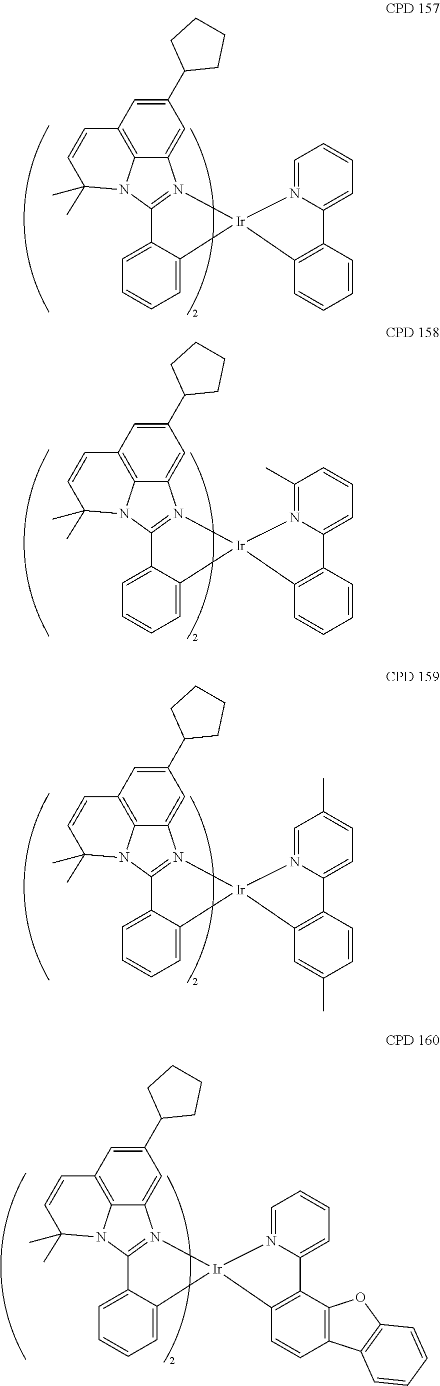

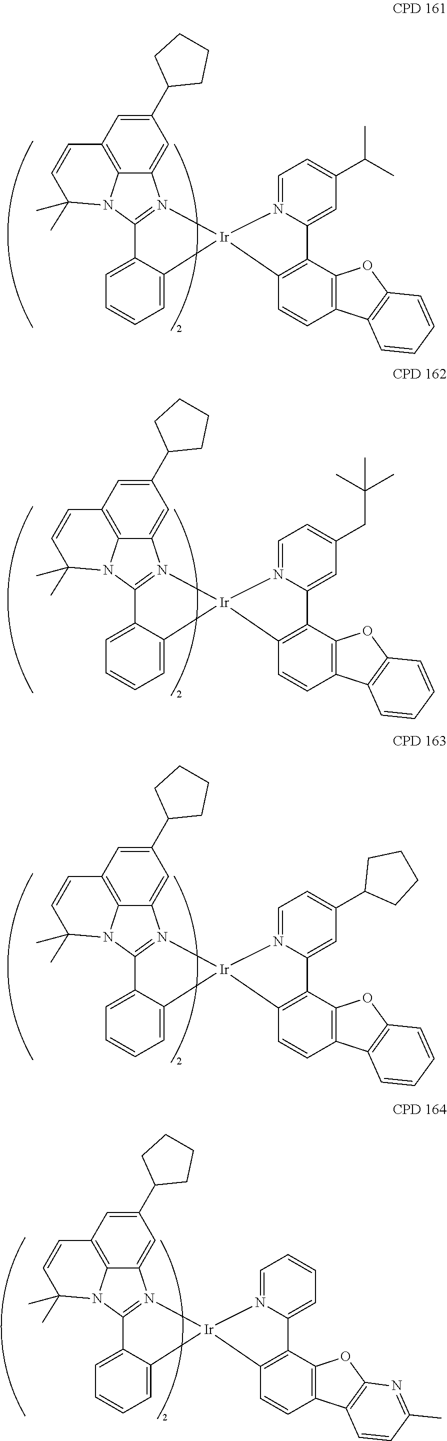

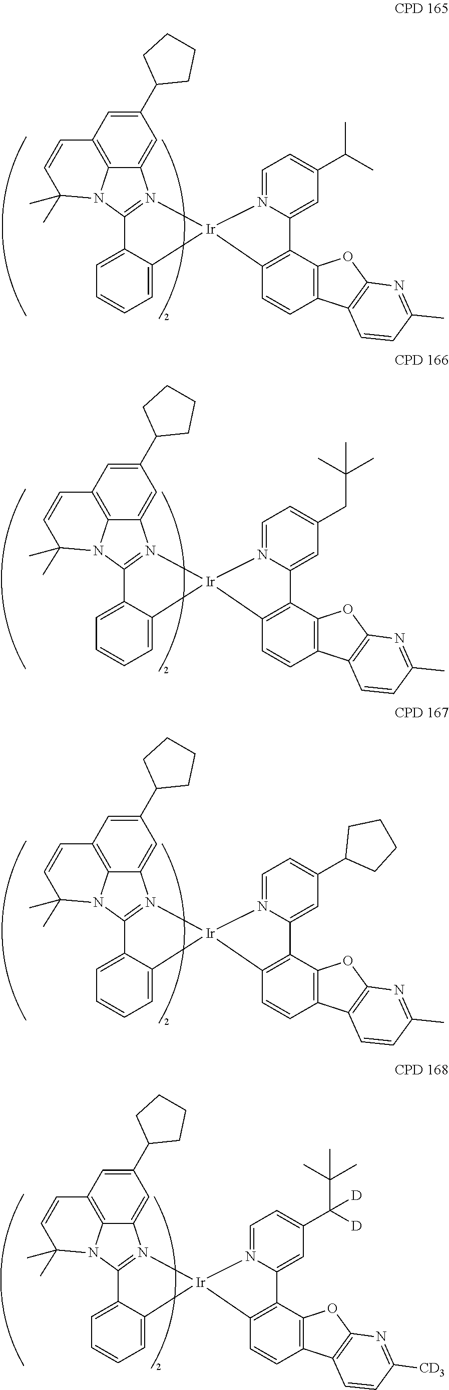

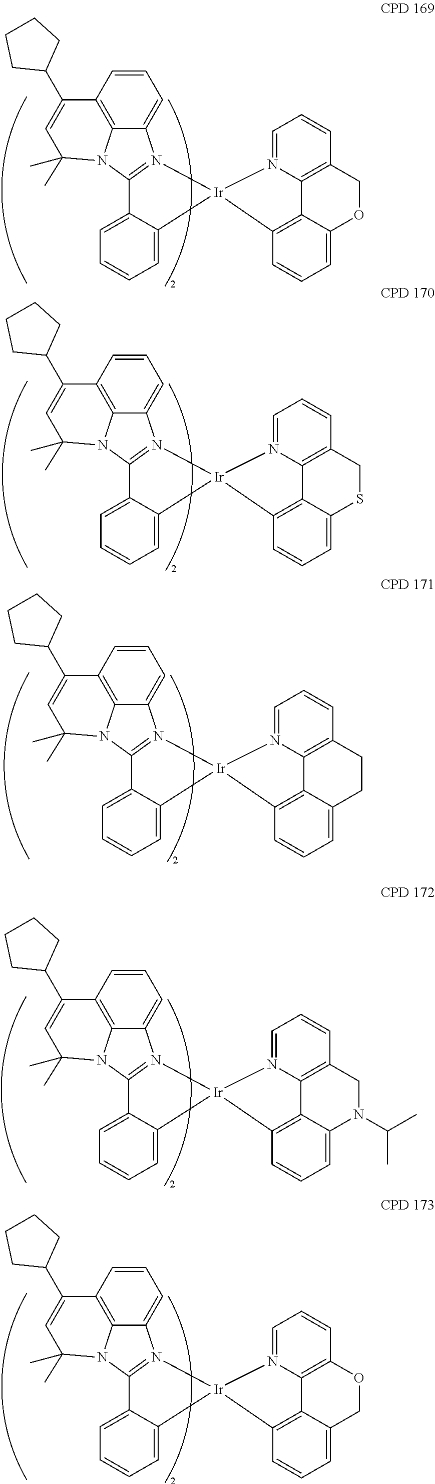

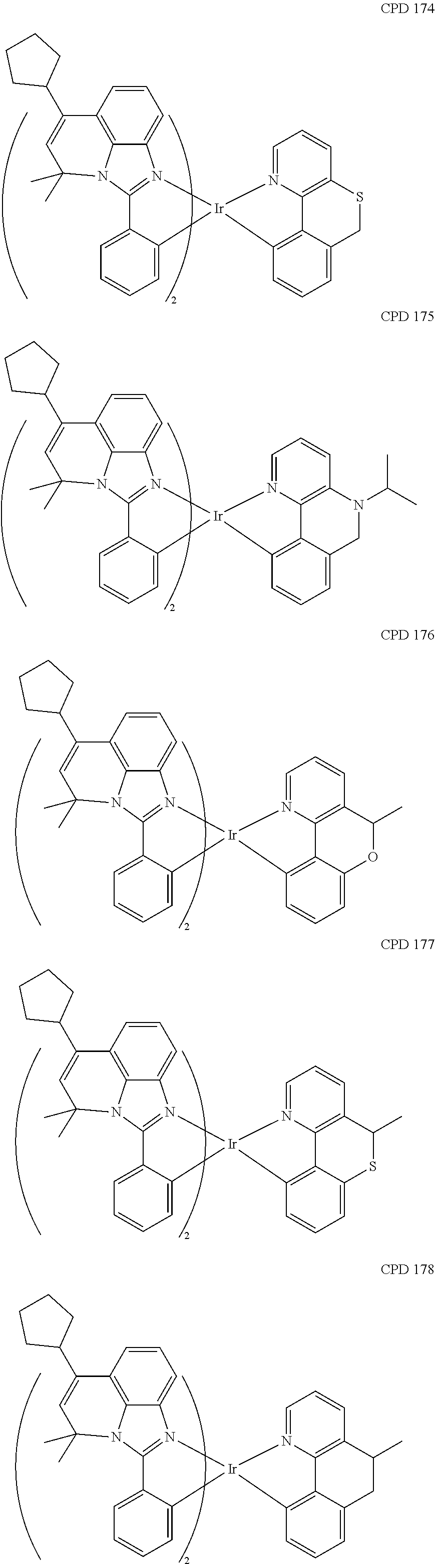

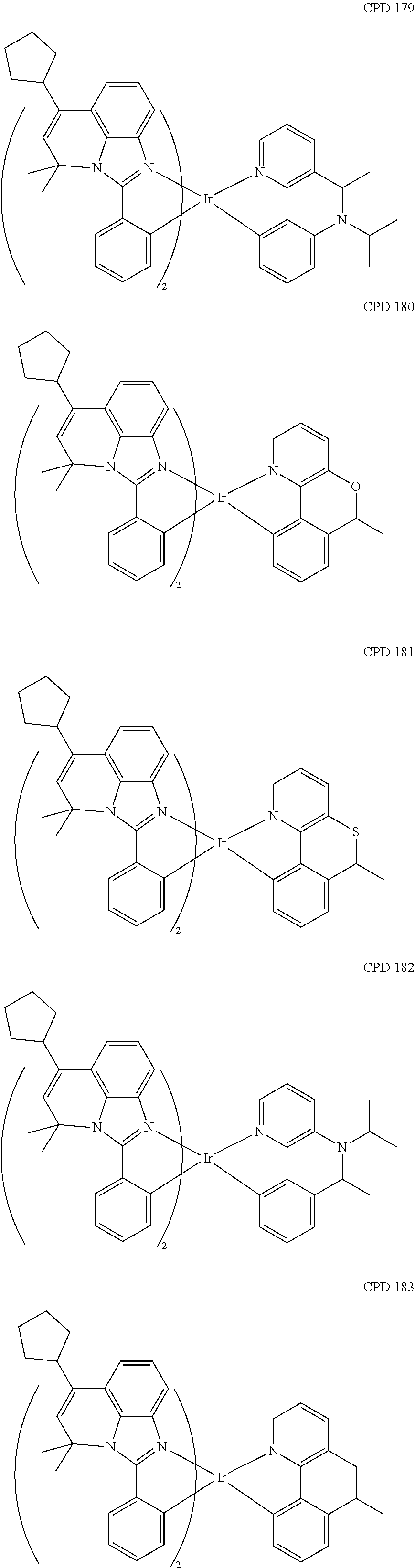

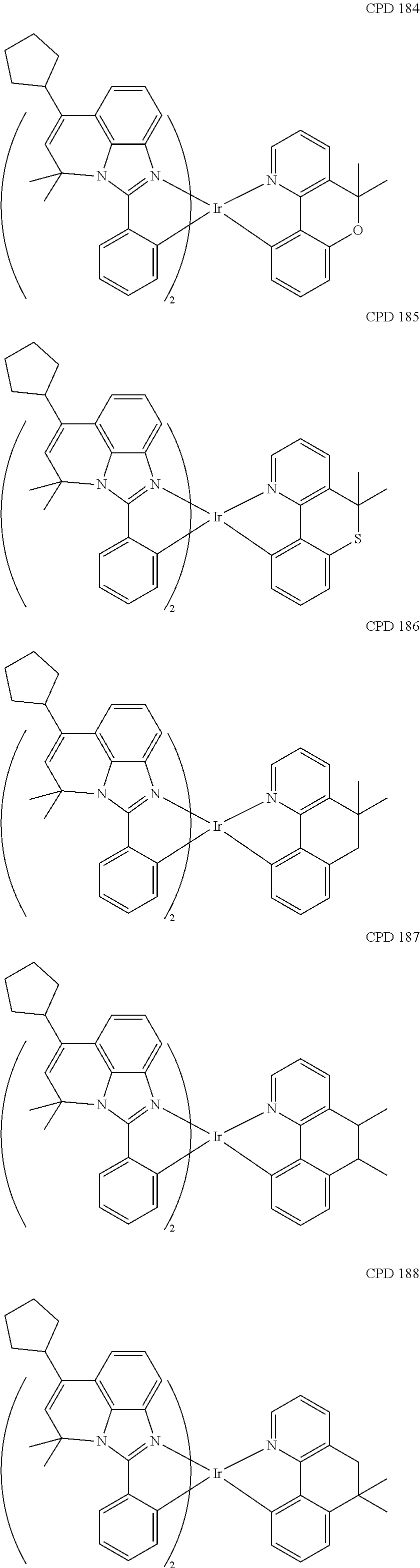

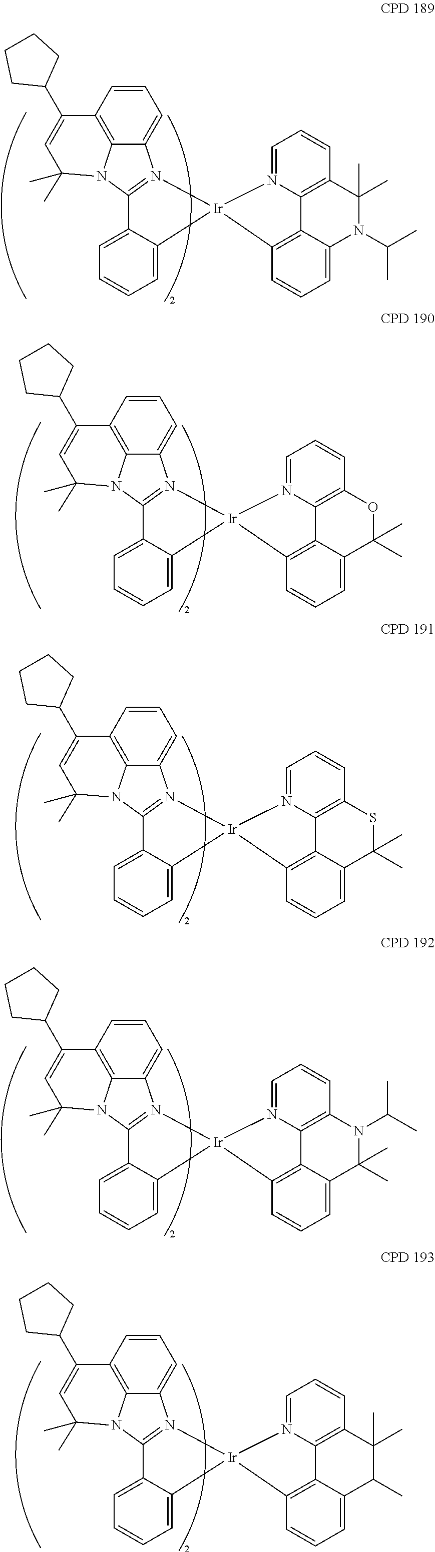

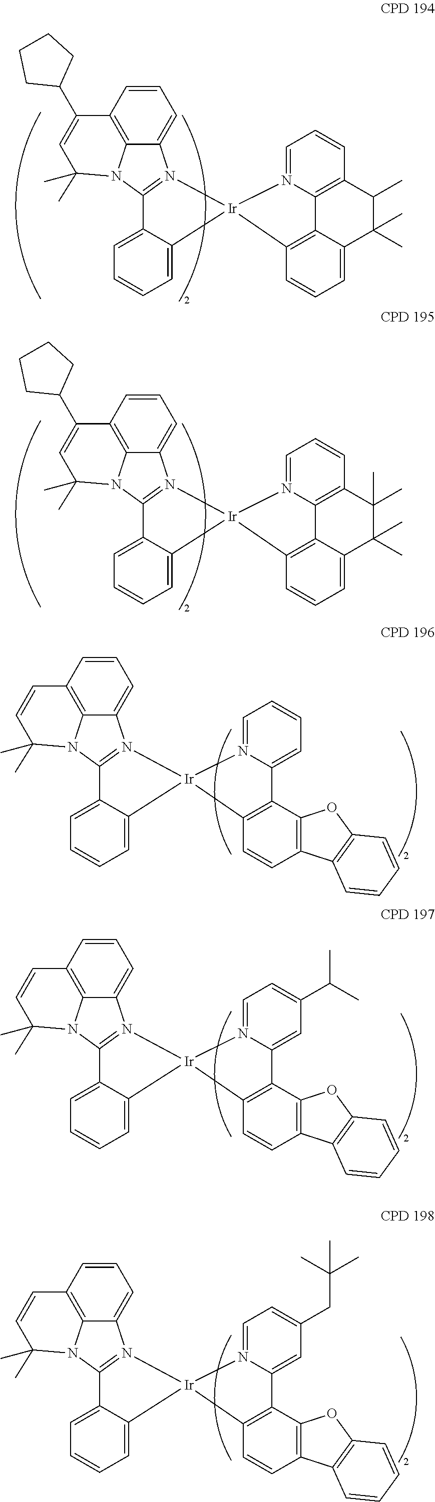

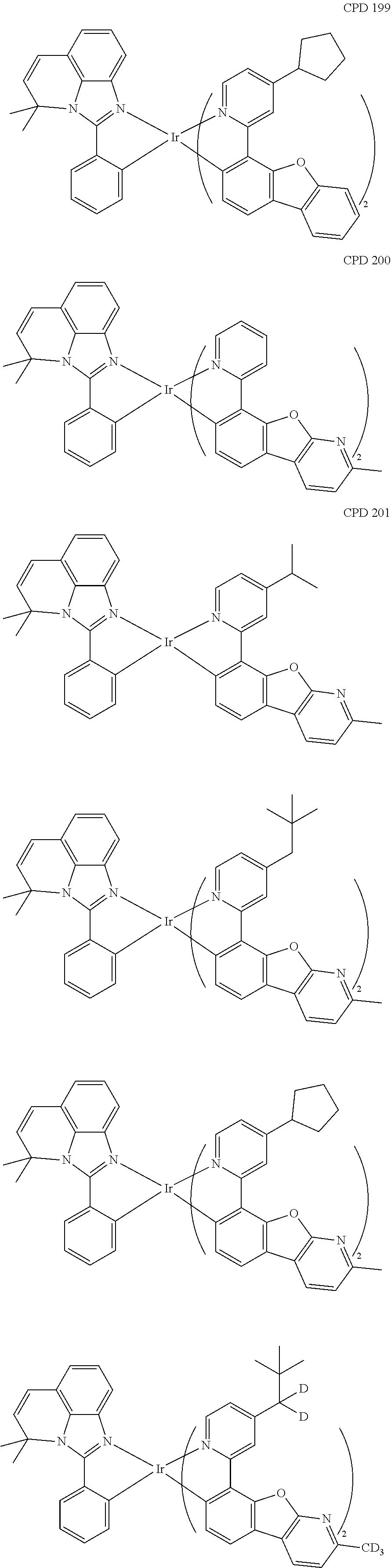

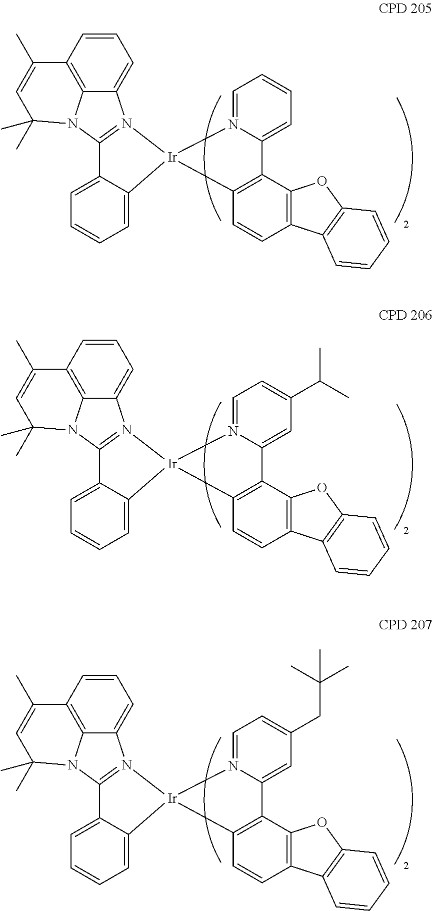

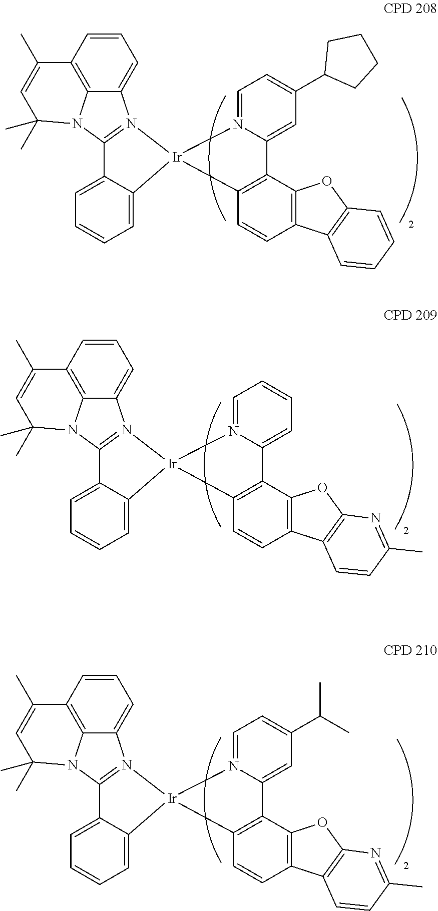

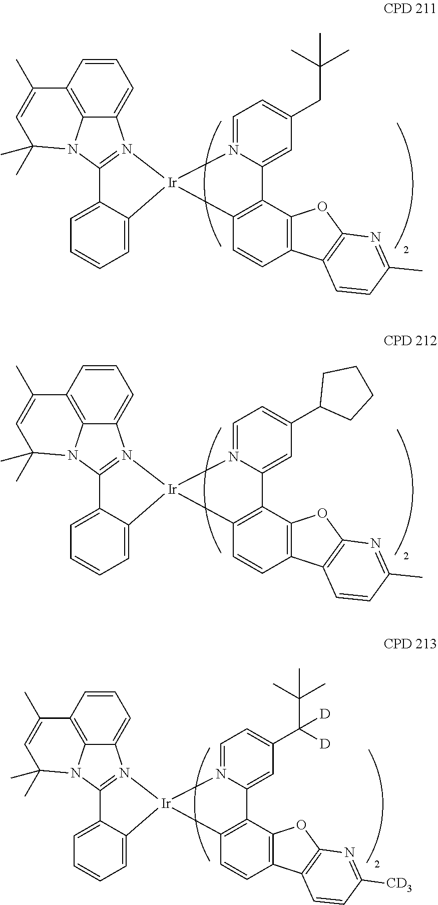

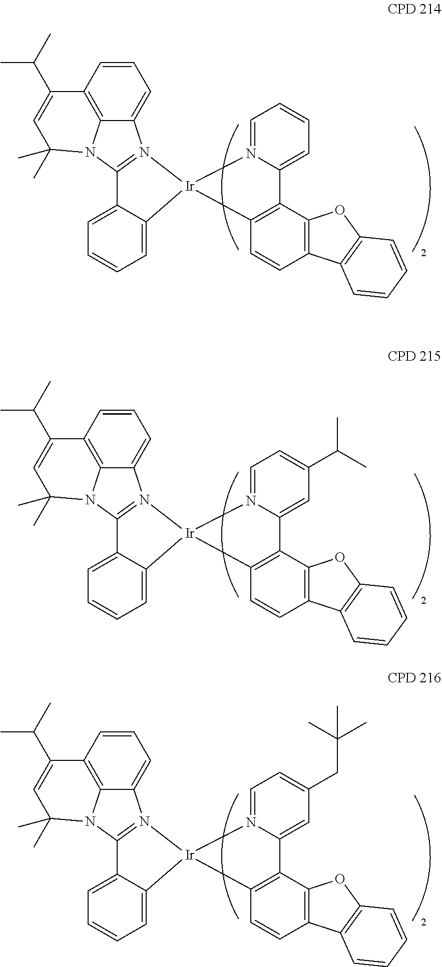

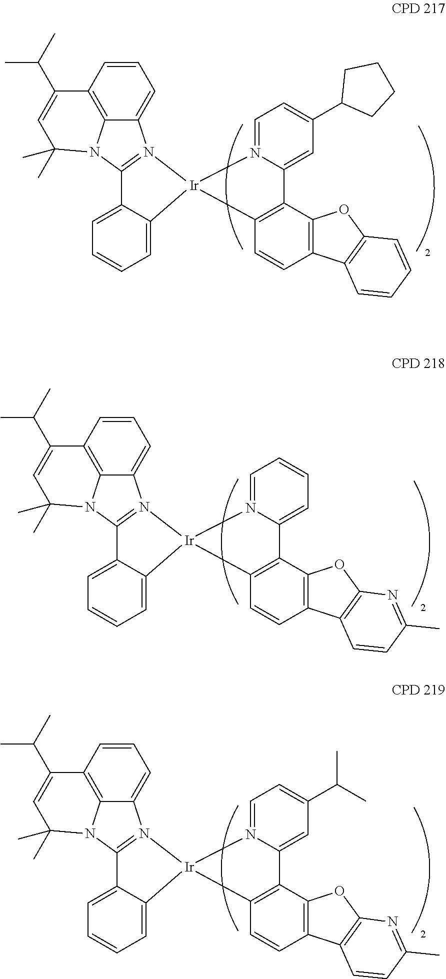

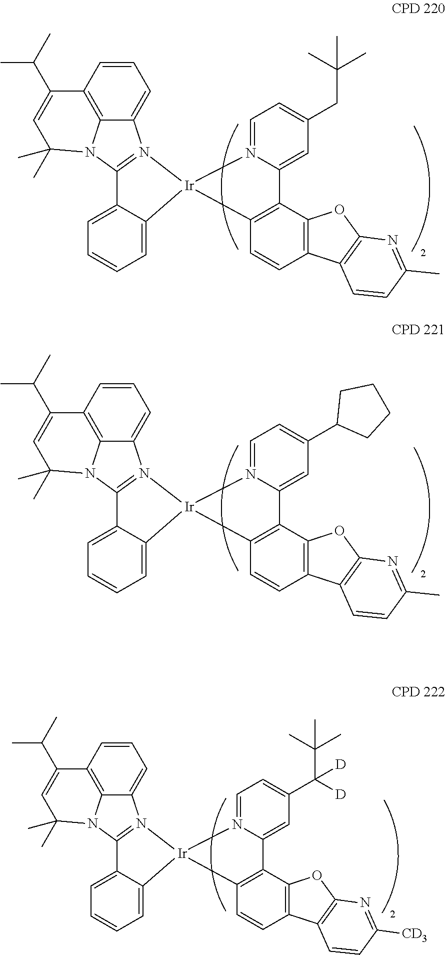

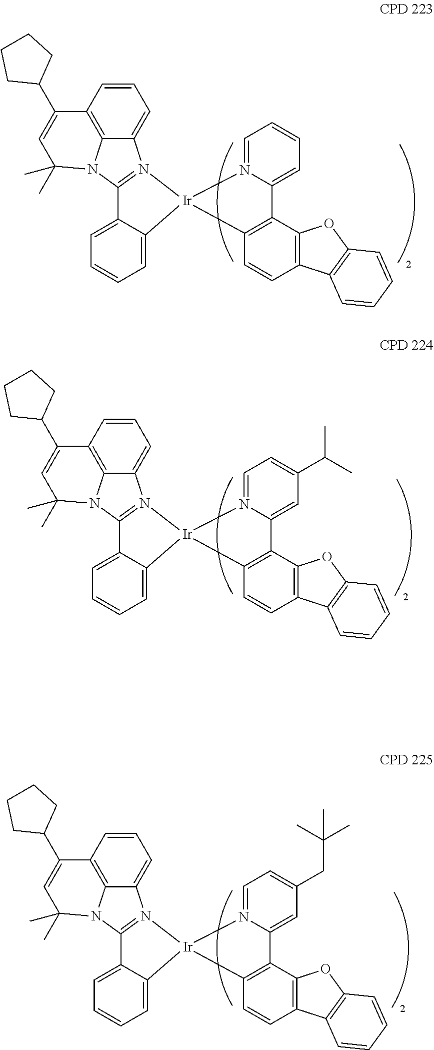

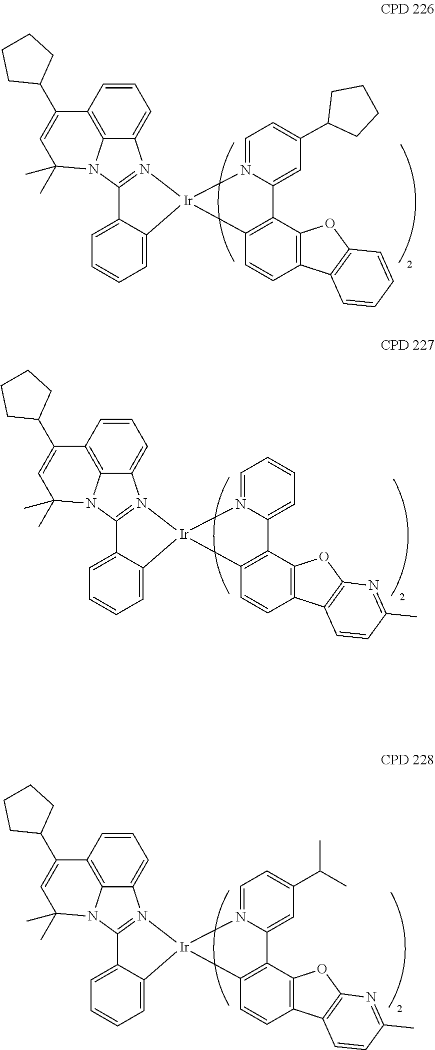

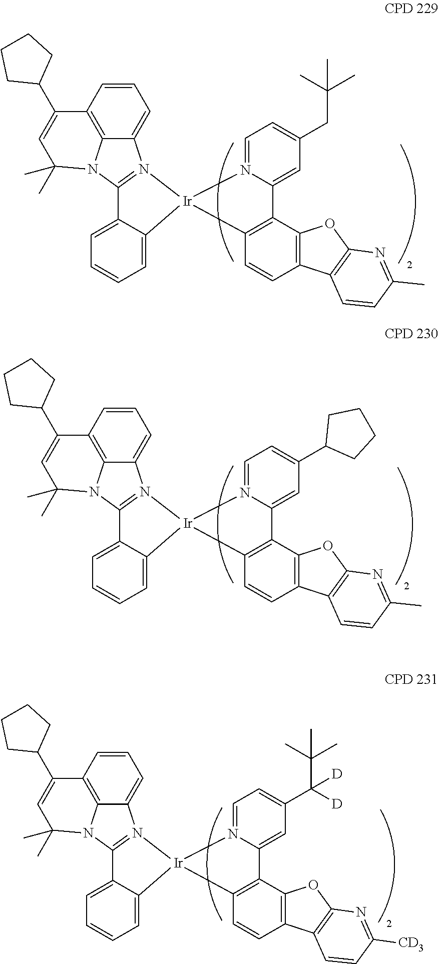

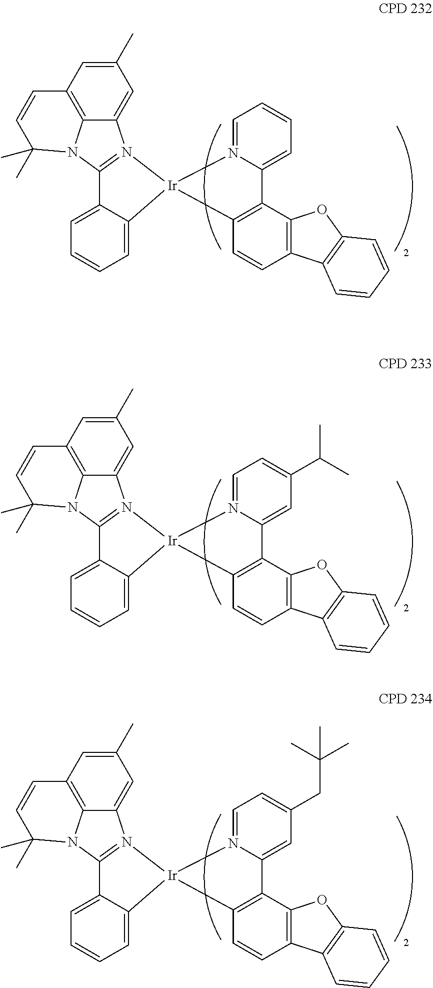

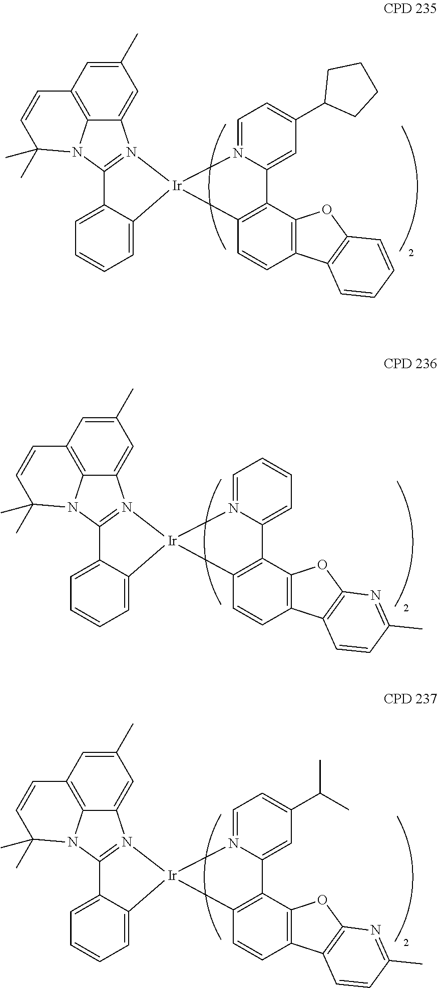

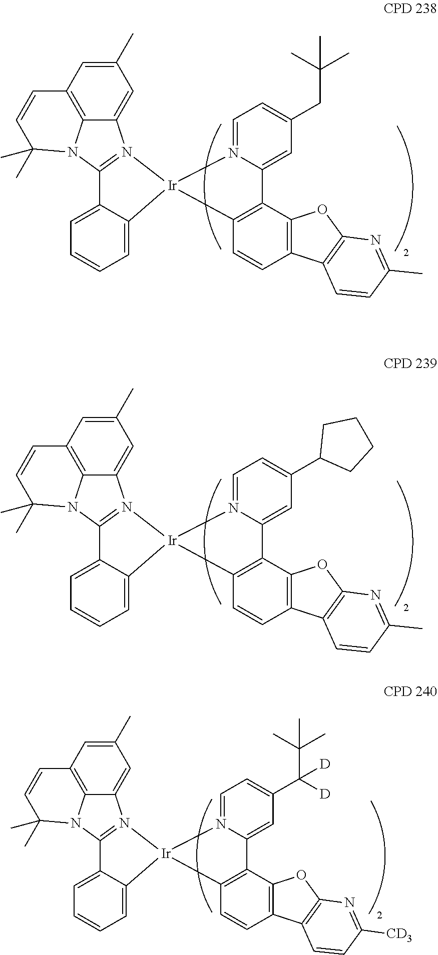

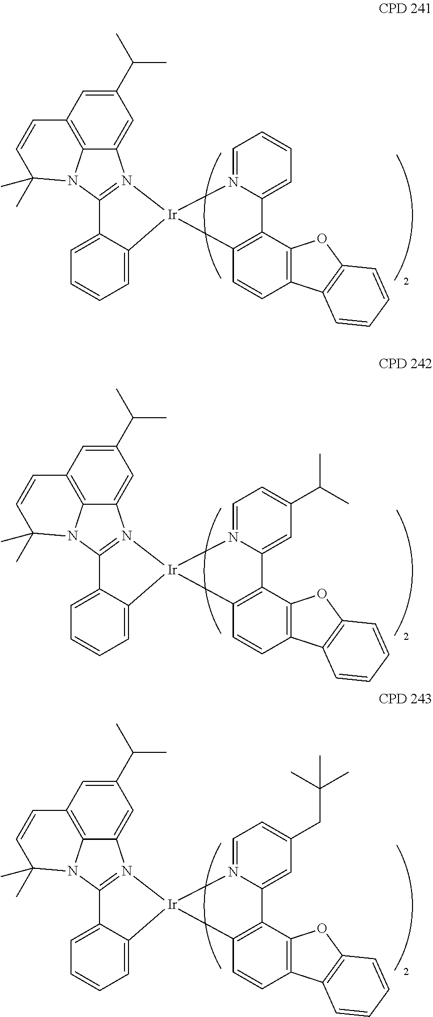

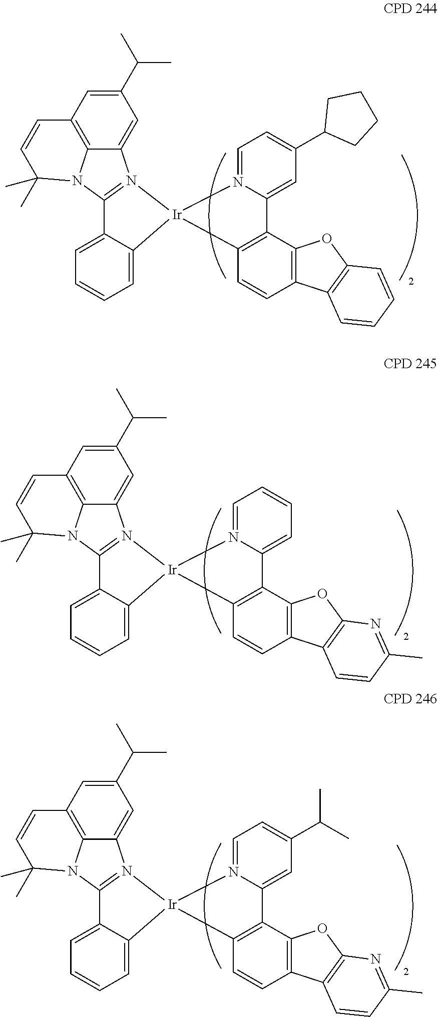

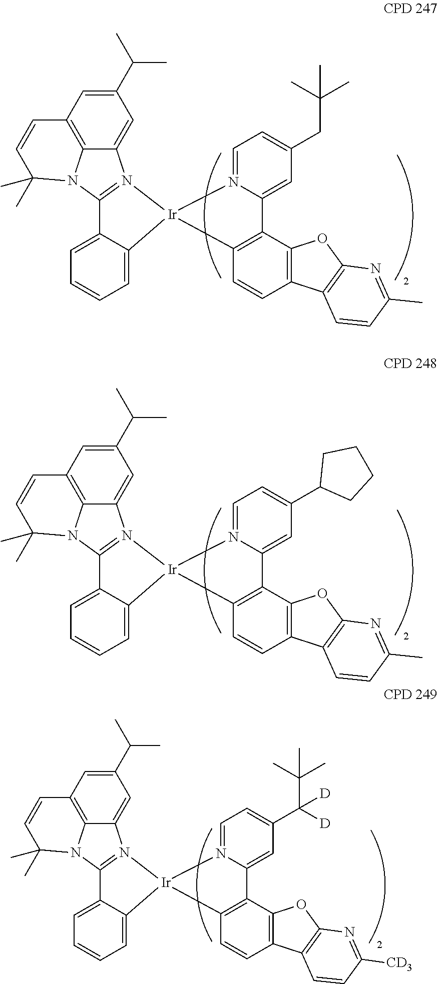

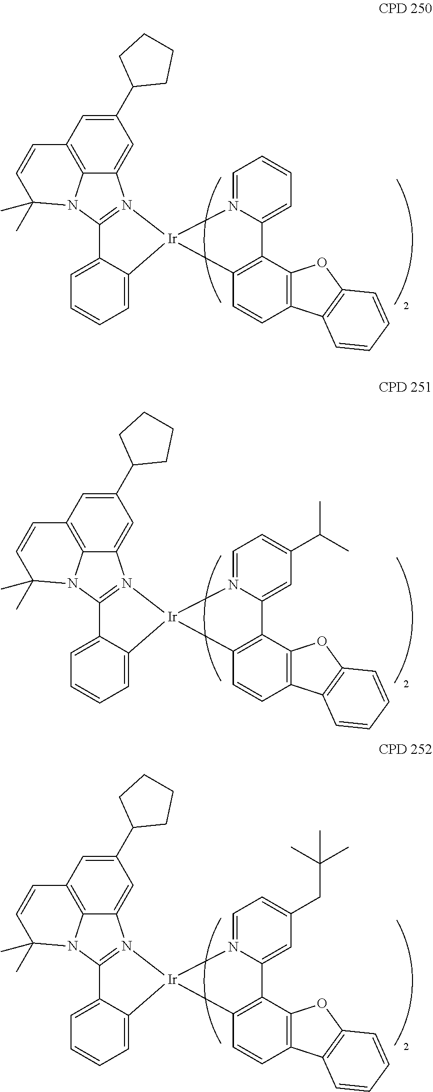

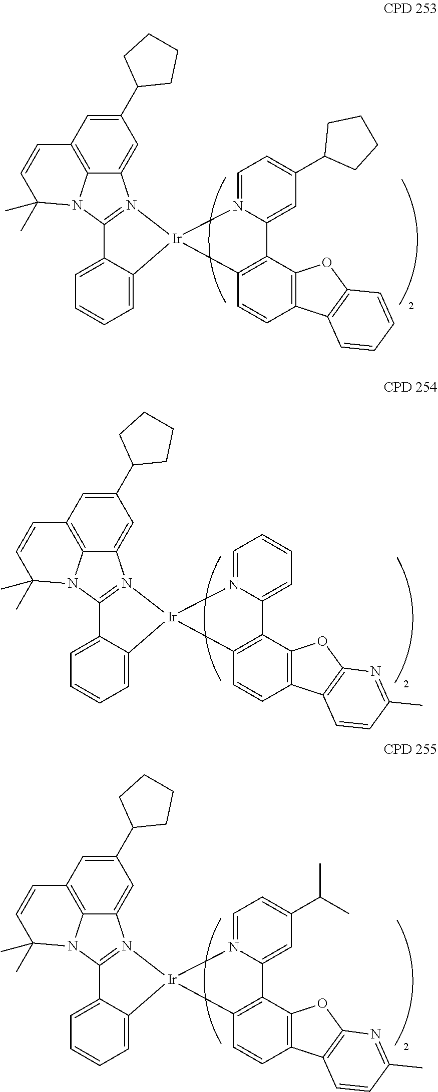

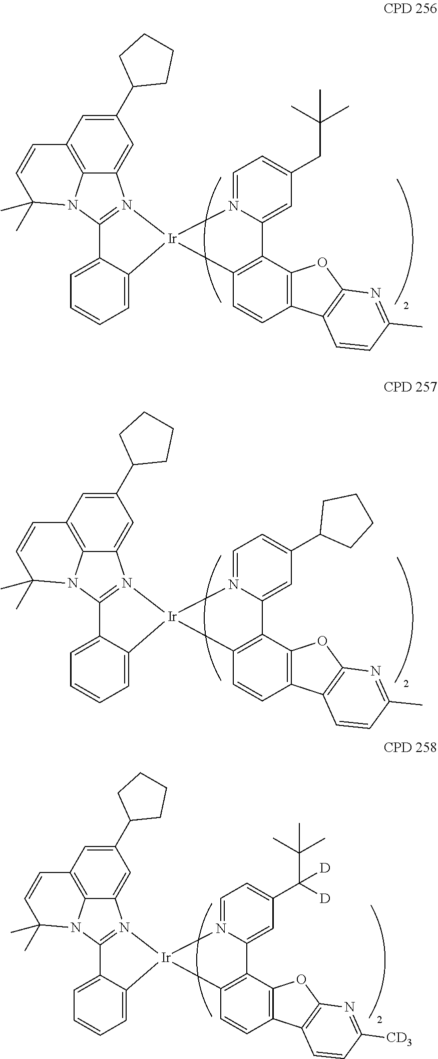

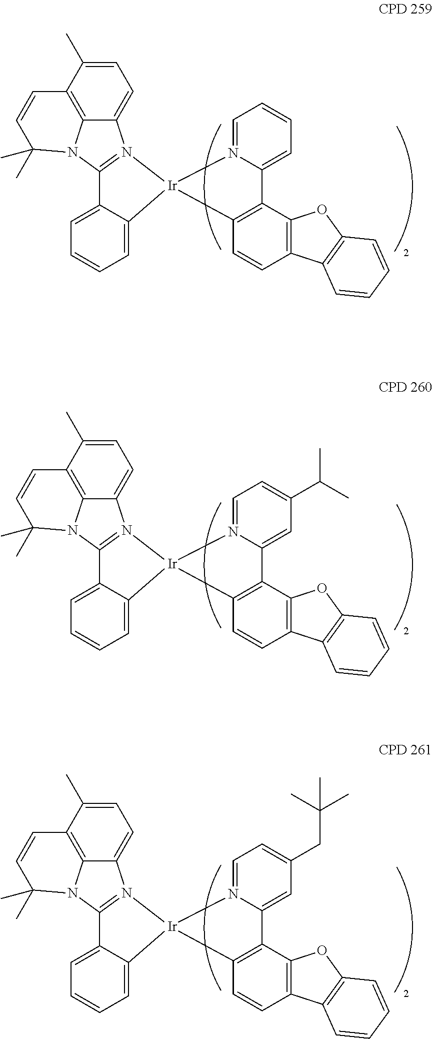

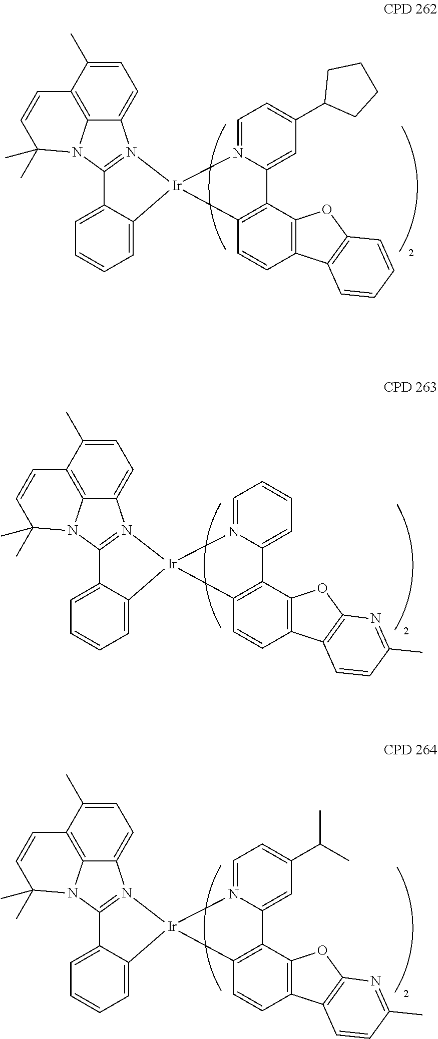

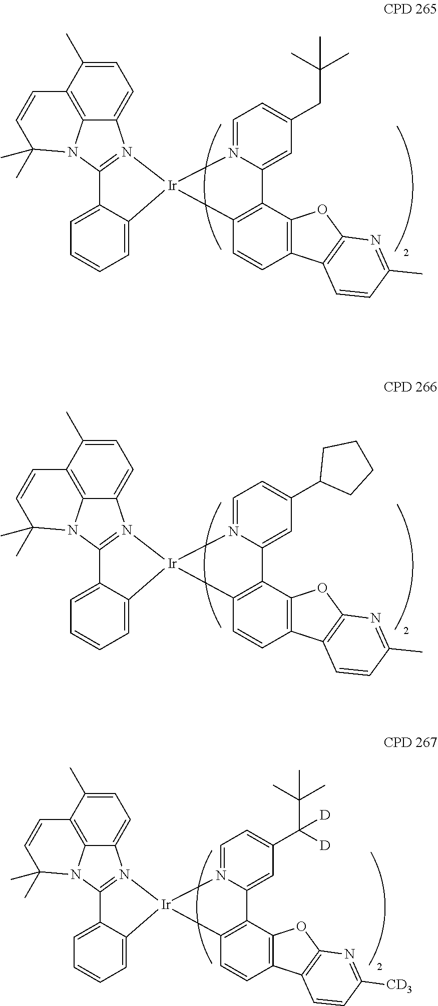

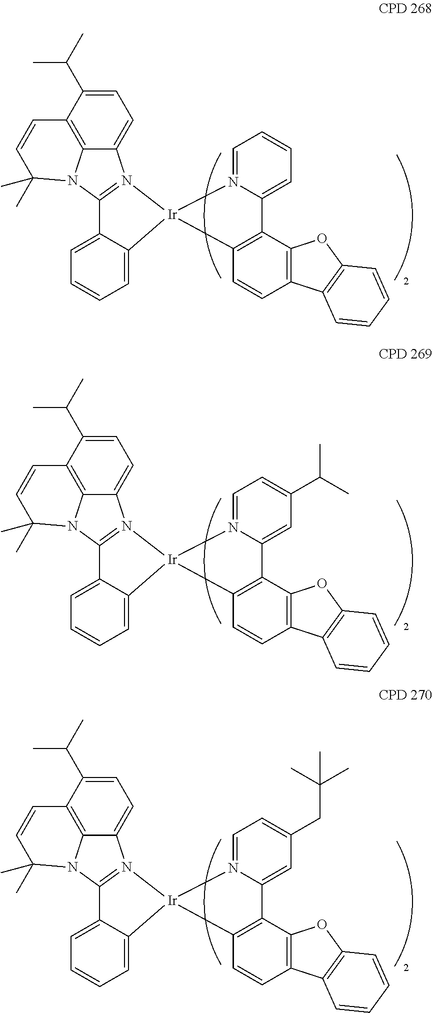

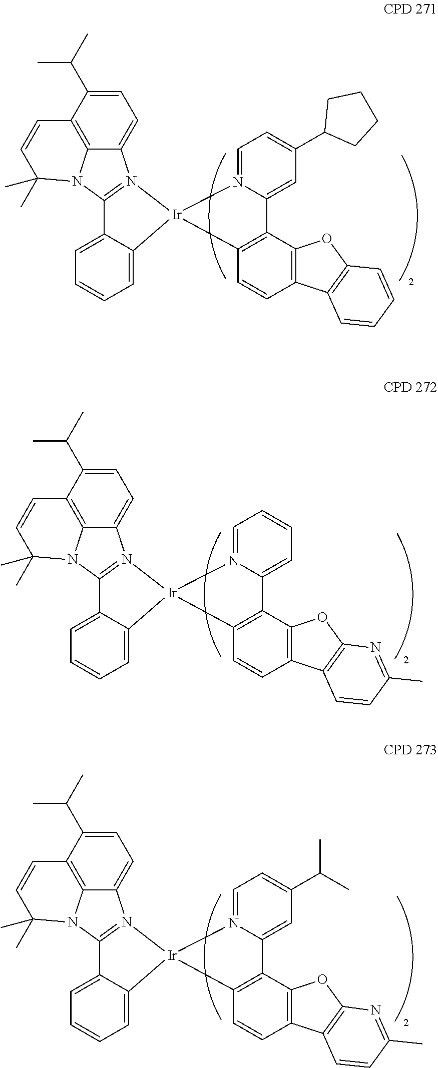

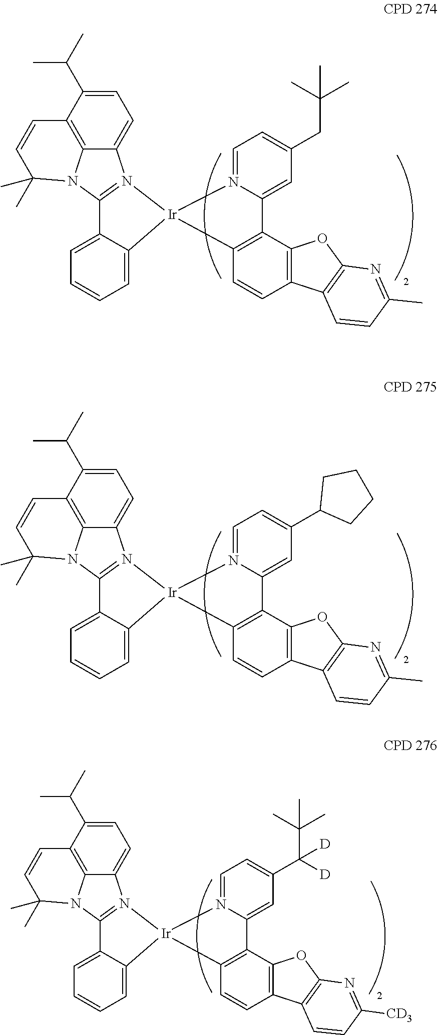

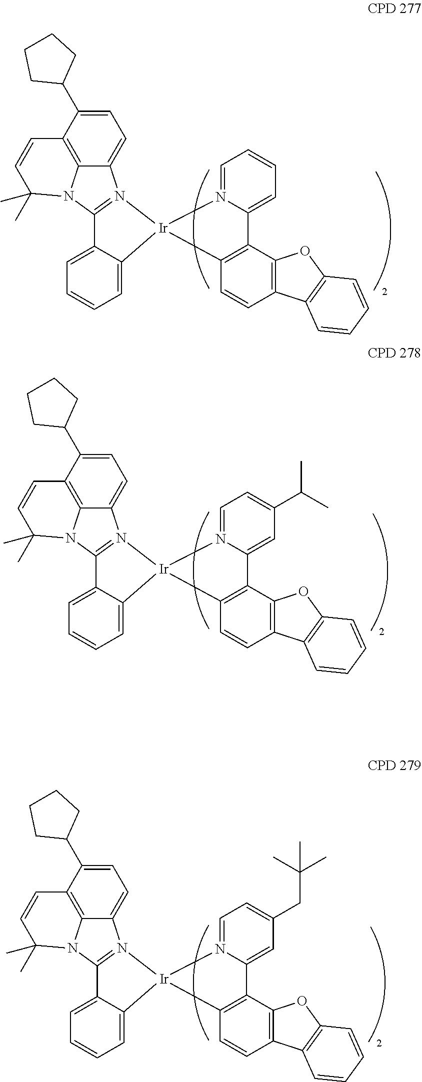

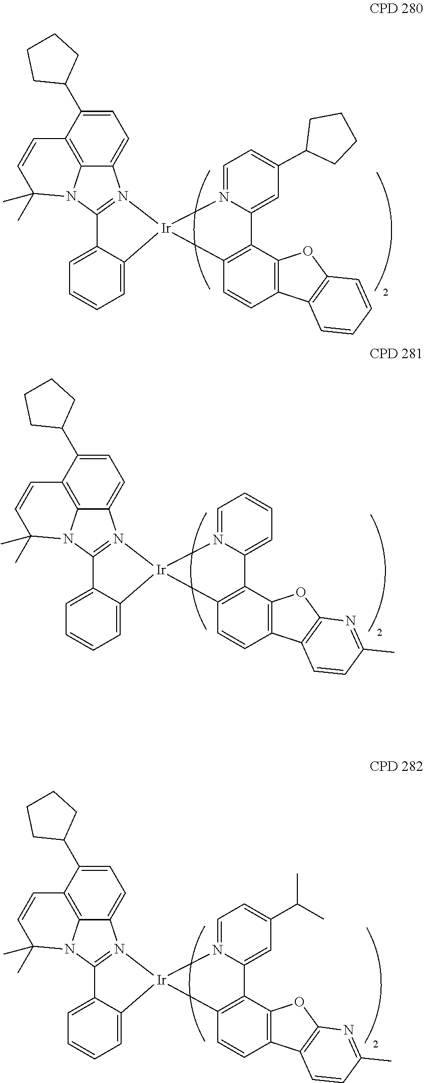

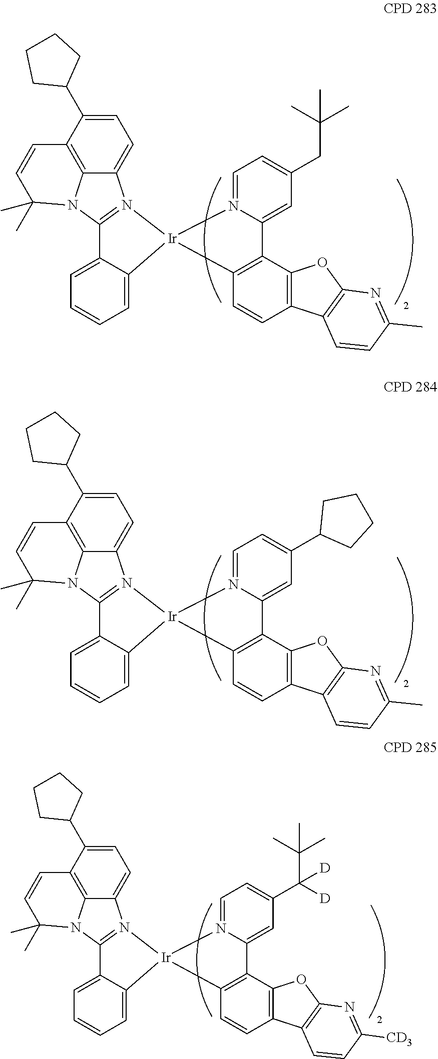

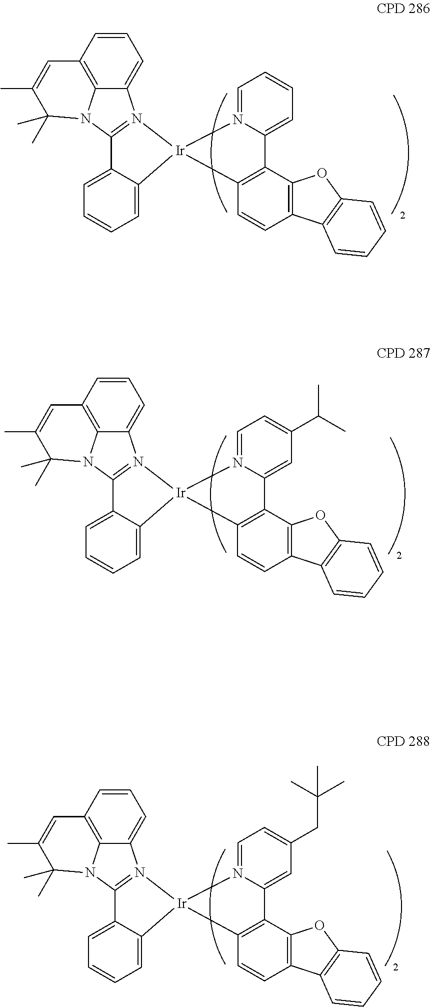

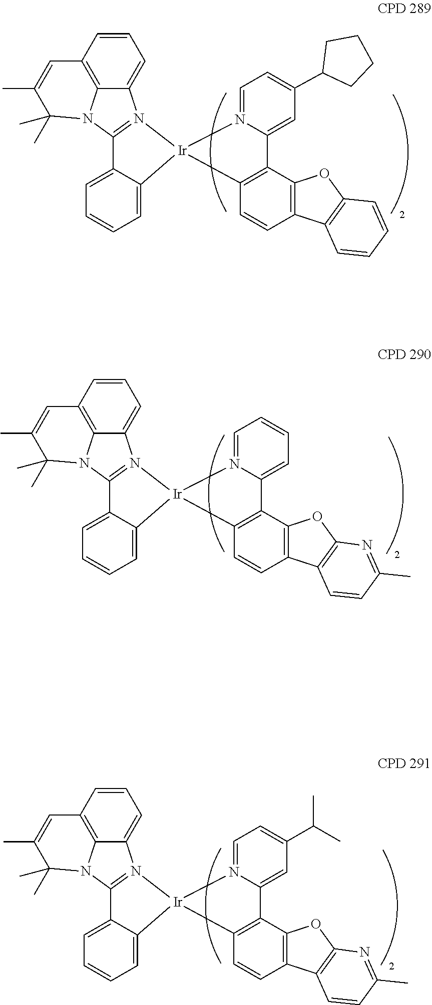

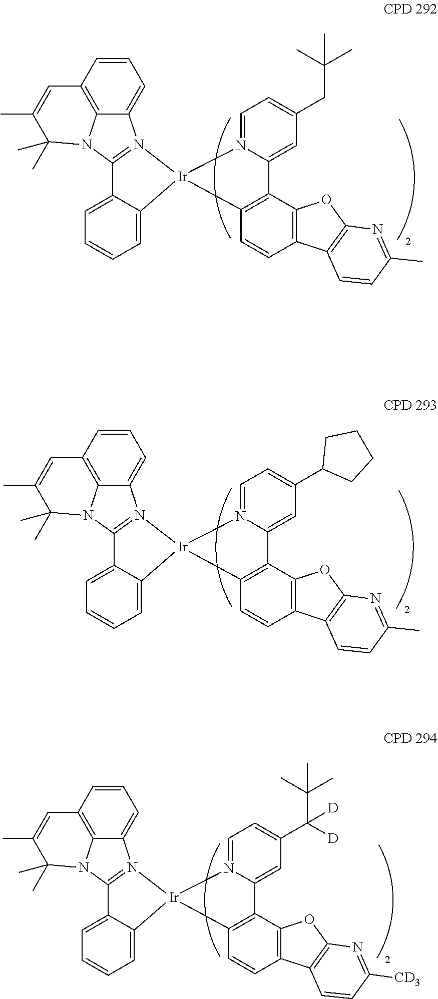

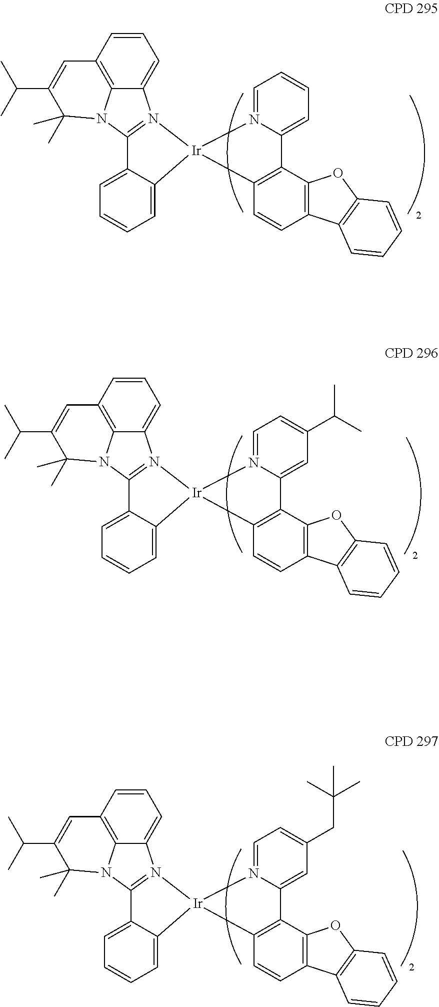

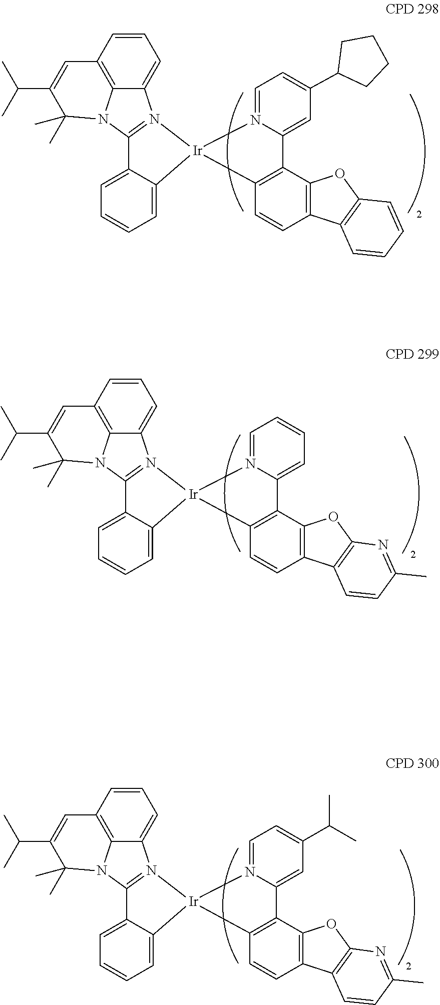

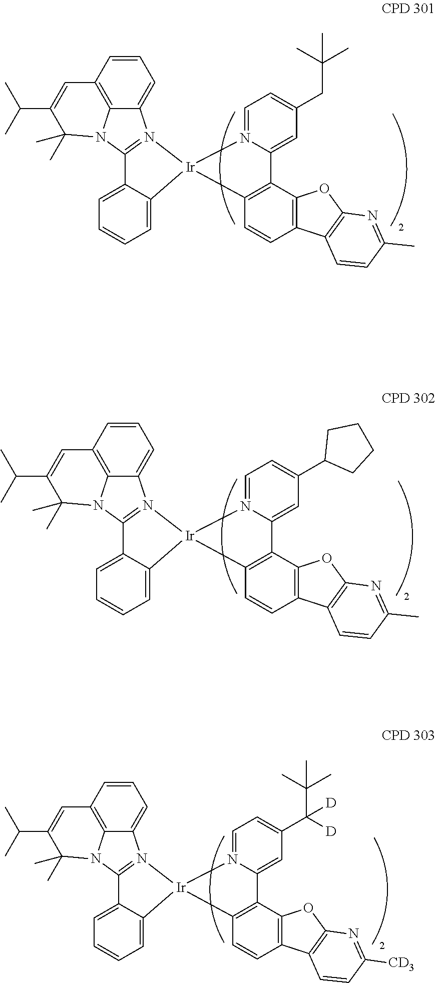

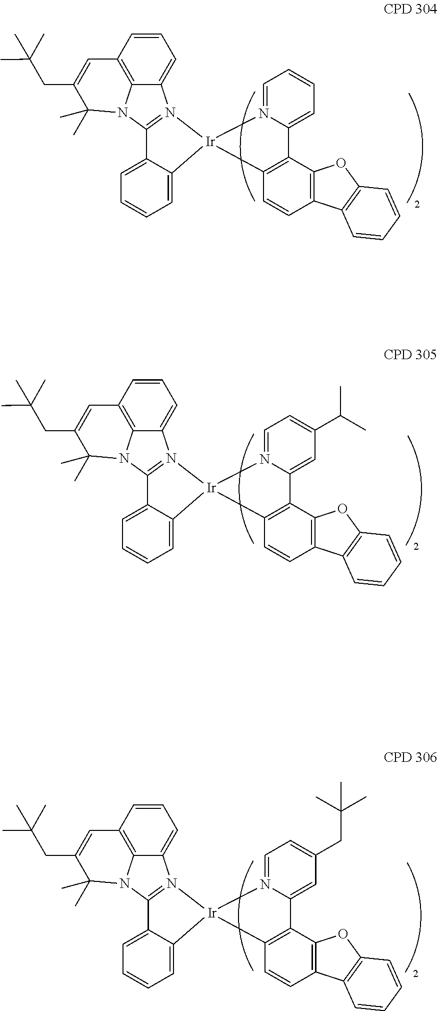

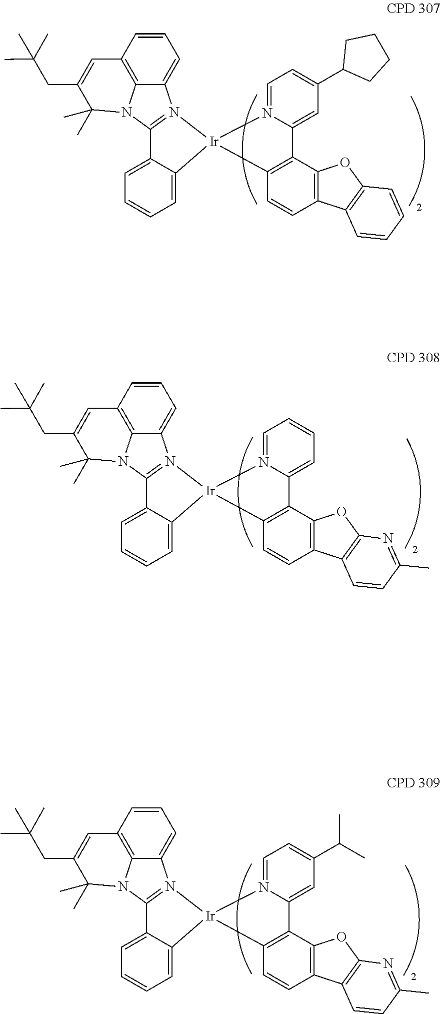

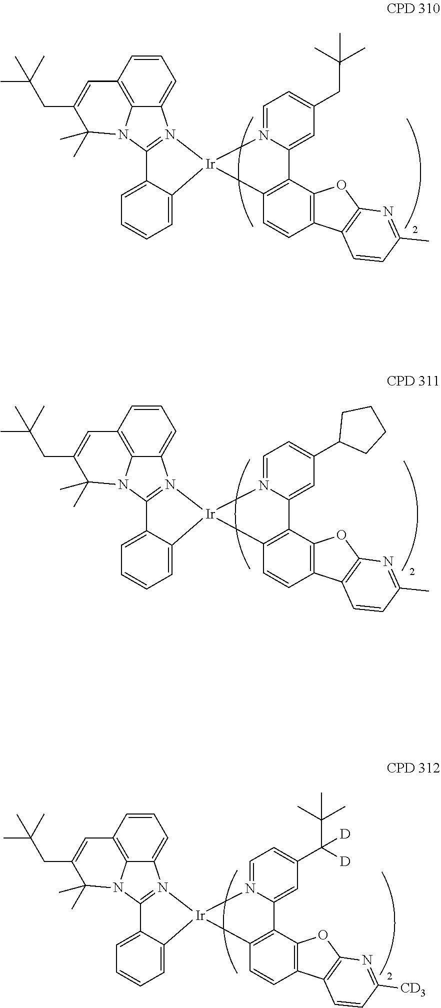

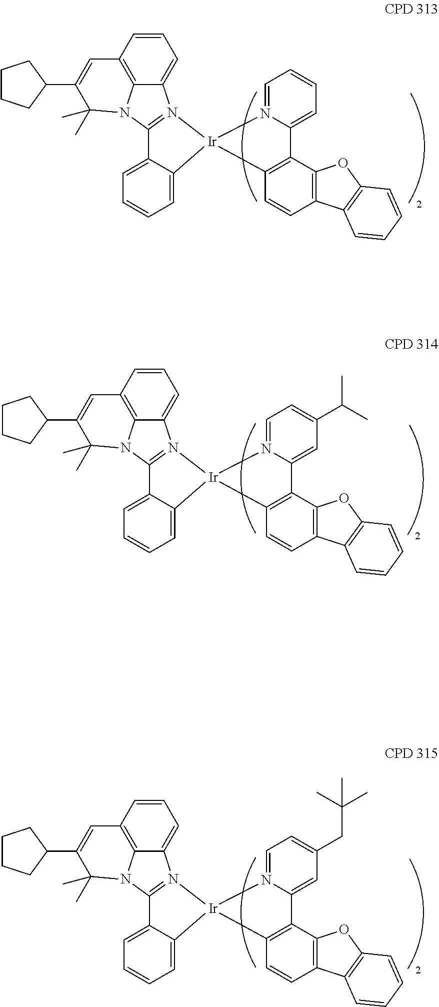

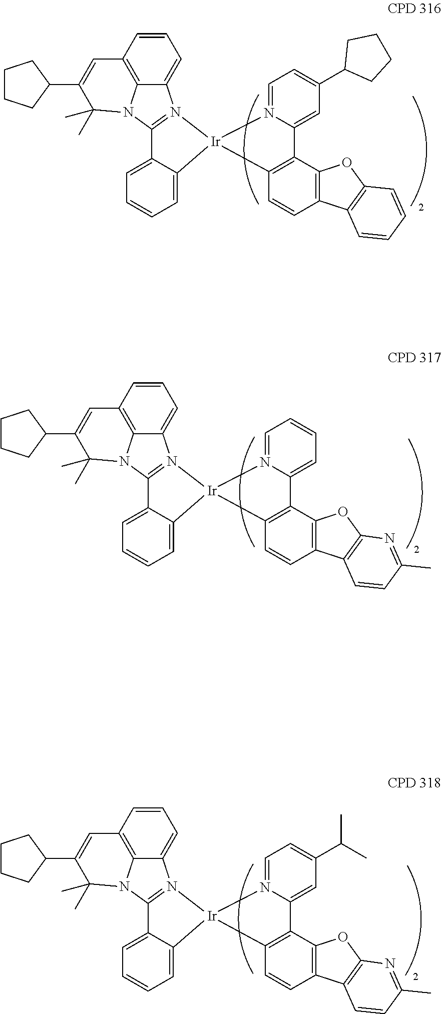

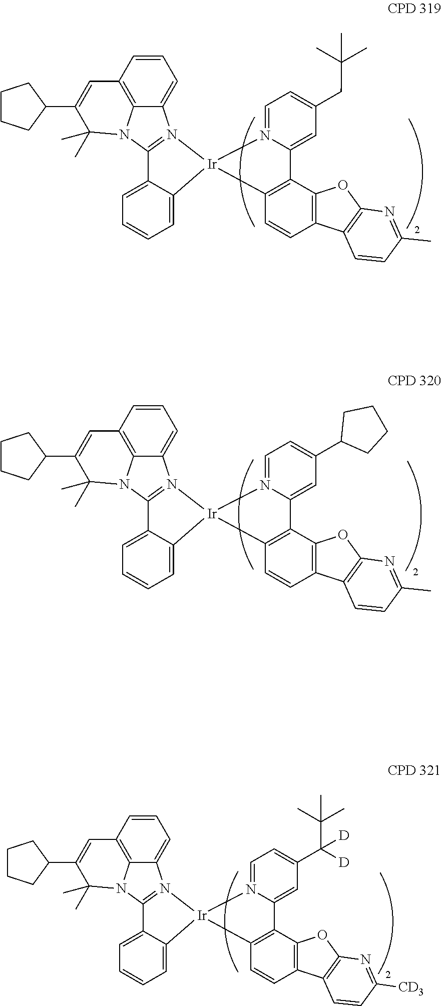

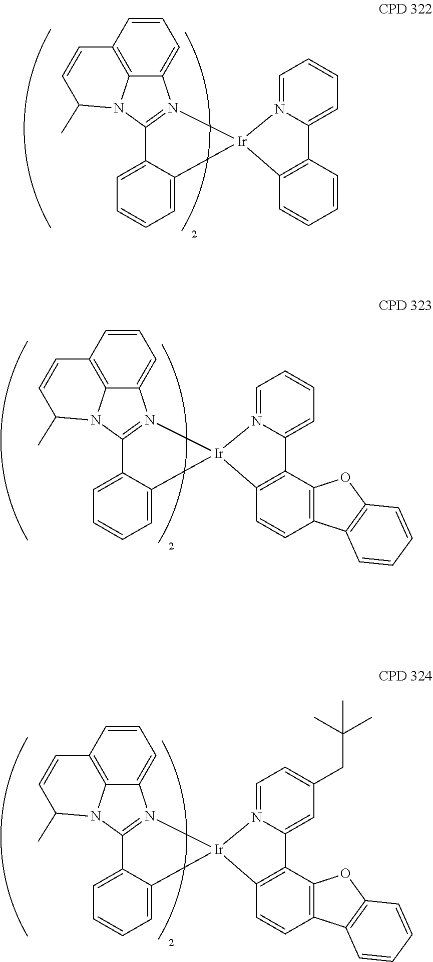

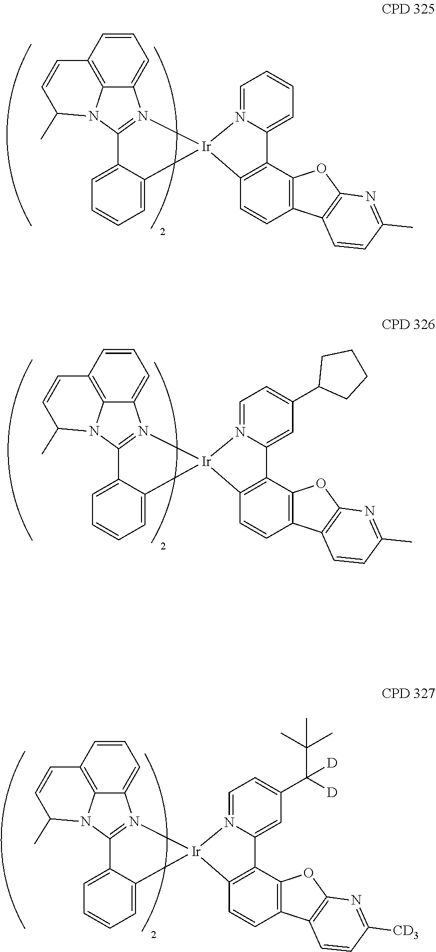

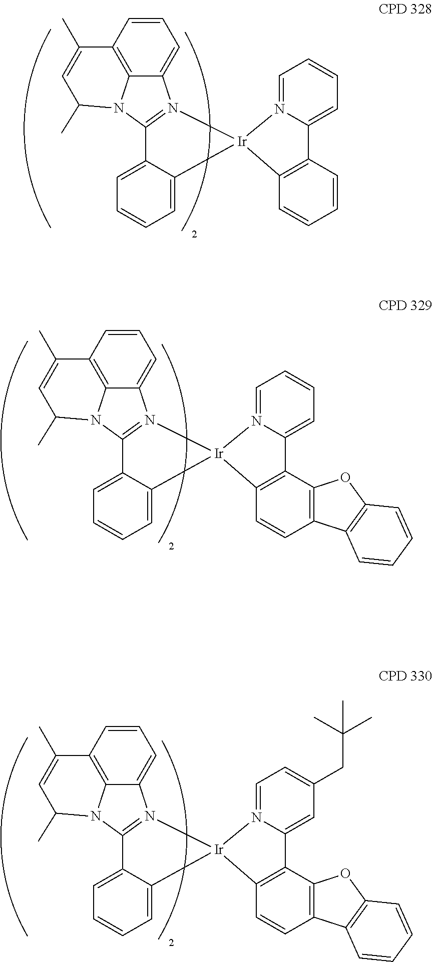

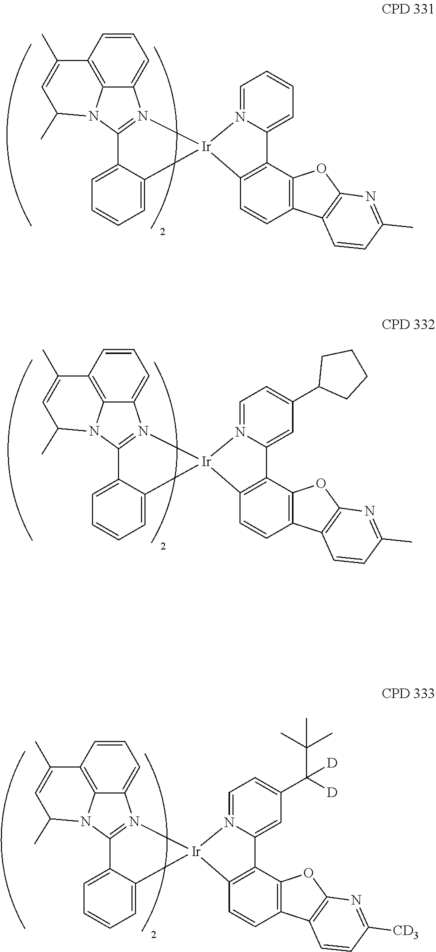

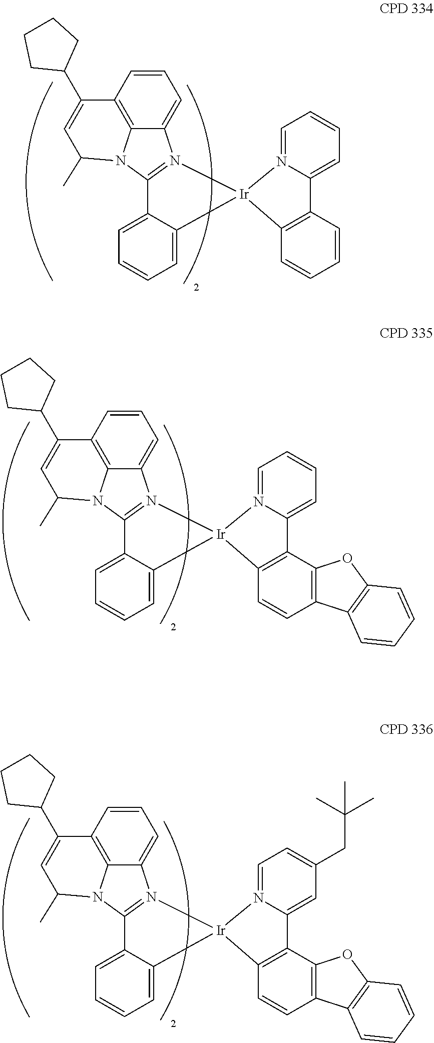

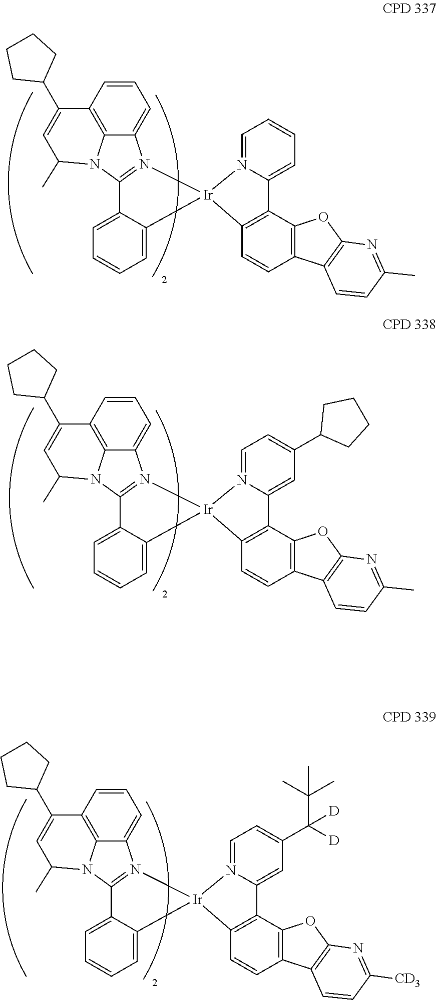

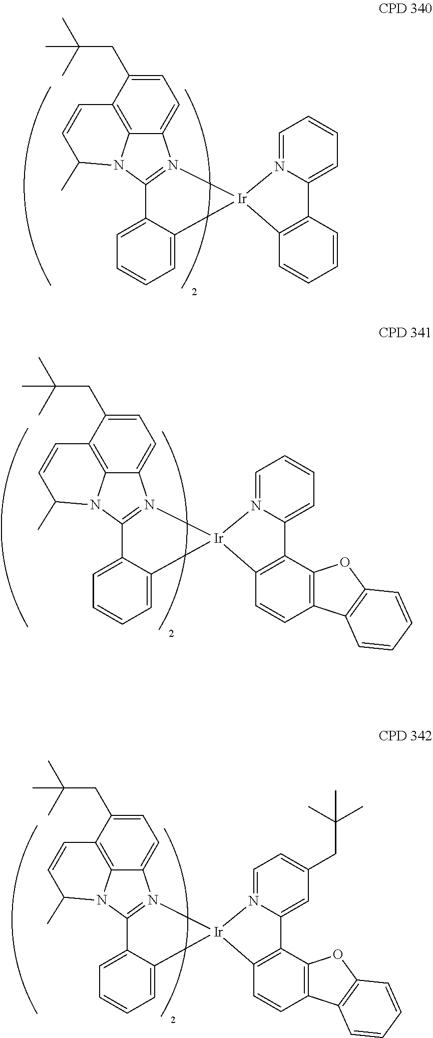

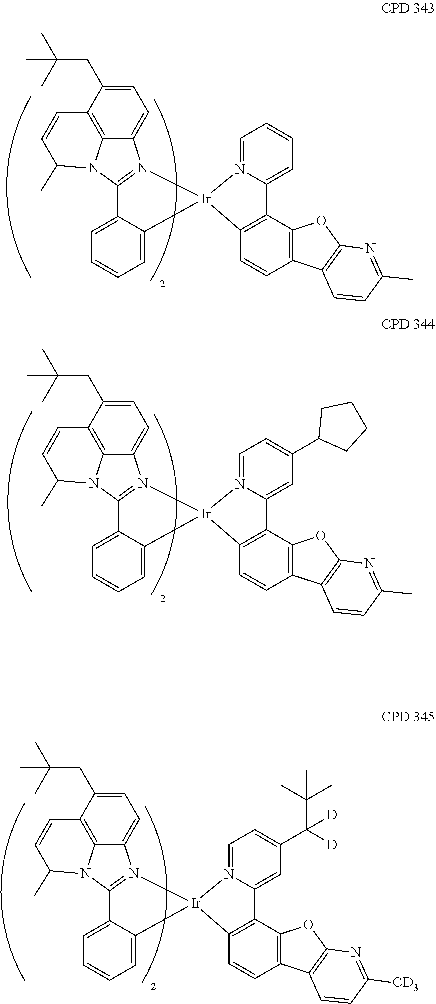

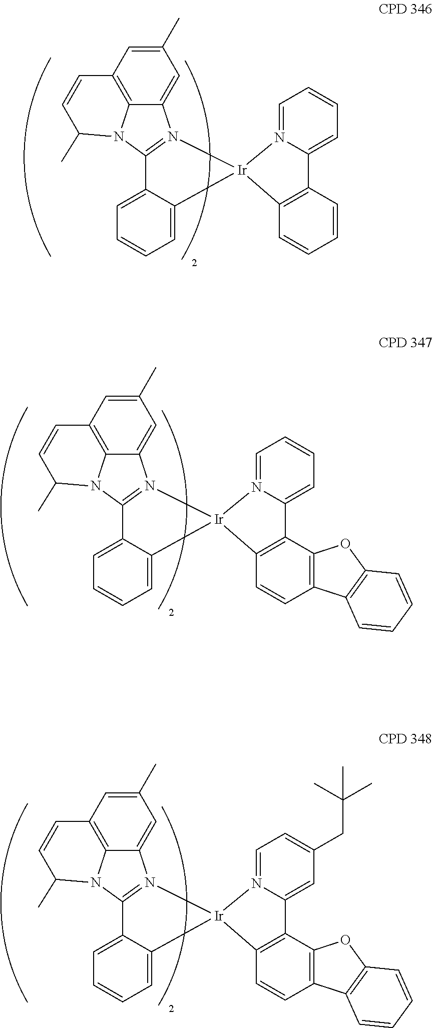

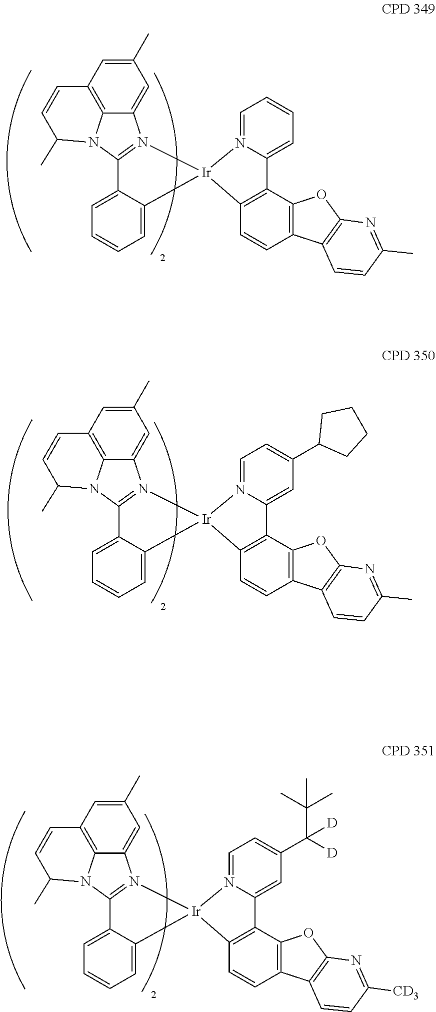

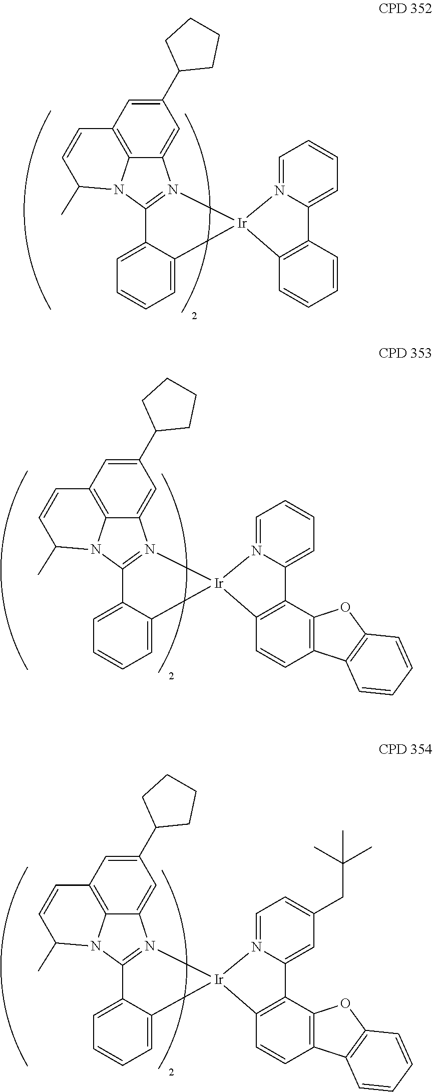

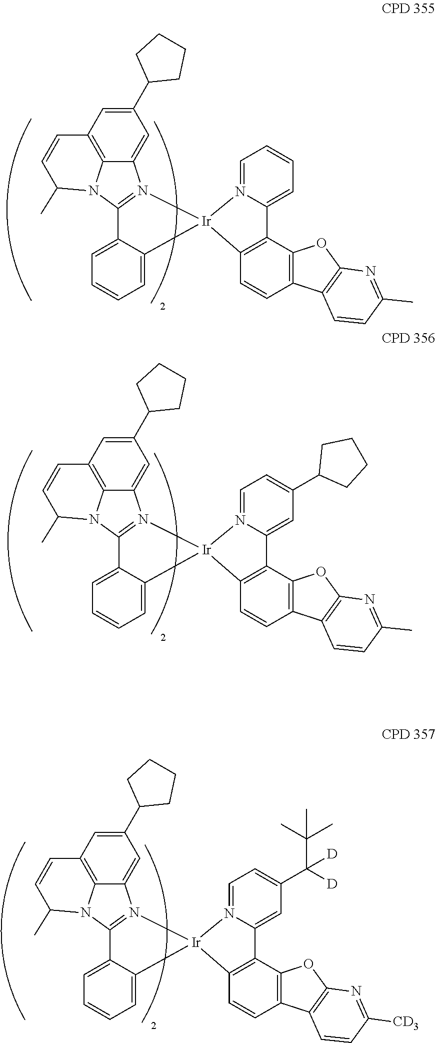

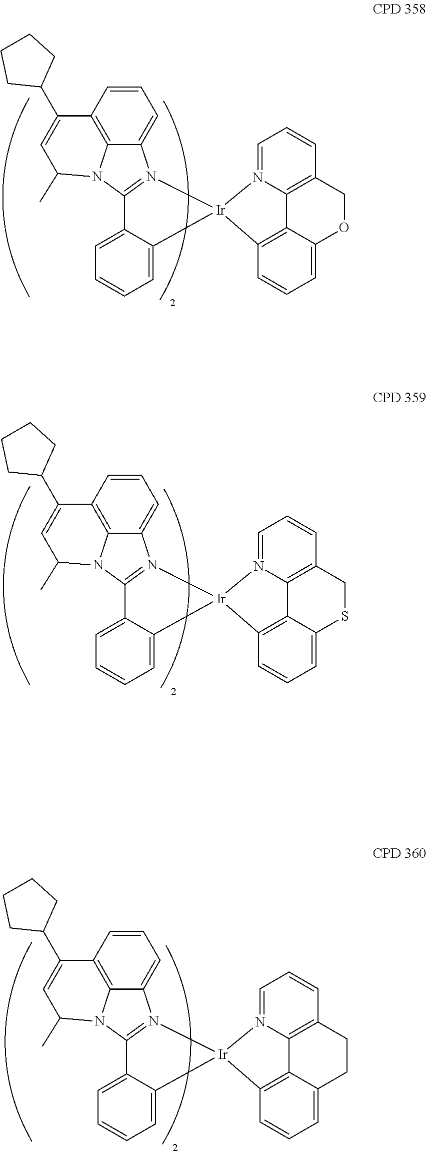

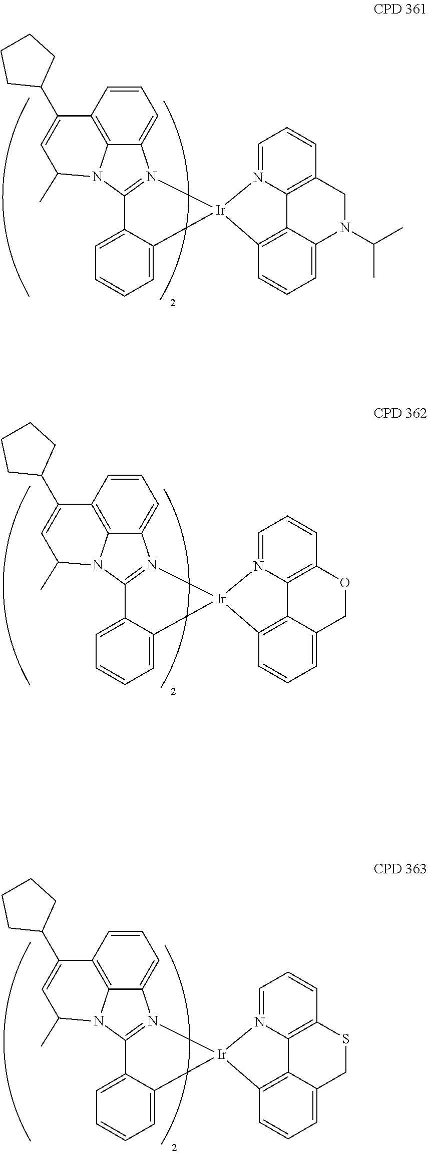

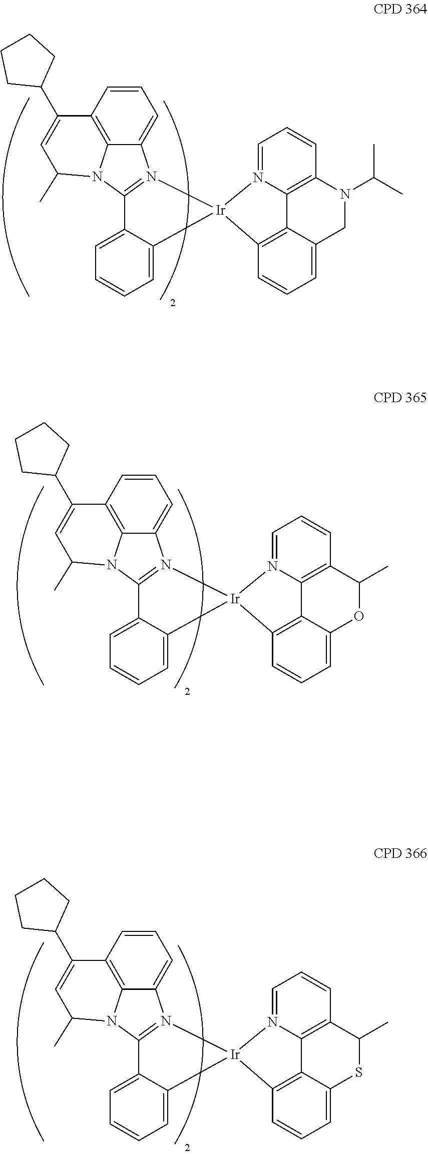

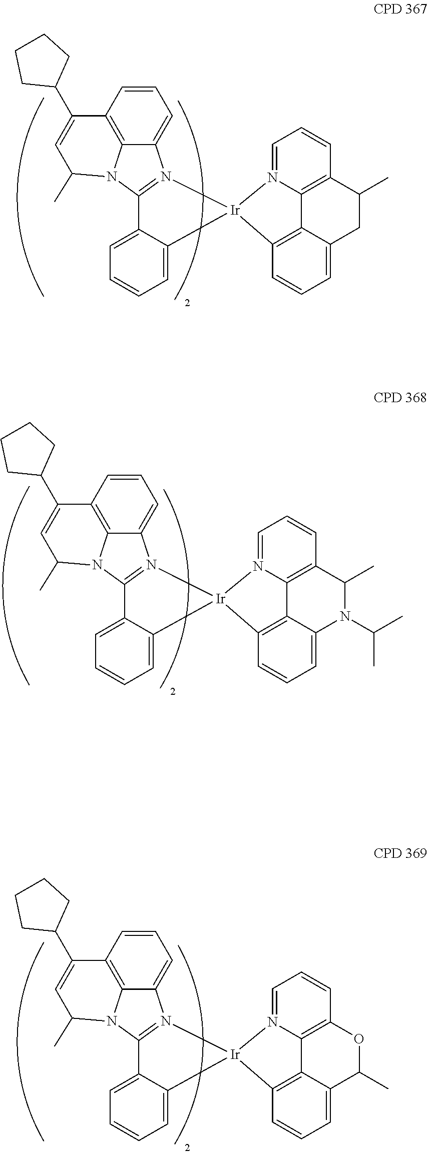

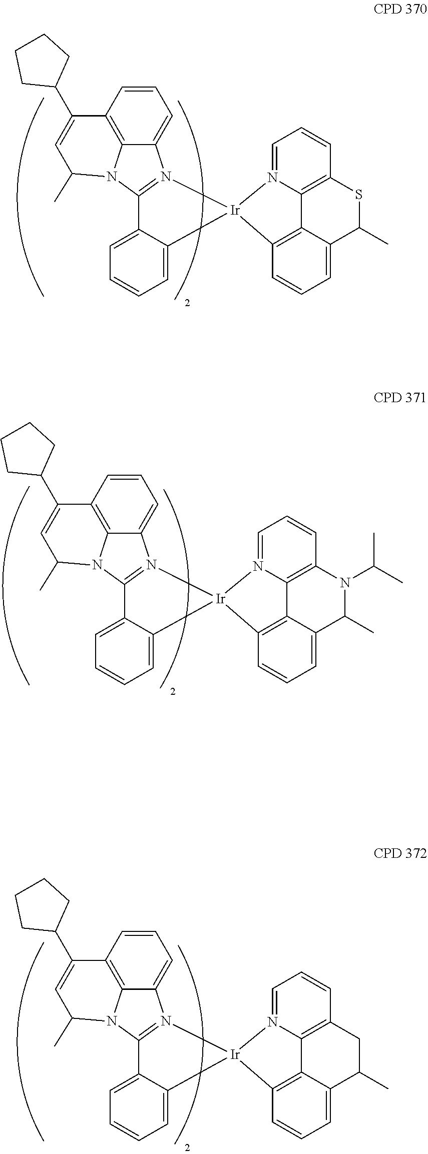

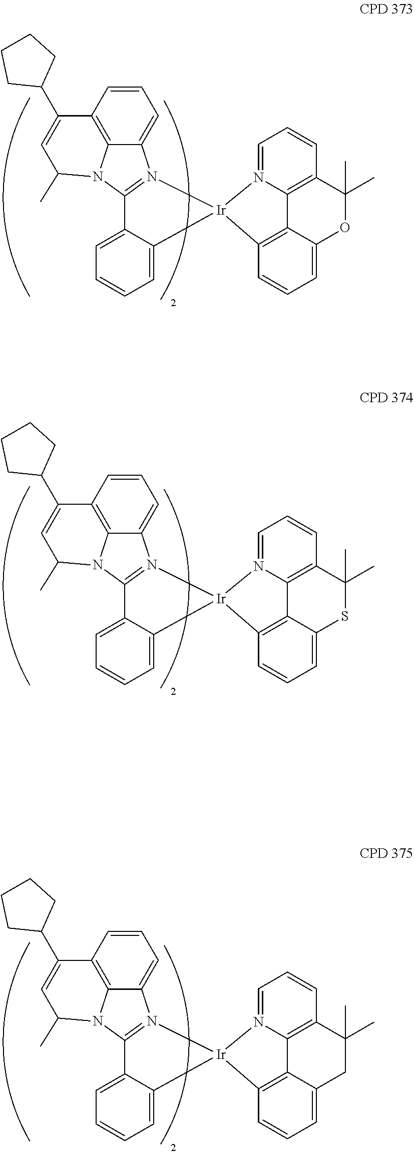

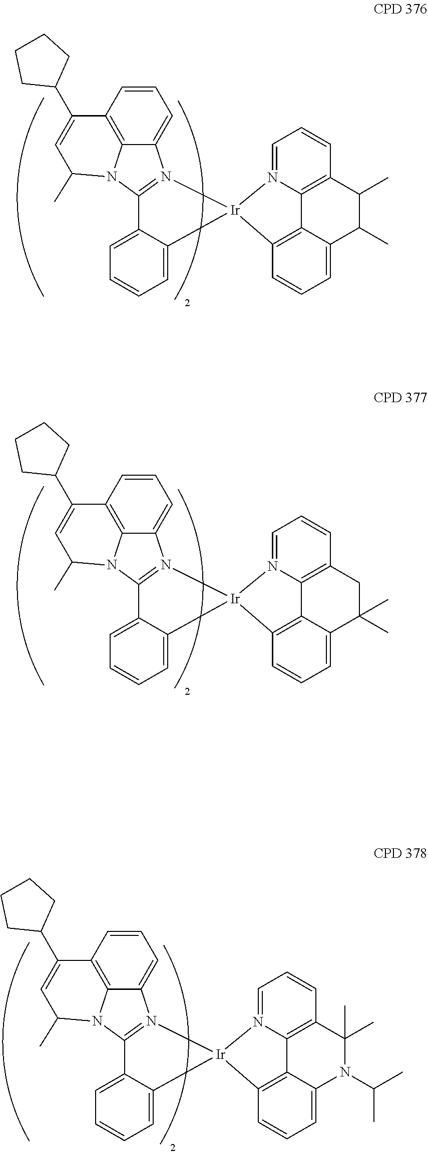

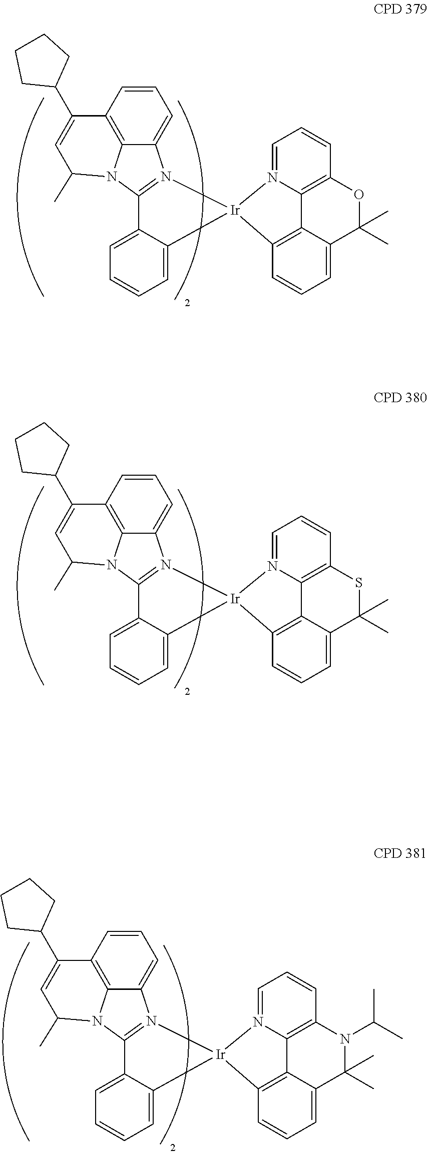

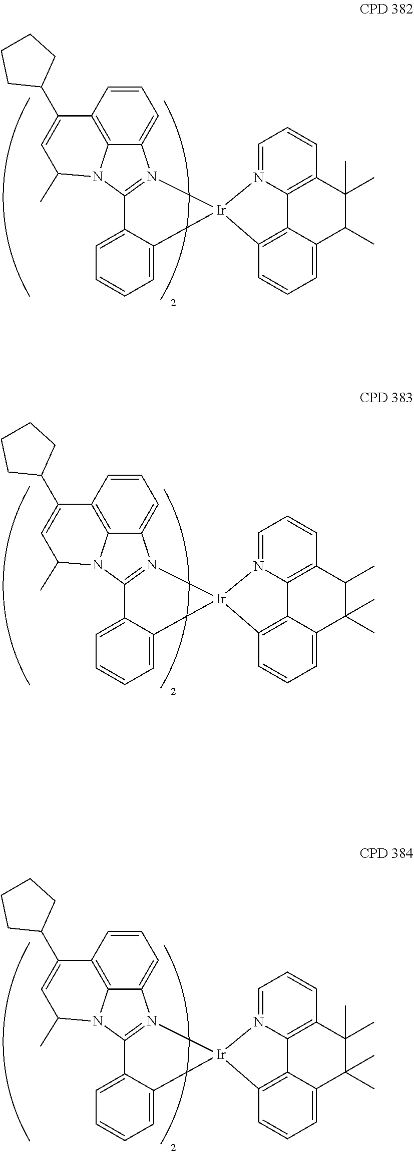

One of objectives of the present invention is to provide an OLED phosphorescent material containing the compound.

One of objectives of the present invention is to provide an OLED containing the compound.

The material of the present invention has the advantages of high optical and electrochemical stability, narrow emission half-peak width, high color saturation, high luminous efficiency, long device service life and the like. As a phosphorescent material, the material of the present invention can convert a triplet state into light, thereby improving the luminous efficiency of organic electroluminescent devices and reducing energy consumption. In particular, the compound has the potential for application in the AMOLED industry as a green light-emitting dopant.

### DETAILED DESCRIPTION OF EMBODIMENTS

A compound of the present invention has a structure formula represented by Formula (1):

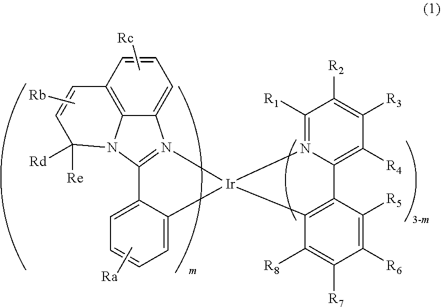

where

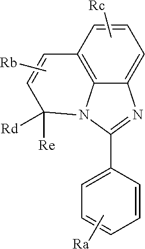

### is L1, and

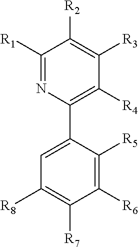

### is L2;

m is 1, 2 or 3, two L2 groups may be the same or different when the m is 1, and multiple L1 groups are the same or different when the m is greater than 1;
Ra, Rb and Rc independently indicate no substitution to a maximum substitution possibility;
Ra, Rb, Rc, Rd and Re are independently selected from hydrogen, deuterium, halogen, substituted or unsubstituted C₁-C₁₀ alkyl, substituted or unsubstituted C₃-C₂₀ cycloalkyl, substituted or unsubstituted C₆-C₁₈ aryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
at least one of the Rd and the Re is not hydrogen;
R₁-R₈ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁₀ alkenyl, substituted or unsubstituted C₂-C₁₀ alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
any two adjacent groups of the R₁-R₄ or R₅-R₈ may be connected to each other to form an aliphatic ring structure or an aromatic ring structure;
the heteroalkyl is alkyl at least containing one heteroatom such as O, N or S;
and the “substituted” refers to substitution with deuterium, F, Cl, Br, C₁-C₆ alkyl, C₃-C₆ cycloalkyl, amino substituted with C₁-C₆ alkyl, cyano, isocyano, or phosphino, and the substitution ranges from a single substitution number to a maximum substitution number.

In Formula (1), in a case of 2 or more Ra, Rb or Rc, multiple Ra, Rb or Rc may be the same or different, respectively.

In Formula (1), in a case of 2 or more substituents, multiple substituents may be the same or different, respectively.

In Formula (1), at least one of the Rb and the Rc is deuterium, fluorine, substituted or unsubstituted C₁-C₆ alkyl, or substituted or unsubstituted C₃-C₆ cycloalkyl, indicating that the Rb is selected from the above groups while the Rc is not selected from the above groups, the Rc is selected from the above groups while the Rb is not selected from the above groups, or the Rb and the Rc are both selected from the above groups.

Examples of various groups of the compound represented by Formula (1) are described below.

It is to be noted that in the specification, “Cₐ-C_{b}” in the term “substituted or unsubstituted Cₐ-C_{b} X group” refers to the number of carbons when the X group is unsubstituted, excluding the number of carbons of a substituent when the X group is substituted.

As a linear or branched alkyl, the C₁-C₁₀ alkyl specifically includes methyl, ethyl, propyl, isopropyl, n-butyl, isobutyl, sec-butyl, tert-butyl, n-pentyl and isomers thereof, n-hexyl and isomers thereof, n-heptyl and isomers thereof, n-octyl and isomers thereof, n-nonyl and isomers thereof, and n-decyl and isomers thereof, optionally includes methyl, ethyl, propyl, isopropyl, n-butyl, isobutyl, sec-butyl, and tert-butyl, and more optionally includes propyl, isopropyl, isobutyl, sec-butyl, and tert-butyl.

The C₃-C₂₀ cycloalkyl may include cyclopropyl, cyclobutyl, cyclopentyl, cyclohexyl, 1-adamantyl, 2-adamantyl, 1-norbornyl, and 2-norbornyl, and optionally includes cyclopentyl and cyclohexyl.

The C₂-C₁₀ alkenyl may include vinyl, propenyl, allyl, 1-butadienyl, 2-butadienyl, 1-hexatrienyl, 2-hexatrienyl, and 3-hexatrienyl, and optionally includes propenyl and allyl.

As a linear or branched alkyl or cycloalkyl consisting of atoms other than carbon and hydrogen, the C₁-C₁₀ heteroalkyl may include mercaptomethyl methyl, methoxymethyl, ethoxymethyl, tert-butoxyl methyl, N,N-dimethyl methyl, epoxy butyl, epoxy pentyl, and epoxy hexyl, and optionally includes methoxymethyl and epoxy pentyl.

Specific examples of the aryl include phenyl, naphthyl, anthracyl, phenanthryl, tetracenyl, pyrenyl, chrysenyl, benzo[c]phenanthryl,
benzo[g]chrysenyl, fluorenyl, benzofluorenyl, dibenzofluorenyl, biphenyl, triphenyl, tetraphenyl, and fluoranthracyl, and optionally include phenyl and naphthyl.

Specific examples of the heteroaryl may include pyrrolyl, pyrazinyl, pyridyl, pyrimidinyl, triazinyl, indolyl, isoindolyl, imidazolyl, furyl, benzofuryl, isobenzofuryl, dibenzofuryl, dibenzothienyl, azodibenzofuryl, azodibenzothienyl, diazodibenzofuryl, diazodibenzothienyl, quinolyl, isoquinolyl, quinoxalinyl, carbazolyl, phenanthridinyl, acridinyl, phenanthrolinyl, phenazinyl, phenothiazinyl, phenoxazinyl, oxazolinyl, oxadiazolyl, furzanyl, thienyl, benzothienyl, dihydroacridinyl, azocarbazolyl, diazocarbazolyl, and quinazolinyl, and optionally include pyridyl, pyrimidinyl, triazinyl, dibenzofuryl, dibenzothienyl, azodibenzofuryl, azodibenzothienyl, diazodibenzofuryl, diazodibenzothienyl, carbazolyl, azocarbazolyl, and diazocarbazolyl.

The following embodiments are merely described to facilitate the understanding of the technical invention, and should not be considered as specific limitations of the present invention.

All raw materials, solvents and the like involved in the synthesis of compounds in the present invention are purchased from Alfa, Acros, and other suppliers known to persons skilled in the art.

### Synthesis of a Common Intermediate L1

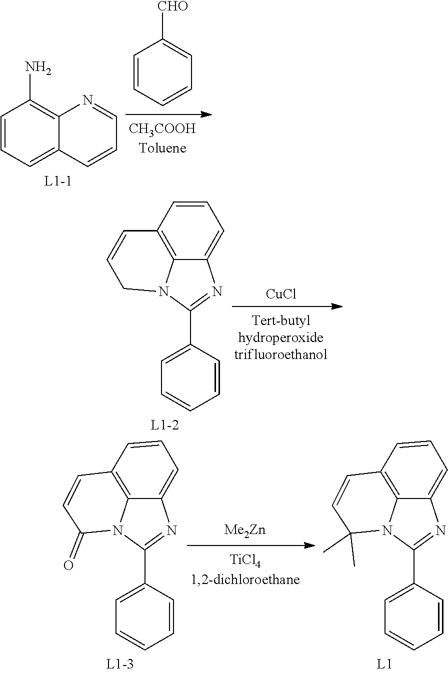

### Synthesis of a Compound L1-2

A compound L1-1 (40.0 g, 0.28 mol, 1.0 eq), La001-2 (35.33 g, 0.33 mol, 1.20 eq), acetic acid (25 g, 0.42 mol, 1.5 eq) and toluene (200 ml) were added into a 500 ml three-necked flask, vacuumization was performed for nitrogen replacement for 3 times, and stirring was performed at 110° C. for reflux for 18 hours under the protection of nitrogen. According to monitoring by thin-layer chromatography (TLC), the raw material L1-1 was completely reacted. Cooling was performed to room temperature, and 120 ml of deionized water was added for water washing and liquid separation. An organic phase on an upper layer was collected, concentrated to remove an organic solvent, spin-dried and separated by column chromatography (with an eluting agent including ethyl acetate and n-hexane at a ratio of 1:20), followed by drying to obtain 40.73 g of a grayish white solid compound L1-2 with a yield of 63.2%. The mass spectrum was: 233.28 (M+H).

### Synthesis of a Compound L1-3

The compound L1-2 (30 g, 129.1 mmol, 1.0 eq), cuprous chloride (1.28 g, 12.92 mmol, 0.1 eq), tert-butyl hydroperoxide (23.28 g, 258.3 mmol, 2.0 eq) and trifluoroethanol (300 ml) were sequentially added into a 1 L three-necked flask, vacuumization was performed for nitrogen replacement for 3 times, and the above compounds were heated to about 50° C. in an oil bath and stirred for 6 hours. According to monitoring of a sample by TLC, the raw material L1-2 was basically completely reacted. Cooling was performed to room temperature, and deionized water was added for water washing for 3 times (150 ml/time). Then, liquid separation was performed, and an organic phase was concentrated under reduced pressure to obtain a solid. The crude product was separated by column chromatography (with a mixture of ethyl acetate (EA) and n-hexane (Hex) at a ratio of 1:10), and a resulting product was dried to obtain 19.3 g of a white-like solid compound L1-3 with a yield of 60.8%. The mass spectrum was: 247.2 (M+H).

### Synthesis of a Compound L1

The compound L1-3 (15 g, 60.91 mmol, 1.0 eq), dimethyl zinc (17.44 g, 182.7 mmol, 3.0 eq) and 1,2-dichloromethane (300 ml) were sequentially added into a 1 L three-necked flask, vacuumization was performed for nitrogen replacement for 3 times, and the reaction system was cooled to −30° C. Titanium tetrachloride (34.66 g, 182.7 mmol, 3.0 eq) was slowly added dropwise, and after the dropping was completed, the above compounds were stirred at room temperature for 2 hours. According to monitoring of a sample by TLC, the raw material L1-3 was basically completely reacted. Deionized water (200 ml) was slowly added for quenching, and ethyl acetate (350 ml) was added. Then, stirring was performed for extraction and liquid separation, and an organic phase was concentrated under reduced pressure to obtain a solid. The crude product was separated by column chromatography (with a mixture of EA and Hex at a ratio of 1:20), and a resulting product was dried to obtain 12.18 g of a white-like solid compound L1 with a yield of 76.8%. The mass spectrum was: 261.3 (M+H).

### Synthesis of a Compound CPD 1

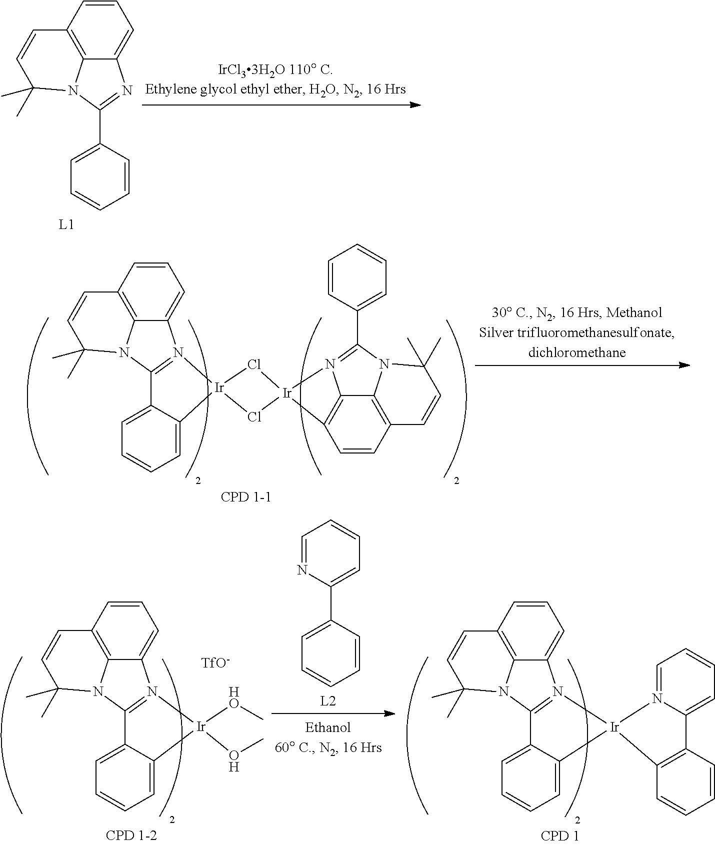

### Synthesis of a Compound CPD 1-1

The compound L1 (27.0 g, 103.7 mmol, 3.0 eq) and IrCl₃·3H₂O (12.19 g, 34.57 mol, 1.0 eq) were added into a 1 L one-necked flask, ethylene glycol ethyl ether (270 ml) and deionized water (90 ml) were added, vacuumization was performed for replacement for 3 times, and a mixture was stirred at 110° C. for reflux for 16 hours under the protection of N₂. After cooling was performed to room temperature, filtration was performed. A filter reside was sequentially washed with methanol (100 ml*3) and n-hexane (100 ml*3) and then dried to obtain 22.86 g of a compound CPD 1-1 with a yield of 88.6%. The obtained compound was directly used in the next step without purification.

### Synthesis of a Compound CPD 1-2

The dimer CPD 1-1 (20.0 g, 26.8 mmol, 1.0 eq) and dichloromethane (1.5 L) were added into a 3 L three-necked flask and stirred for dissolution. Silver trifluoromethanesulfonate (13.77 g, 53.6 mmol, 2.0 eq) was dissolved in methanol (1.2 L) and then added into the original reaction solution flask, vacuumization was performed for replacement for 3 times, and a mixture was stirred at room temperature for 16 hours under the protection of N₂. Then, a reaction solution was filtered with diatomite. A filter residue was rinsed with dichloromethane (150 ml), and a filtrate was spin-dried to obtain 13.69 g of a compound CPD 1-2 with a yield of 80.5%. The obtained compound was directly used in the next step without purification.

### Synthesis of a Compound CPD 1

The compound CPD 1-2 (7.5 g, 8.12 mmol, 1.0 eq) and L2 (2.52 g, 16.23 mmol, 2.0 eq) were added into a 250 ml three-necked flask, ethanol (75 ml) was added, vacuumization was performed for replacement for 3 times, and stirring was performed for reflux for 16 hours under the protection of N₂. After cooling was performed to room temperature, filtration was performed. A solid was collected, dissolved in dichloromethane (150 ml) and filtered with silica gel. A filter cake was rinsed with dichloromethane (50 ml), and a filtrate was spin-dried and separated by column chromatography (with a developing agent including dichloromethane and n-hexane at a ratio of 1:5) to obtain a crude product. Then, the crude product was recrystallized with tetrahydrofuran/methanol for 2 times (the ratio of the product to the tetrahydrofuran to the methanol was 1:5:5) and beaten with n-hexane (80 ml) for 1 time, followed by drying to obtain 4.62 g of a compound CPD 1 with a yield of 65.8%. 4.62 g of the crude product CPD 1 was sublimated and purified to obtain 2.88 g of sublimated and purified CPD 1 with a yield of 62.33%. The mass spectrum was: 866.06 (M+H). ¹H NMR (400 MHz, CDCl₃) δ 8.37 (d, 1H), 8.16 (d, 1H), 7.77 (m, 3H), 7.56-7.34 (m, 9H), 7.22-7.02 (m, 5H), 6.90 (m, 3H), 6.50 (d, 2H), 5.76 (d, 2H), 1.75 (s, 12H).

### Synthesis of a Compound CPD 6

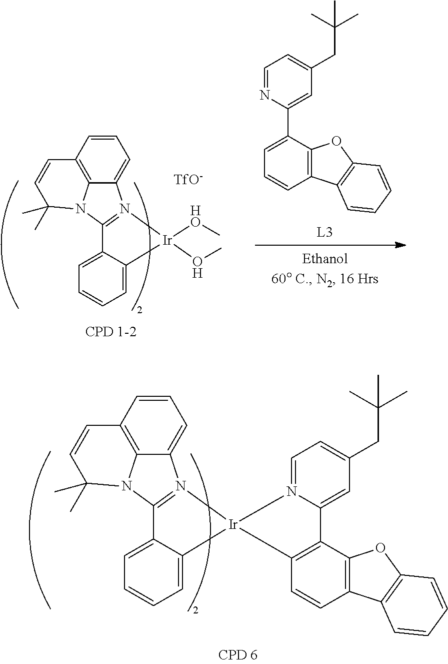

With reference to synthesis and purification methods of the compound CPD 1, only the corresponding raw materials were required to be changed, and 5.11 g of a target compound CPD 6 with a yield of 63.8% was obtained. 5.11 g of the crude product CPD 6 was sublimated and purified to obtain 3.24 g of sublimated and purified CPD 6 with a yield of 63.4%. The mass spectrum was: 1026.27 (M+H). ¹H NMR (400 MHz, DMSO) δ 8.50 (d, 1H), 7.98 (d, 1H), 7.87-7.66 (m, 4H), 7.58-7.27 (m, 9H), 7.22-7.01 (m, 6H), 6.52 (m, 4H), 5.76 (m, 2H), 3.21 (s, 2H), 1.75 (s, 12H), 0.85 (s, 9H).

### Synthesis of a Compound CPD 12

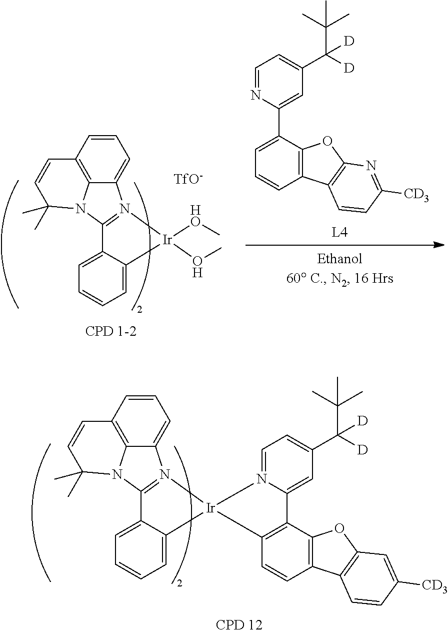

With reference to synthesis and purification methods of the compound CPD 1, only the corresponding raw materials were required to be changed, and 3.66 g of a target compound CPD 12 with a yield of 48.3% was obtained. 3.66 g of the crude product CPD 12 was sublimated and purified to obtain 2.12 g of sublimated and purified CPD 12 with a yield of 65.43%. The mass spectrum was: 1046.31 (M+H). ¹H NMR (400 MHz, DMSO) δ 8.49 (d, J=5.0 Hz, 2H), 7.88-7.66 (m, 4H), 7.46 (m, 9H), 7.21-6.98 (m, 6H), 6.61 (d, 2H), 5.76 (s, 2H), 1.76 (s, 12H), 1.01 (s, 9H).

### Synthesis of a Common Intermediate L5

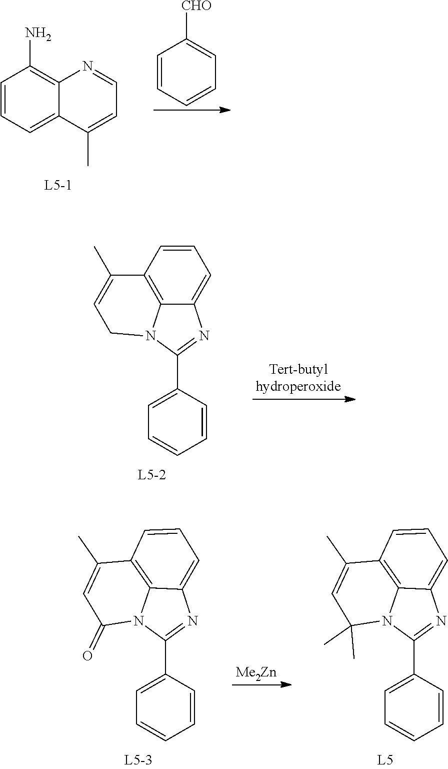

### Synthesis of a Compound L5-2

With reference to synthesis and purification methods of the compound L1-2, only the corresponding raw materials were required to be changed, and 16.3 g of a target compound L5-2 with a yield of 63.5% was obtained. The mass spectrum was: 247.3 (M+H).

### Synthesis of a Compound L5-3

With reference to synthesis and purification methods of the compound L1-3, only the corresponding raw materials were required to be changed, and 11.8 g of a target compound L5-3 with a yield of 53.8% was obtained. The mass spectrum was: 261.2 (M+H).

### Synthesis of a Compound L5

With reference to synthesis and purification methods of the compound L1, only the corresponding raw materials were required to be changed, and 9.8 g of a target compound L5 with a yield of 67.9% was obtained. The mass spectrum was: 275.3 (M+H).

### Synthesis of a Compound CPD 19

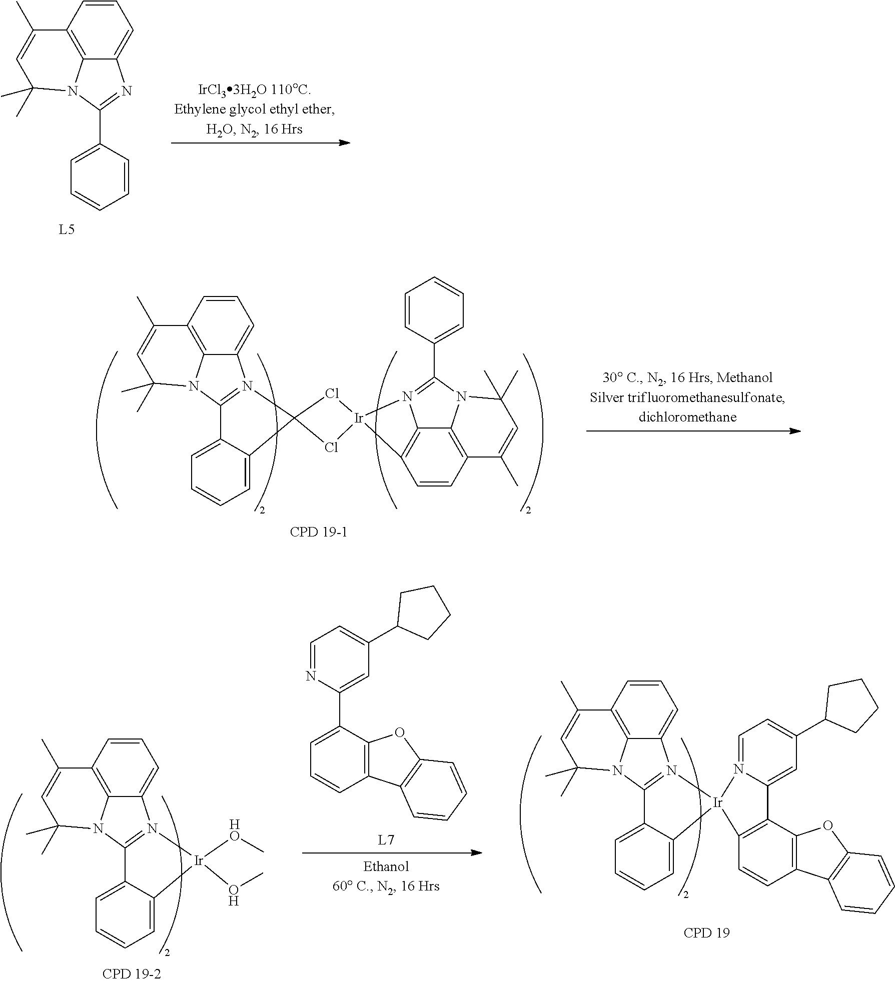

### Synthesis of a Compound CPD 19-1

With reference to synthesis and purification methods of the compound CPD 1-1, only the corresponding raw materials were required to be changed, and an obtained compound was directly used in the next step without purification.

### Synthesis of a Compound CPD 19-2

With reference to synthesis and purification methods of the compound CPD 1-2, only the corresponding raw materials were required to be changed, and an obtained compound was directly used in the next step without purification.

### Synthesis of a Compound CPD 19

With reference to synthesis and purification methods of the compound CPD 1, only the corresponding raw materials were required to be changed, and 3.77 g of a target compound CPD 19 with a yield of 56.8% was obtained. 3.77 g of the crude product CPD 19 was sublimated and purified to obtain 2.45 g of sublimated and purified CPD 19 with a yield of 64.98%. The mass spectrum was: 1052.3 (M+H). ¹H NMR (400 MHz, CDCl₃) δ 8.52 (d, 1H), 7.98 (d, 1H), 7.87-7.66 (m, 6H), 7.58-7.27 (m, 9H), 7.17 (d, 3H), 7.06 (d, J=10.0 Hz, 3H), 5.54 (s, 2H), 2.97 (m, 1H), 1.99 (d, J=23.0 Hz, 8H), 1.85-1.58 (m, 18H).

### Synthesis of a Common Intermediate L8

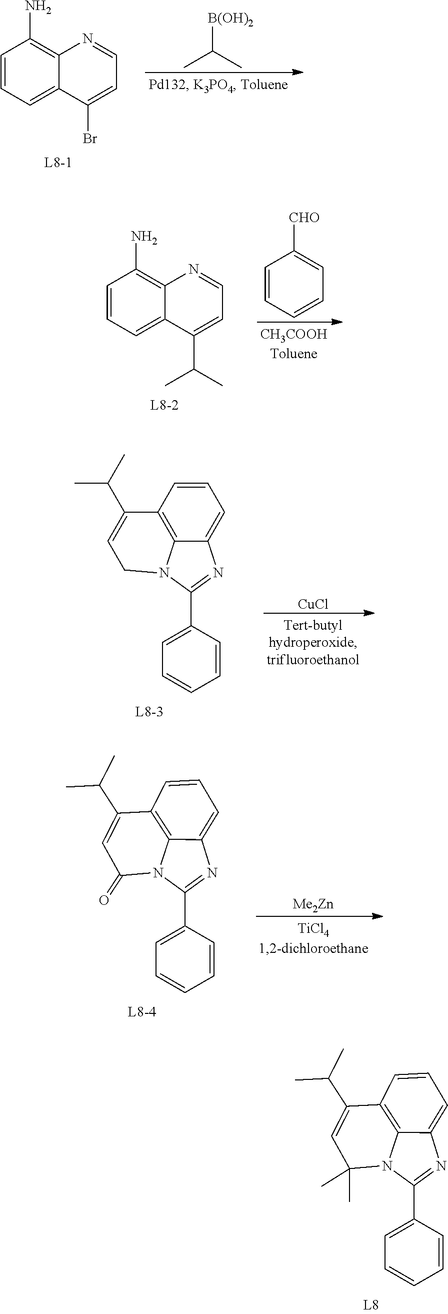

### Synthesis of a Compound L8-2

A compound L8-1 (22 g, 98.62 mmol, 1.0 eq), isopropylboronic acid (10.4 g, 118.35 mmol, 1.2 eq), bis(di-tert-butyl(4-dimethylaminophenyl)phosphine)dichloropalladium (II) (1.4 g, 1.97 mmol, 0.02 eq), K₃PO₄ (41.87 g, 197.25 mmol, 2.0 eq) and toluene (220 ml) were sequentially added into a 500 ml three-necked flask, vacuumization was performed for nitrogen replacement for 3 times, and the above compounds were heated to about 70° C. in an oil bath and stirred for 16 hours. According to monitoring of a sample by TLC, the raw material L8-1 was basically completely reacted. Cooling was performed to room temperature, and deionized water was added for water washing for 3 times (120 ml/time). Then, liquid separation was performed, and an organic phase was concentrated under reduced pressure to obtain a solid. The crude product was separated by column chromatography (with a mixture of EA and Hex at a ratio of 1:20), and a resulting product was dried to obtain 14.83 g of a white-like solid compound L8-2 with a yield of 78.3%. The mass spectrum was: 187.25 (M+H).

### Synthesis of a Compound L8-3

With reference to synthesis and purification methods of the compound L1-2, only the corresponding raw materials were required to be changed, and 17.1 g of a target compound L8-3 with a yield of 57.7% was obtained. The mass spectrum was: 275.3 (M+H).

### Synthesis of a Compound L8-4

With reference to synthesis and purification methods of the compound L1-3, only the corresponding raw materials were required to be changed, and 13.4 g of a target compound L8-4 with a yield of 50.7% was obtained. The mass spectrum was: 289.3 (M+H).

### Synthesis of a Compound L8

With reference to synthesis and purification methods of the compound L1, only the corresponding raw materials were required to be changed, and 8.7 g of a target compound L8 with a yield of 63.9% was obtained. The mass spectrum was: 303.4 (M+H).

### Synthesis of a Compound CPD 34

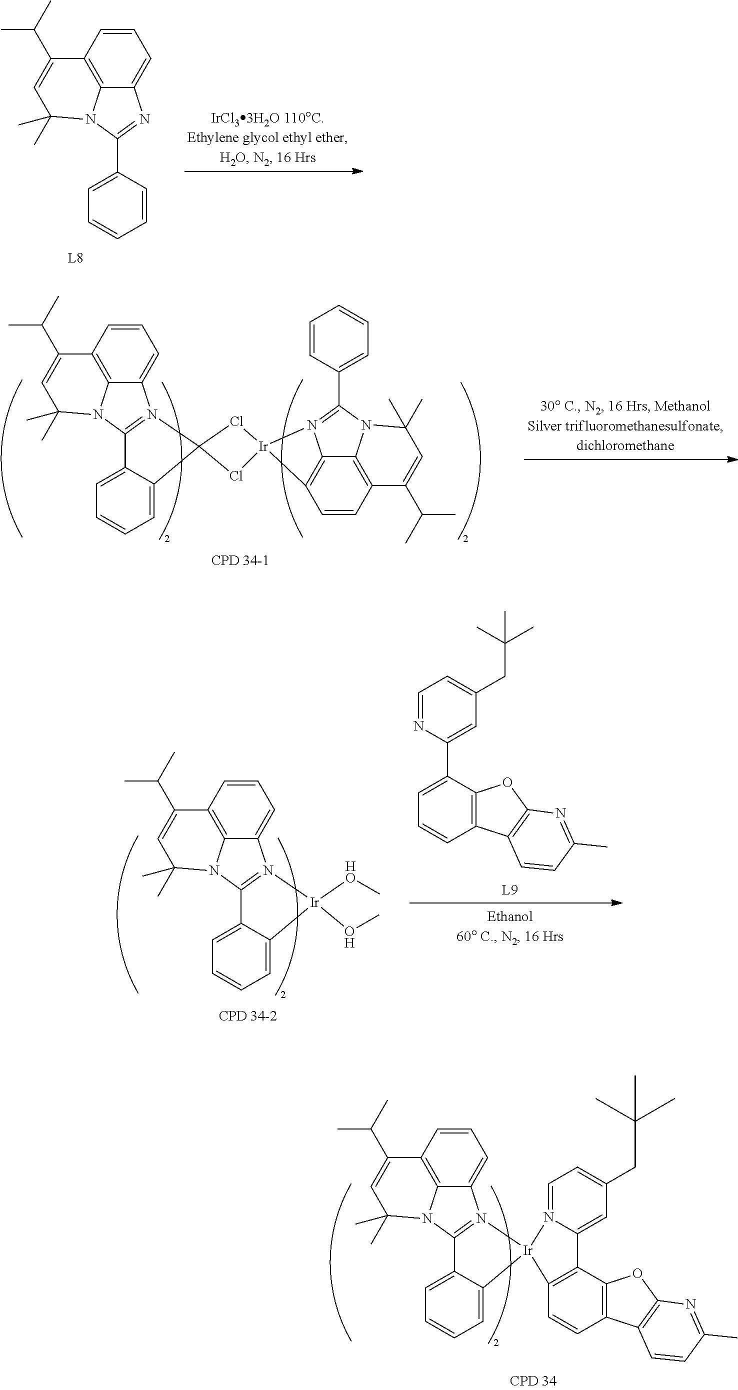

### Synthesis of a Compound CPD 34-1

With reference to synthesis and purification methods of the compound CPD 1-1, only the corresponding raw materials were required to be changed, and an obtained compound was directly used in the next step without purification.

### Synthesis of a Compound CPD 34-2

With reference to synthesis and purification methods of the compound CPD 1-2, only the corresponding raw materials were required to be changed, and an obtained compound was directly used in the next step without purification.

### Synthesis of a Compound CPD 34

With reference to synthesis and purification methods of the compound CPD 1, only the corresponding raw materials were required to be changed, and 3.05 g of a target compound CPD 34 with a yield of 47.6% was obtained. 3.05 g of the crude product CPD 34 was sublimated and purified to obtain 1.87 g of sublimated and purified CPD 34 with a yield of 61.31%. The mass spectrum was: 1025.44 (M+H). ¹H NMR (400 MHz, CDCl₃) δ 8.47 (d, J=26.0 Hz, 2H), 7.87-7.66 (m, 4H), 7.46 (d, J=40.0 Hz, 6H), 7.22-6.97 (m, 9H), 5.54 (s, 2H), 3.21 (s, 2H), 2.94 (m, 2H), 2.68 (s, 3H), 1.74 (s, 12H), 0.94 (d, J=95.0 Hz, 21H).

### Synthesis of a Common Intermediate L10

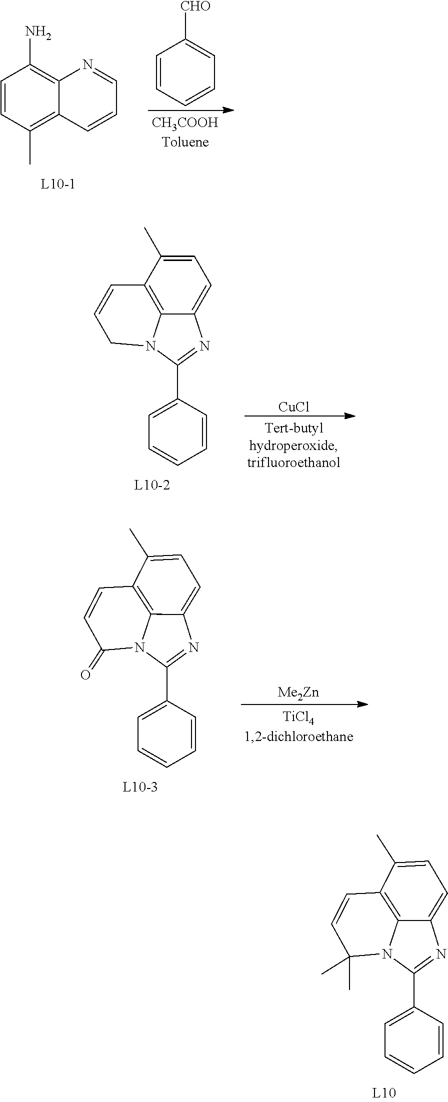

### Synthesis of a Compound L10-2

With reference to synthesis and purification methods of the compound L1-2, only the corresponding raw materials were required to be changed, and 13.7 g of a target compound L10-2 with a yield of 69.4% was obtained. The mass spectrum was: 247.3 (M+H).

### Synthesis of a Compound L10-3

With reference to synthesis and purification methods of the compound L1-3, only the corresponding raw materials were required to be changed, and 10.7 g of a target compound L10-3 with a yield of 65.2% was obtained. The mass spectrum was: 261.2 (M+H).

### Synthesis of a Compound L10

With reference to synthesis and purification methods of the compound L1, only the corresponding raw materials were required to be changed, and 8.64 g of a target compound L10 with a yield of 63.9% was obtained. The mass spectrum was: 275.3 (M+H).

### Synthesis of a Compound CPD 50

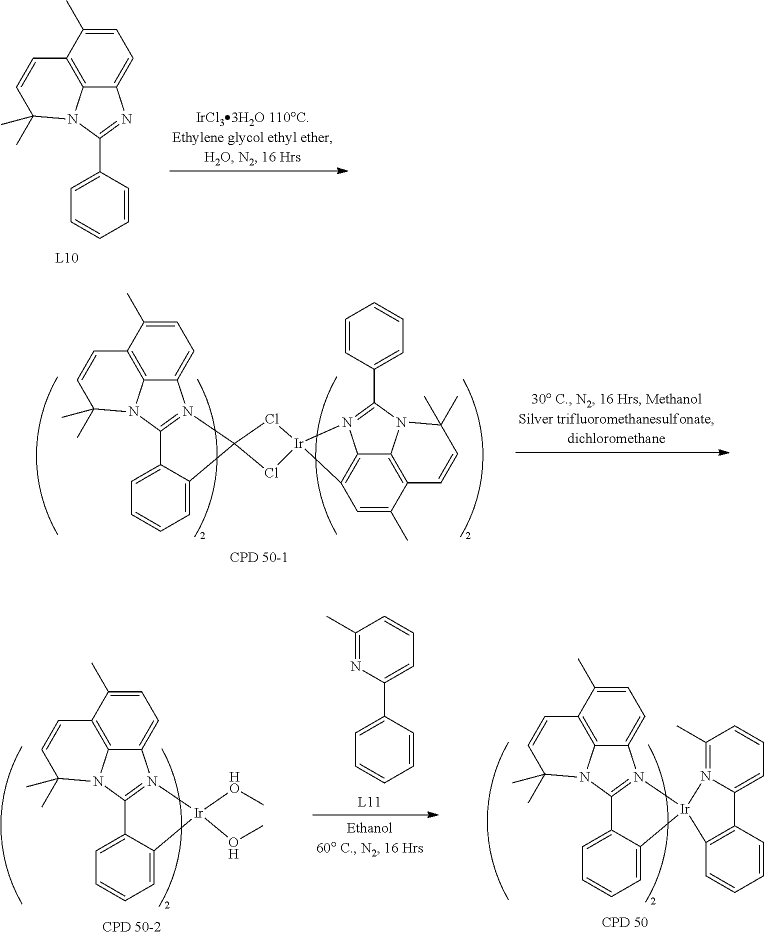

### Synthesis of a Compound CPD 50-1

With reference to synthesis and purification methods of the compound CPD 1-1, only the corresponding raw materials were required to be changed, and an obtained compound was directly used in the next step without purification.

### Synthesis of a Compound CPD 50-2

With reference to synthesis and purification methods of the compound CPD 1-2, only the corresponding raw materials were required to be changed, and an obtained compound was directly used in the next step without purification.

### Synthesis of a Compound CPD 50

With reference to synthesis and purification methods of the compound CPD 1, only the corresponding raw materials were required to be changed, and 3.52 g of a target compound CPD 50 with a yield of 50.9% was obtained. 3.52 g of the crude product CPD 50 was sublimated and purified to obtain 2.23 g of sublimated and purified CPD 50 with a yield of 63.35%. The mass spectrum was: 908.13 (M+H). ¹H NMR (400 MHz, CDCl₃) δ 8.46 (m, 1H), 8.21 (m, 2H), 7.78-7.44 (m, 9H), 7.02 (m, 6H), 6.59 (d, J=22.3 Hz, 3H), 5.92 (s, 2H), 2.76 (s, 3H), 2.22 (s, 6H), 1.74 (s, 12H).

### Synthesis of a Common Intermediate L12

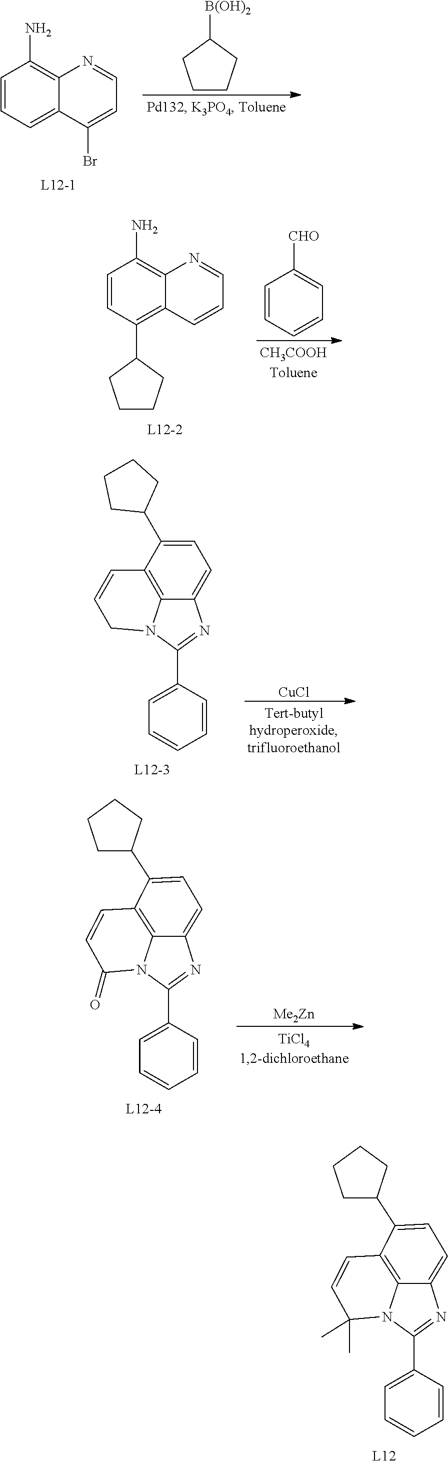

### Synthesis of a Compound L12-2

With reference to synthesis and purification methods of the compound L8-2, only the corresponding raw materials were required to be changed, and 15.6 g of a target compound L12-2 with a yield of 63.7% was obtained. The mass spectrum was: 213.3 (M+H).

### Synthesis of a Compound L12-3

With reference to synthesis and purification methods of the compound L1-2, only the corresponding raw materials were required to be changed, and 12.4 g of a target compound L12-3 with a yield of 52.3% was obtained. The mass spectrum was: 301.4 (M+H).

### Synthesis of a Compound L12-4

With reference to synthesis and purification methods of the compound L1-3, only the corresponding raw materials were required to be changed, and 11.3 g of a target compound L12-4 with a yield of 61.7% was obtained. The mass spectrum was: 315.3 (M+H).

### Synthesis of a Compound L12

With reference to synthesis and purification methods of the compound L1, only the corresponding raw materials were required to be changed, and 7.9 g of a target compound L12 with a yield of 56.4% was obtained. The mass spectrum was: 329.4 (M+H).

### Synthesis of a Compound CPD 78

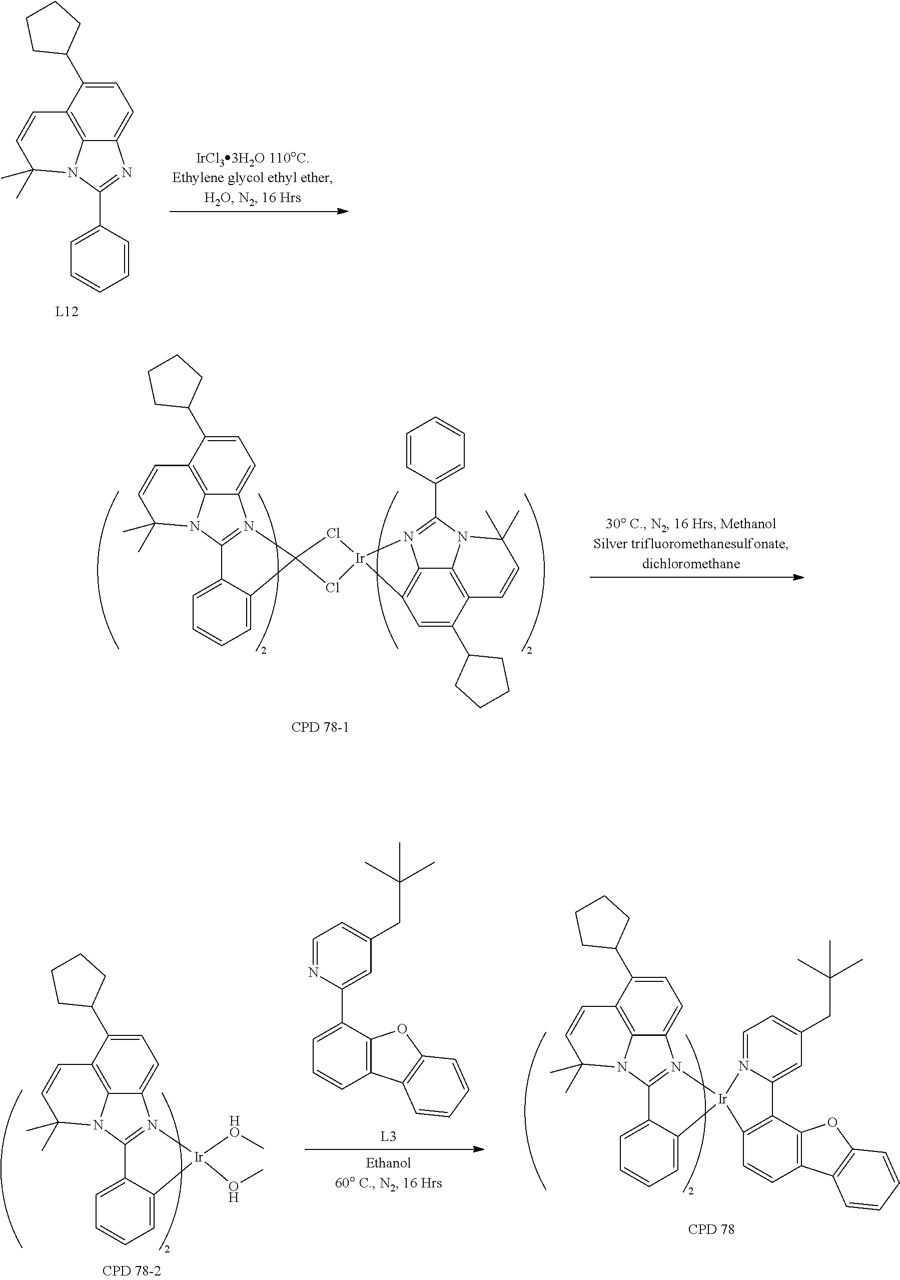

### Synthesis of a Compound CPD 78-1

With reference to synthesis and purification methods of the compound CPD 1-1, only the corresponding raw materials were required to be changed, and an obtained compound was directly used in the next step without purification.

### Synthesis of a Compound CPD 78-2

With reference to synthesis and purification methods of the compound CPD 1-2, only the corresponding raw materials were required to be changed, and an obtained compound was directly used in the next step without purification.

### Synthesis of a Compound CPD 78

With reference to synthesis and purification methods of the compound CPD 1, only the corresponding raw materials were required to be changed, and 3.31 g of a target compound CPD 78 with a yield of 51.3% was obtained. 3.31 g of the crude product CPD 78 was sublimated and purified to obtain 1.87 g of sublimated and purified CPD 78 with a yield of 56.49%. The mass spectrum was: 1162.5 (M+H). ¹H NMR (400 MHz, CDCl₃) δ8.53 (d, 1H), 7.98 (d, 1H), 7.88-7.60 (m, 6H), 7.58-7.24 (m, 7H), 7.05 (m, 6H), 6.56 (d, 2H), 5.92 (d, 2H), 3.21 (s, 2H), 3.09 (m, 2H), 2.00 (m, 4H), 1.86-1.54 (m, 24H), 0.85 (s, 9H).

### Synthesis of a Common Intermediate L13

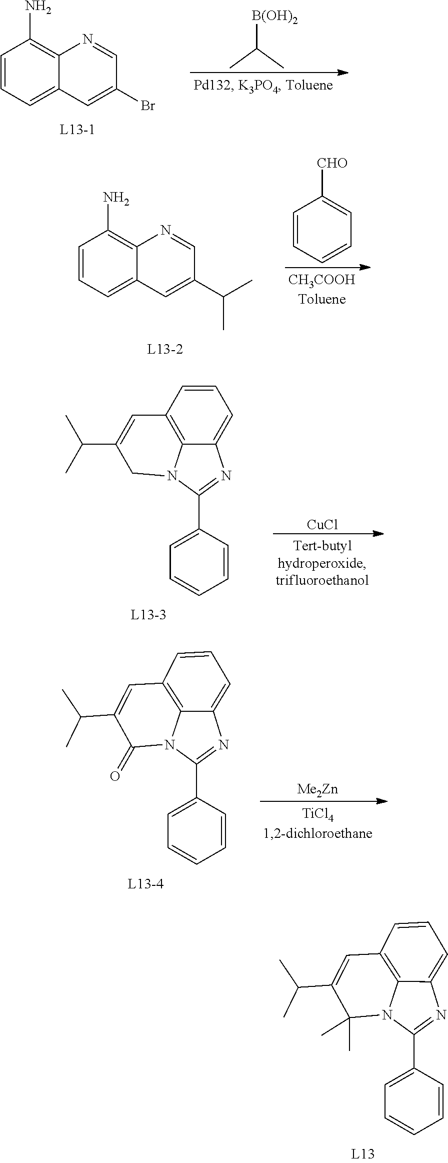

### Synthesis of a Compound L13-2

With reference to synthesis and purification methods of the compound L8-2, only the corresponding raw materials were required to be changed, and 16.9 g of a target compound L13-2 with a yield of 53.7% was obtained. The mass spectrum was: 187.2 (M+H).

### Synthesis of a Compound L13-3

With reference to synthesis and purification methods of the compound L1-2, only the corresponding raw materials were required to be changed, and 14.7 g of a target compound L13-3 with a yield of 57.2% was obtained. The mass spectrum was: 275.3 (M+H).

### Synthesis of a Compound L13-4

With reference to synthesis and purification methods of the compound L1-3, only the corresponding raw materials were required to be changed, and 12.6 g of a target compound L13-4 with a yield of 58.1% was obtained. The mass spectrum was: 289.3 (M+H).

### Synthesis of a Compound L13

With reference to synthesis and purification methods of the compound L1, only the corresponding raw materials were required to be changed, and 10.2 g of a target compound L13 with a yield of 55.4% was obtained. The mass spectrum was: 303.4 (M+H).

### Synthesis of a Compound CPD 107

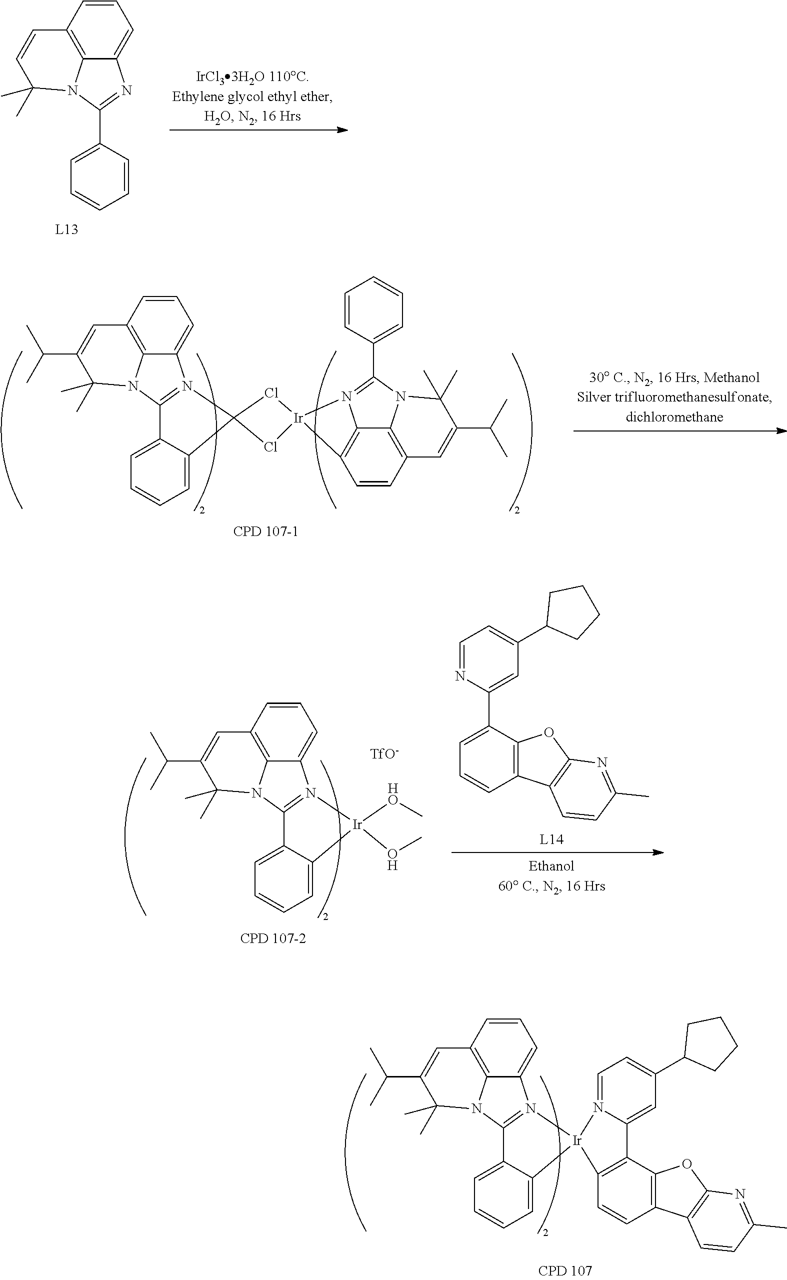

### Synthesis of a Compound CPD 107-1

With reference to synthesis and purification methods of the compound CPD 1-1, only the corresponding raw materials were required to be changed, and an obtained compound was directly used in the next step without purification.

### Synthesis of a Compound CPD 107-2

With reference to synthesis and purification methods of the compound CPD 1-2, only the corresponding raw materials were required to be changed, and an obtained compound was directly used in the next step without purification.

### Synthesis of a Compound CPD 107

With reference to synthesis and purification methods of the compound CPD 1, only the corresponding raw materials were required to be changed, and 2.88 g of a target compound CPD 107 with a yield of 46.3% was obtained. 2.88 g of the crude product CPD 107 was sublimated and purified to obtain 1.46 g of sublimated and purified CPD 107 with a yield of 50.69%. The mass spectrum was: 1123.4 (M+H). ¹H NMR (400 MHz, CDCl₃) δ8.52 (d, 1H), 8.31 (d, 1H), 7.87-7.64 (m, 4H), 7.46 (d, J=40.0 Hz, 6H), 7.25-6.96 (m, 9H), 6.85 (m, 2H), 2.68 (s, 3H), 2.49 (m, 1H), 2.30 (m, 2H), 2.02 (m, 2H), 1.87-1.59 (m, 18H), 1.04 (d, 12H).

### Synthesis of a Common Intermediate L15

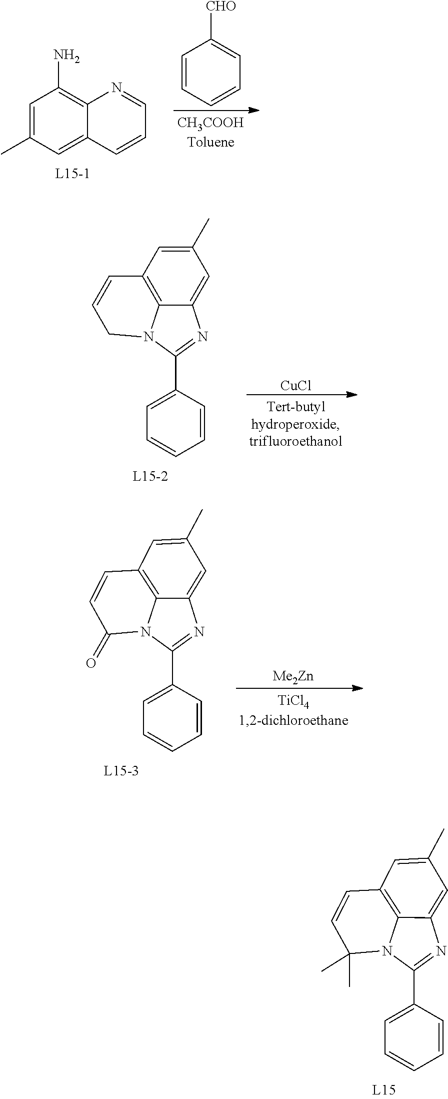

### Synthesis of a Compound L15-2

With reference to synthesis and purification methods of the compound L1-2, only the corresponding raw materials were required to be changed, and 14.8 g of a target compound L15-2 with a yield of 66.3% was obtained. The mass spectrum was: 247.3 (M+H).

### Synthesis of a Compound L15-3

With reference to synthesis and purification methods of the compound L1-3, only the corresponding raw materials were required to be changed, and 13.1 g of a target compound L15-3 with a yield of 70.2% was obtained. The mass spectrum was: 261.2 (M+H).

### Synthesis of a Compound L15

With reference to synthesis and purification methods of the compound L1, only the corresponding raw materials were required to be changed, and 9.3 g of a target compound L15 with a yield of 67.3% was obtained. The mass spectrum was: 275.3 (M+H).

### Synthesis of a Compound CPD 136

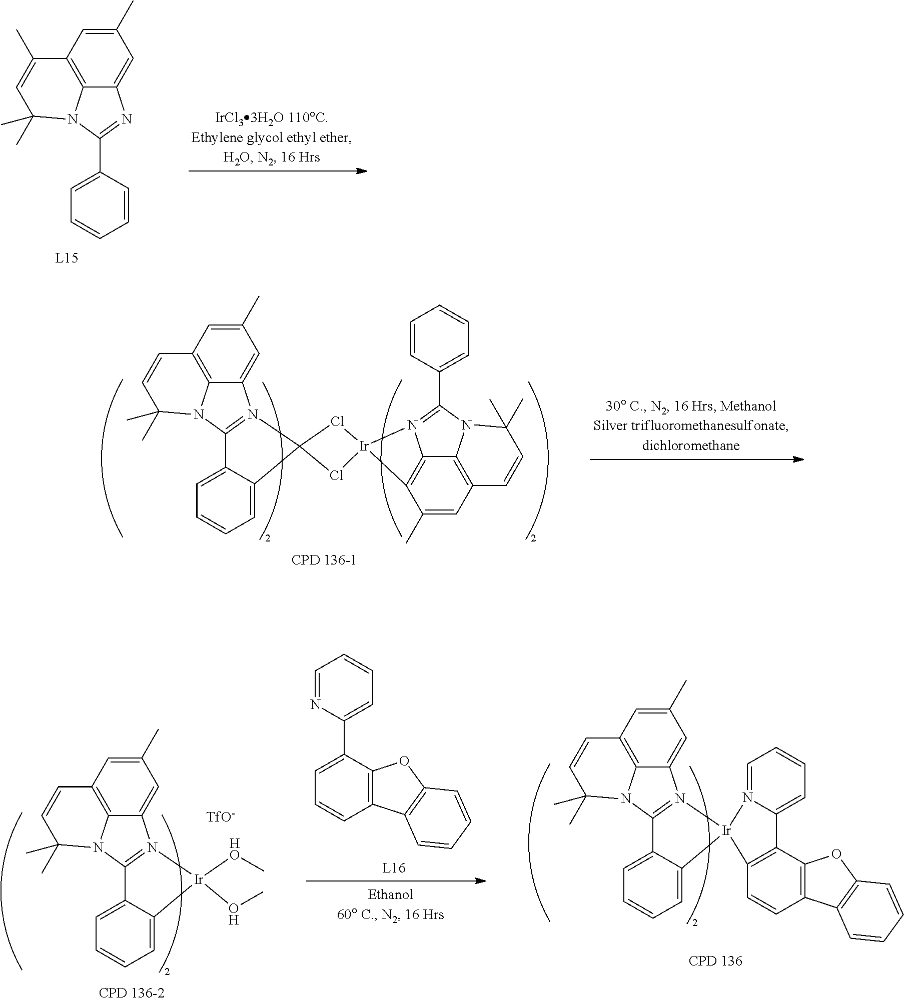

### Synthesis of a Compound CPD 136-1

With reference to synthesis and purification methods of the compound CPD 1-1, only the corresponding raw materials were required to be changed, and an obtained compound was directly used in the next step without purification.

### Synthesis of a Compound CPD 136-2

With reference to synthesis and purification methods of the compound CPD 1-2, only the corresponding raw materials were required to be changed, and an obtained compound was directly used in the next step without purification.

### Synthesis of a Compound CPD 136

With reference to synthesis and purification methods of the compound CPD 1, only the corresponding raw materials were required to be changed, and 3.31 g of a target compound CPD 136 with a yield of 52.3% was obtained. 3.31 g of the crude product CPD 136 was sublimated and purified to obtain 1.94 g of sublimated and purified CPD 136 with a yield of 58.61%. The mass spectrum was: 984.1 (M+H). ¹H NMR (400 MHz, CDCl₃) δ 8.37 (d, 1H), 7.98 (d, 1H), 7.73 (d, J=40.0 Hz, 3H), 7.63-7.26 (m, 10H), 7.16 (m, 6H), 6.90 (d, 1H), 6.54 (d, 2H), 5.76 (s, 2H), 2.31 (s, 6H), 1.74 (s, 12H).

### Synthesis of a Common Intermediate L17

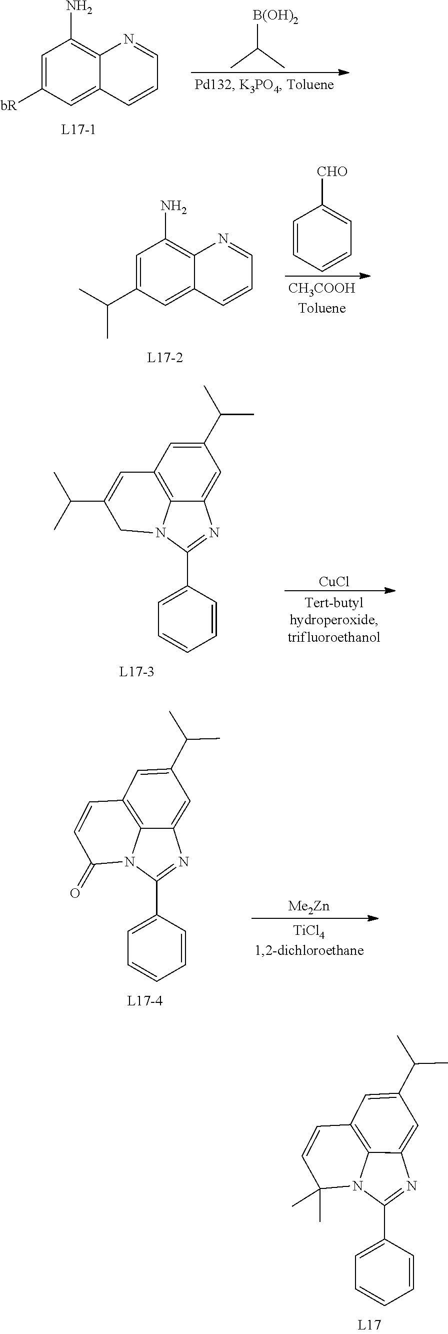

### Synthesis of a Compound L17-2

With reference to synthesis and purification methods of the compound L8-2, only the corresponding raw materials were required to be changed, and 16.9 g of a target compound L17-2 with a yield of 53.7% was obtained. The mass spectrum was: 187.2 (M+H).

### Synthesis of a Compound L17-3

With reference to synthesis and purification methods of the compound L1-2, only the corresponding raw materials were required to be changed, and 14.7 g of a target compound L17-3 with a yield of 57.2% was obtained. The mass spectrum was: 275.3 (M+H).

### Synthesis of a Compound L17-4

With reference to synthesis and purification methods of the compound L1-3, only the corresponding raw materials were required to be changed, and 12.6 g of a target compound L17-4 with a yield of 58.1% was obtained. The mass spectrum was: 289.3 (M+H).

### Synthesis of a Compound L17

With reference to synthesis and purification methods of the compound L1, only the corresponding raw materials were required to be changed, and 10.2 g of a target compound L17 with a yield of 55.4% was obtained. The mass spectrum was: 303.4 (M+H).

### Synthesis of a Compound CPD 150

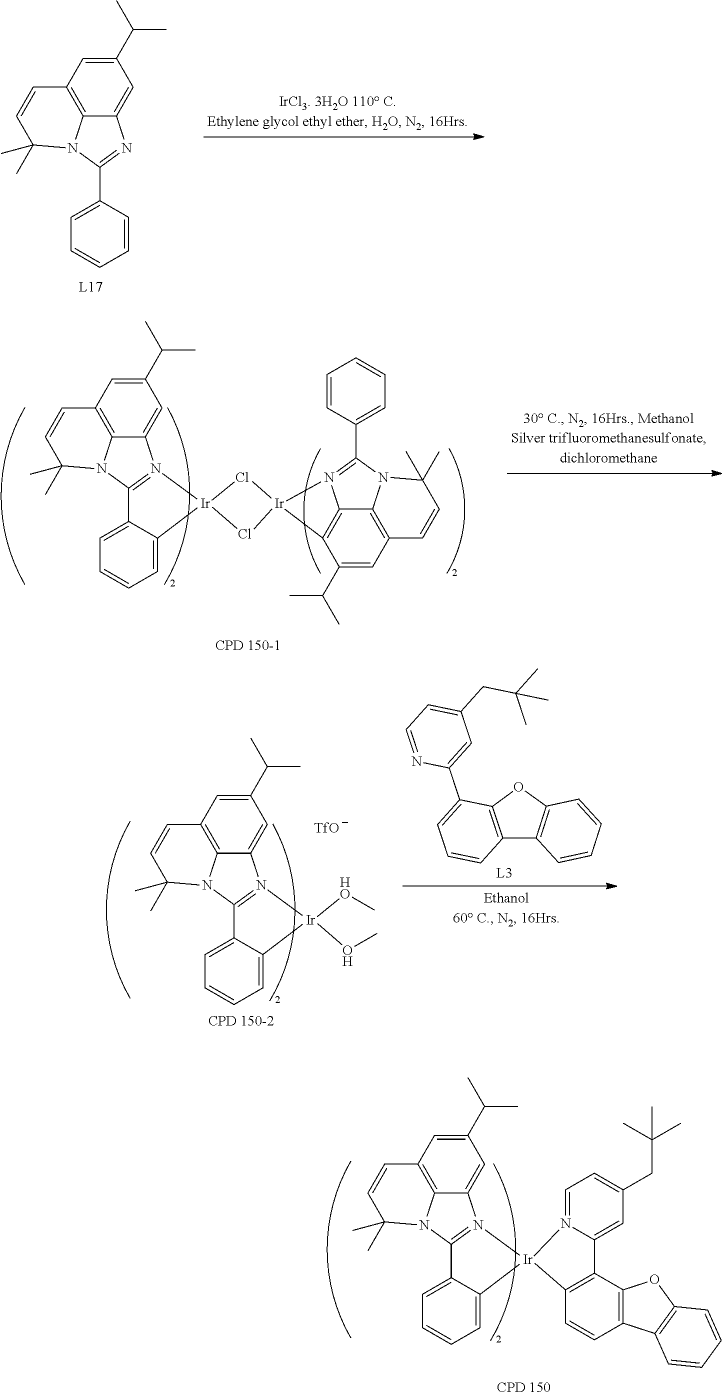

### Synthesis of a Compound CPD 150-1

With reference to synthesis and purification methods of the compound CPD 1-1, only the corresponding raw materials were required to be changed, and an obtained compound was directly used in the next step without purification.

### Synthesis of a Compound CPD 150-2

With reference to synthesis and purification methods of the compound CPD 1-2, only the corresponding raw materials were required to be changed, and an obtained compound was directly used in the next step without purification.

### Synthesis of a Compound CPD 150

With reference to synthesis and purification methods of the compound CPD 1, only the corresponding raw materials were required to be changed, and 3.02 g of a target compound CPD 150 with a yield of 53.1% was obtained. 3.02 g of the crude product CPD 150 was sublimated and purified to obtain 1.68 g of sublimated and purified CPD 150 with a yield of 55.6%. The mass spectrum was: 1110.43 (M+H). ¹H NMR (400 MHz, CDCl₃) δ 8.50 (d, 1H), 7.98 (d, 1H), 7.88-7.66 (m, 7H), 7.59-7.25 (m, 11H), 7.05 (d, 1H), 6.56 (d, 2H), 5.76 (d, 2H), 3.21 (s, 2H), 2.87 (m, 2H), 1.74 (s, 12H), 1.20 (d, 12H), 0.85 (s, 9H).

### Synthesis of a Common Intermediate L18

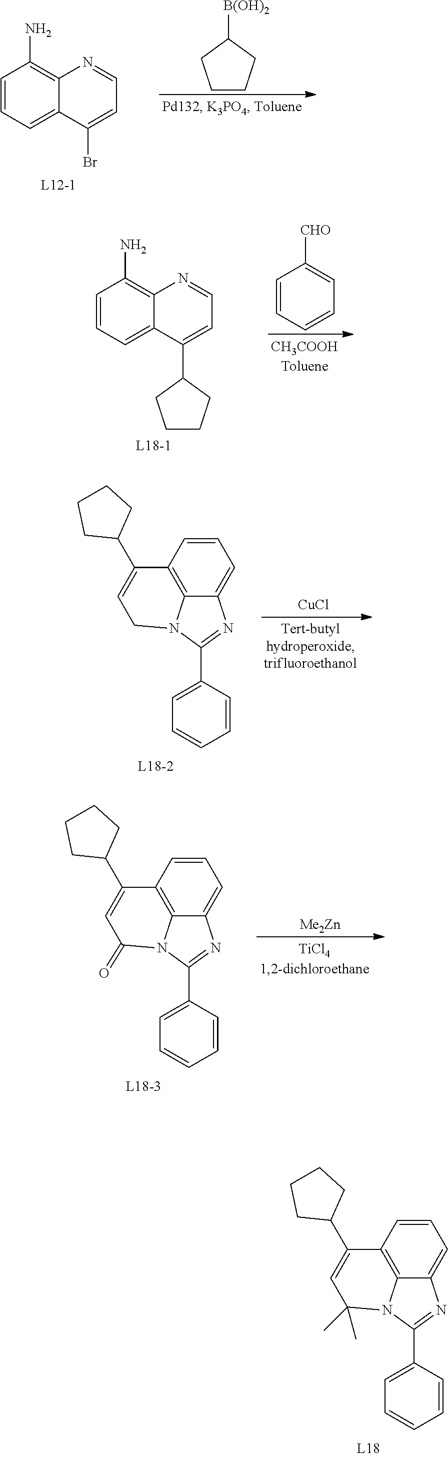

### Synthesis of a Compound L18-1

With reference to synthesis and purification methods of the compound L8-2, only the corresponding raw materials were required to be changed, and 15.4 g of a target compound L18-1 with a yield of 58.9% was obtained. The mass spectrum was: 213.2 (M+H).

### Synthesis of a Compound L18-2

With reference to synthesis and purification methods of the compound L1-2, only the corresponding raw materials were required to be changed, and 14.6 g of a target compound L18-2 with a yield of 60.7% was obtained. The mass spectrum was: 301.4 (M+H).

### Synthesis of a Compound L18-3

With reference to synthesis and purification methods of the compound L1-3, only the corresponding raw materials were required to be changed, and 11.3 g of a target compound L18-3 with a yield of 53.8% was obtained. The mass spectrum was: 315.3 (M+H).

### Synthesis of a Compound L18

With reference to synthesis and purification methods of the compound L1, only the corresponding raw materials were required to be changed, and 8.9 g of a target compound L18 with a yield of 62.1% was obtained. The mass spectrum was: 329.4 (M+H).

### Synthesis of a Compound CPD 171

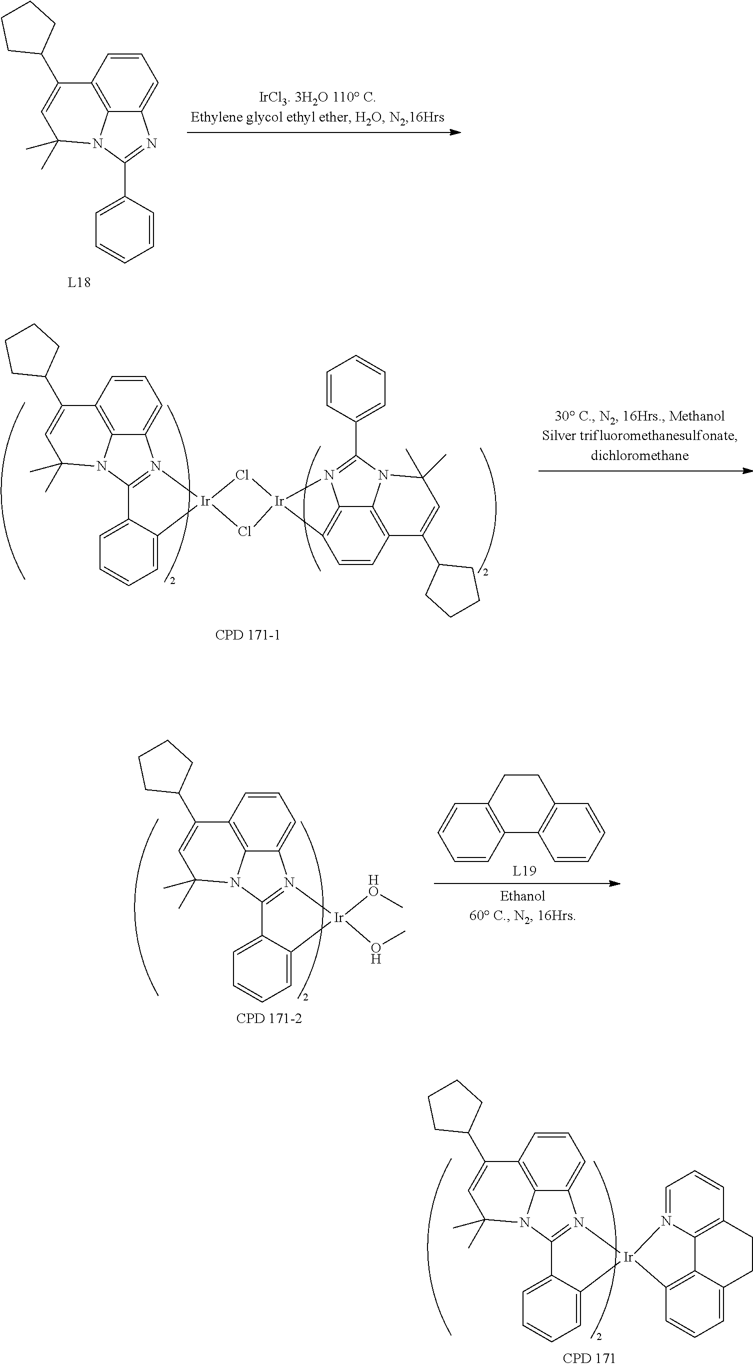

### Synthesis of a Compound CPD 171-1

With reference to synthesis and purification methods of the compound CPD 1-1, only the corresponding raw materials were required to be changed, and an obtained compound was directly used in the next step without purification.

### Synthesis of a Compound CPD 171-2

With reference to synthesis and purification methods of the compound CPD 1-2, only the corresponding raw materials were required to be changed, and an obtained compound was directly used in the next step without purification.

### Synthesis of a Compound CPD 171

With reference to synthesis and purification methods of the compound CPD 1, only the corresponding raw materials were required to be changed, and 2.65 g of a target compound CPD 171 with a yield of 43.8% was obtained. 2.65 g of the crude product CPD 171 was sublimated and purified to obtain 1.44 g of sublimated and purified CPD 171 with a yield of 54.3%. The mass spectrum was: 1028.3 (M+H). ¹H NMR (400 MHz, CDCl₃) δ 8.35 (d, 1H), 7.77 (m, 3H), 7.46 (d, J=40.0 Hz, 7H), 7.36-7.03 (m, 6H), 6.67 (m, 3H), 5.54 (s, 2H), 2.97 (d, J=20.0 Hz, 4H), 2.80 (m, 2H), 1.87-1.44 (m, 24H), 1.30 (m, 4H).

### Synthesis of a Compound CPD 195

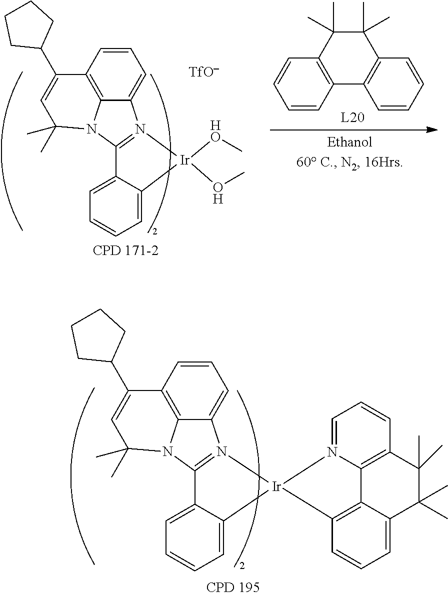

With reference to synthesis and purification methods of the compound CPD 1, only the corresponding raw materials were required to be changed, and 2.73 g of a target compound CPD 195 with a yield of 47.9% was obtained. 2.73 g of the crude product CPD 195 was sublimated and purified to obtain 1.48 g of sublimated and purified CPD 195 with a yield of 54.2%. The mass spectrum was: 1084.4 (M+H). ¹H NMR (400 MHz, CDCl₃) δ8.55 (d, 1H), 7.77 (d, 2H), 7.61-7.25 (m, 9H), 7.12 (m, 7H), 6.67 (t, 1H), 5.54 (s, 2H), 2.42 (m, 2H), 1.92-1.43 (m, 24H), 1.32 (m, 16H).

### Synthesis of a Compound CPD 198

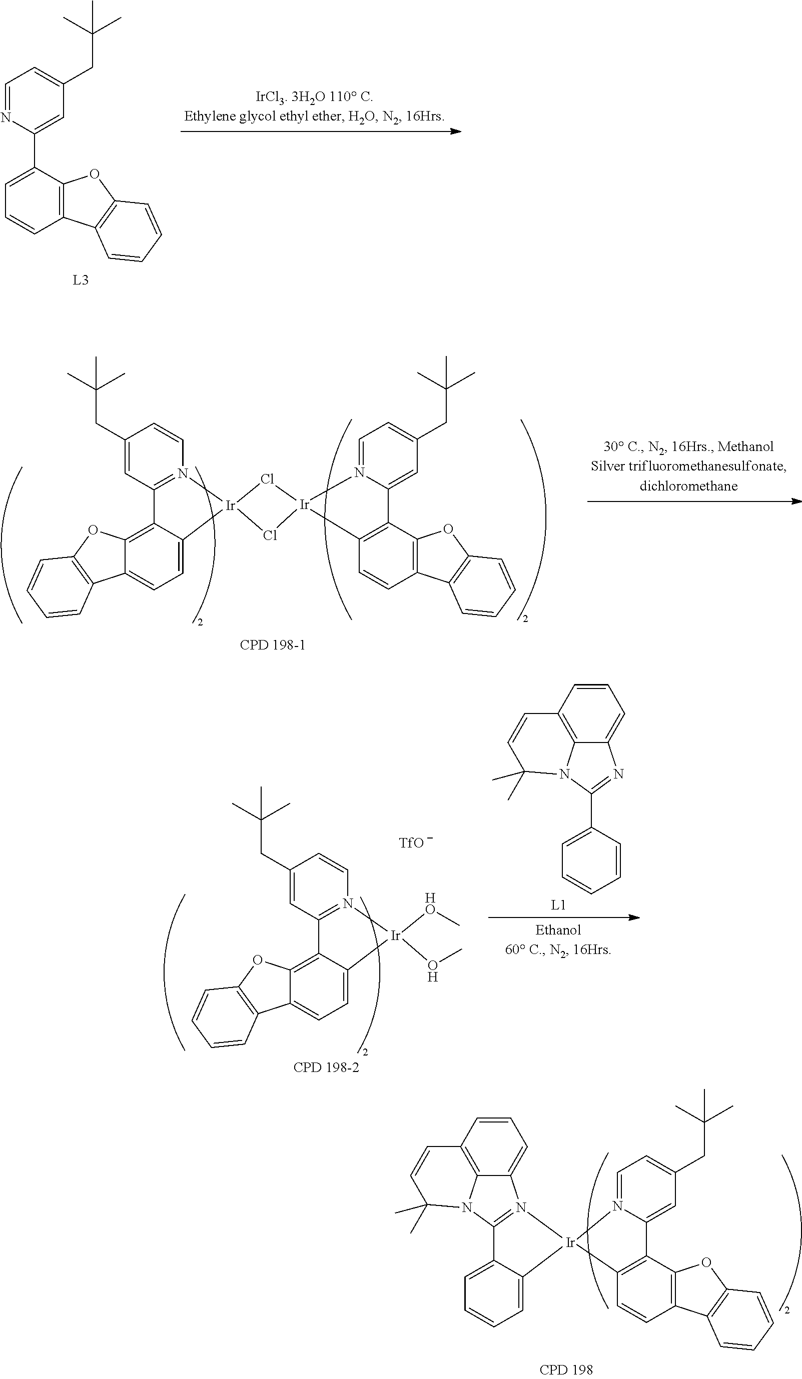

### Synthesis of a Compound CPD 198-1

With reference to synthesis and purification methods of the compound CPD 1-1, only the corresponding raw materials were required to be changed, and an obtained compound was directly used in the next step without purification.

### Synthesis of a Compound CPD 198-2

With reference to synthesis and purification methods of the compound CPD 1-2, only the corresponding raw materials were required to be changed, and an obtained compound was directly used in the next step without purification.

### Synthesis of a Compound CPD 198

With reference to synthesis and purification methods of the compound CPD 1, only the corresponding raw materials were required to be changed, and 2.53 g of a target compound CPD 198 with a yield of 40.7% was obtained. 2.53 g of the crude product CPD 198 was sublimated and purified to obtain 1.21 g of sublimated and purified CPD 198 with a yield of 48.7%. The mass spectrum was: 1026.3 (M+H). ¹H NMR (400 MHz, CDCl₃) δ 8.50 (d, 1H), 7.98 (d, 1H), 7.87-7.66 (m, 6H), 7.59-7.27 (m, 9H), 7.22-7.00 (m, 6H), 6.53 (d, 2H), 5.76 (d, 2H), 3.21 (s, 2H), 1.74 (s, 12H), 0.85 (s, 9H).

### Synthesis of a Compound CPD 244

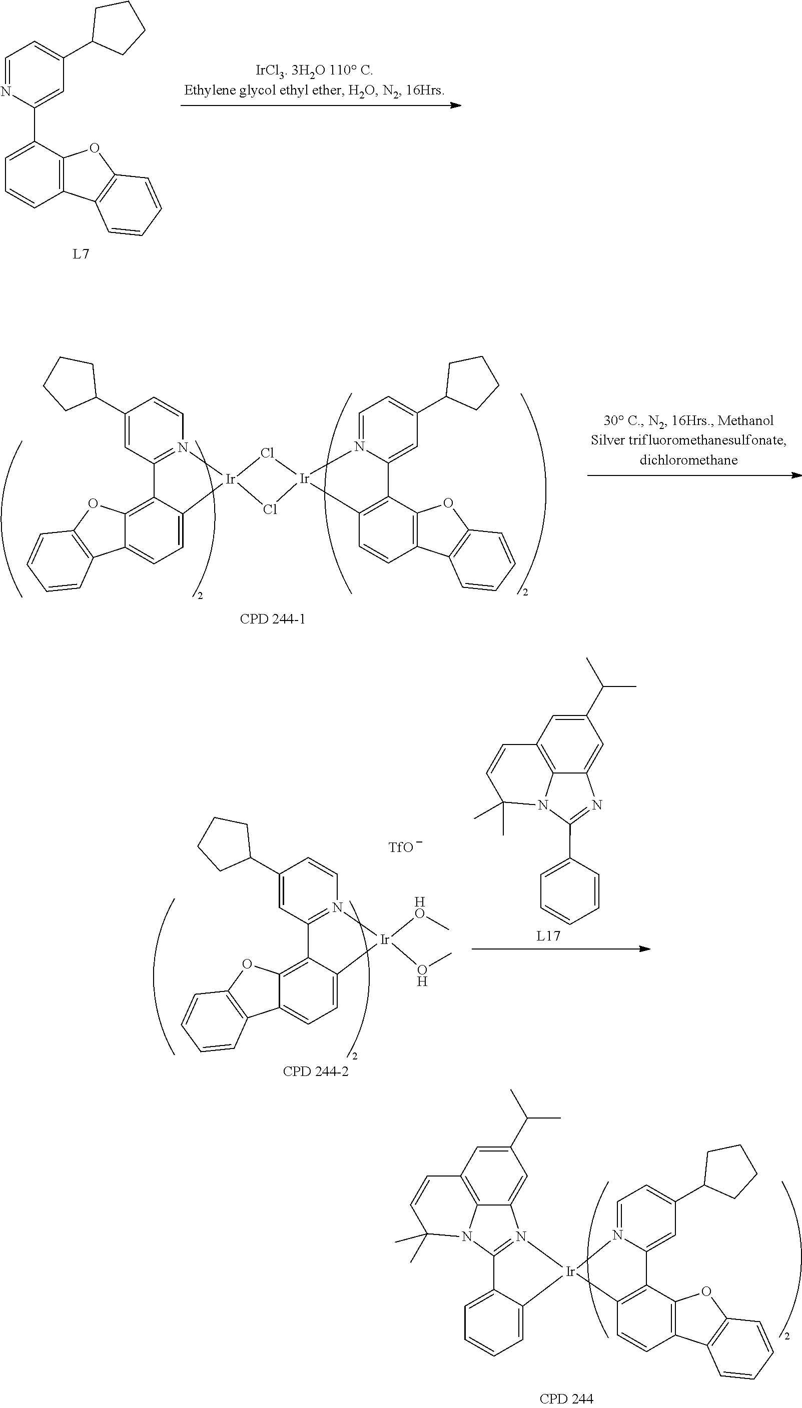

### Synthesis of a Compound CPD 244-1

With reference to synthesis and purification methods of the compound CPD 1-1, only the corresponding raw materials were required to be changed, and an obtained compound was directly used in the next step without purification.

### Synthesis of a Compound CPD 244-2

With reference to synthesis and purification methods of the compound CPD 1-2, only the corresponding raw materials were required to be changed, and an obtained compound was directly used in the next step without purification.

### Synthesis of a Compound CPD 244

With reference to synthesis and purification methods of the compound CPD 1, only the corresponding raw materials were required to be changed, and 2.61 g of a target compound CPD 244 with a yield of 46.1% was obtained. 2.61 g of the crude product CPD 244 was sublimated and purified to obtain 1.55 g of sublimated and purified CPD 244 with a yield of 59.3%. The mass spectrum was: 1108.4 (M+H). ¹H NMR (400 MHz, CDCl₃) δ 8.54 (d, 1H), 7.98 (d, 1H), 7.87-7.65 (m, 4H), 7.58-7.26 (m, 11H), 7.05 (m, 4H), 6.51 (d, 2H), 5.76 (d, 2H), 2.85 (m, 3H), 2.03 (m, 2H), 1.85-1.59 (m, 18H), 1.20 (s, 12H).

### Synthesis of a Common Intermediate L21

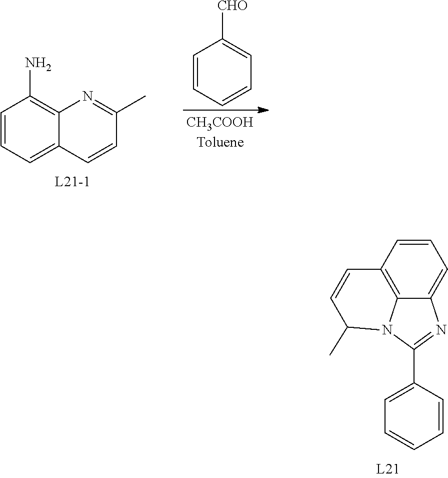 [SMILES: Cc1ccc2cccc(N)c2n1 ; O=Cc1ccccc1 ; CC1C=Cc2cccc3nc(-c4ccccc4)n1c23]

### Synthesis of a Compound L21

With reference to synthesis and purification methods of the compound L1-2, only the corresponding raw materials were required to be changed, and 15.3 g of a target compound L21 with a yield of 65.7% was obtained. The mass spectrum was: 247.3 (M+H).

### Synthesis of a Compound CPD 324

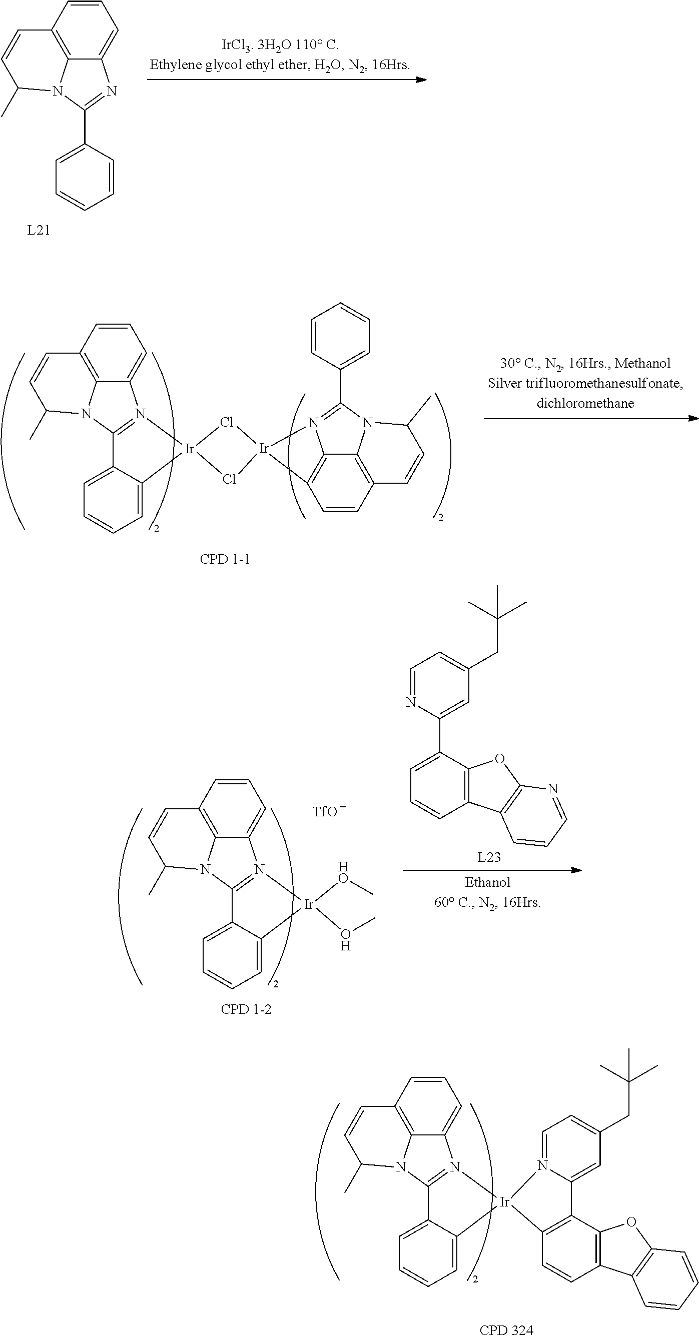

### Synthesis of a Compound CPD 324-1

With reference to synthesis and purification methods of the compound CPD 1-1, only the corresponding raw materials were required to be changed, and an obtained compound was directly used in the next step without purification.

### Synthesis of a Compound CPD 324-2

With reference to synthesis and purification methods of the compound CPD 1-2, only the corresponding raw materials were required to be changed, and an obtained compound was directly used in the next step without purification.

### Synthesis of a Compound CPD 324

With reference to synthesis and purification methods of the compound CPD 1, only the corresponding raw materials were required to be changed, and 2.66 g of a target compound CPD 324 with a yield of 45.9% was obtained. 2.66 g of the crude product CPD 324 was sublimated and purified to obtain 1.27 g of sublimated and purified CPD 324 with a yield of 47.7%. The mass spectrum was: 998.2 (M+H). ¹H NMR (400 MHz, CDCl₃) δ 8.52 (d, 1H), 7.98 (d, 1H), 7.89-7.66 (m, 6H), 7.60-7.26 (m, 9H), 7.25-7.00 (m, 6H), 6.55 (d, 2H), 5.76 (q, 2H), 5.58 (dt, 2H), 3.21 (s, 2H), 1.72 (d, 6H), 0.85 (s, 9H).

### Synthesis of a Common Intermediate L22

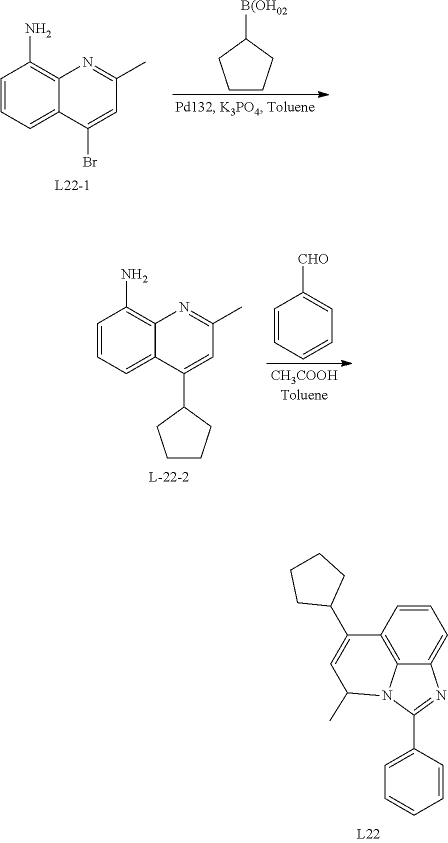

### Synthesis of a Compound L22-2

With reference to synthesis and purification methods of the compound L8-2, only the corresponding raw materials were required to be changed, and 12.2 g of a target compound L22-2 with a yield of 62.7% was obtained. The mass spectrum was: 227.3 (M+H).

### Synthesis of a Compound L22

With reference to synthesis and purification methods of the compound L1-2, only the corresponding raw materials were required to be changed, and 8.5 g of a target compound L22 with a yield of 48.6% was obtained. The mass spectrum was: 315.4 (M+H).

### Synthesis of a Compound CPD 337

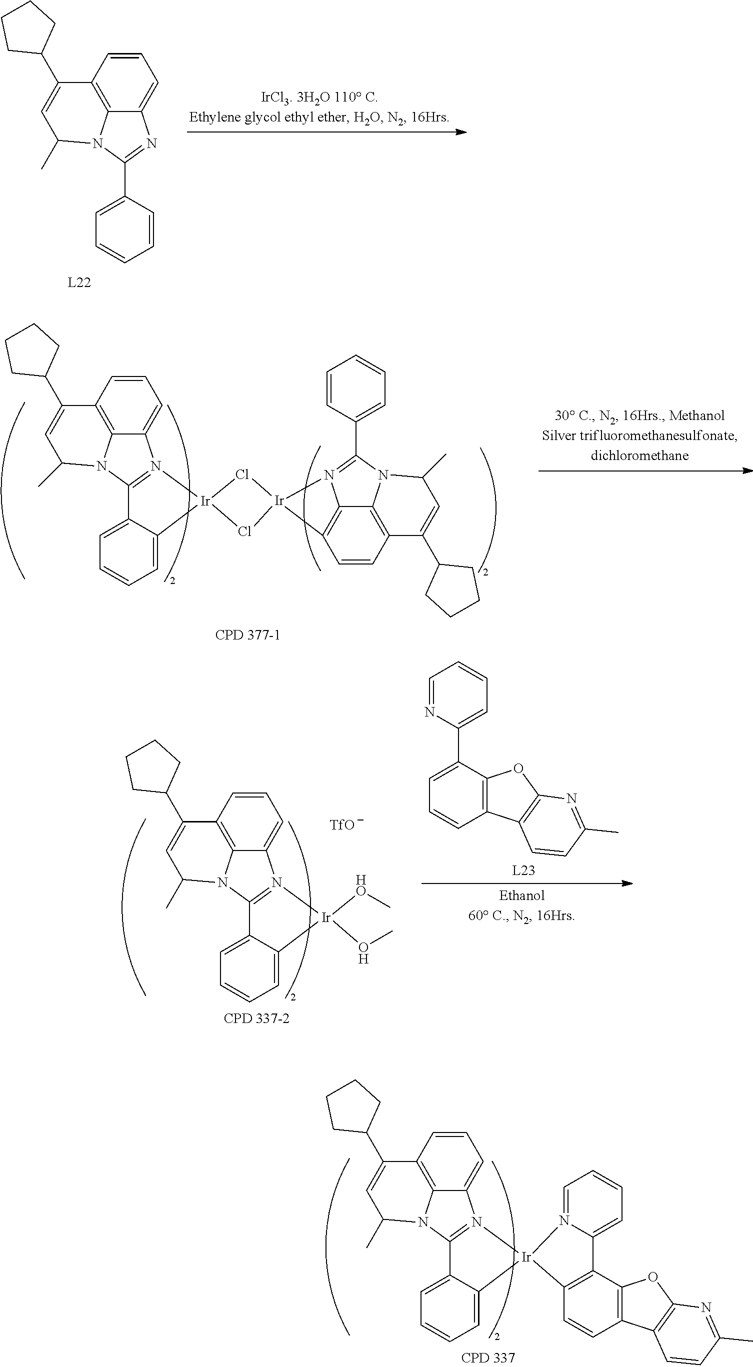

### Synthesis of a Compound CPD 337-1

With reference to synthesis and purification methods of the compound CPD 1-1, only the corresponding raw materials were required to be changed, and an obtained compound was directly used in the next step without purification.

### Synthesis of a Compound CPD 337-2

With reference to synthesis and purification methods of the compound CPD 1-2, only the corresponding raw materials were required to be changed, and an obtained compound was directly used in the next step without purification.

### Synthesis of a Compound CPD 337

With reference to synthesis and purification methods of the compound CPD 1, only the corresponding raw materials were required to be changed, and 3.22 g of a target compound CPD 337 with a yield of 46.1% was obtained. 3.22 g of the crude product CPD 337 was sublimated and purified to obtain 1.37 g of sublimated and purified CPD 337 with a yield of 42.5%. The mass spectrum was: 1079.3 (M+H). ¹H NMR (400 MHz, CDCl₃) δ8.49 (d, 1H), 8.23 (d, 1H), 7.73 (dd, J=40.0 Hz, 3H), 7.56-7.30 (m, 9H), 7.25-6.85 (m, 8H), 5.91 (m, 2H), 5.54 (d, 2H), 2.68 (s, 3H), 2.55 (dt, 2H), 1.64 (m, 18H), 1.30 (m, 4H).

### Synthesis of a Common Intermediate L24

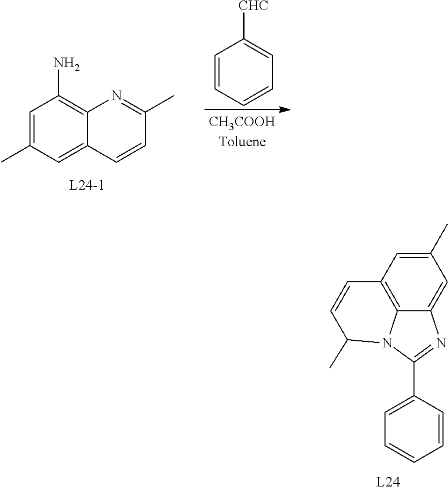

### Synthesis of a Compound L24

With reference to synthesis and purification methods of the compound L1-2, only the corresponding raw materials were required to be changed, and 14.2 g of a target compound L24 with a yield of 52.8% was obtained. The mass spectrum was: 261.3 (M+H).

### Synthesis of a Compound CPD 348

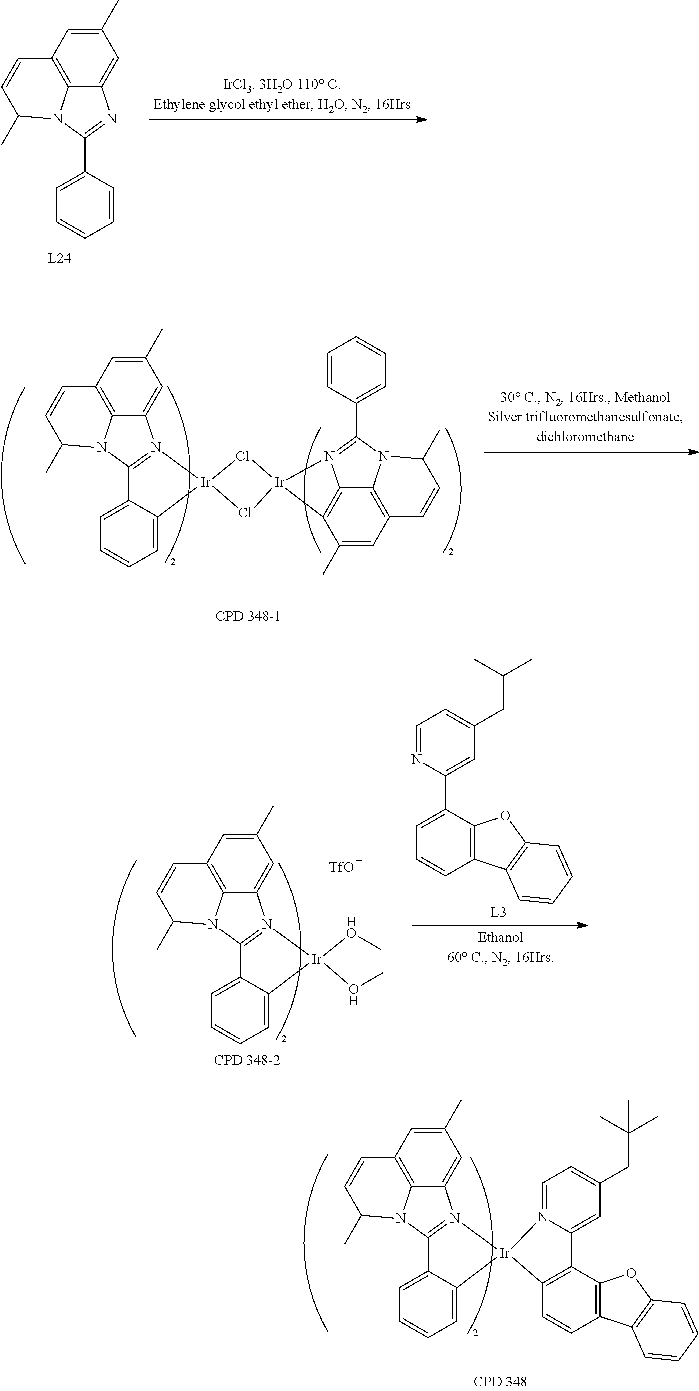

### Synthesis of a Compound CPD 348-1

With reference to synthesis and purification methods of the compound CPD 1-1, only the corresponding raw materials were required to be changed, and an obtained compound was directly used in the next step without purification.

### Synthesis of a Compound CPD 348-2

With reference to synthesis and purification methods of the compound CPD 1-2, only the corresponding raw materials were required to be changed, and an obtained compound was directly used in the next step without purification.

### Synthesis of a Compound CPD 348

With reference to synthesis and purification methods of the compound CPD 1, only the corresponding raw materials were required to be changed, and 2.66 g of a target compound CPD 348 with a yield of 43.7% was obtained. 2.66 g of the crude product CPD 348 was sublimated and purified to obtain 1.38 g of sublimated and purified CPD 348 with a yield of 51.8%. The mass spectrum was: 1026.2 (M+H). ¹H NMR (400 MHz, CDCl₃) δ 8.55 (d, 1H), 7.98 (dd, 1H), 7.88-7.65 (m, 7H), 7.59-7.25 (m, 9H), 7.18 (d, 2H), 7.05 (dd, 1H), 6.49 (d, 2H), 5.76 (m, 2H), 5.49 (m, 2H), 3.21 (s, 2H), 2.31 (s, 6H), 1.67 (d, 6H), 0.85 (s, 9H).

### Synthesis of a Compound CPD 360

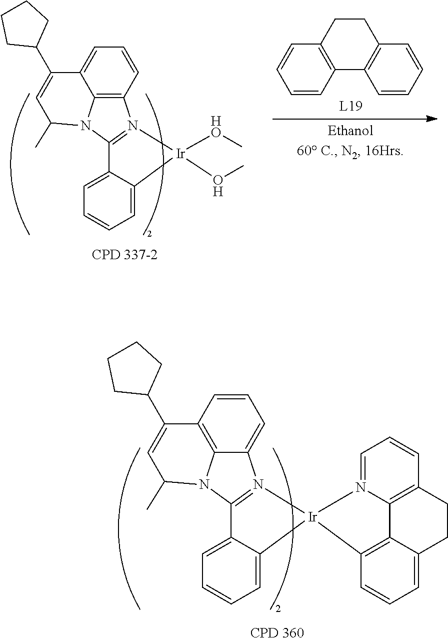

With reference to synthesis and purification methods of the compound CPD 1, only the corresponding raw materials were required to be changed, and 2.59 g of a target compound CPD 360 with a yield of 43.7% was obtained. 2.59 g of the crude product CPD 360 was sublimated and purified to obtain 1.41 g of sublimated and purified CPD 360 with a yield of 54.4%. The mass spectrum was: 1000.2 (M+H). ¹H NMR (400 MHz, CDCl₃) δ8.45 (d, 1H), 7.77 (d, 2H), 7.46 (m, 7H), 7.34-7.02 (m, 8H), 6.67 (t, 2H), 5.53 (m, 4H), 2.97 (m, 4H), 2.60 (m, 2H), 1.85-1.60 (m, 14H), 1.55 (m, 4H), 1.30 (m, 4H).

### Synthesis of a Compound CPD 381

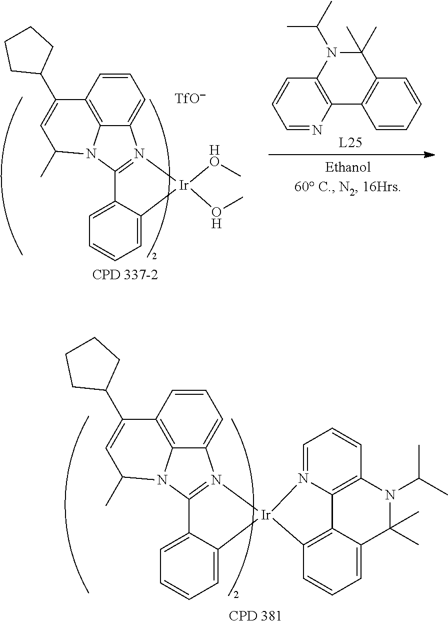

With reference to synthesis and purification methods of the compound CPD 1, only the corresponding raw materials were required to be changed, and 2.33 g of a target compound CPD 381 with a yield of 40.2% was obtained. 2.33 g of the crude product CPD 381 was sublimated and purified to obtain 1.12 g of sublimated and purified CPD 381 with a yield of 48.0%. The mass spectrum was: 1071.3 (M+H). ¹H NMR (400 MHz, CDCl₃) δ8.53 (dd, 1H), 8.21 (dd, 2H), 7.76 (m, 8H), 7.42 (m, 4H), 7.20 (m, 5H), 6.35 (dt, 2H), 5.54 (dd, 2H), 4.15 (m, 1H), 2.58 (m, 2H), 1.67 (m, 18H), 1.33 (m, 10H), 1.17 (d, 6H).

Other compounds can be synthesized and sublimated by selecting corresponding materials based on same or similar methods.

### Application Example: Manufacturing of an Organic Electroluminescent Device

A glass substrate with a size of 50 mm*50 mm*1.0 mm including an indium tin oxide (ITO, 100 nm) transparent electrode was ultrasonically cleaned in ethanol for 10 minutes, dried at 150° C., and then treated with N₂ plasma for 30 minutes. The washed glass substrate was installed on a substrate support of a vacuum evaporation device. At first, a compound HATCN for covering the transparent electrode was evaporated on the surface of the side having a transparent electrode line to form a thin film with a thickness of 5 nm. Then, a layer of HTM1 was evaporated to form a thin film with a thickness of 60 nm. Then, a layer of HTM2 was evaporated on the HTM1 thin film to form a thin film with a thickness of 10 nm. Then, a main material 1, a main material 2 and a doping compound (including reference compounds X and CPD X) were co-evaporated on the HTM2 film layer to obtain a film with a thickness of 30 nm, wherein the ratio of the main material 1 to the main material 2 to the doping material was 45%:45%:10%. Then, an electron transport layer (ETL) and an electron injection layer (EIL) were sequentially evaporated on a light-emitting layer to obtain a film with a thickness of 35 nm, wherein the ratio of the ETL to the EIL was 50%:50%. Finally, a metal Al layer (100 nm) was evaporated to serve as an electrode.

[chemical structure]

Evaluation: Properties of a device obtained above were tested. In various examples and comparative examples, a constant-current power supply (Keithley 2400) was used, a current at a fixed density was used for flowing through light-emitting elements, and a spectroradiometer (CS 2000) was used for testing the light-emitting spectrum. Meanwhile, the voltage value was measured, and the time (LT95) when the brightness was reduced to 95% of the initial brightness was tested. Results are shown as follows.

| | | Peak | | Starting | Current | |
|---|---|---|---|---|---|---|
| | Doping | wavelength | FWHM | voltage | efficiency | LT95@ |
| | material | nm | nm | V | Cd/A | 10000 nits |
| Example 1 | CPD 1 | 522 | 53 | 4.43 | 80 | 271 |
| Example 2 | CPD 6 | 523 | 52 | 4.44 | 78 | 283 |
| Example 3 | CPD 12 | 523 | 51 | 4.46 | 83 | 276 |
| Example 4 | CPD 19 | 525 | 52 | 4.51 | 81 | 245 |
| Example 5 | CPD 34 | 525 | 55 | 4.52 | 79 | 259 |
| Example 6 | CPD 50 | 524 | 55 | 4.47 | 82 | 286 |
| Example 7 | CPD 78 | 526 | 52 | 4.49 | 84 | 307 |
| Example 8 | CPD 107 | 526 | 54 | 4.45 | 79 | 310 |
| Example 9 | CPD 136 | 525 | 54 | 4.42 | 81 | 279 |
| Example 10 | CPD 150 | 523 | 52 | 4.43 | 83 | 277 |
| Example 11 | CPD 171 | 525 | 52 | 4.47 | 82 | 293 |
| Example 12 | CPD 195 | 525 | 56 | 4.52 | 79 | 261 |
| Example 13 | CPD 198 | 526 | 52 | 4.42 | 83 | 244 |
| Example 14 | CPD 244 | 526 | 51 | 4.44 | 84 | 269 |
| Example 15 | CPD 324 | 524 | 51 | 4.46 | 83 | 253 |
| Example 16 | CPD 337 | 524 | 54 | 4.48 | 82 | 291 |
| Example 17 | CPD 348 | 526 | 49 | 4.47 | 83 | 322 |
| Example 18 | CPD 360 | 523 | 52 | 4.55 | 81 | 337 |
| Example 19 | CPD 381 | 523 | 49 | 4.56 | 83 | 281 |
| Comparative | Reference | 509 | 73 | 5.01 | 53 | 60 |
| Example 1 | compound 1 | | | | | |
| Comparative | Reference | 530 | 76 | 5.11 | 77 | 152 |
| Example 2 | compound 2 | | | | | |
| Comparative | Reference | 549 | 69 | 4.86 | 76 | 183 |
| Example 3 | compound 3 | | | | | |
| Comparative | Reference | 523 | 75 | 5.06 | 52 | 98 |
| Example 4 | compound 4 | | | | | |
| Comparative | Reference | 519 | 72 | 4.82 | 54 | 121 |
| Example 5 | compound 5 | | | | | |
| Comparative | Reference | 528 | 66 | 4.76 | 72 | 130 |
| Example 6 | compound 6 | | | | | |
| Comparative | Reference | 524 | 68 | 4.92 | 71 | 200 |
| Example 7 | compound 7 | | | | | |

Through comparison of the data in the above table, it can be seen that compared with reference compounds, the compound of the present invention used as a dopant in an organic electroluminescent device has more excellent properties, such as driving voltage, luminous efficiency and device service life.

The above results show that the compound of the present invention has the advantages of high optical and electrochemical stability, narrow emission half-peak width, high color saturation, high luminous efficiency, long device service life and the like, and can be used in organic electroluminescent devices. In particular, the compound has the potential for application in the OLED industry as a green light-emitting dopant.

1. An organometallic iridium compound, having a structure formula represented by Formula (1): 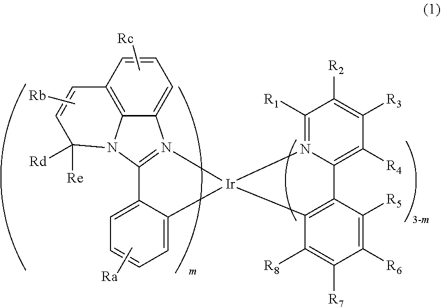
wherein 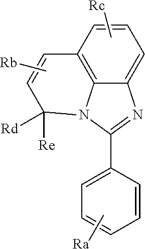
is L1, and 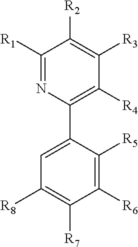
is L2;
m is 1, 2 or 3, two L2 groups are the same or different when the m is 1, and multiple L1 groups are the same or different when the m is greater than 1;
the number of Ra, Rb and Rc is from 1 to a maximum substitution number;
Ra, Rb, Rc, Rd and Re are independently selected from hydrogen, deuterium, halogen, substituted or unsubstituted C₁-C₁₀ alkyl, substituted or unsubstituted C₃-C₂₀ cycloalkyl, substituted or unsubstituted C₆-C₁₈ aryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl;
at least one of the Rd and the Re is not hydrogen;
R₁-R₈ are independently selected from hydrogen, deuterium, halogen, hydroxyl, sulfhydryl, substituted or unsubstituted C₁-C₁₀ alkyl, substituted or unsubstituted C₁-C₁₀ heteroalkyl, substituted or unsubstituted C₃-C₂₀ cycloalkyl, substituted or unsubstituted C₂-C₁n alkenyl, substituted or unsubstituted C₂-C₁n alkynyl, substituted or unsubstituted C₆-C₁₈ aryl, substituted or unsubstituted C₂-C₁₇ heteroaryl, substituted or unsubstituted tri-C₁-C₁₀ alkyl silyl, substituted or unsubstituted tri-C₆-C₁₂ aryl silyl, and substituted or unsubstituted di-C₁-C₁₀ alkyl mono-C₆-C₃₀ aryl silyl, or any two adjacent groups of the R₁-R₈ may be connected to each other to form an aliphatic ring structure or an aromatic ring structure;
the heteroalkyl and the heteroaryl at least contain one O, N or S heteroatom;
and the “substituted” refers to substitution with deuterium, F, Cl, Br, C₁-C₆ alkyl, C₃-C₆cycloalkyl, amino substituted with C₁-C₆ alkyl, cyano, isocyano, or phosphino, and the substitution ranges from a single substitution number to a maximum substitution number.

2. The organometallic iridium compound according to claim 1, wherein the m is 1 or 2, and the two L1 groups or the two L2 groups are the same.

3. The organometallic iridium compound according to claim 2, wherein at least one of the Rd and the Re is not hydrogen, and at least one of the Rd and the Re is substituted or unsubstituted C₁-C₆ alkyl, or substituted or unsubstituted C₃-C₆ cycloalkyl.

4. The organometallic iridium compound according to claim 3, wherein the Ra is hydrogen.

5. The organometallic iridium compound according to claim 3, wherein at least one of the R₁-R₄ is not hydrogen.

6. The organometallic iridium compound according to claim 3, wherein at least one of the R₅-R₈ is not hydrogen.

7. The organometallic iridium compound according to claim 3, wherein at least one of the R₁-R₄ is not hydrogen, and at least one of the R₅-R₈ is not hydrogen.

8. The organometallic iridium compound according to claim 7, wherein one of the R₁-R₄ is deuterium, C₁-C₅ alkyl substituted or unsubstituted with deuterium, or C₃-C₅ cycloalkyl substituted or unsubstituted with deuterium, one of the R₅-R₈ is deuterium, C₁-C₅ alkyl substituted or unsubstituted with deuterium, or C₃-C₅ cycloalkyl substituted or unsubstituted with deuterium, and the other groups are hydrogen.

9. The organometallic iridium compound according to claim 7, wherein the R₅ and the R₆, the R₆ and the R₇, or the R₇ and the R₈ are connected to each other to form a ring-fused structure represented by Formula (2): 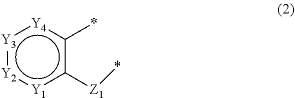
wherein * indicates a connecting position;
Y₁-Y₄ are independently CR₀ or N;
Z1 is selected from O and S;
R₀ is independently hydrogen, deuterium, F, cyano, substituted or unsubstituted C₁-C₁₀ alkyl, substituted or unsubstituted C₃-C₂₀ cycloalkyl, substituted or unsubstituted C₂-C₃₀ alkenyl, substituted or unsubstituted C₂-C₃₀ alkynyl, substituted or unsubstituted C₆-C₃₀ aryl, substituted or unsubstituted C₁-C₃₀ heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

10. The organometallic iridium compound according to claim 7, wherein the R₄ and the R₅ are connected to each other to form an aliphatic ring structure represented by Formula (3): 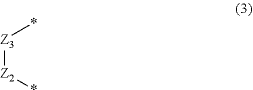
wherein * indicates a connecting position;
Z2 and Z3 are independently selected from O, S, N(R₀) and C(R₀)₂, and at least one of the Z2 and the Z3 is C(R₀)₂;
R₀ is independently hydrogen, deuterium, F, cyano, substituted or unsubstituted C₁-C₁₀ alkyl, substituted or unsubstituted C₃-C₂₀ cycloalkyl, substituted or unsubstituted C₂-C₃₀ alkenyl, substituted or unsubstituted C₂-C₃ alkynyl, substituted or unsubstituted C₆-C₃₀ aryl, substituted or unsubstituted C₁-C₃₀ heteroaryl, substituted or unsubstituted tri-C₁-C₁₀ alkyl silyl, substituted or unsubstituted tri-C₆-C₃₀ aryl silyl, or substituted or unsubstituted di-C₁-C₁₀ alkyl mono-C₆-C₃₀ aryl silyl;
and the “substituted” refers to substitution with deuterium, F, Cl, Br, C₁-C₄ alkyl, C₁-C₄ alkoxyl, C₃-C₆ cycloalkyl, amino substituted with C₁-C₄ alkyl, cyano, isocyano, or phosphino.

11. The organometallic iridium compound according to any one of claims 1-10, wherein at least one of the Rb and the Rc is not hydrogen.

12. The organometallic iridium compound according to claim 11, wherein at least one of the Rb and the Rc is substituted or unsubstituted C₁-C₆ alkyl, or substituted or unsubstituted C₃-C₆ cycloalkyl.

13. The organometallic iridium compound according to claim 12, wherein one of the Rb and the Rc is substituted or unsubstituted C₁-C₆ alkyl, or substituted or unsubstituted C₃-C₆ cycloalkyl, and the other groups are hydrogen.

14. The organometallic iridium compound according to claim 3, wherein the L1 has one of the following structural formulas, or is partially or completely deuterated or fluorinated correspondingly,

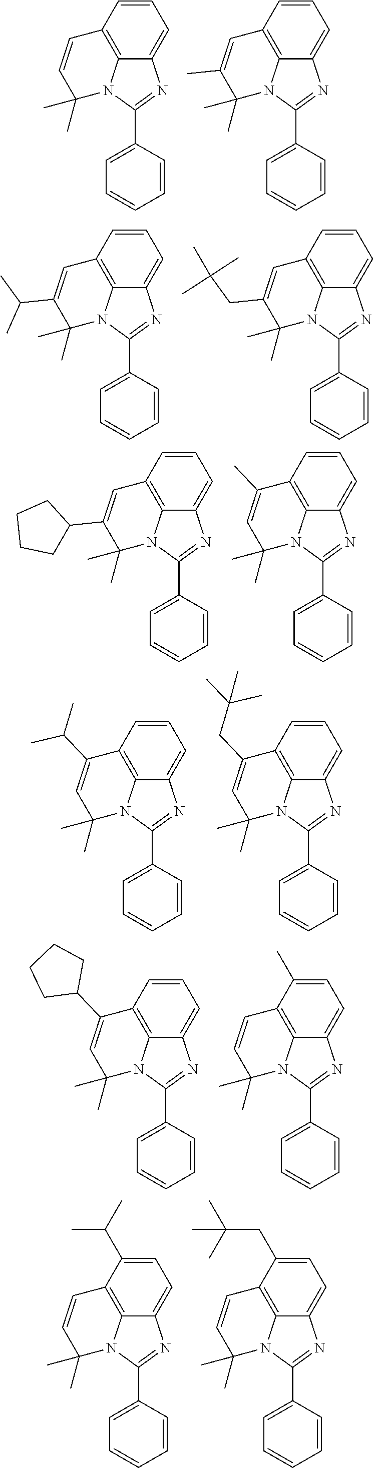

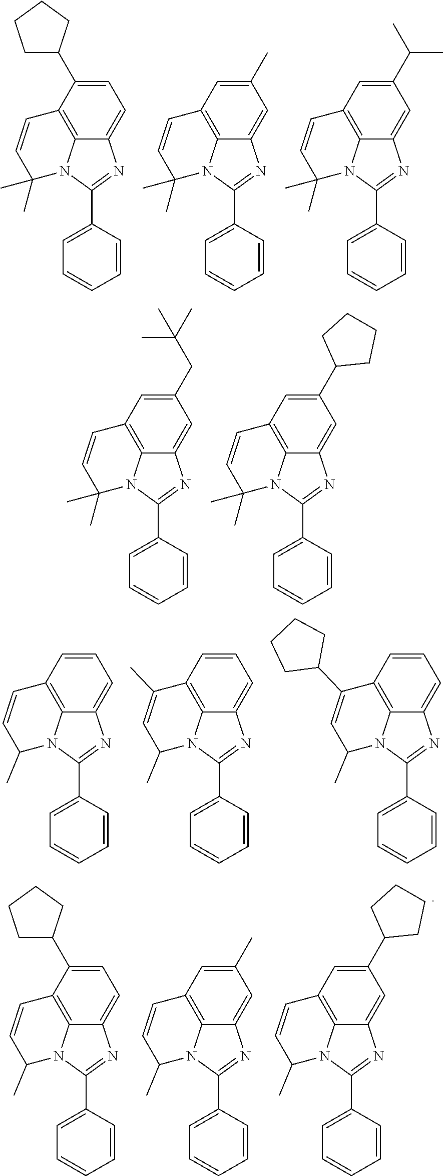

15. The organometallic iridium compound according to claim 3, wherein the L2 has one of the following structural formulas, or is partially or completely deuterated or fluorinated correspondingly,

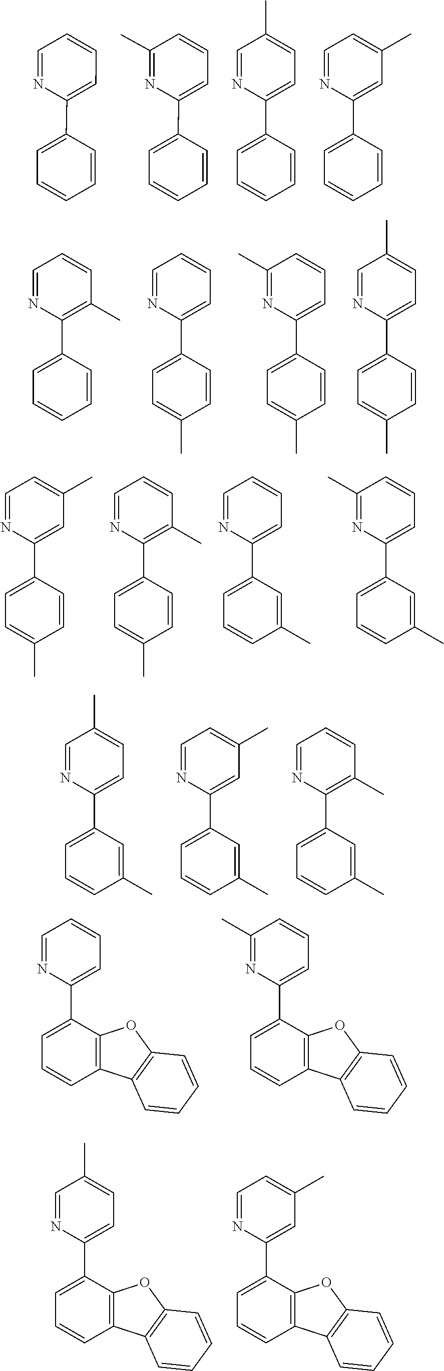

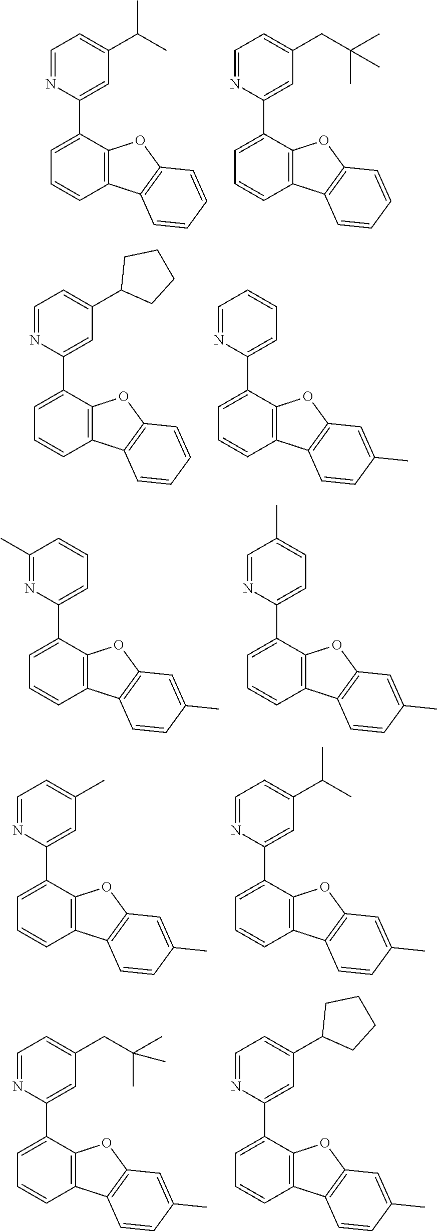

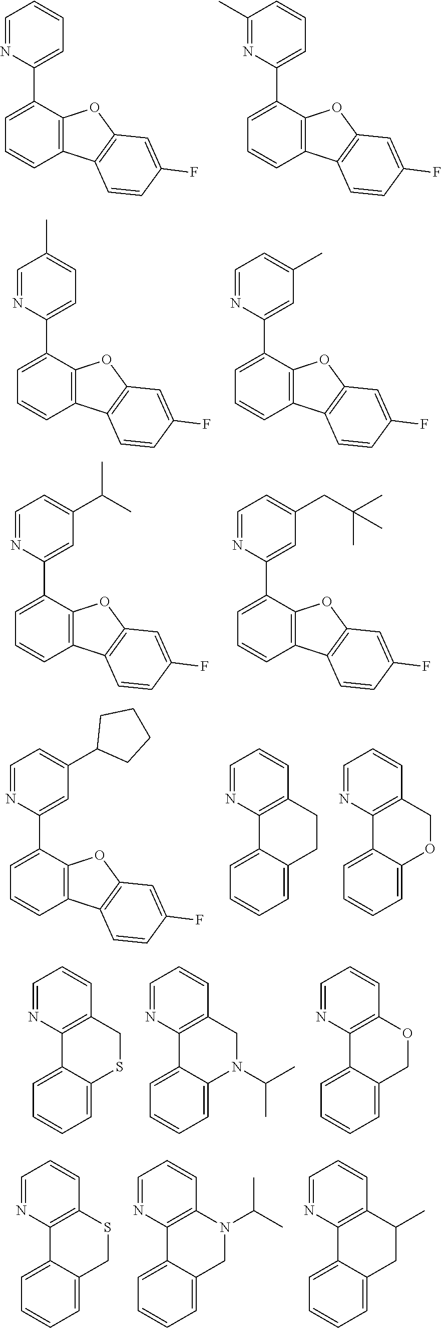

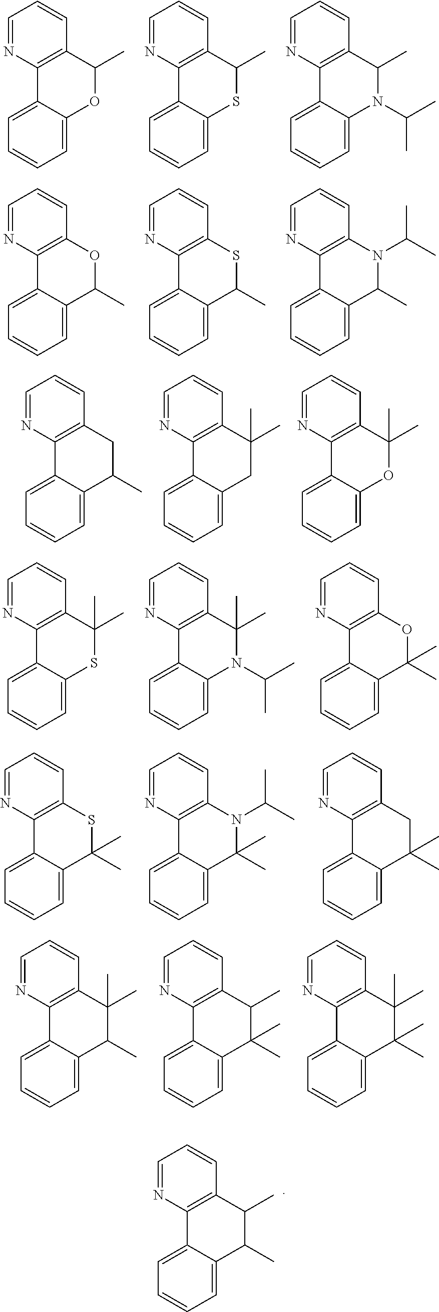

16. The organometallic iridium compound according to claim 1, wherein the compound represented by Formula (1) has one of the following structural formulas, or is partially or completely deuterated or fluorinated correspondingly,

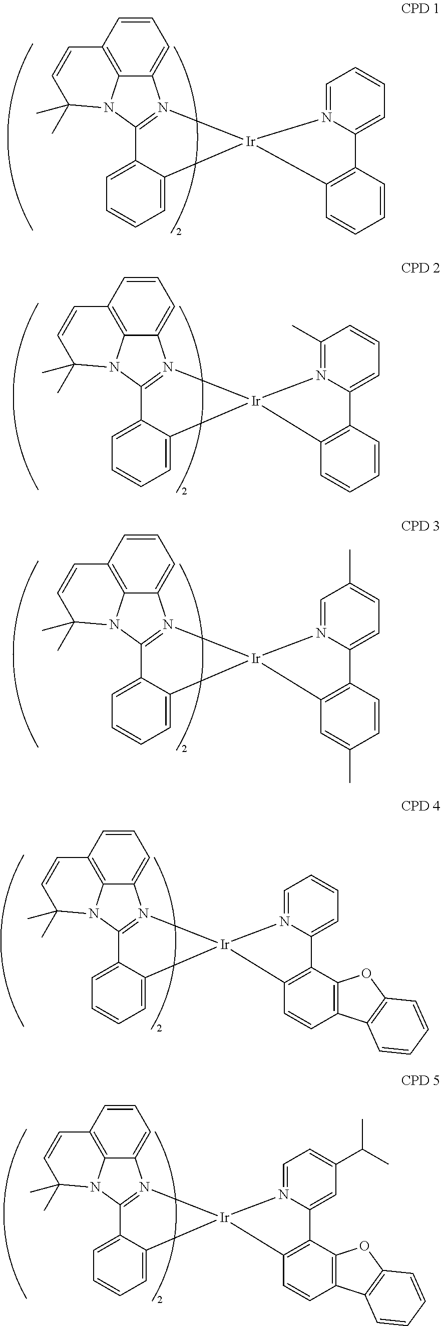

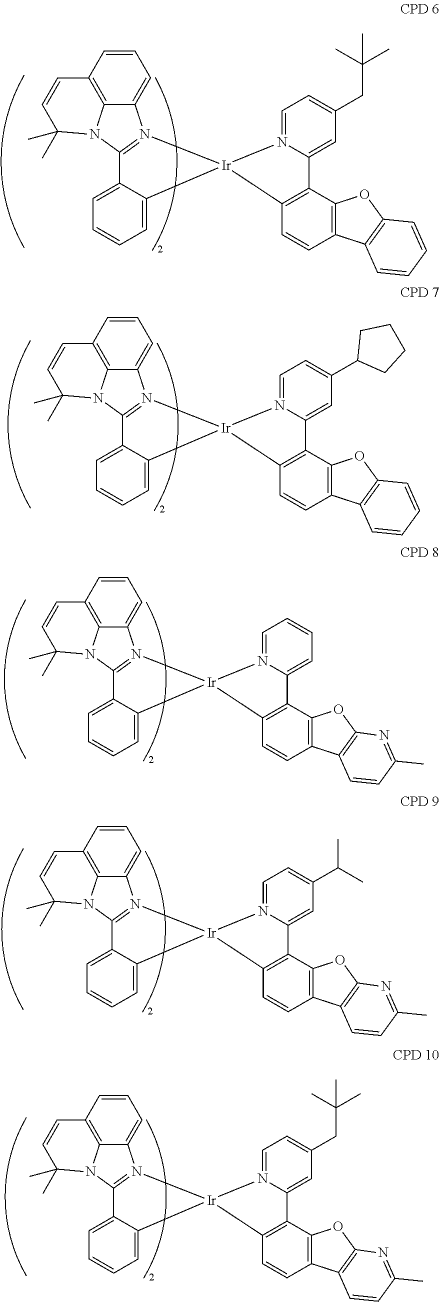

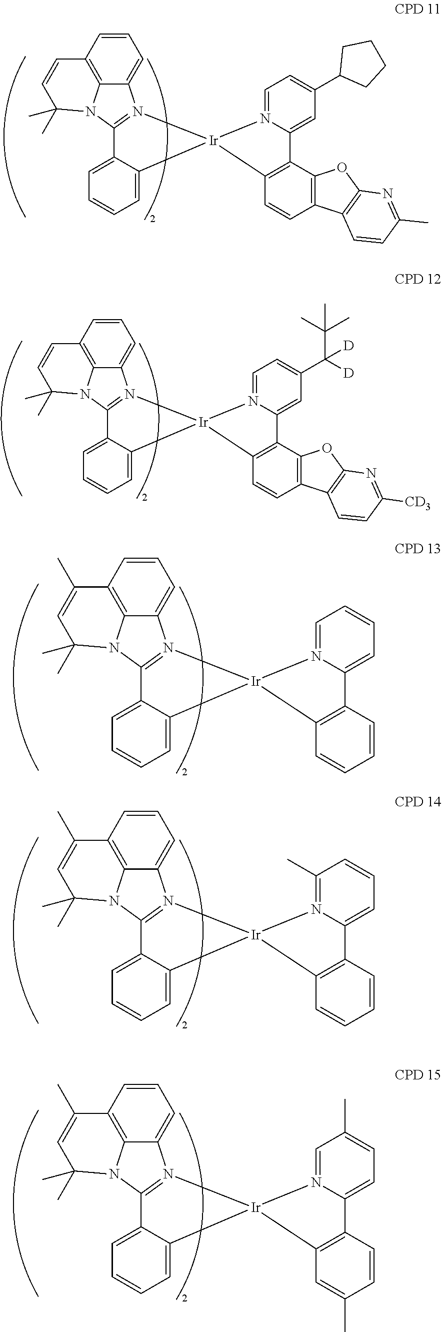

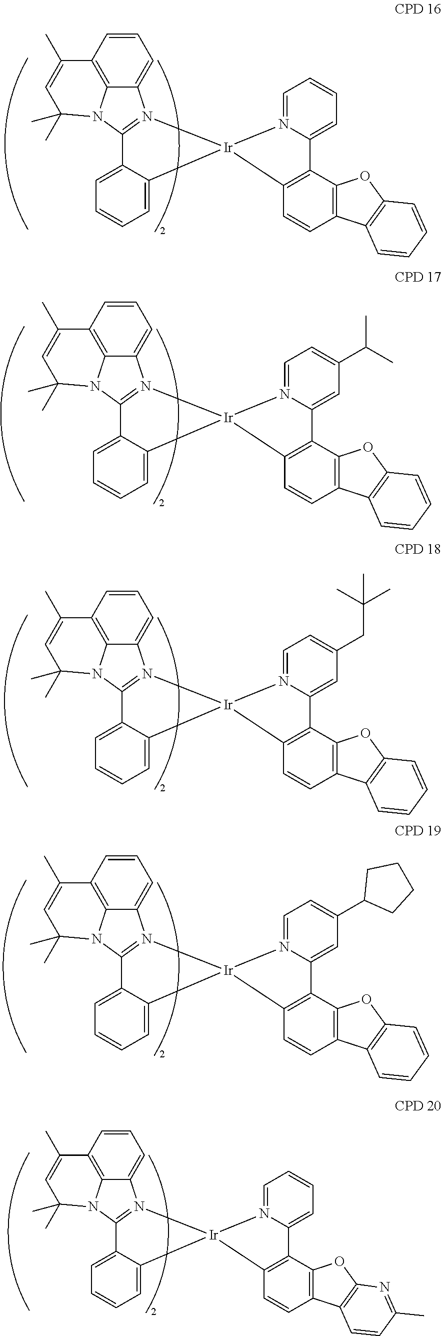

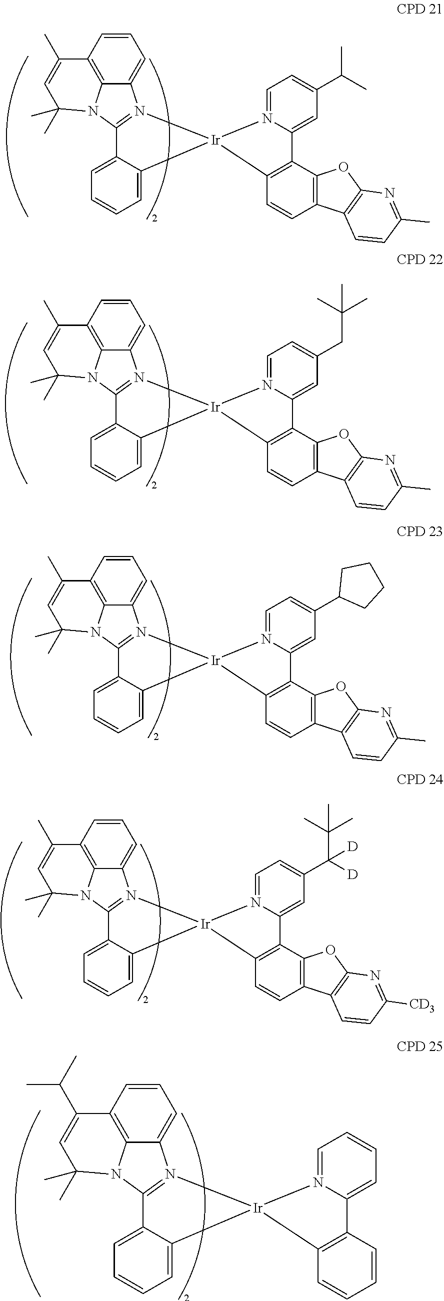

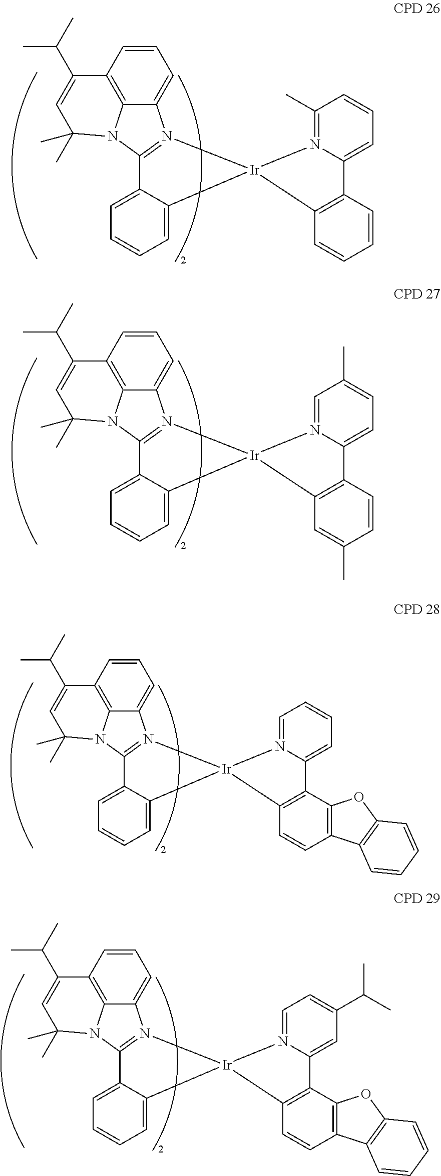

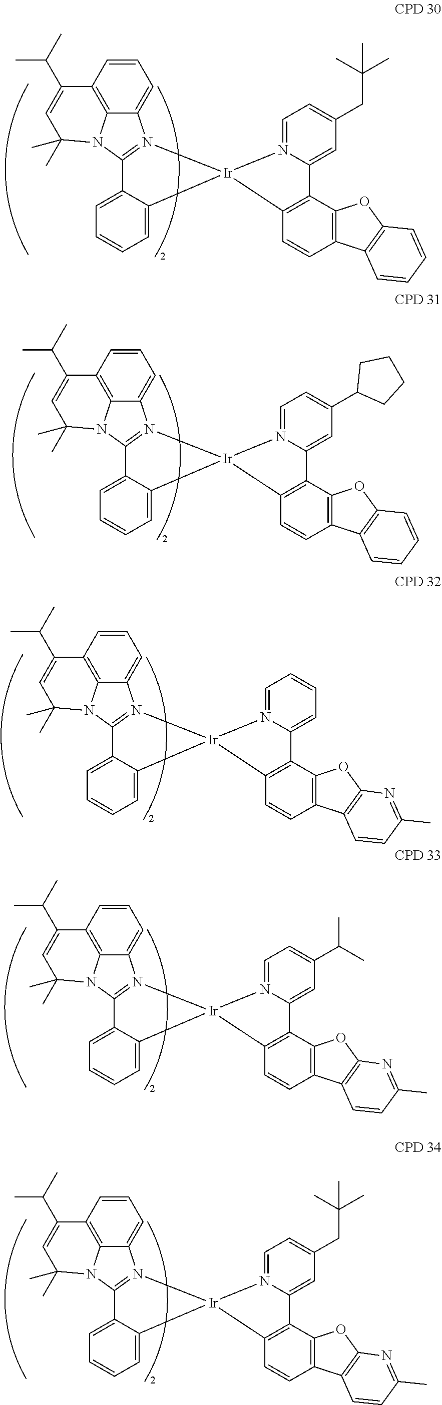

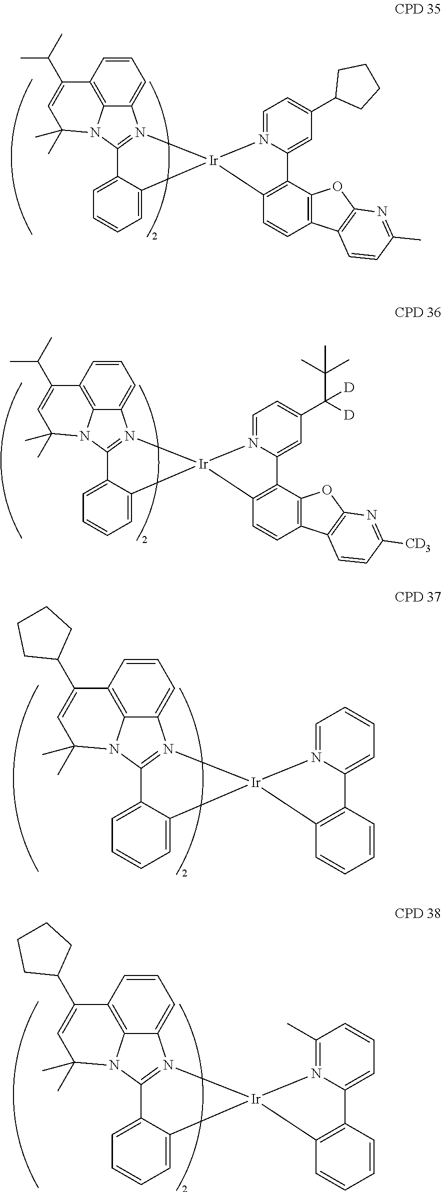

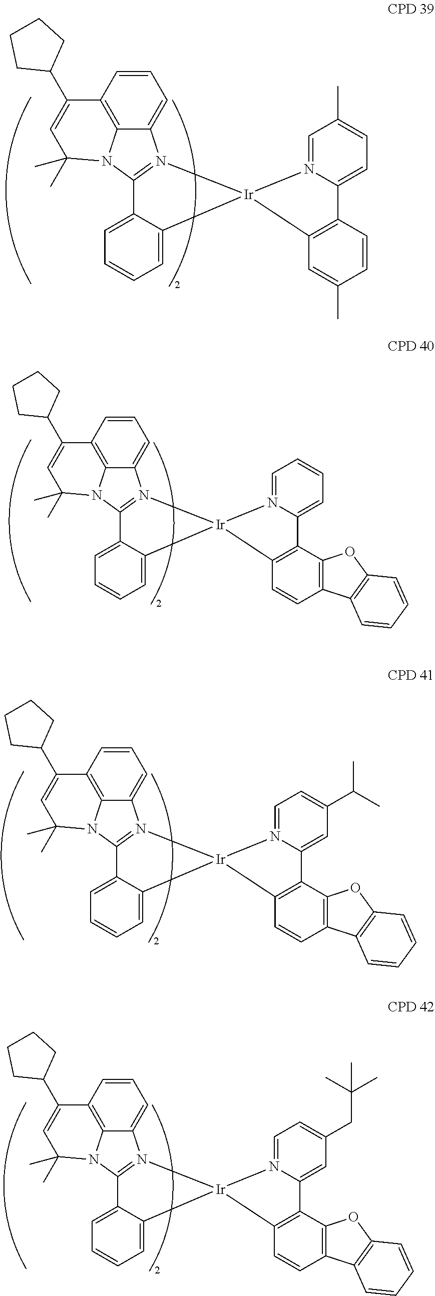

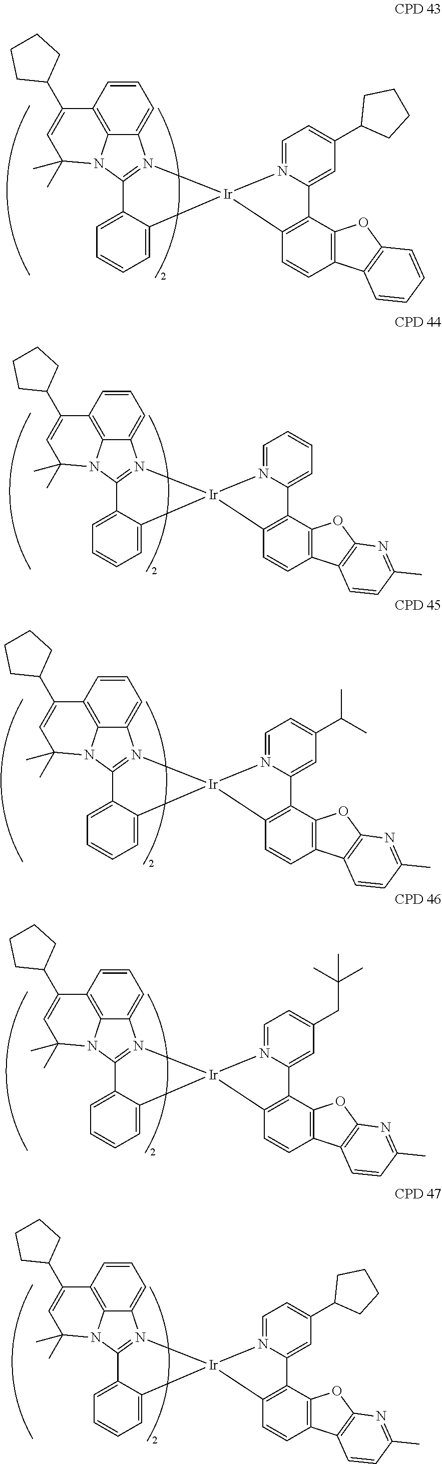

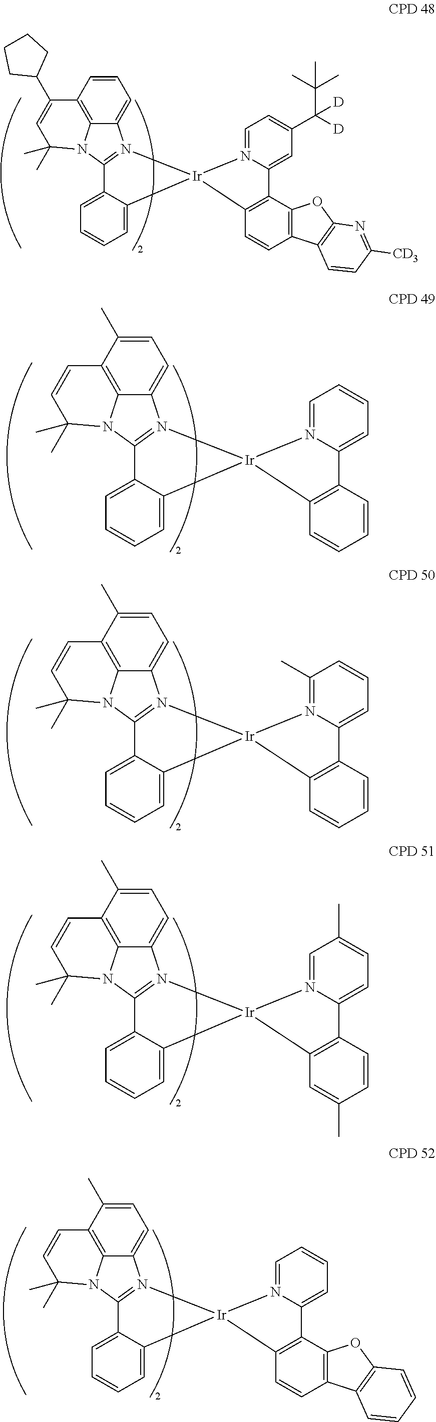

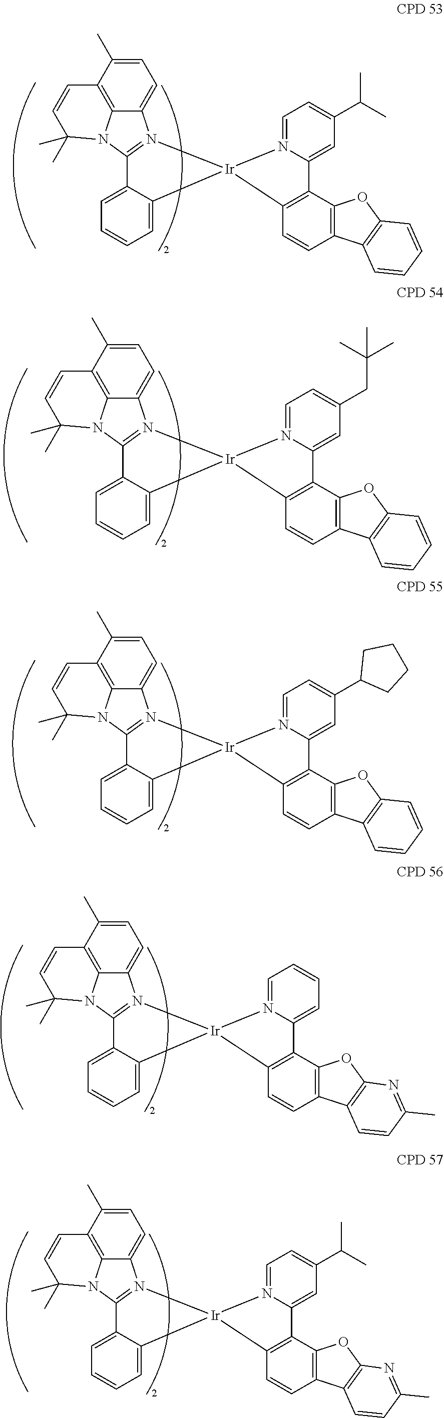

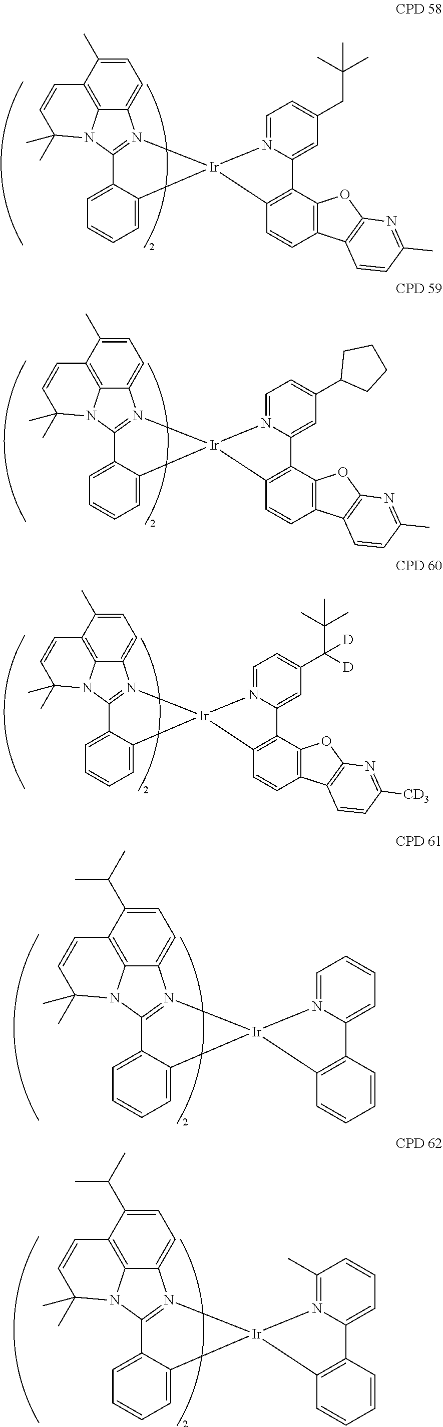

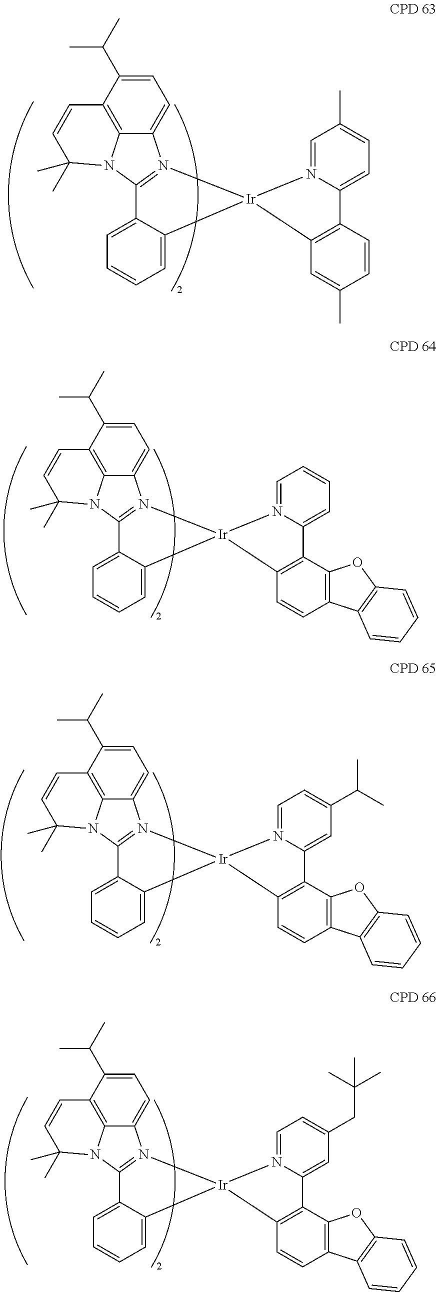

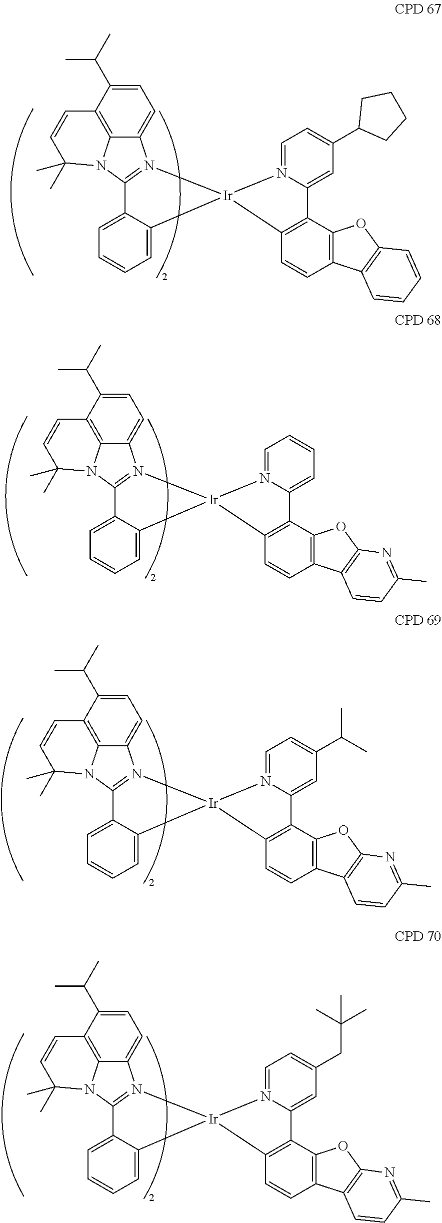

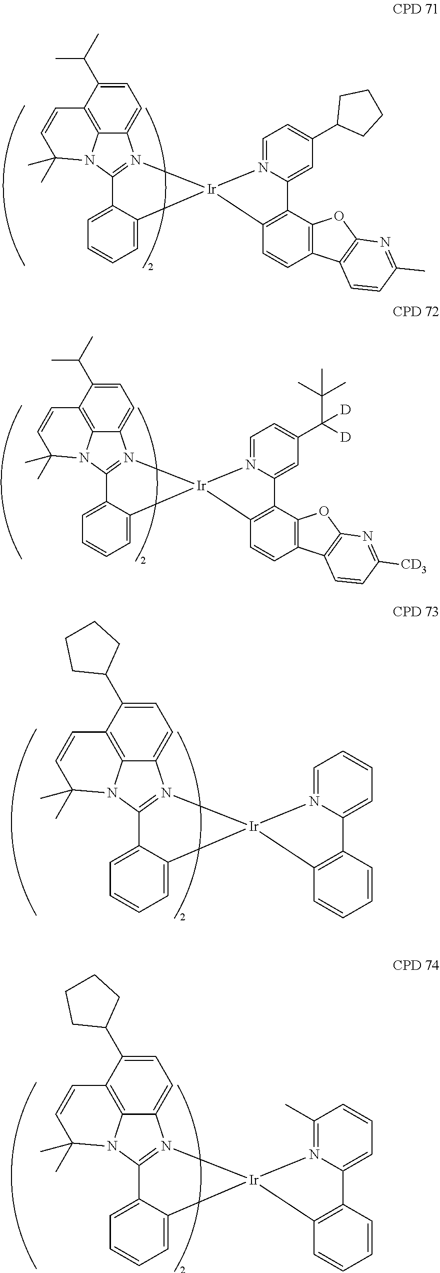

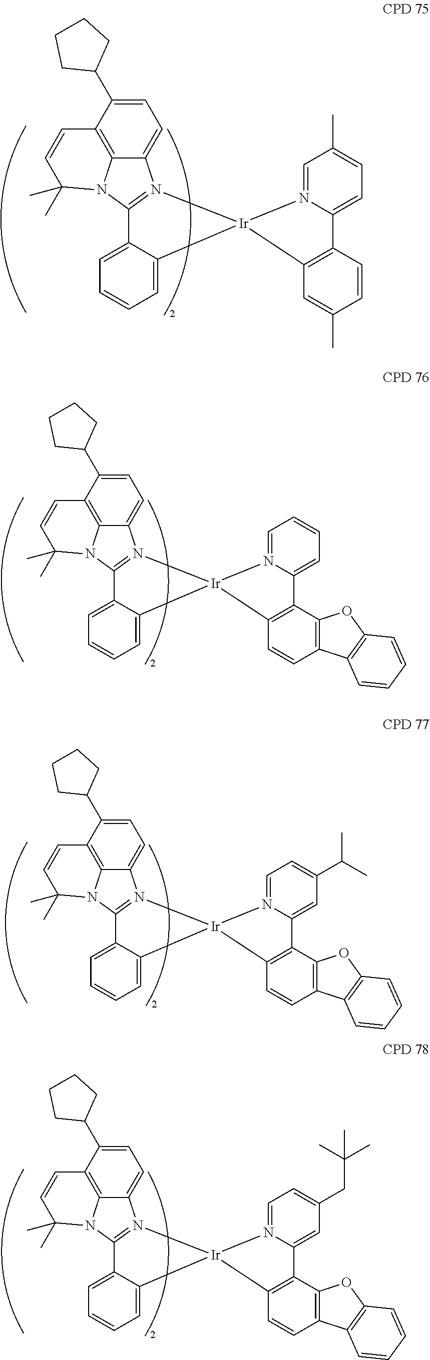

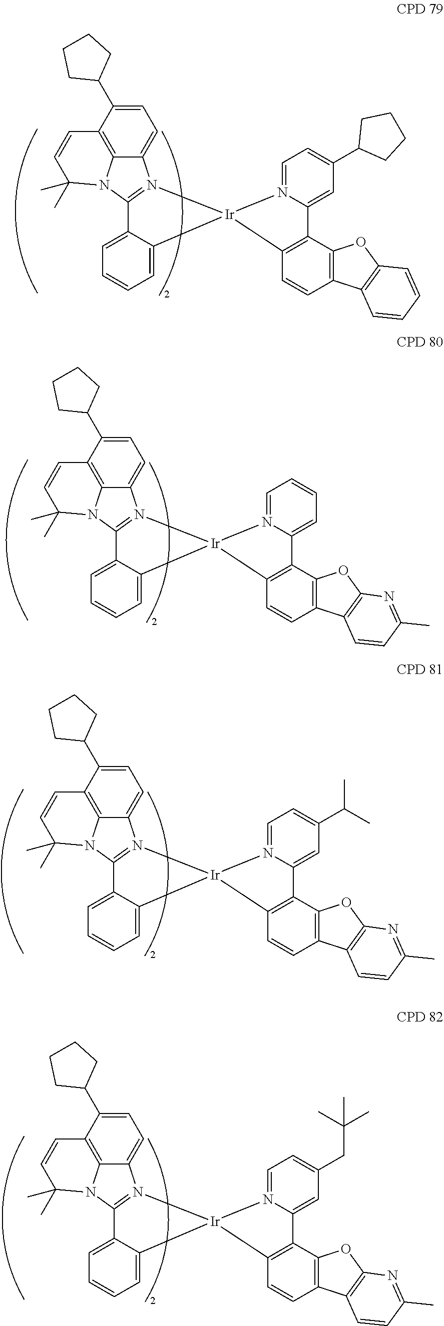

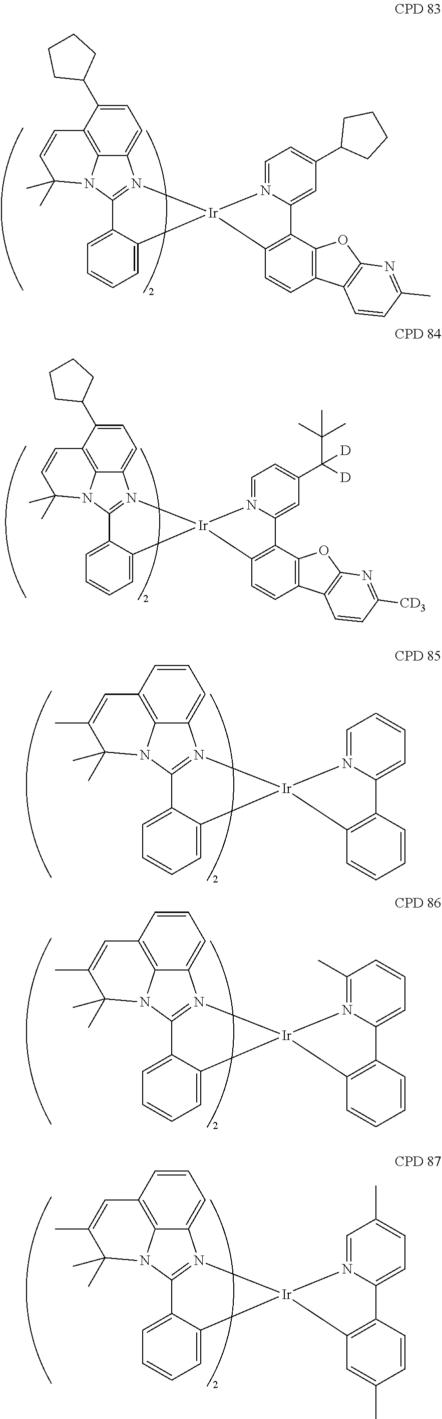

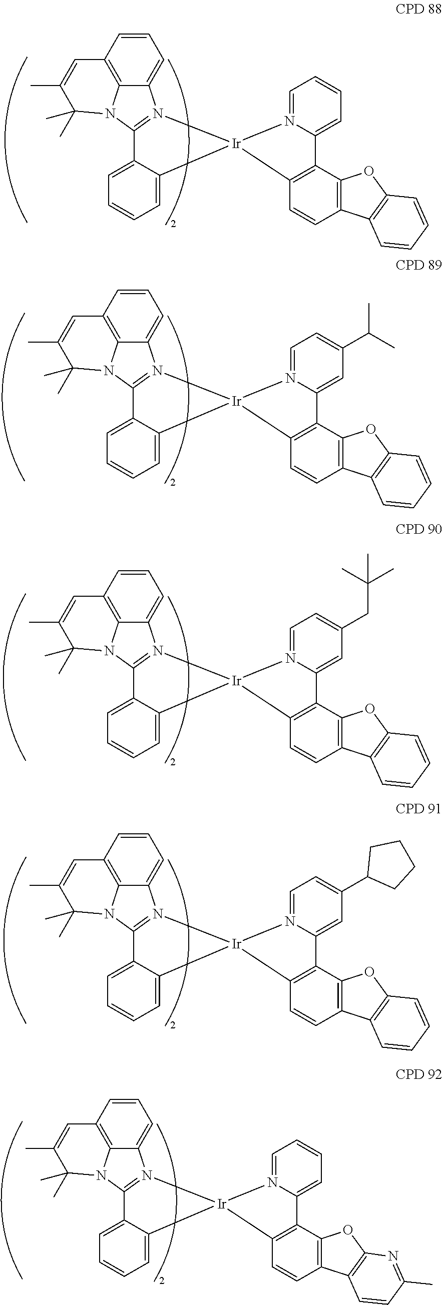

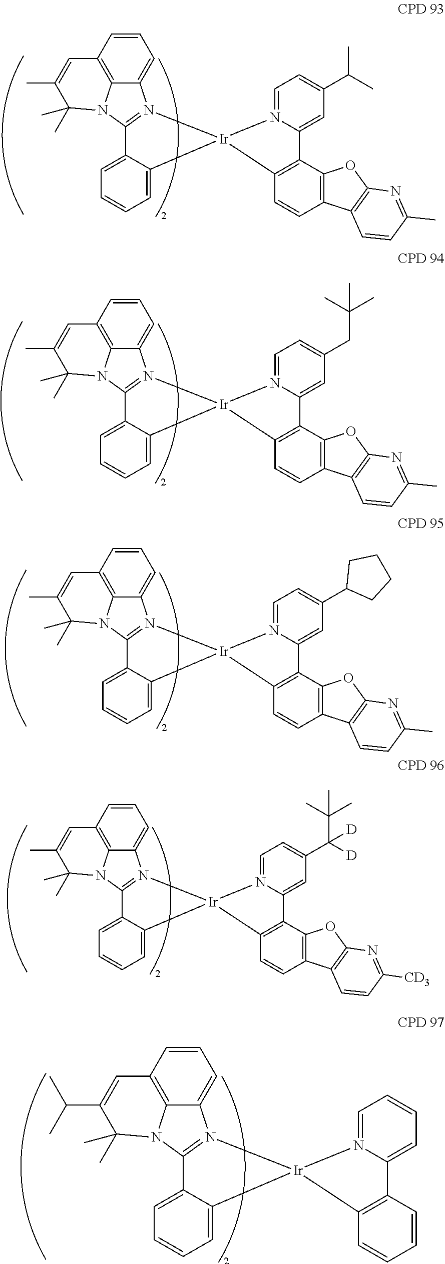

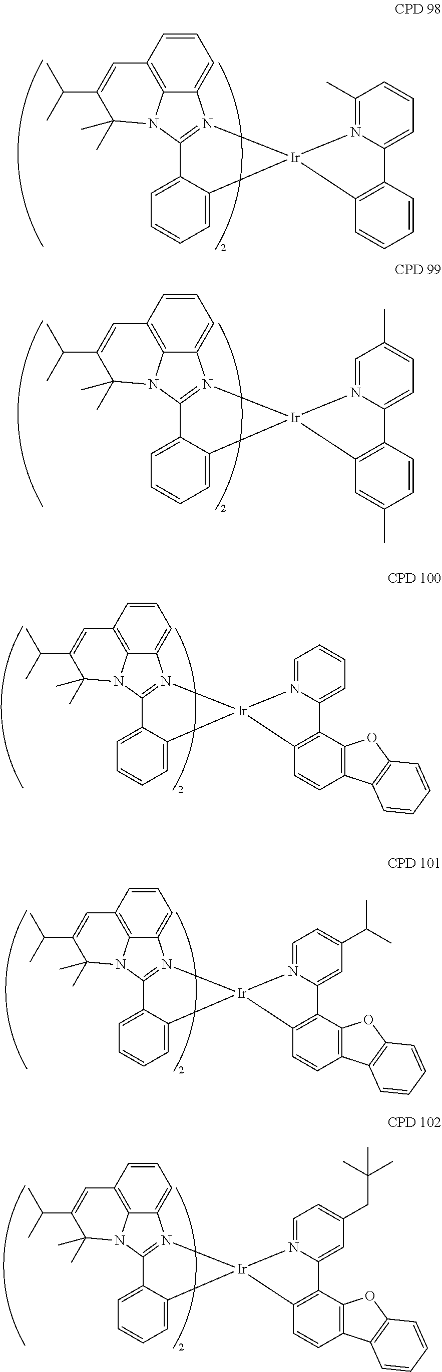

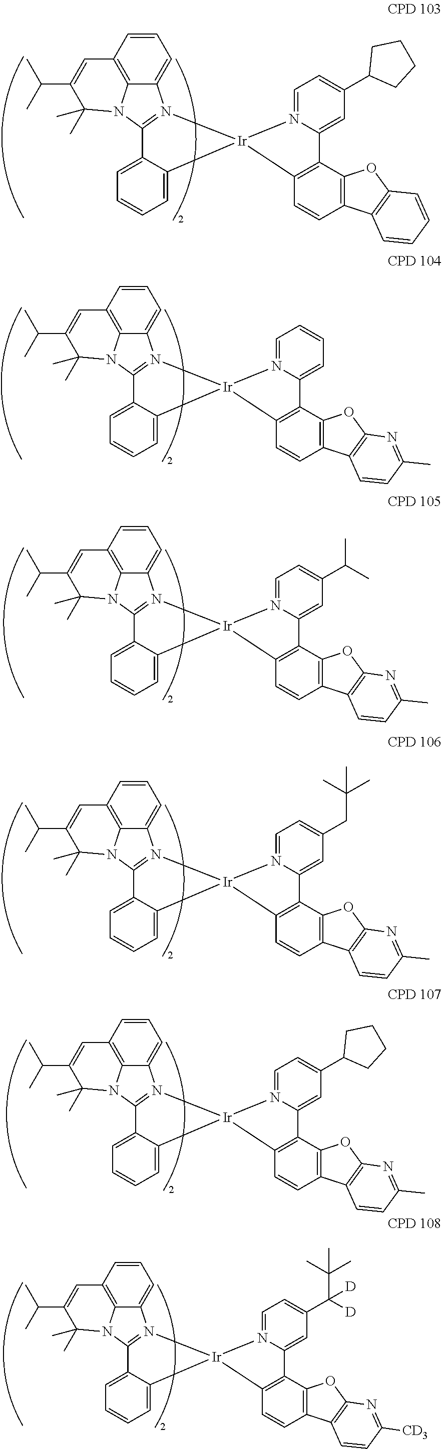

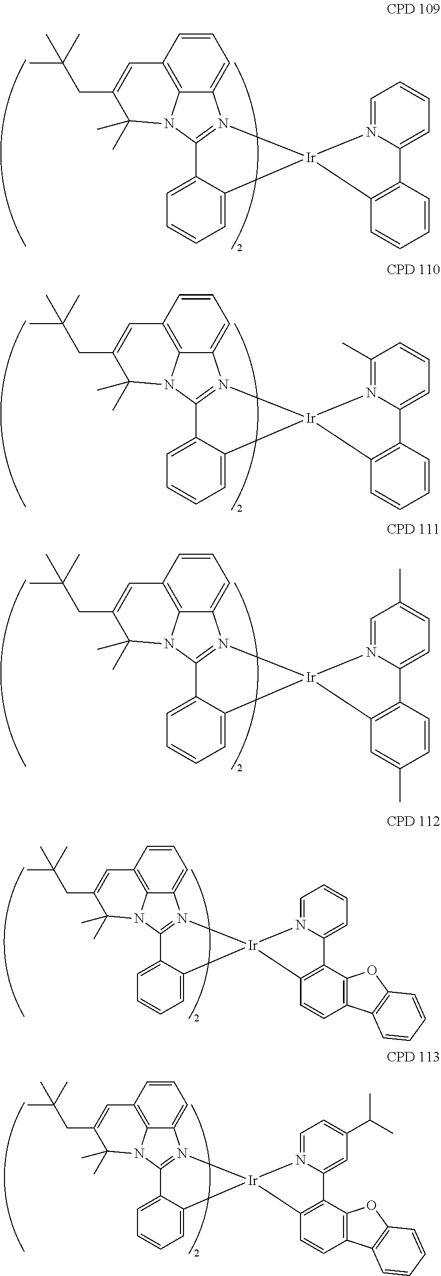

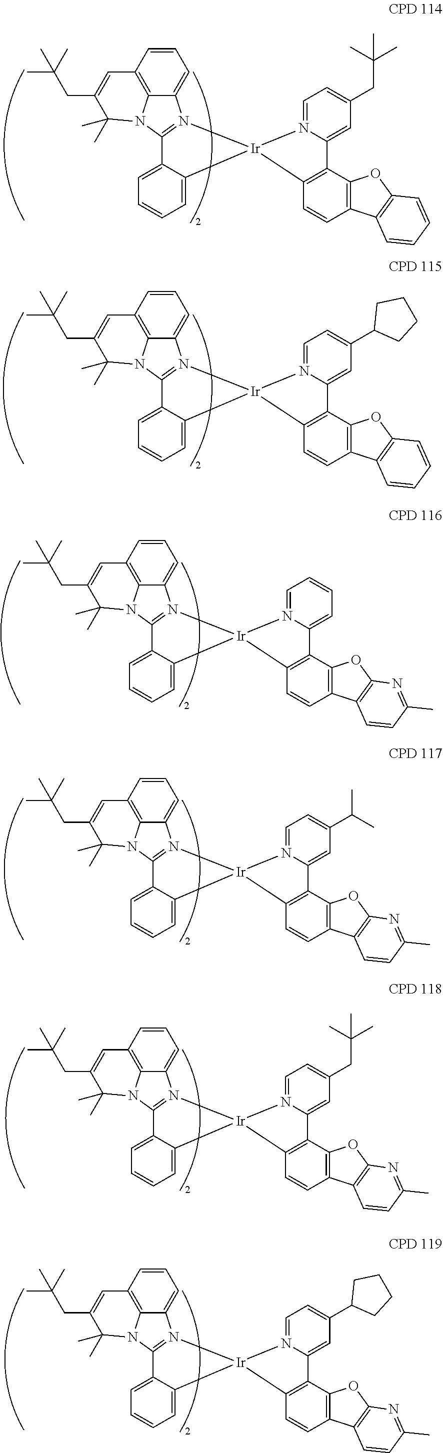

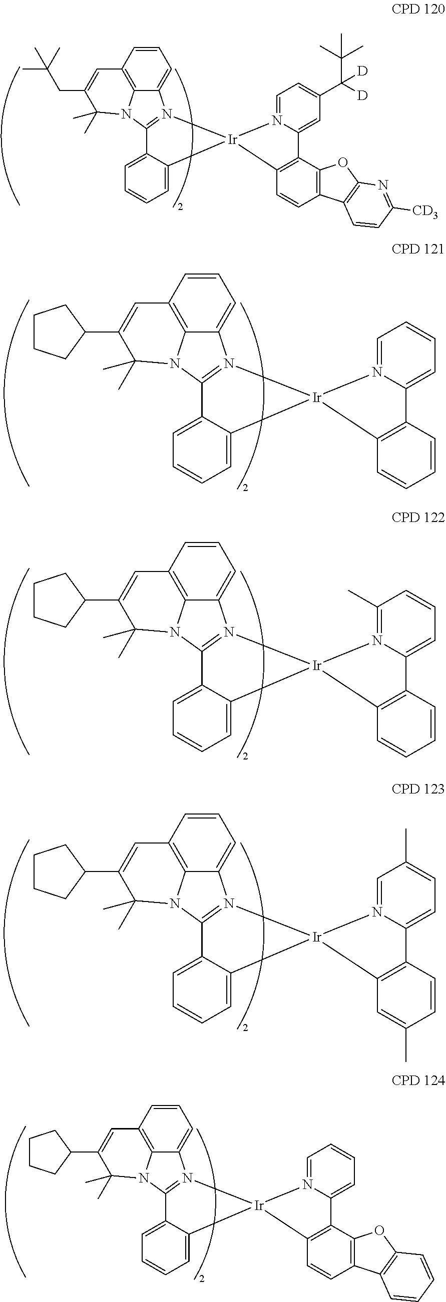

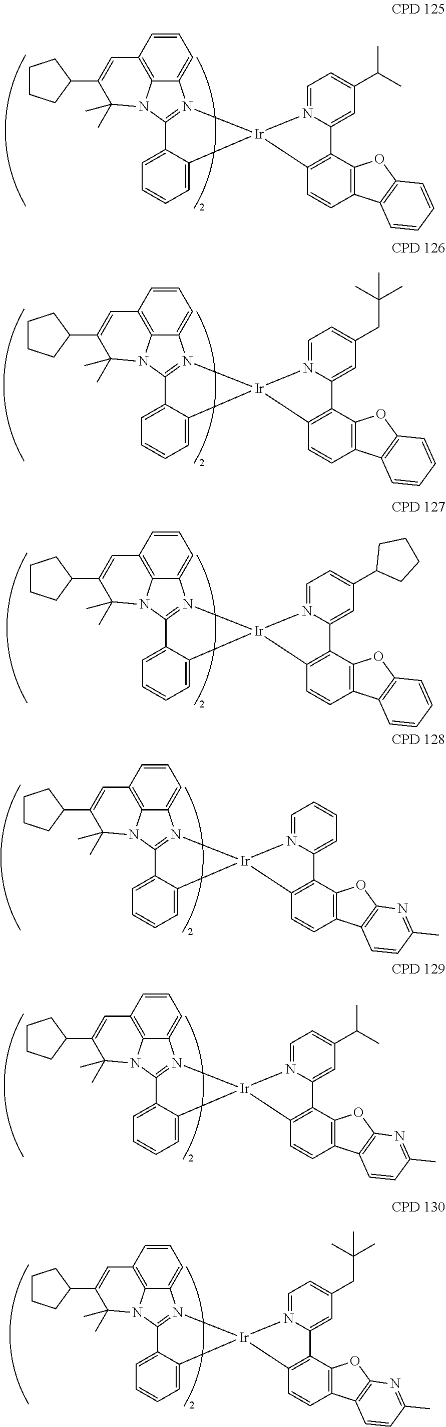

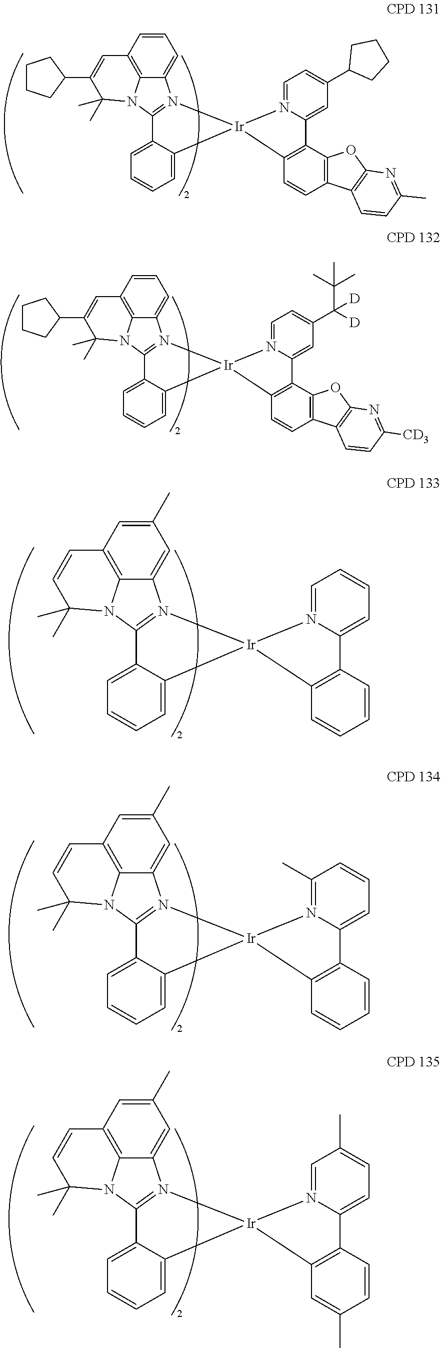

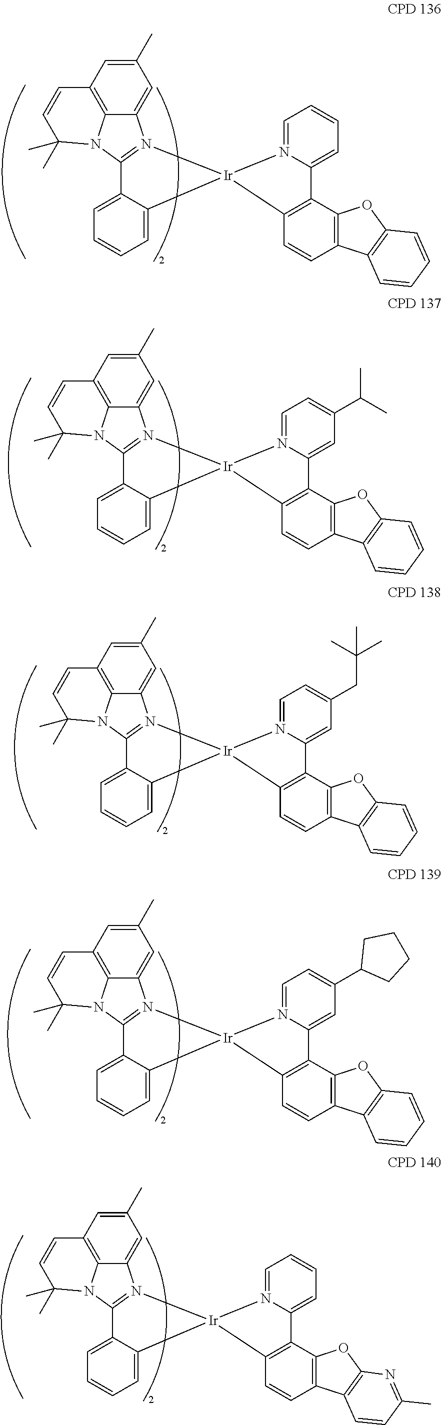

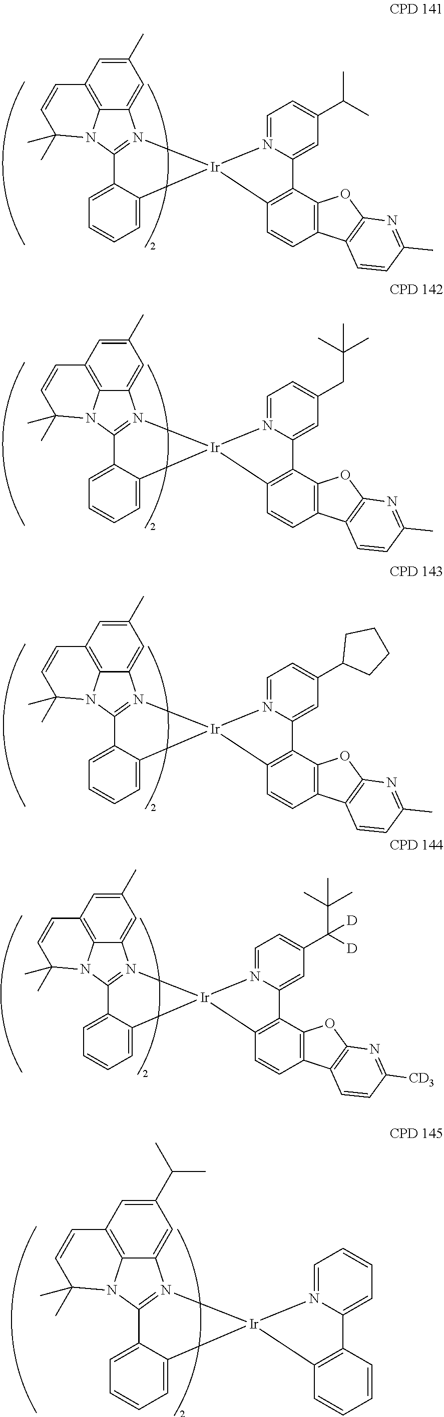

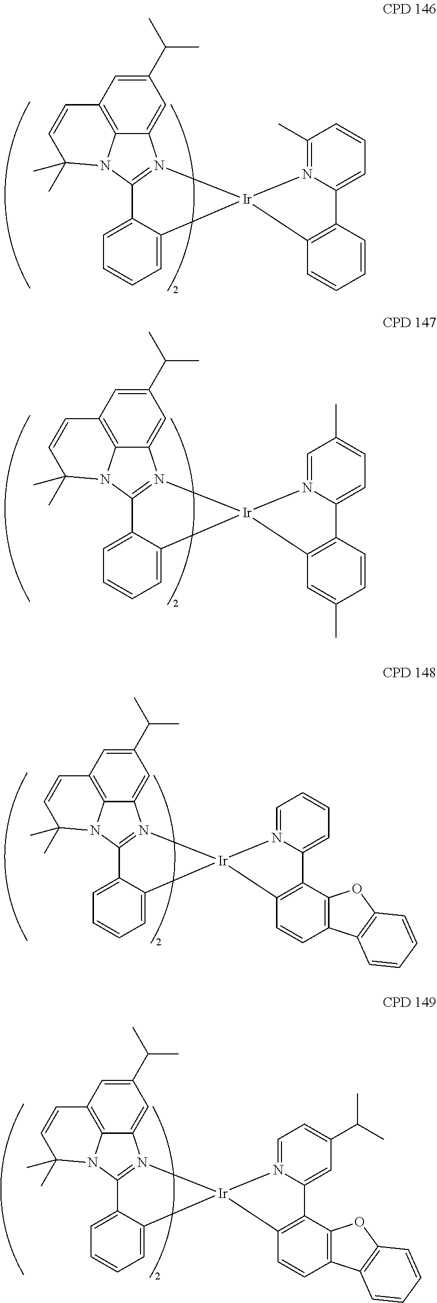

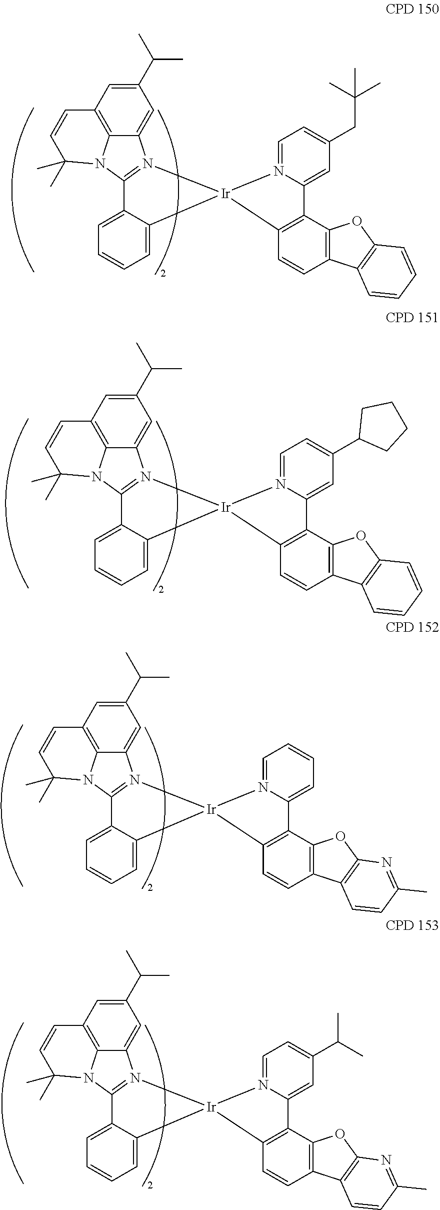

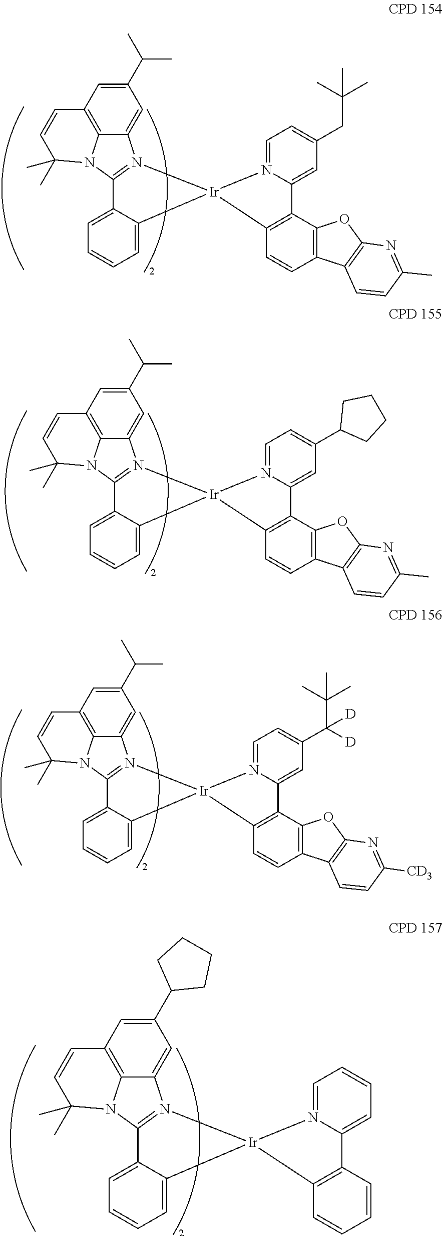

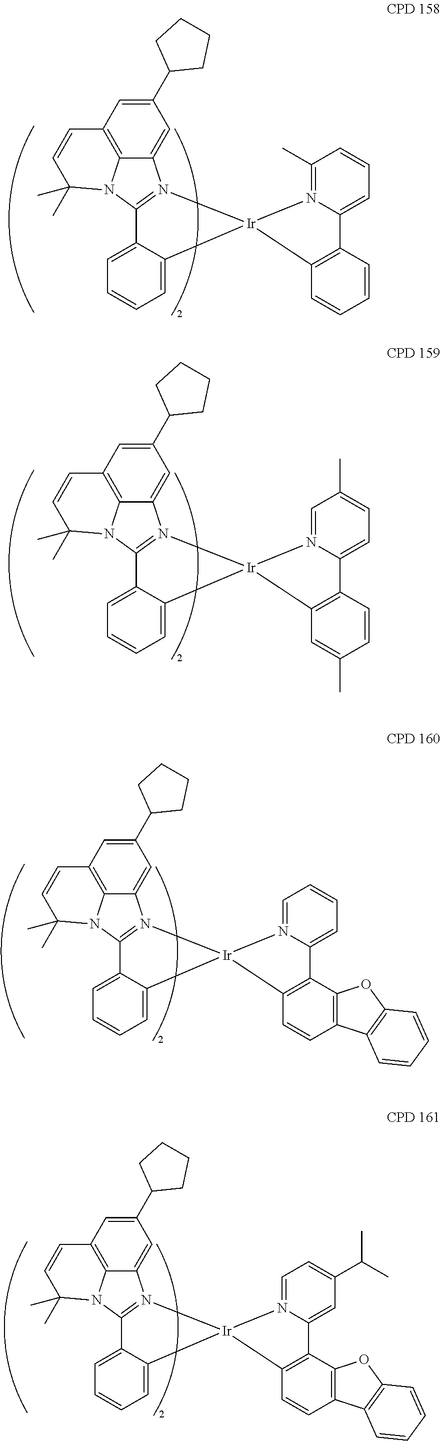

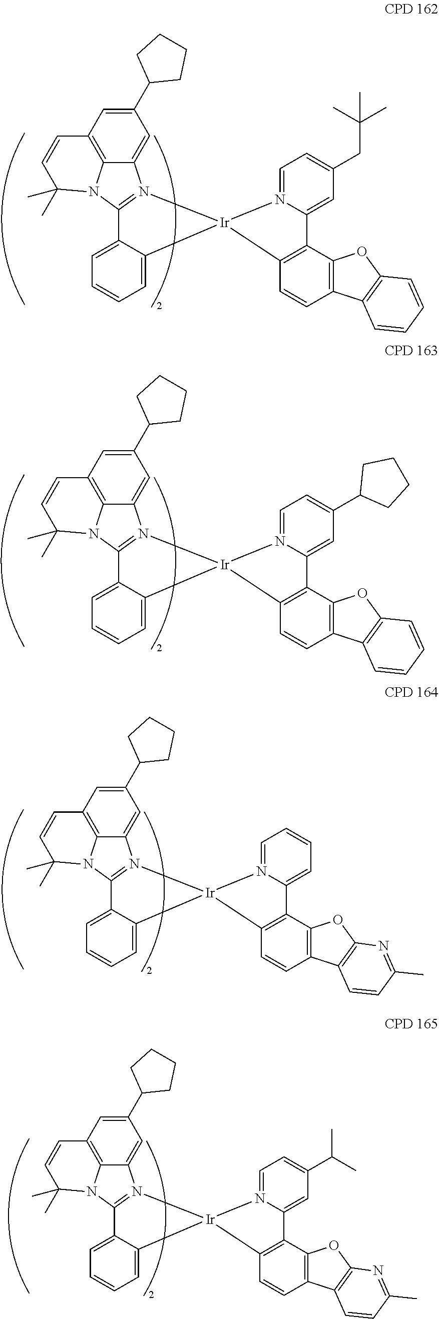

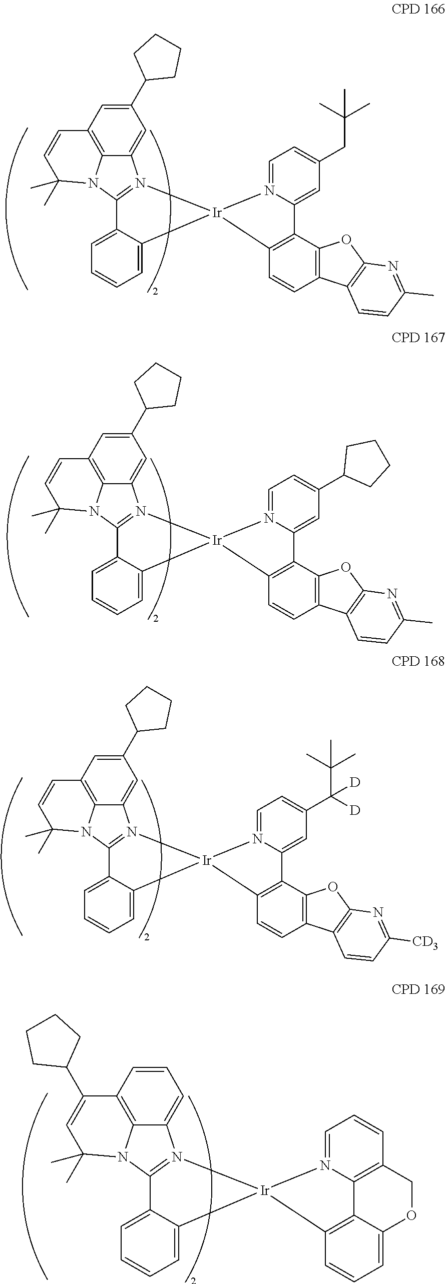

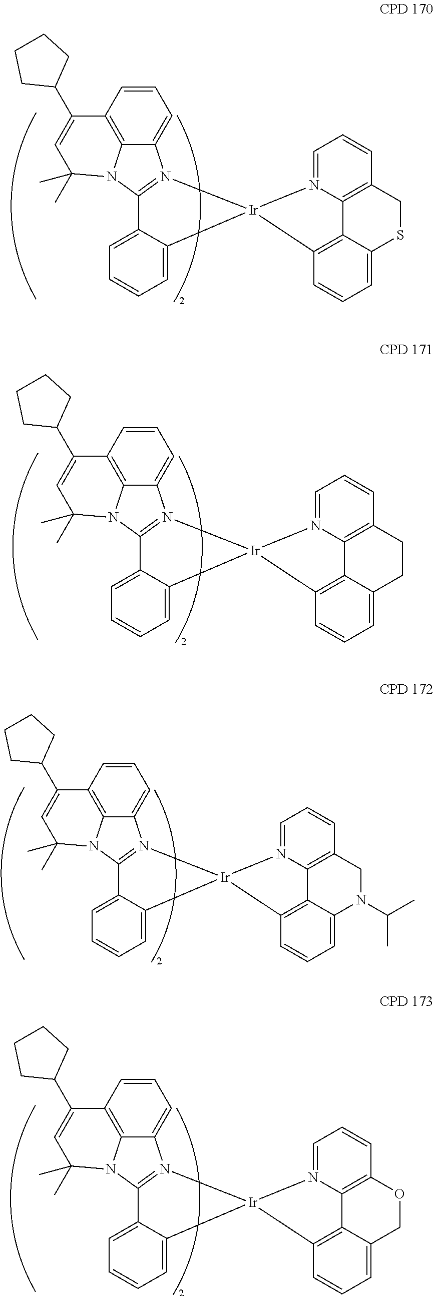

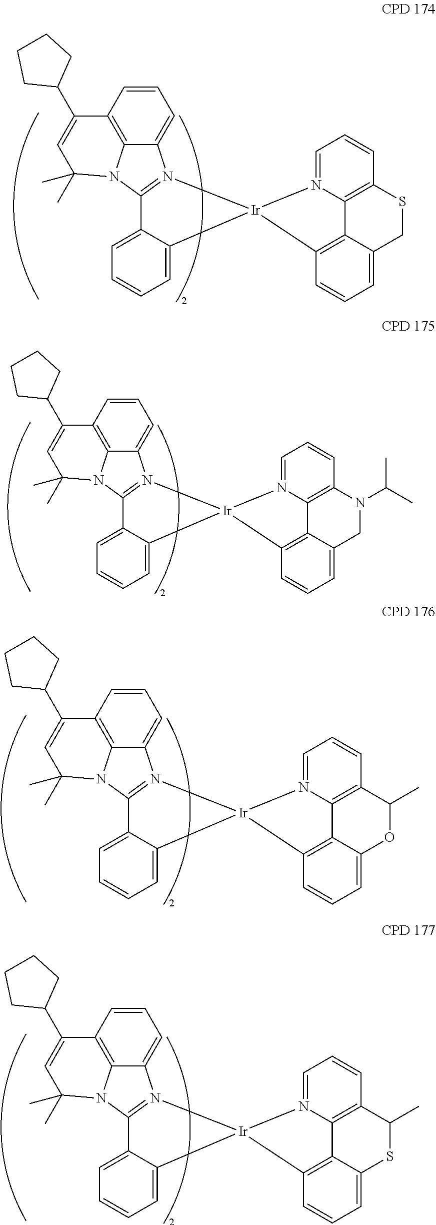

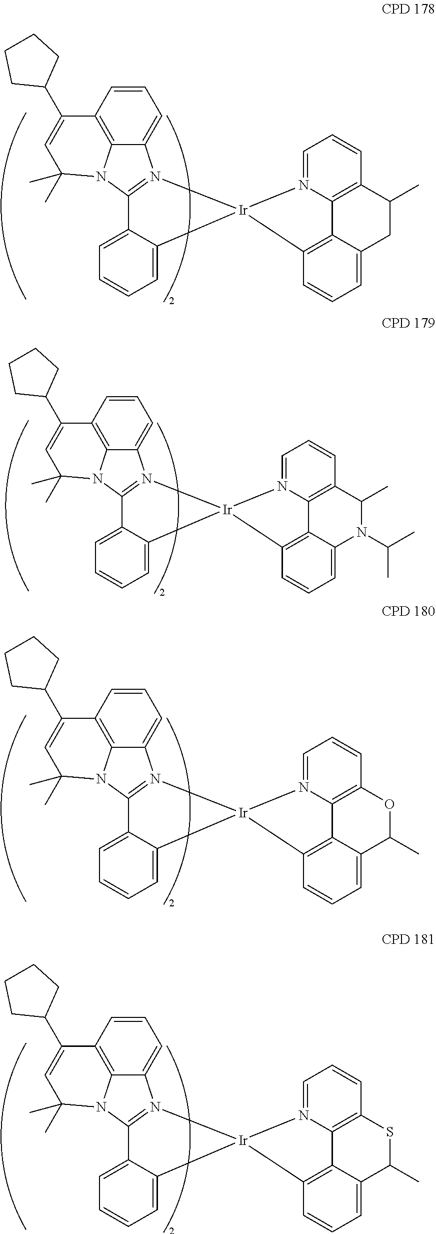

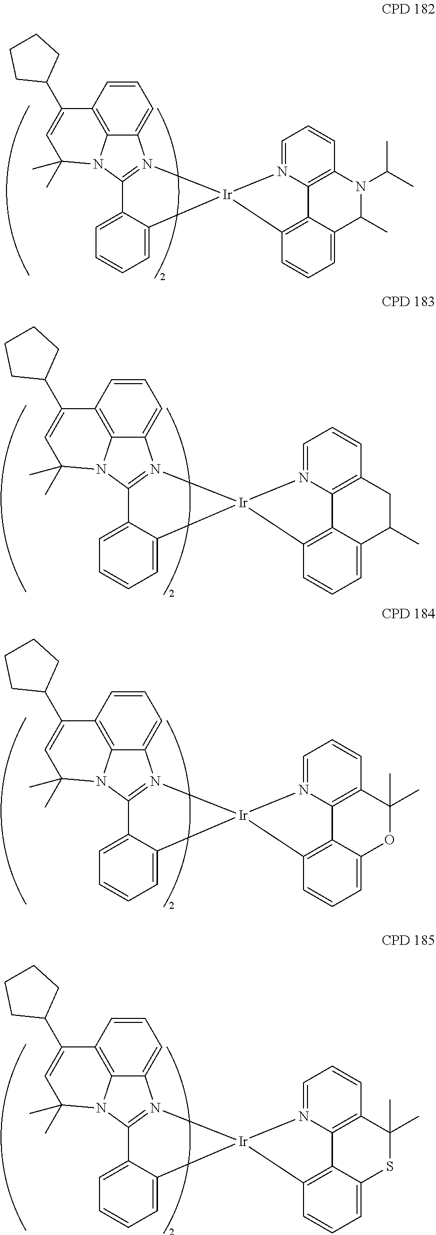

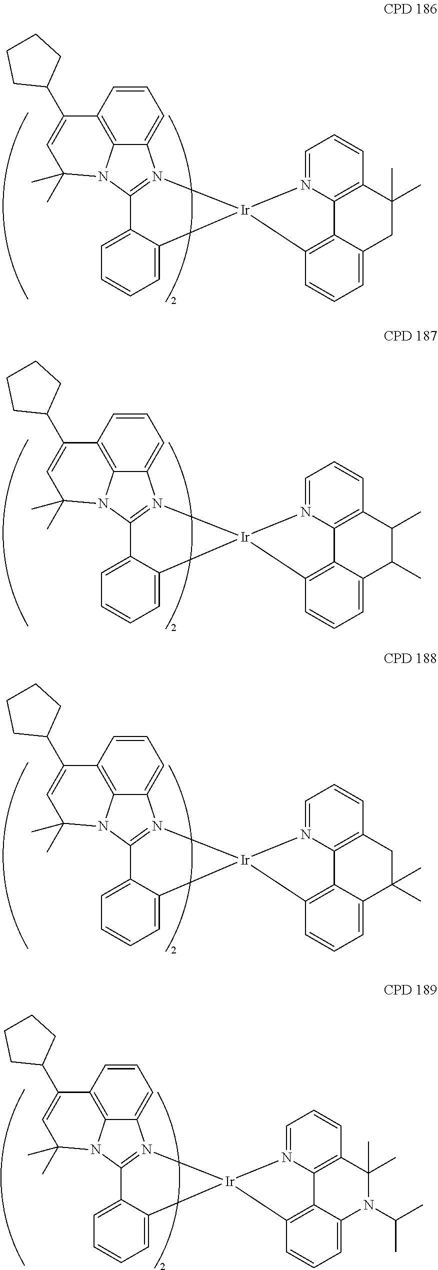

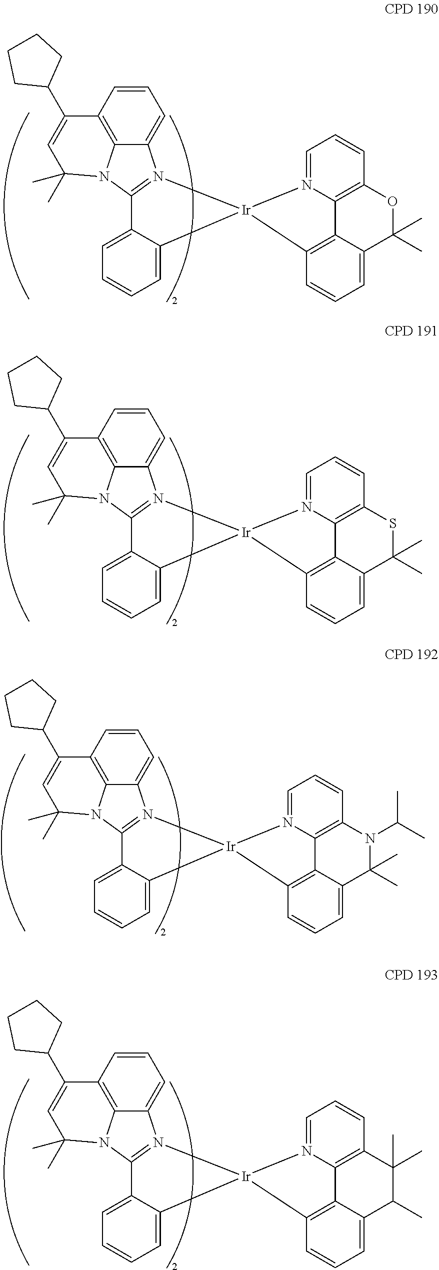

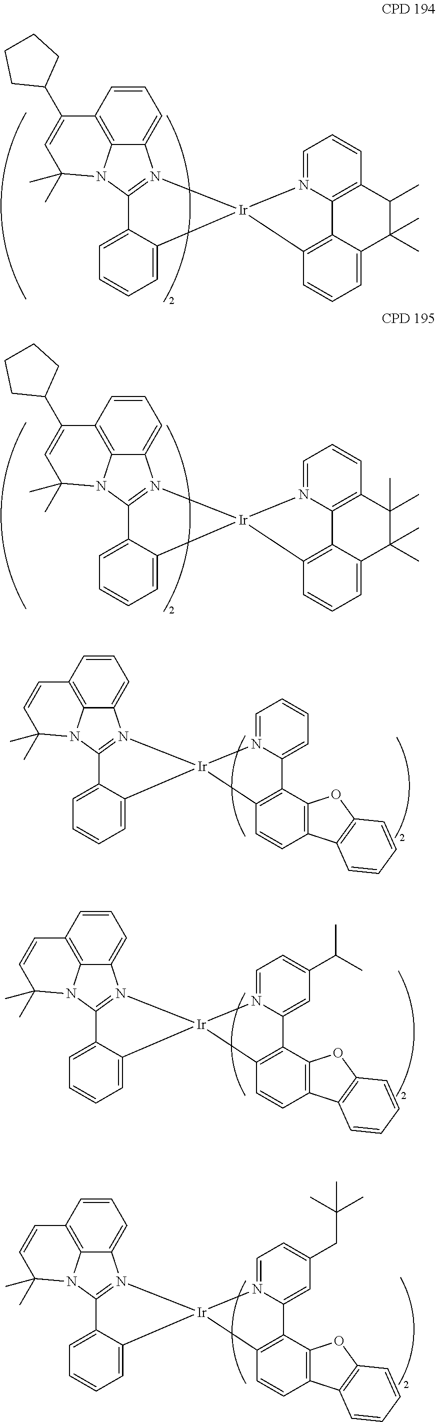

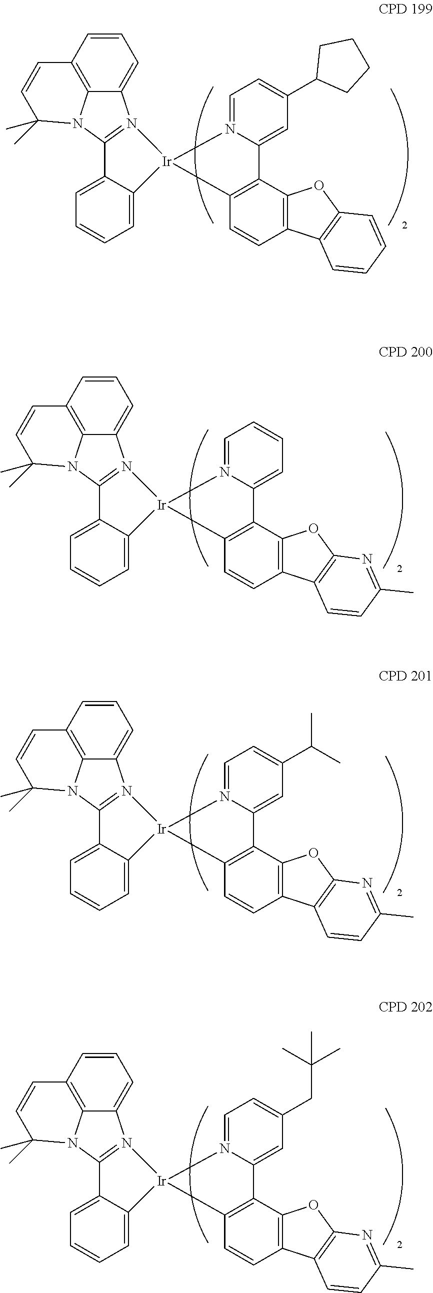

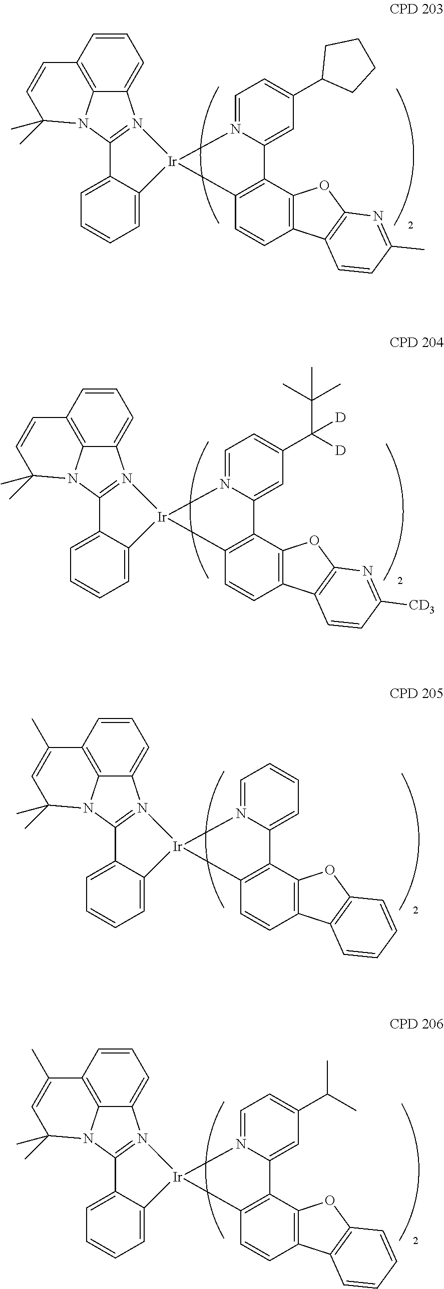

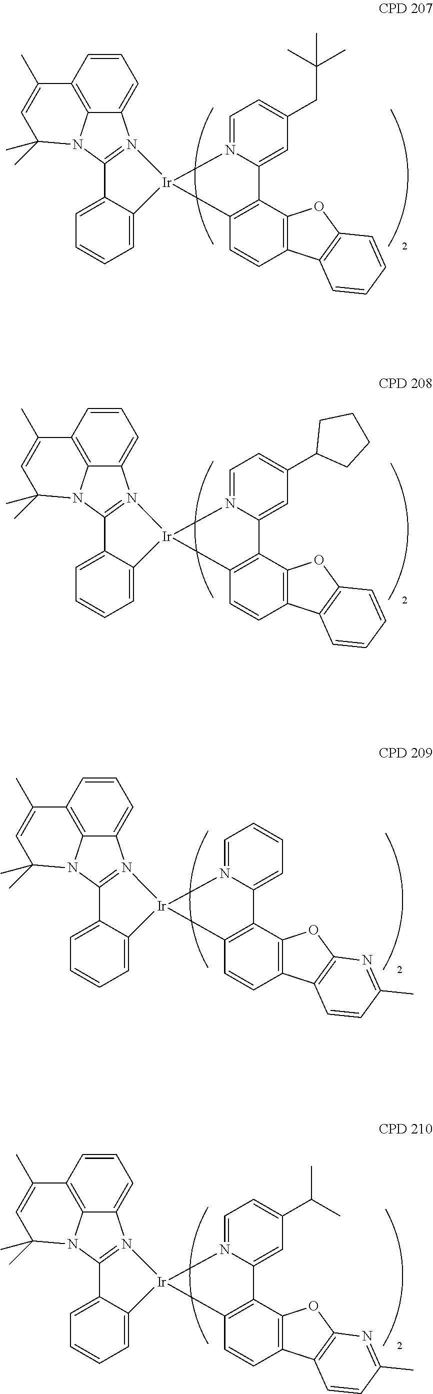

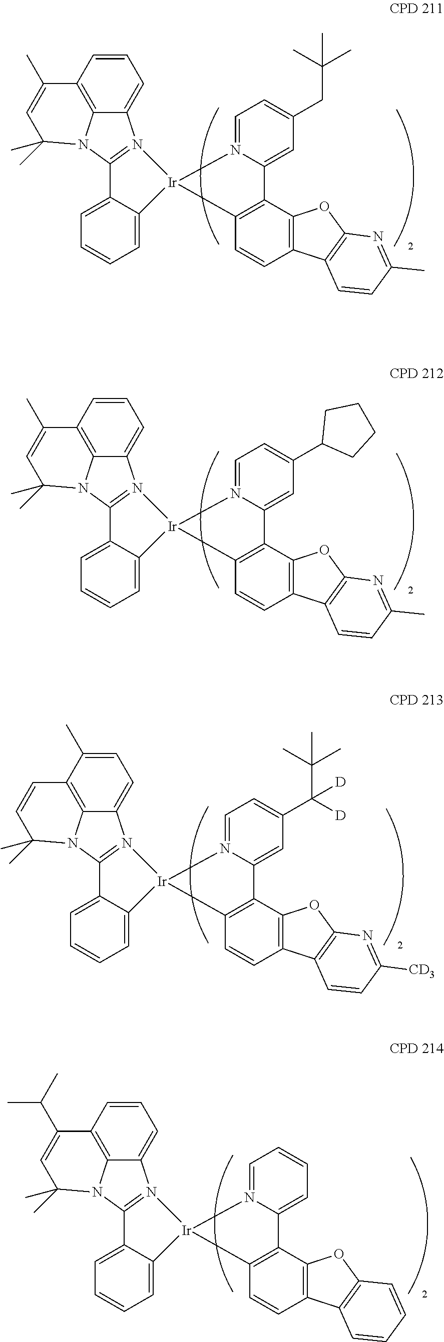

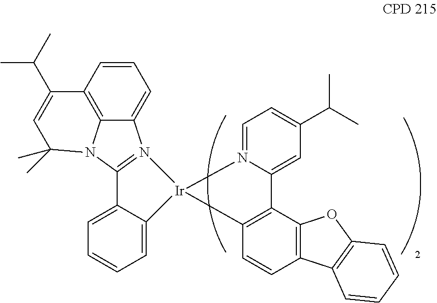

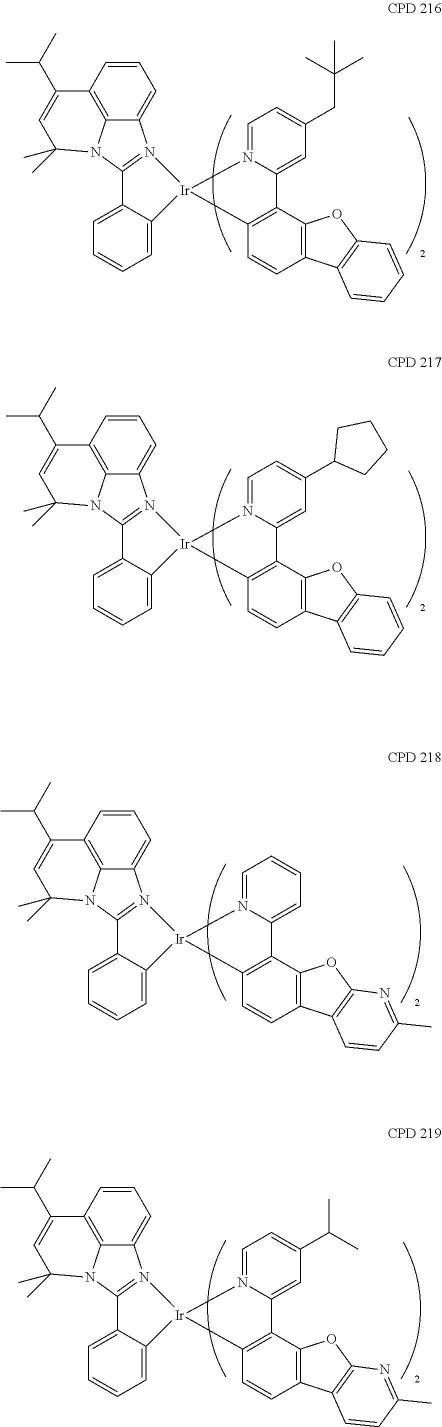

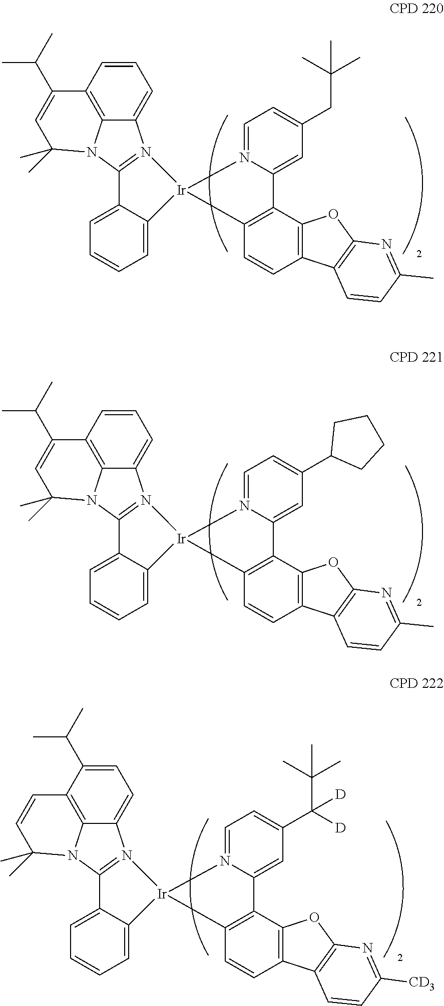

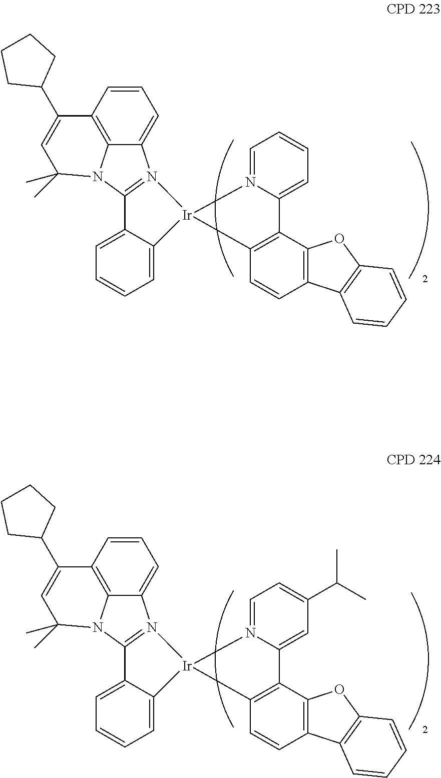

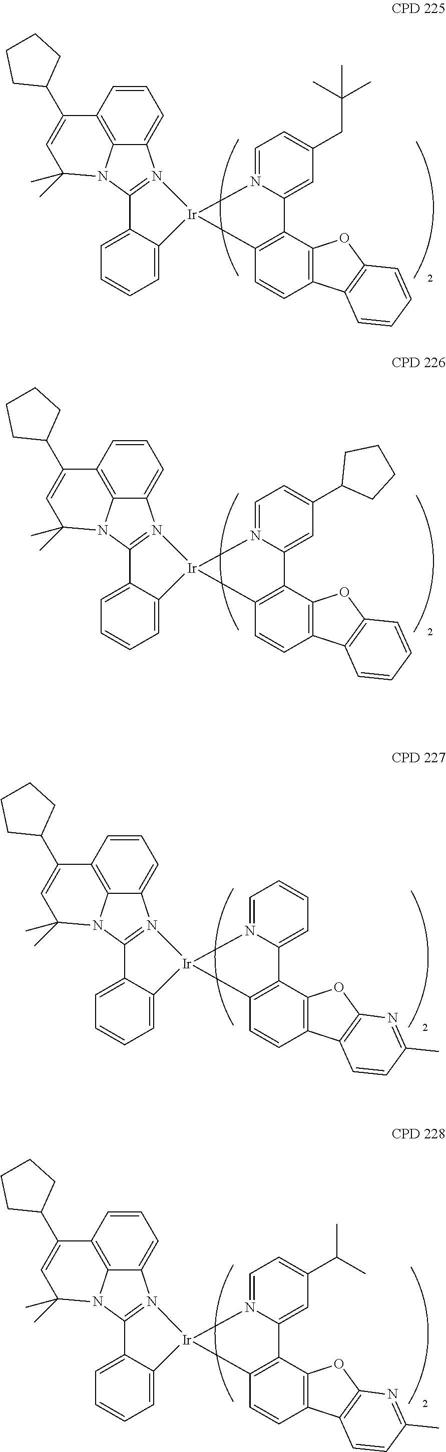

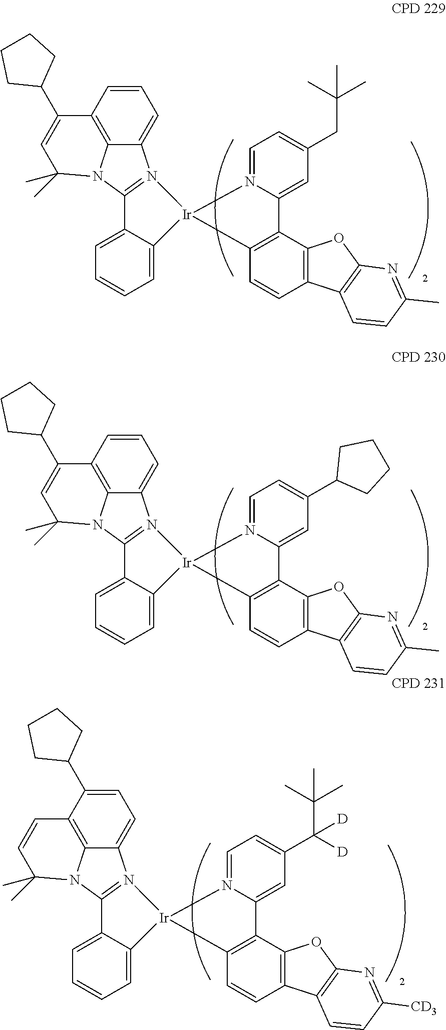

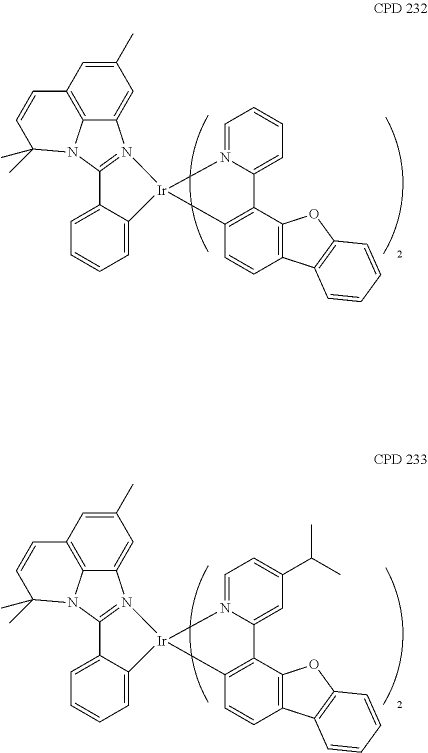

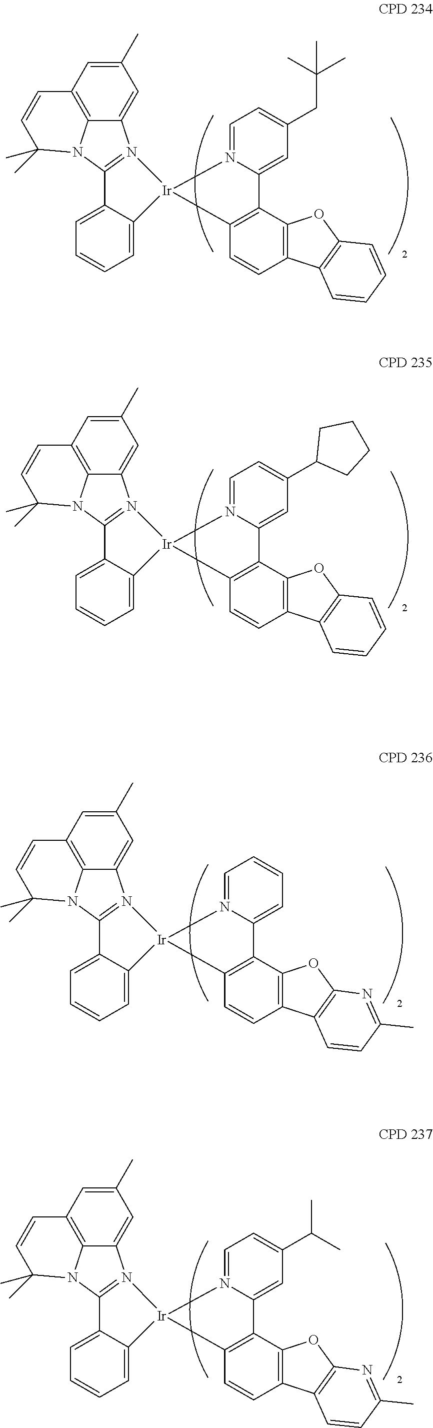

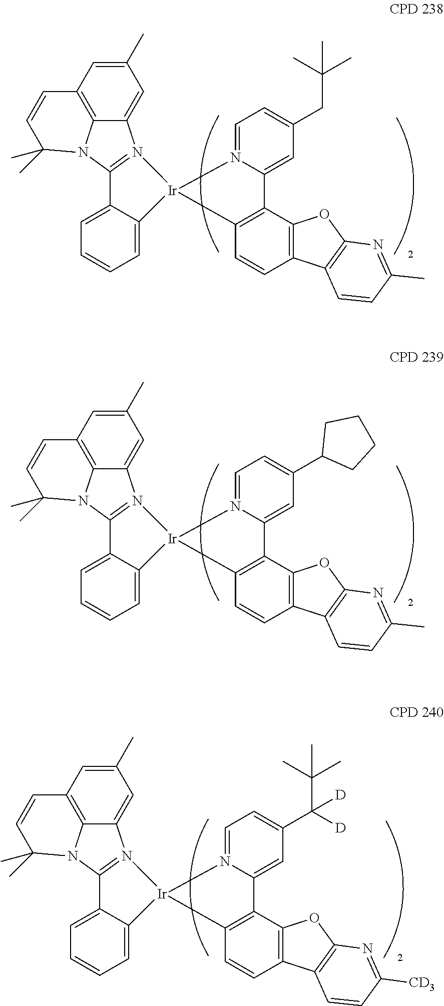

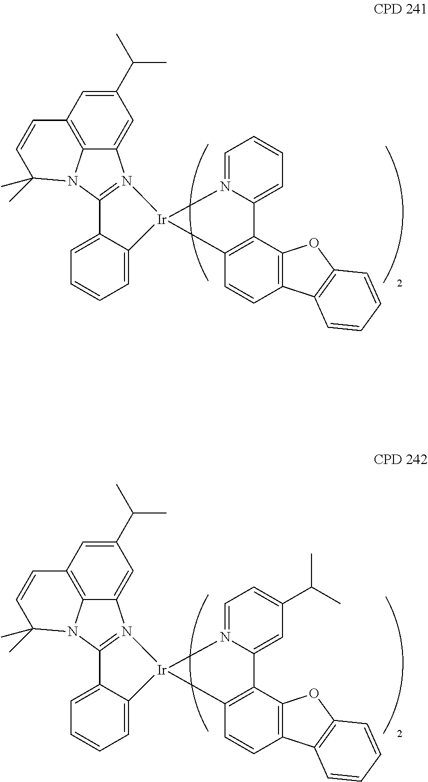

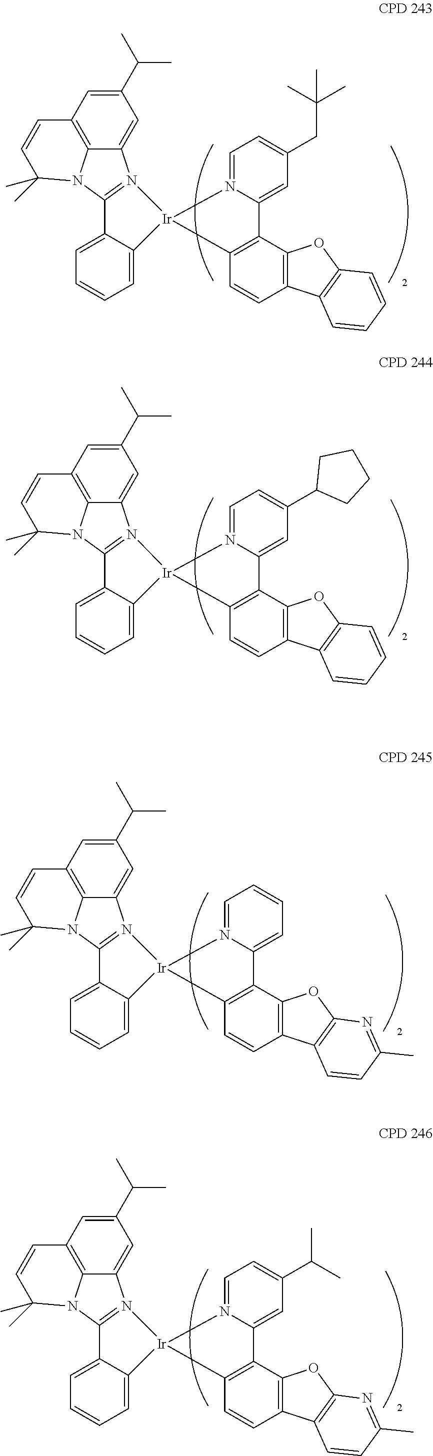

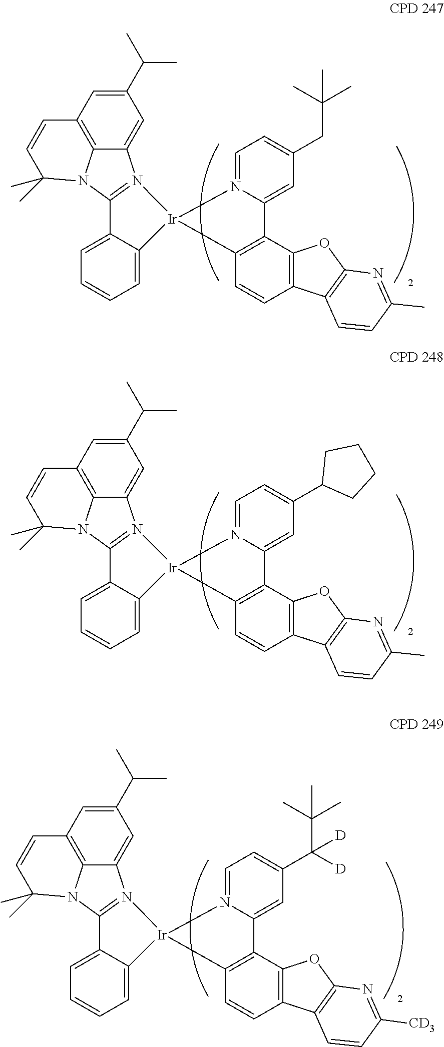

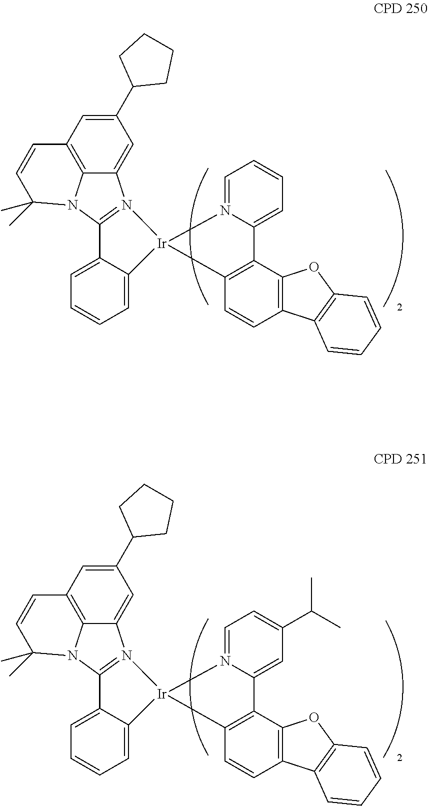

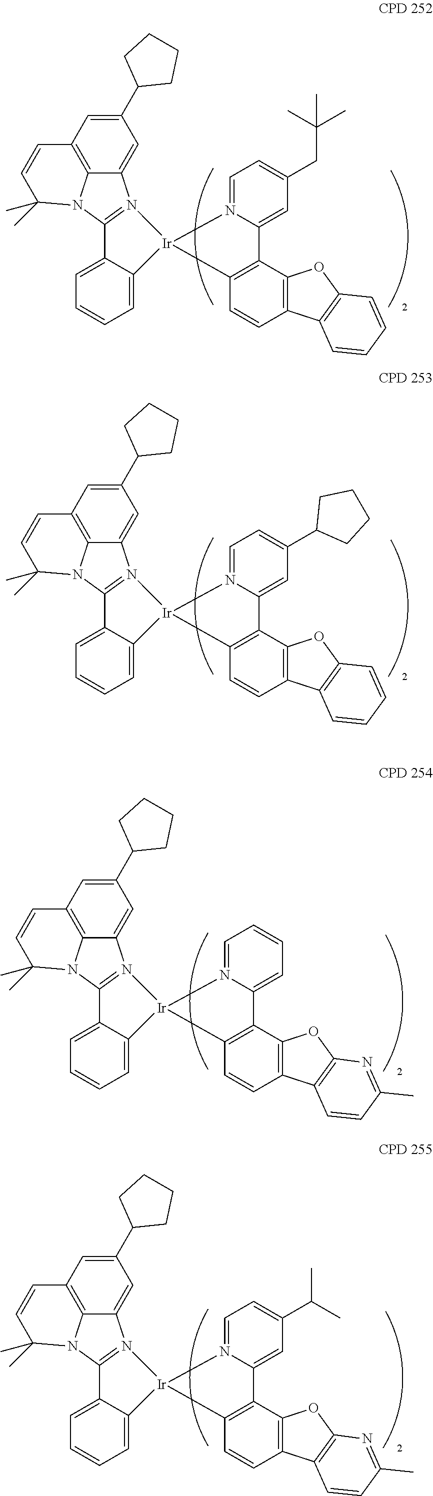

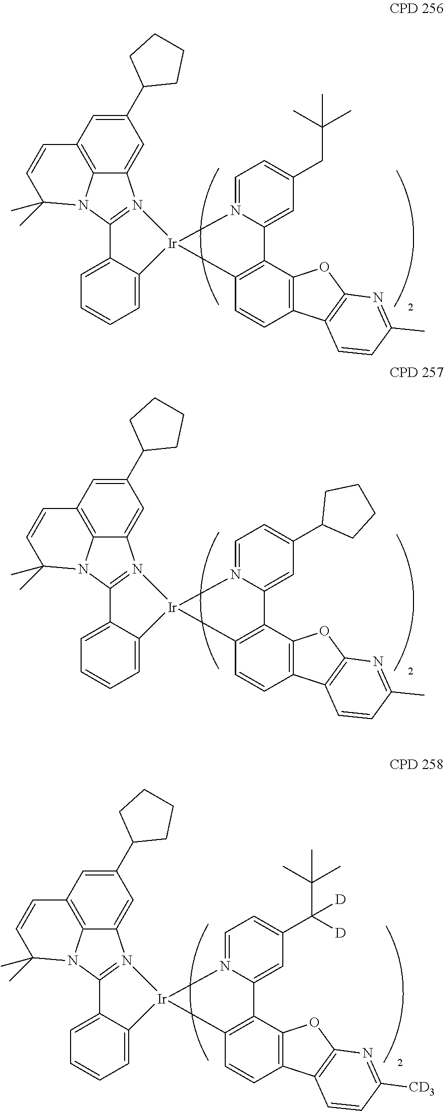

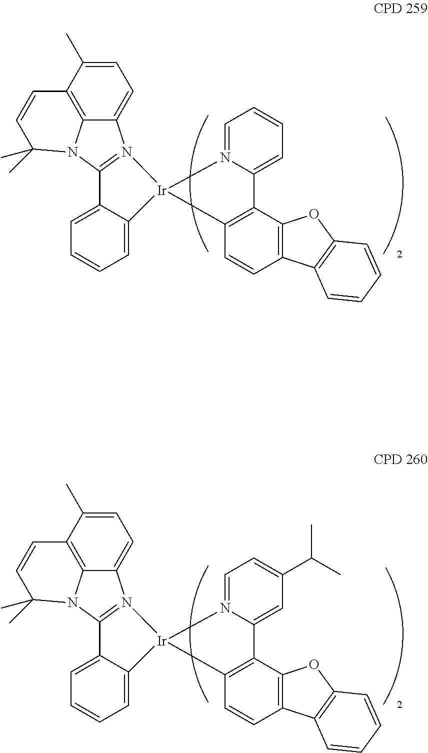

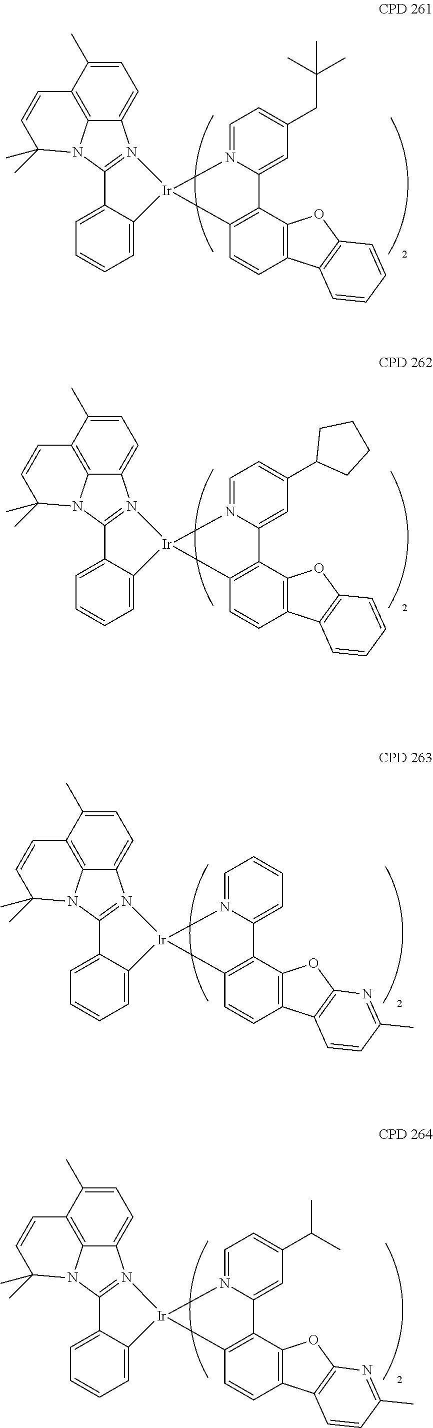

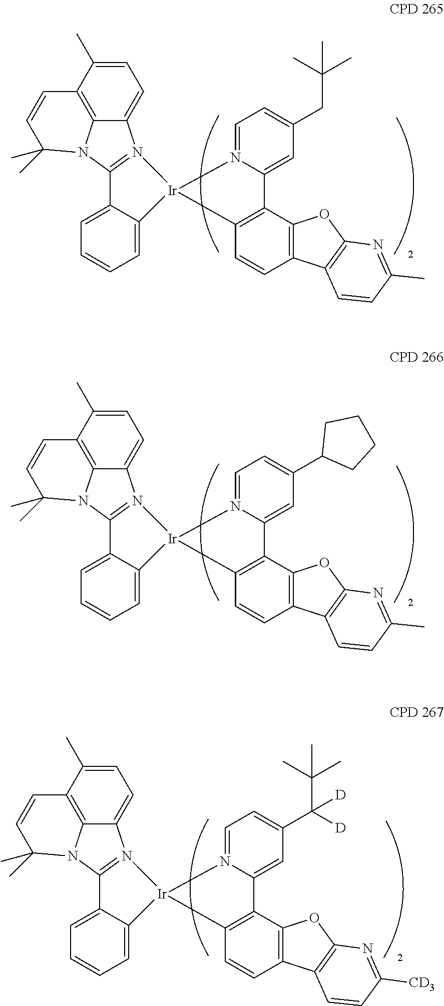

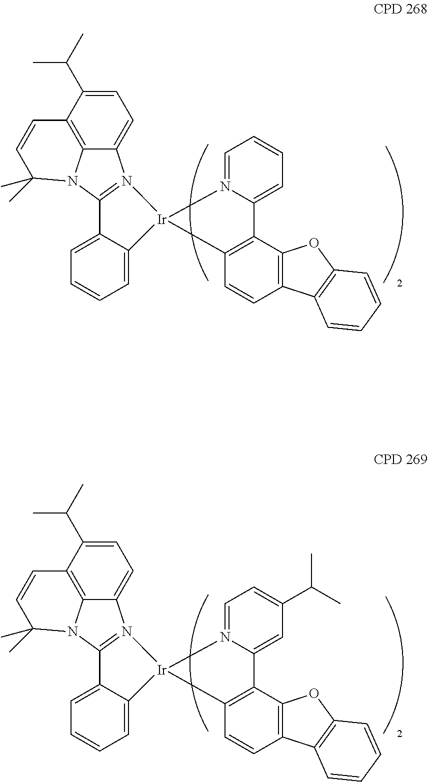

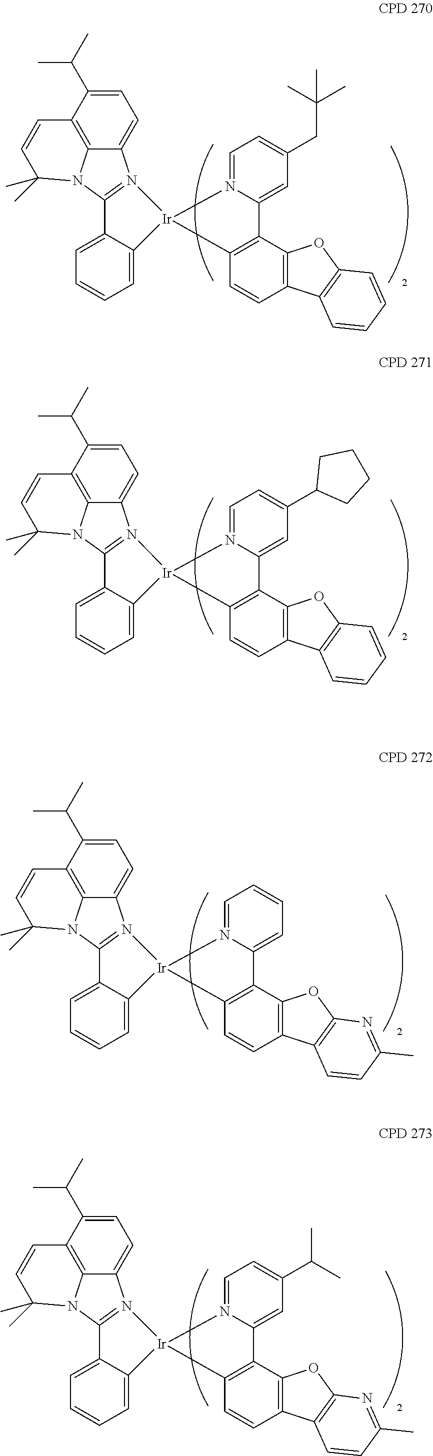

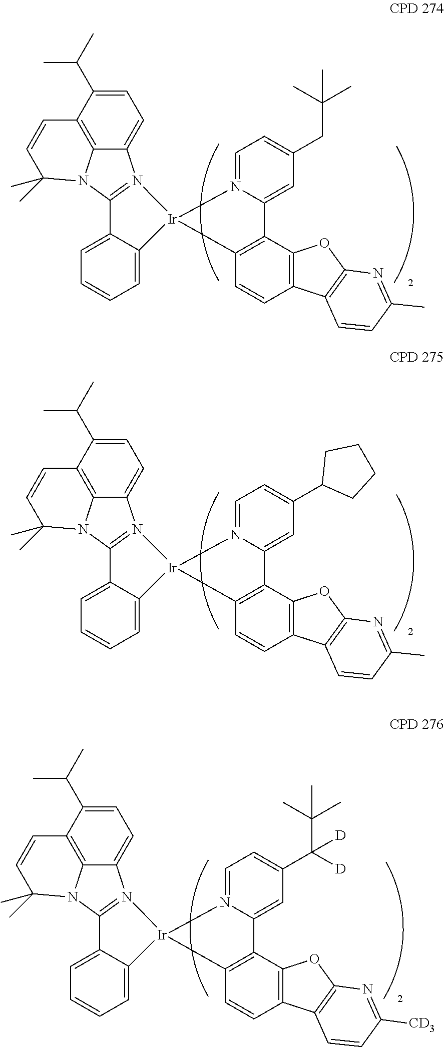

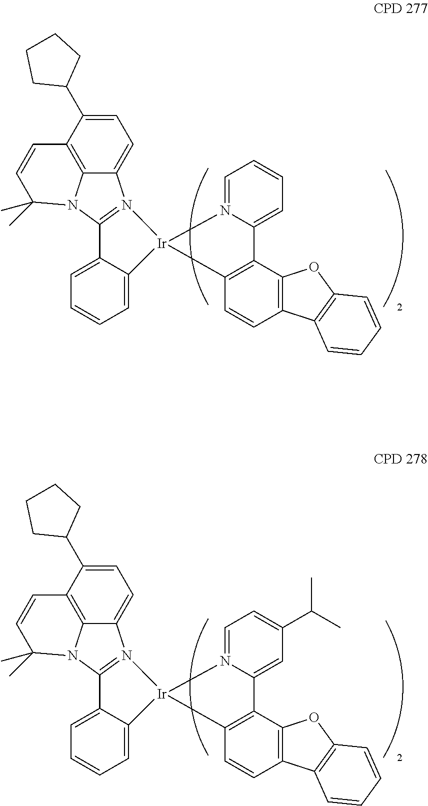

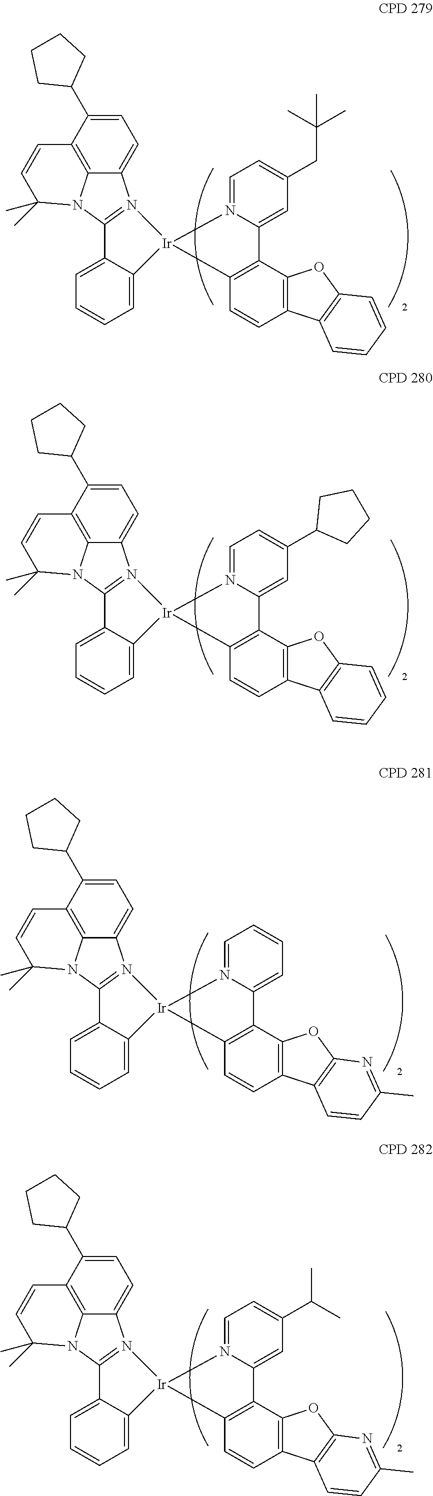

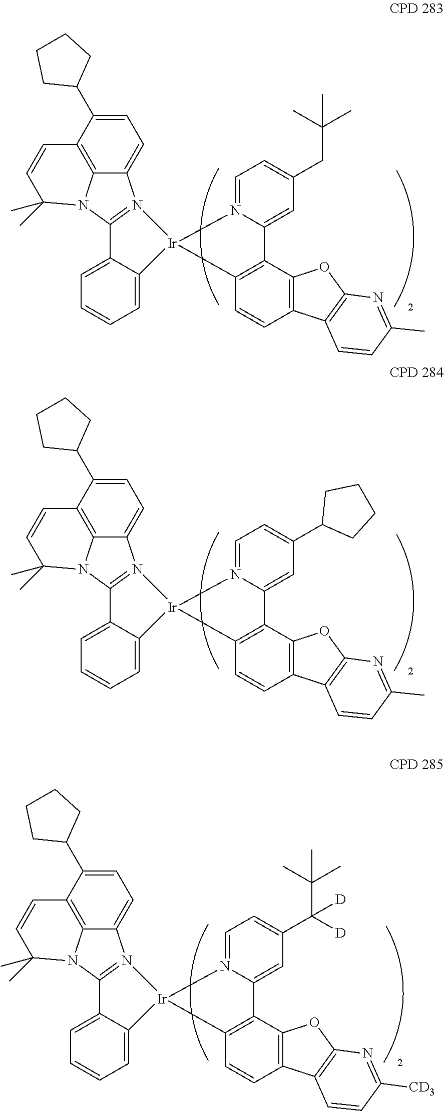

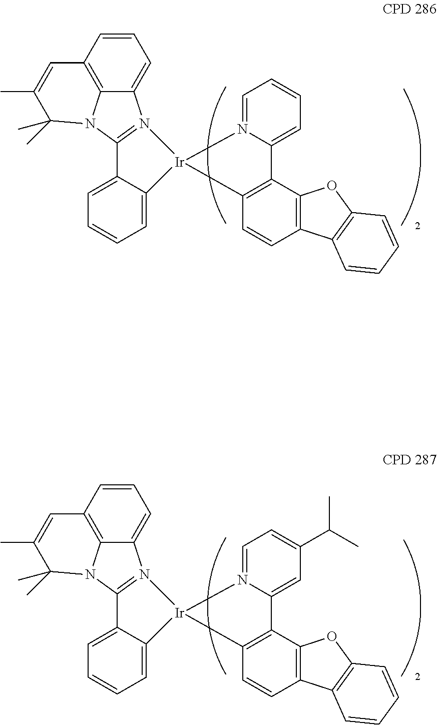

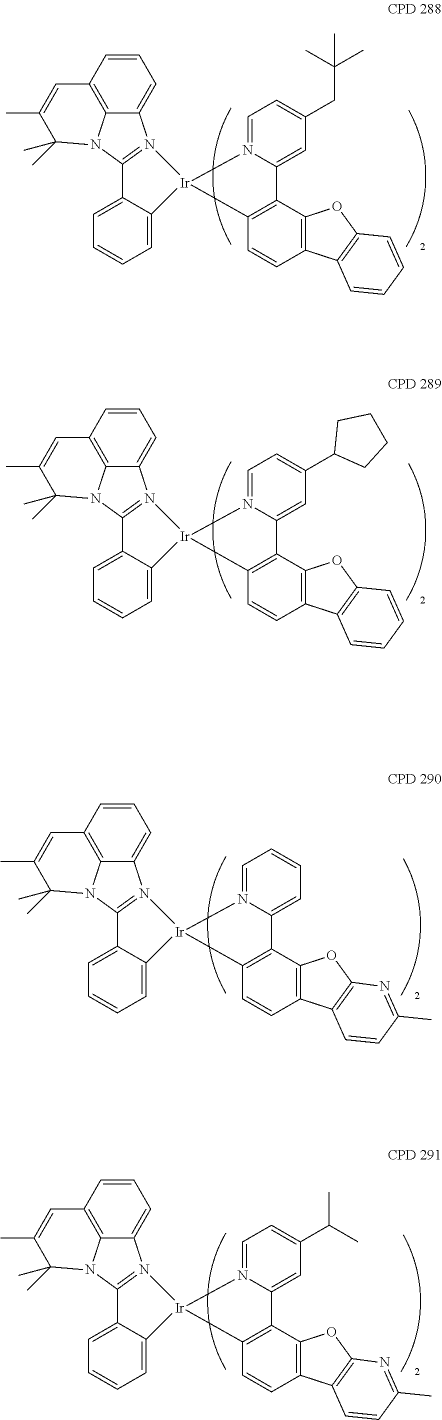

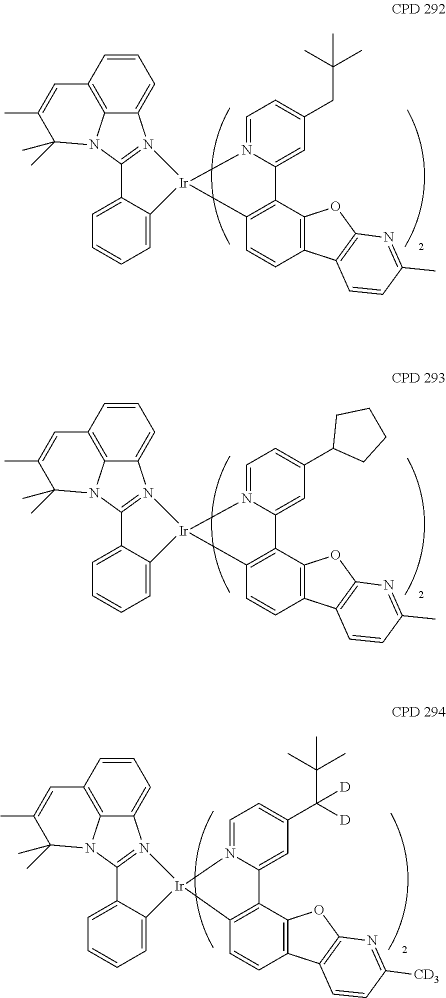

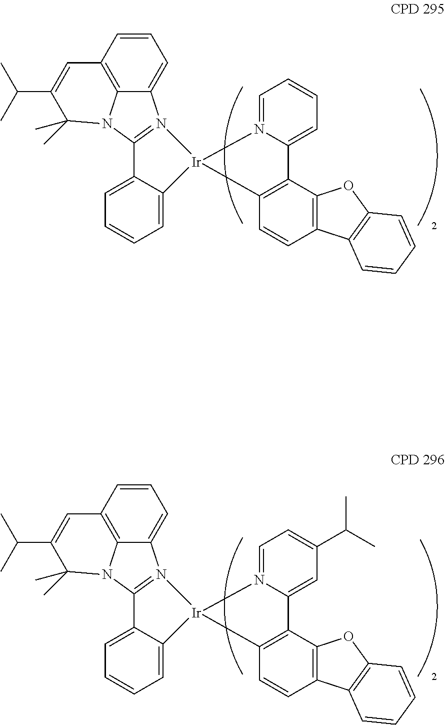

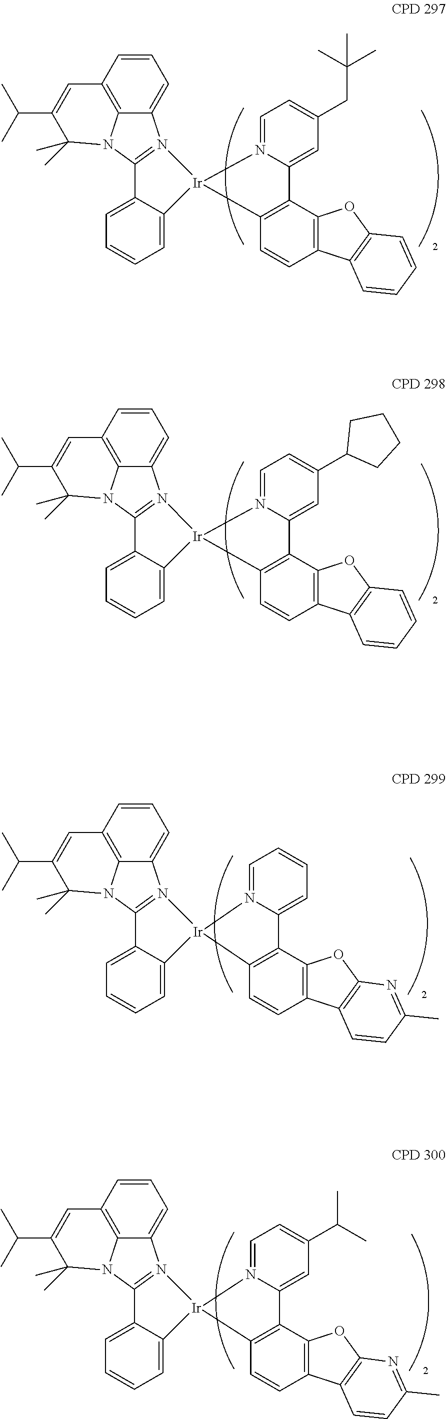

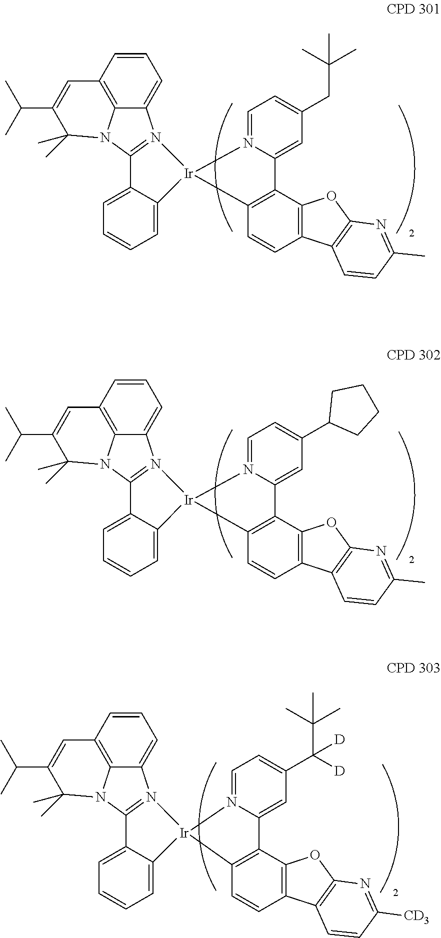

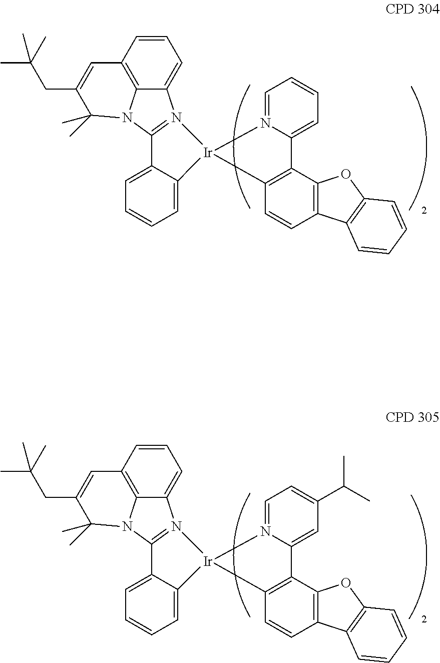

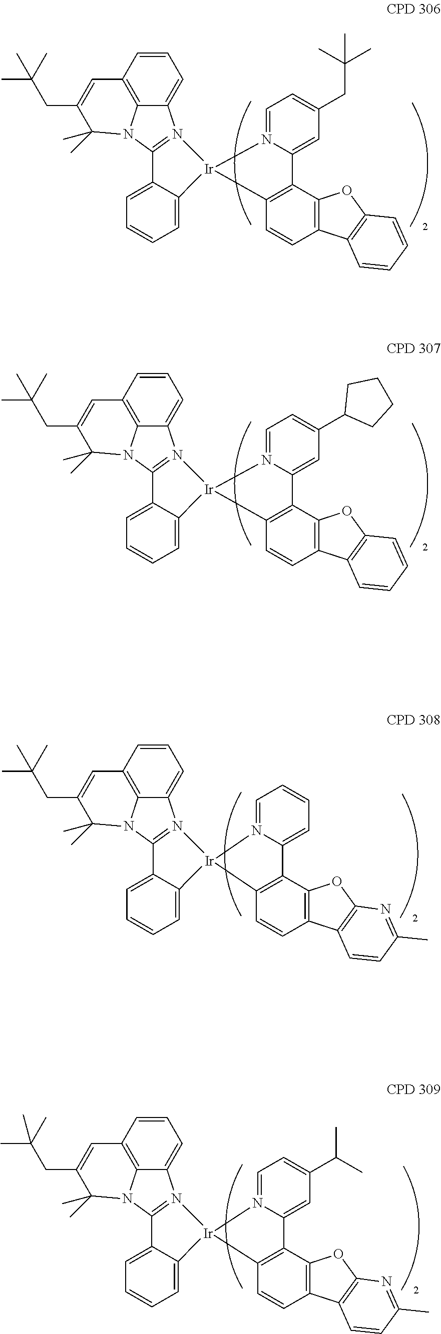

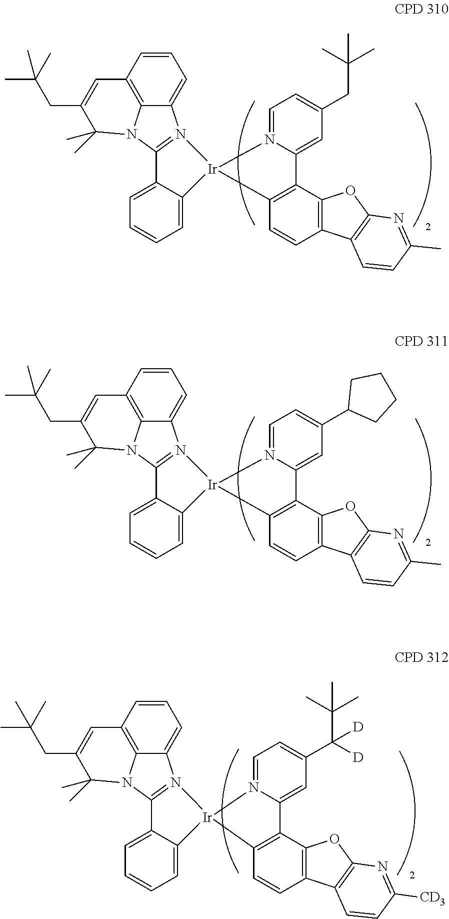

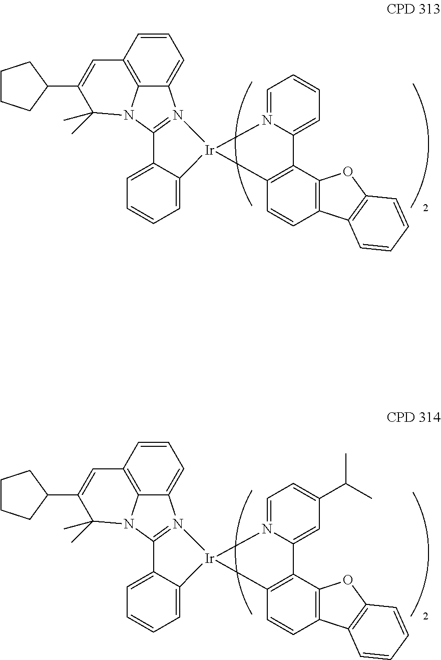

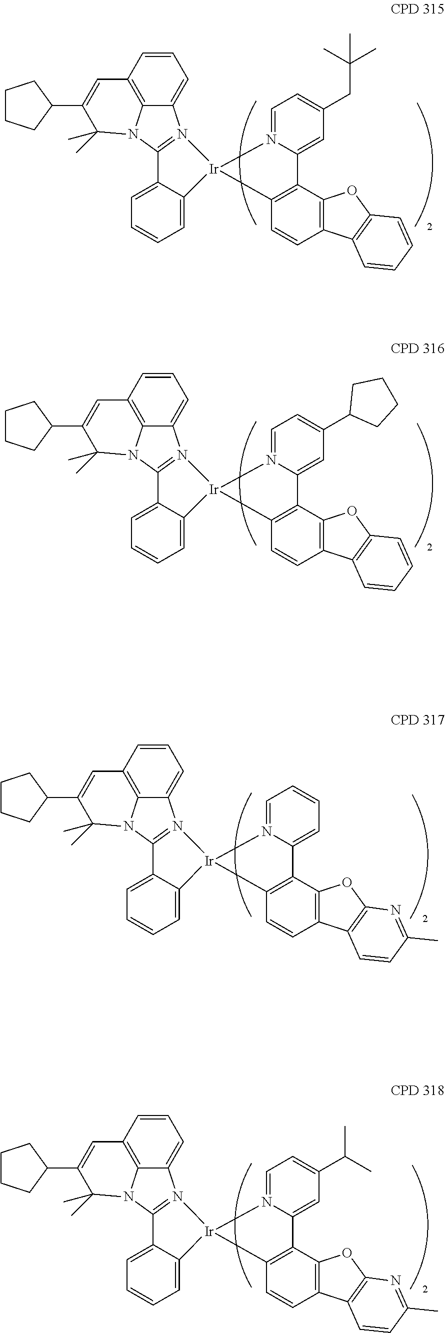

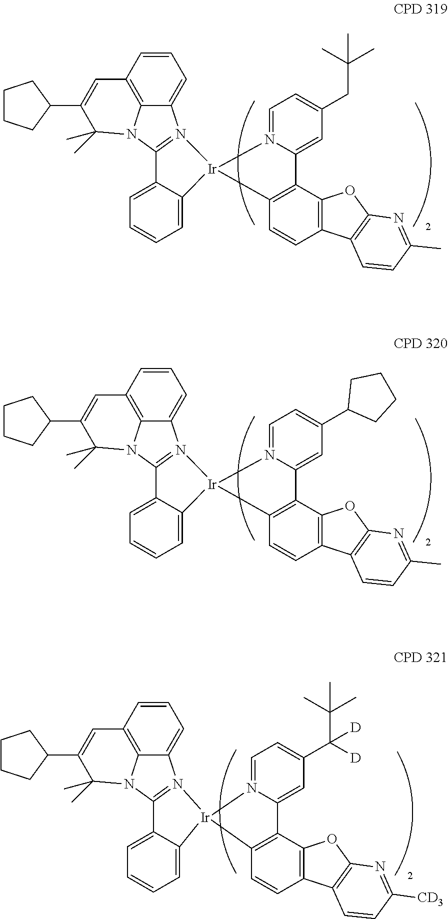

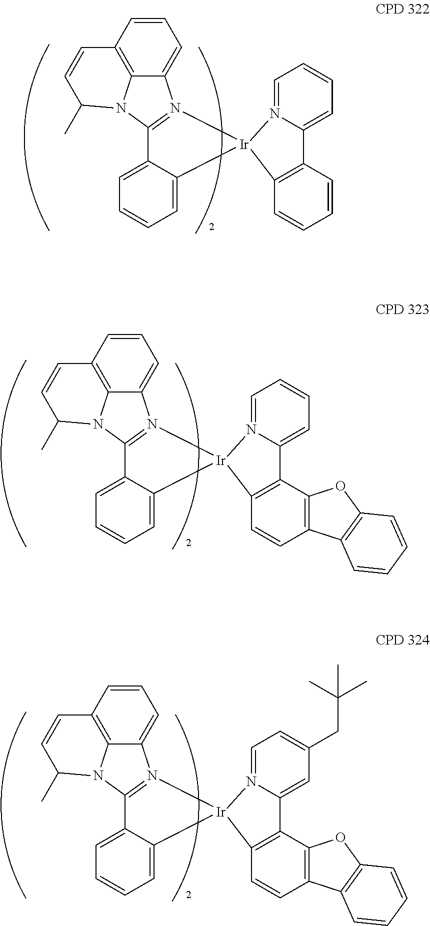

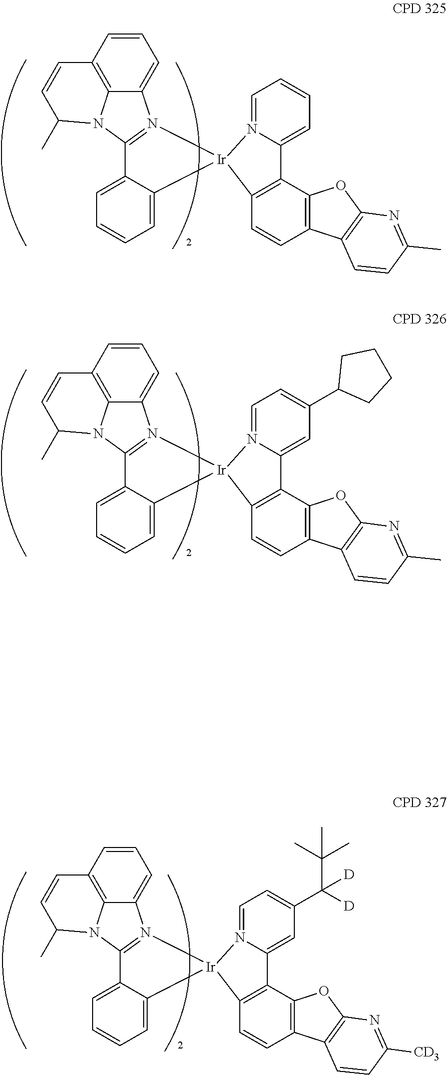

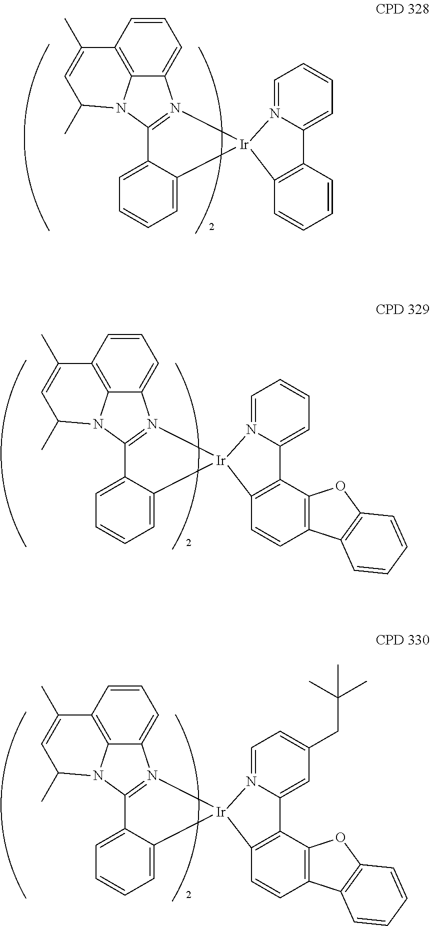

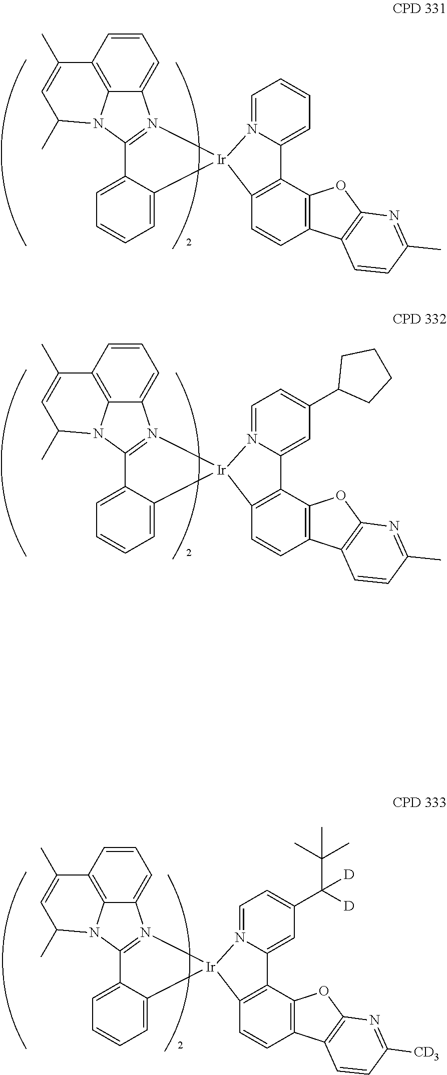

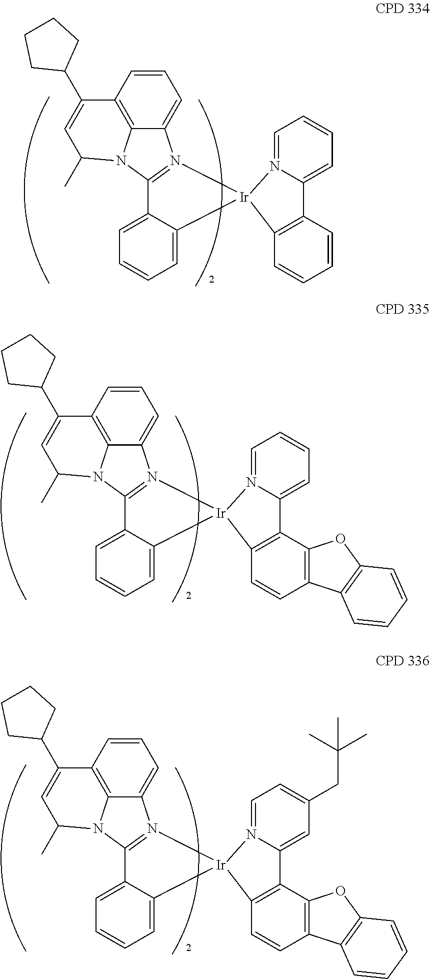

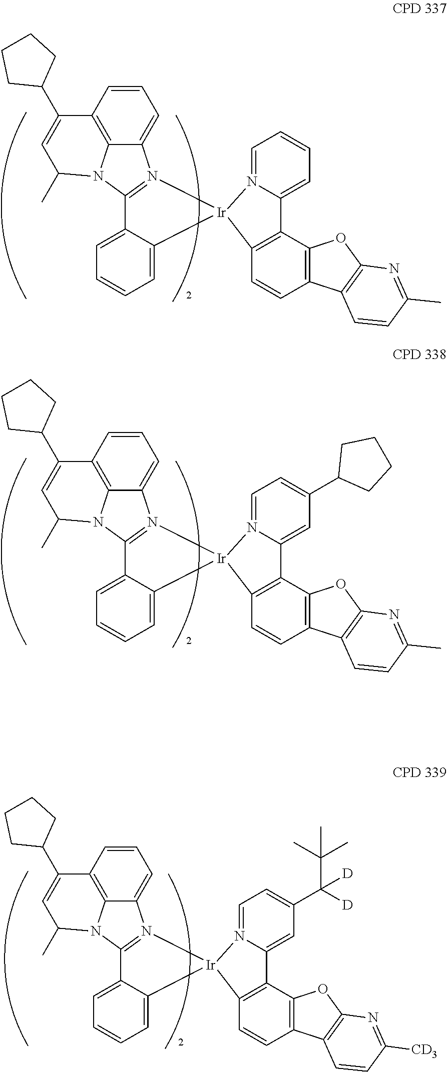

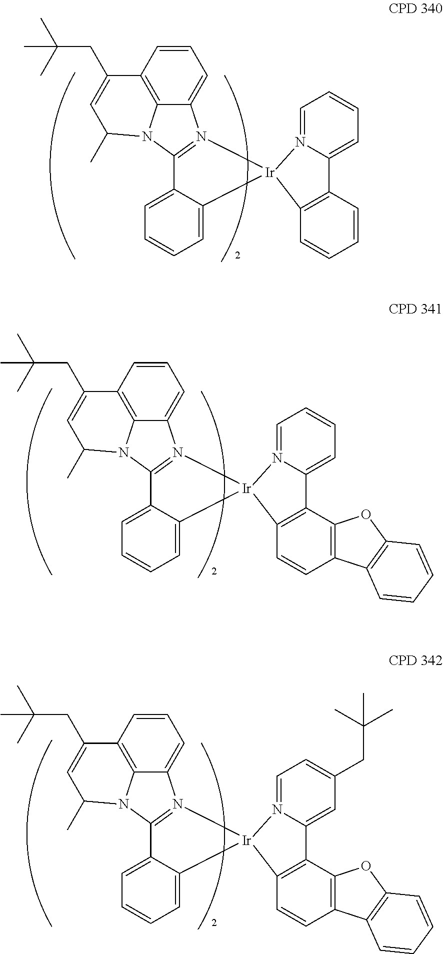

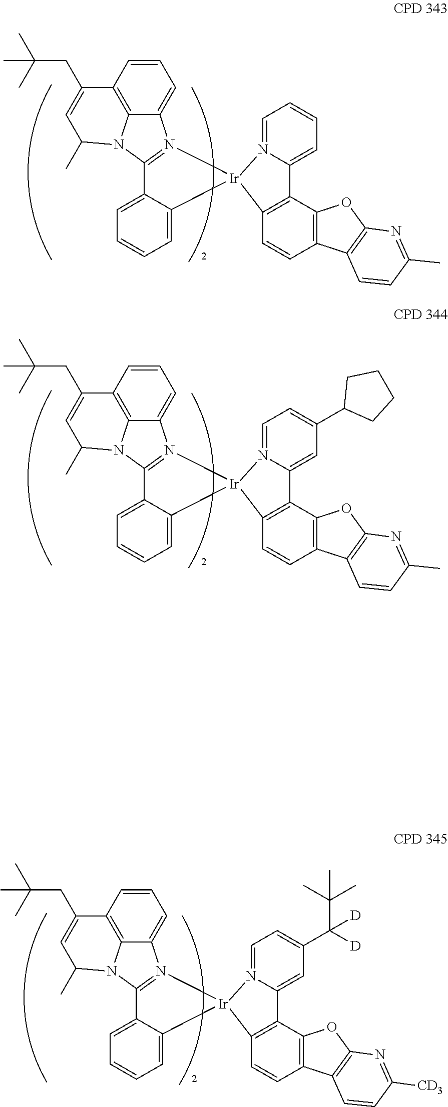

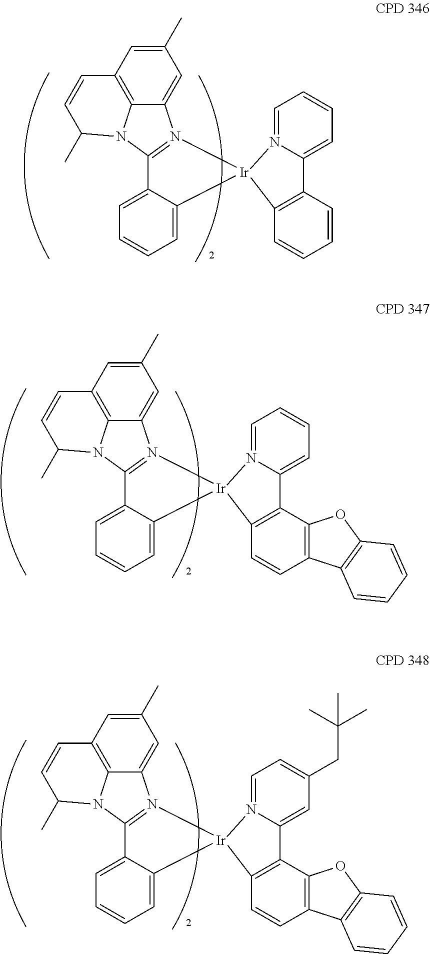

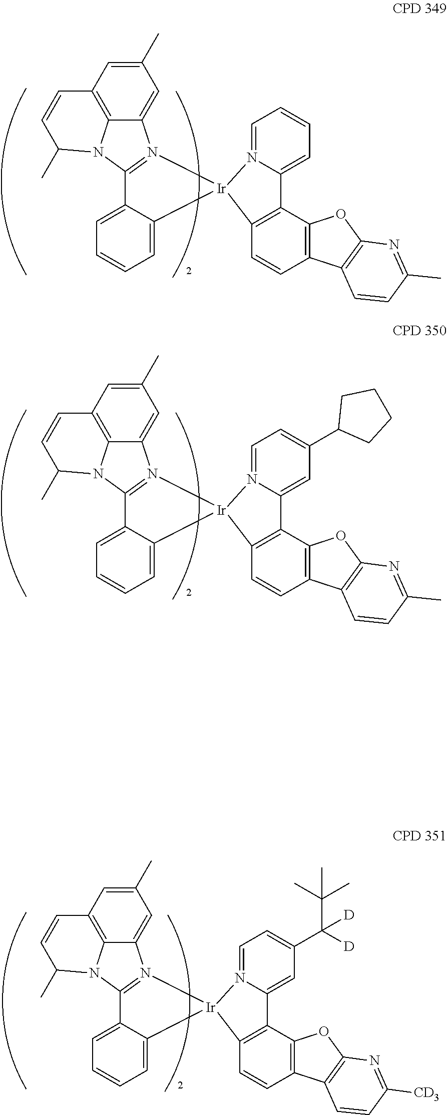

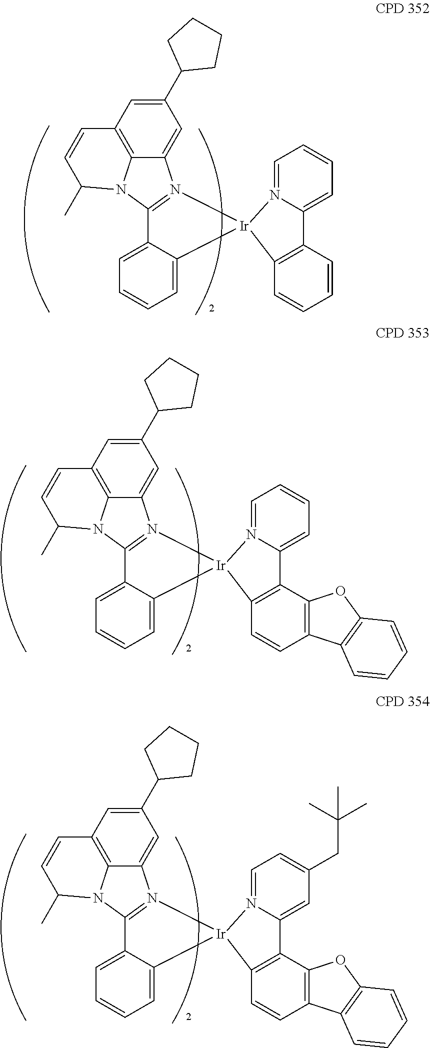

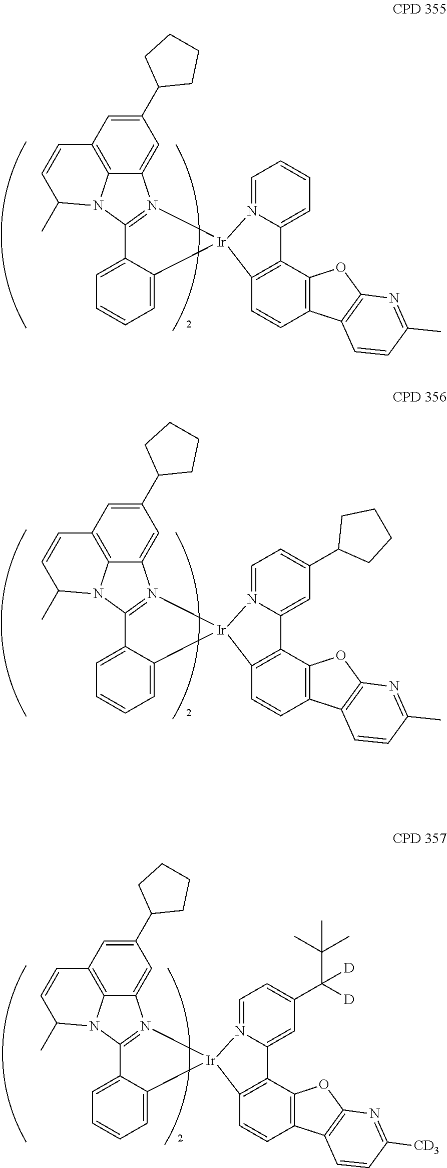

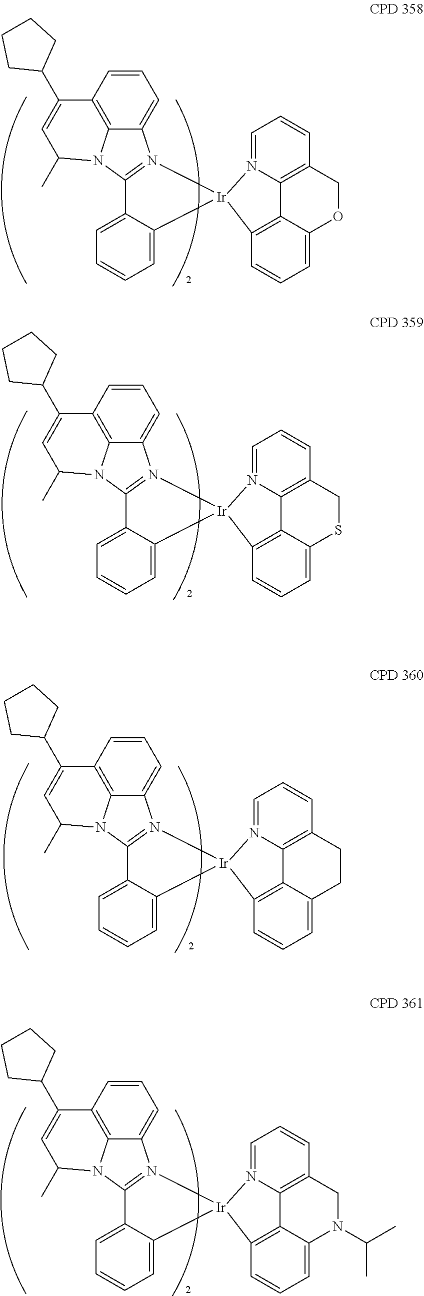

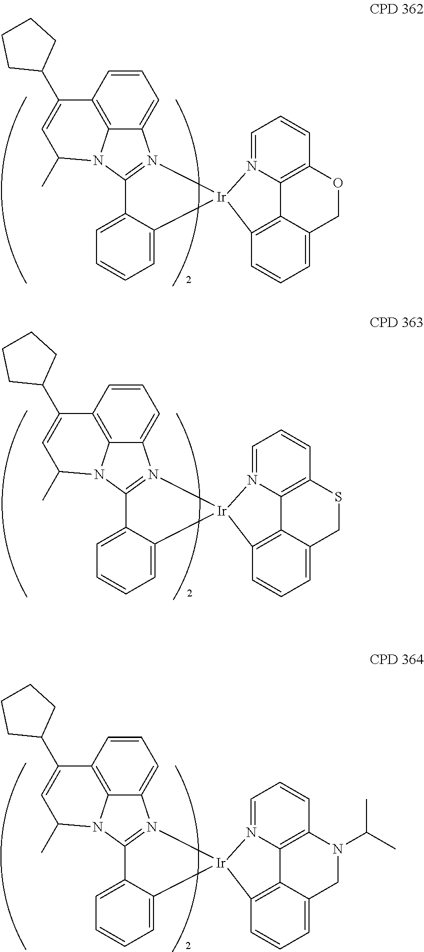

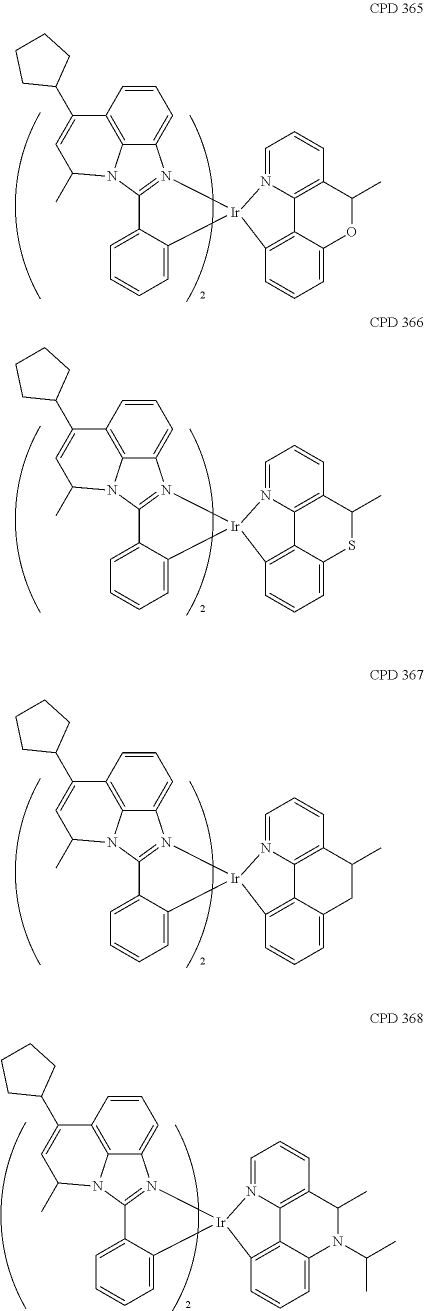

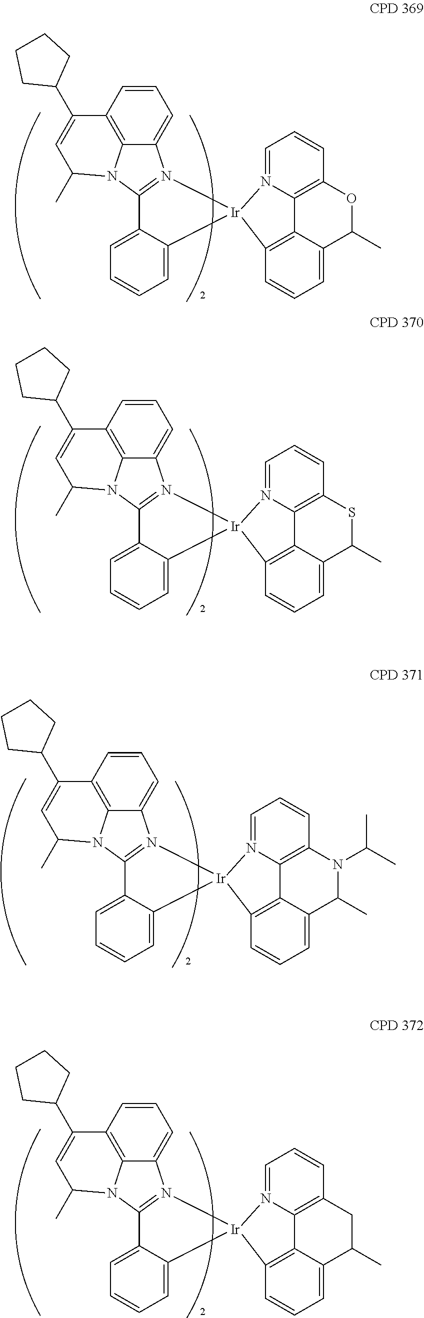

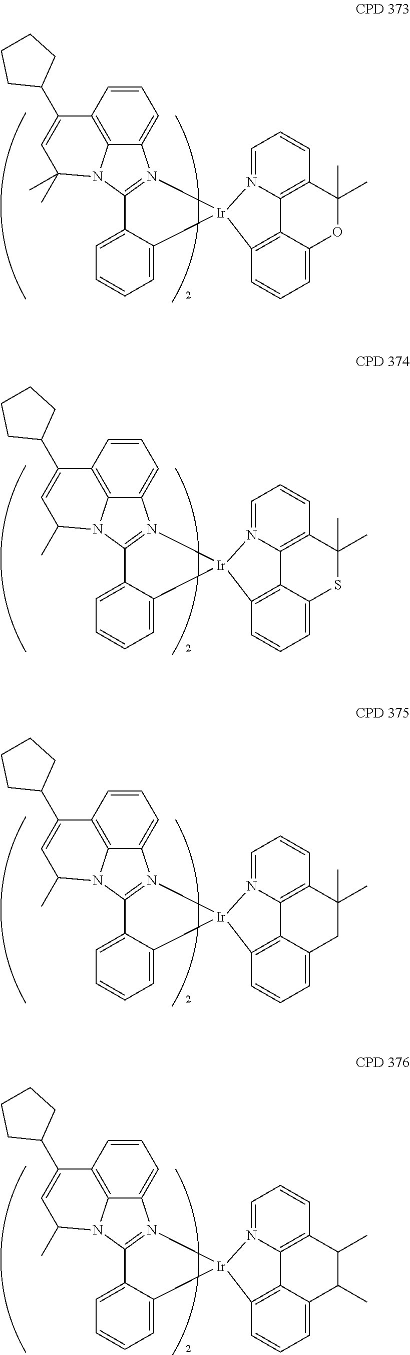

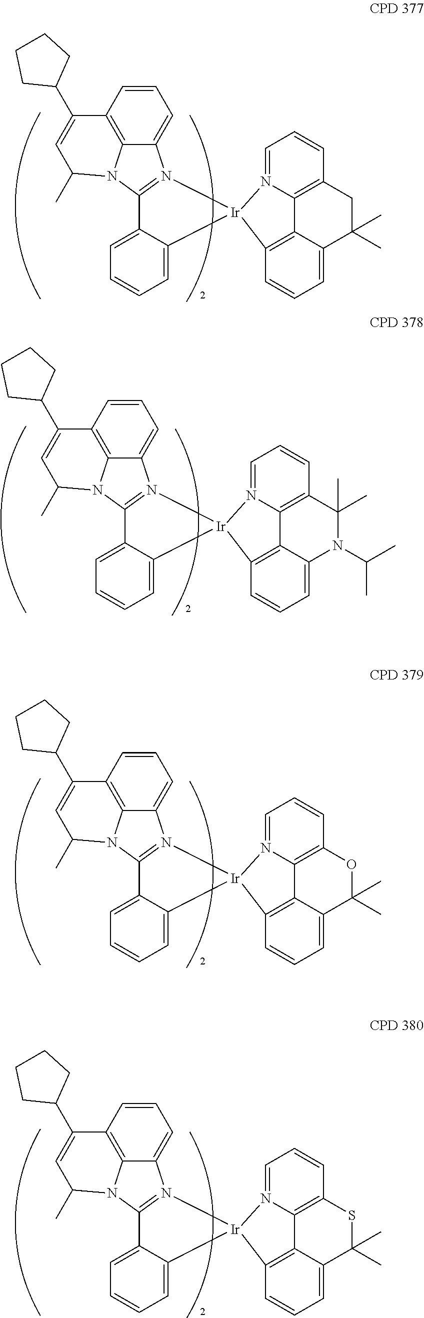

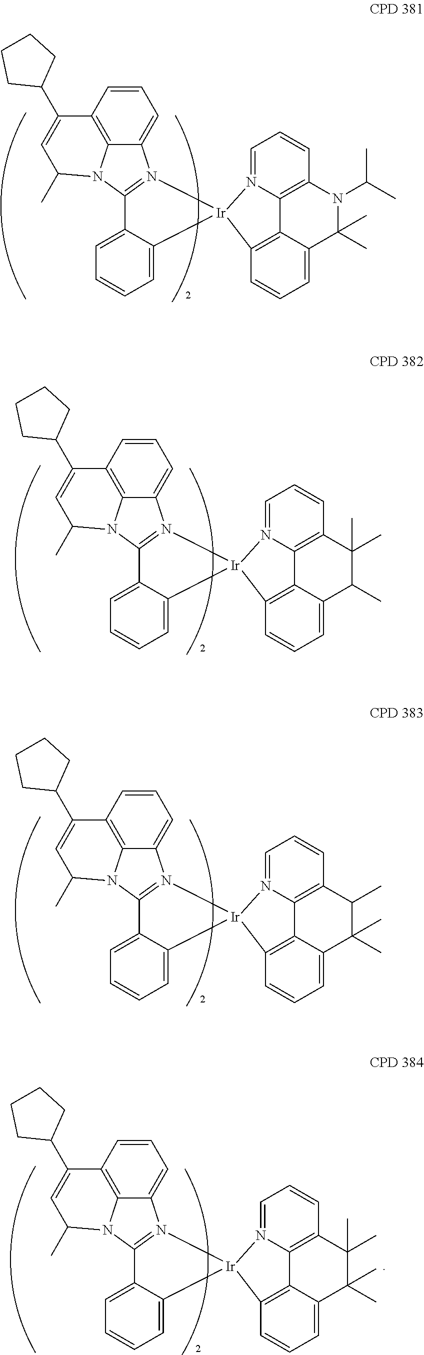

17. Application of the organometallic iridium compound according to any one of claims 1-16 in an organic electroluminescent device.

18. The application according to claim 17, wherein the organometallic iridium compound according to any one of claims 1-16 is used as a green light-emitting doping material for a light-emitting layer in the organic electroluminescent device.
